(19) United States
(12) Patent Application Publication
(10) Pub. No.: US 2026/0157108 A1
(43) Pub. Date: Jun. 4, 2026

(54) METAL IRIDIUM COMPLEX AND ORGANIC ELECTROLUMINESCENT DEVICE

(71) Applicant: GUANGDONG AGLAIA OPTOELECTRONIC MATERIALS CO., LTD, Guangdong (CN)

(72) Inventors: Shaofu CHEN, Guangdong (CN); Kangzhi YE, Guangdong (CN); Li WANG, Guangdong (CN); Lei DAI, Guangdong (CN); Lifei CAI, Guangdong (CN)

(73) Assignee: GUANGDONG AGLAIA OPTOELECTRONIC MATERIALS CO., LTD, Guangdong (CN)

(21) Appl. No.: 19/500,001

(22) PCT Filed: Apr. 16, 2024
(86) PCT No.: PCT/CN2024/087873

§ 371 Date: Jan. 7, 2026

(30) Foreign Application Priority Data
May 11, 2023 (CN) 202310528106.8
Mar. 18, 2024 (CN) 202410302084.8

(51) Int. Cl. H10K 85/30; C07F 15/00; C09K 11/06; H10K 50/12

(52) U.S. Cl. CPC H10K 85/342; C07F 15/0033; C09K 11/06; C09K 2211/1029; C09K 2211/1033; C09K 2211/1037; C09K 2211/1044; C09K 2211/185; H10K 50/12

(57) ABSTRACT

The present application relates to a metal iridium complex and an organic electroluminescent device. The metal iridium complex has a general formula of Ir(La)(Lb)(Lc), the structure thereof being shown as a formula (1). The metal iridium complex provided by the present application has the advantages of low evaporation deposition temperature, high optical and electrochemical stability, narrow half-peak width, high color saturation, high light-emitting efficiency, long device service life and the like. Therefore, the metal iridium complex can be used in organic light-emitting devices, particularly used as a red light-emitting phosphorescent material, and has the possibility of being applied to the AMOLED industry.

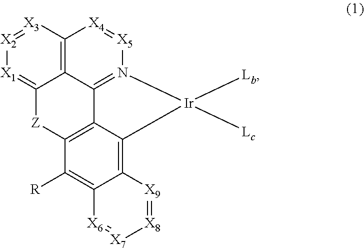

### CROSS-REFERENCE TO RELATED APPLICATIONS

This application is a national phase entry under 35 USC § 371 of International Application No. PCT/CN2024/087873 filed Apr. 16, 2024, which claims the benefit of and priority to Chinese Patent Application No. 202310528106.8, filed May 11, 2023, and Chinese Patent Application No. 202410302084.8, filed Mar. 18, 2024, the entire disclosures of which are incorporated herein by reference.

### TECHNICAL FIELD

The present disclosure relates to the technical field of organic electroluminescence, in particular, to organic luminescent materials, and more particularly, to a metal iridium complex and an organic electroluminescent device using the metal iridium complex.

### BACKGROUND

At present, organic electroluminescent devices (OLEDs), as a new generation of display technology, have been attracting increasing attention in display and illumination technologies, with extremely broad application prospects. However, compared with market application requirements, the luminous efficiency, driving voltage, service life and other performance of OLEDs in related technologies need to be further strengthened and improved.

Generally, a basic structure of an OLED consists of thin film layers of organic functional materials with various functions sandwiched between metal iridium electrodes, resembling a sandwich structure. Driven under an electric current, holes and electrons are injected from the anode and the cathode, respectively. After moving at a certain distance, the holes and the electrons are compounded on the light-emitting layer and are released in the form of light or heat, thereby generating illumination of the OLED.

However, the organic functional materials are the core compositions of the organic electroluminescent device, and their thermal stability, photochemical stability, electrochemical stability, quantum yield, film forming stability, crystallinity, color saturation, and other properties are all important factors affecting the performance of the device.

Generally, organic functional materials include fluorescent materials and phosphorescent materials. Fluorescent materials are usually small organic molecular materials, which can generally only utilize 25% singlet state to emit light, thus having relatively low luminescence efficiency. Whereas, due to spin-orbit coupling caused by the heavy-atom effect, phosphorescent materials can utilize the energy of 75% triplet excitons in addition to the 25% singlet excitons, thus enabling a significant improvement in luminous efficiency. However, compared with fluorescent materials, the research of phosphorescent materials started later, and their thermal stability, lifetime, color saturation, etc., all need to be improved, which is a challenging task. Various organometallic iridium compounds have been developed as such phosphorescent materials. For example, Invention patent document discloses a class of metal iridium complexes CN1589307A

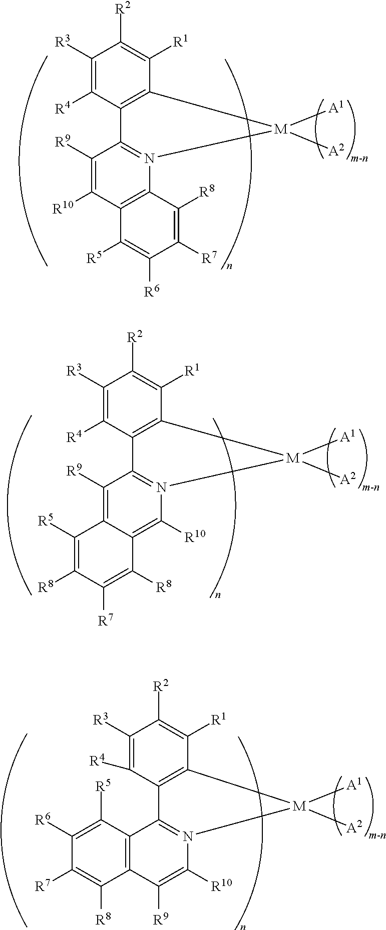

in which quinoline, isoquinoline and benzene ring-linked compounds are used as ligands, especially iridium complexes, which can provide a luminescence of 500-700 nm, and points out that the color of luminescence for compounds is adjusted upon selection of electron-donating or electron-withdrawing groups at specific positions. Invention patent document CN102627671B discloses an iridium compound

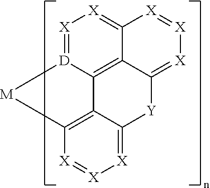

in which isoquinoline and phenyl groups are connected by an atom bridge, which can improve oxidation stability and obtain high thermal stability, thereby helping to improve device life. Invention patent document CN104885248B discloses an iridium complex

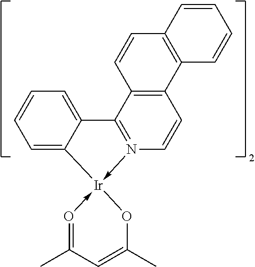

with phenyl groups linked to benzisoquinoline as ligands, in which the applicant points out that higher device efficiency and longer lifetime can be achieved by adjusting the combination and configuration of light-emitting layers. Invention patent document US20170012223A1 discloses an iridium complex

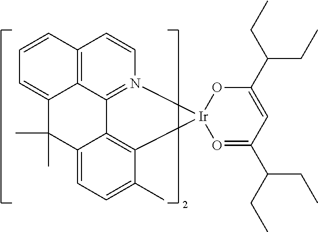

in which isoquinoline is connected to an alkyl-substituted benzene ring via a dimethyl bridge, however, the compound emits orange light, and the luminescent color does not meet the application requirements. Invention patent document US20220306666A1 reports an iridium complex

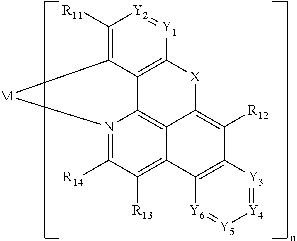

of benzisoquinoline bridged by a benzene ring, where this type of compound has a narrow full width at half maximum and good luminous efficiency, however, the luminescent light is orange-yellow, and the luminous color does not meet the application requirements. In addition, the device life also needs to be improved. Invention patents CN115260243A and CN114437134A disclose iridium complexes in which quinoline/isoquinoline is bridged to a naphthalene structure through an oxygen-like group, as well as organic electroluminescent devices and compounds

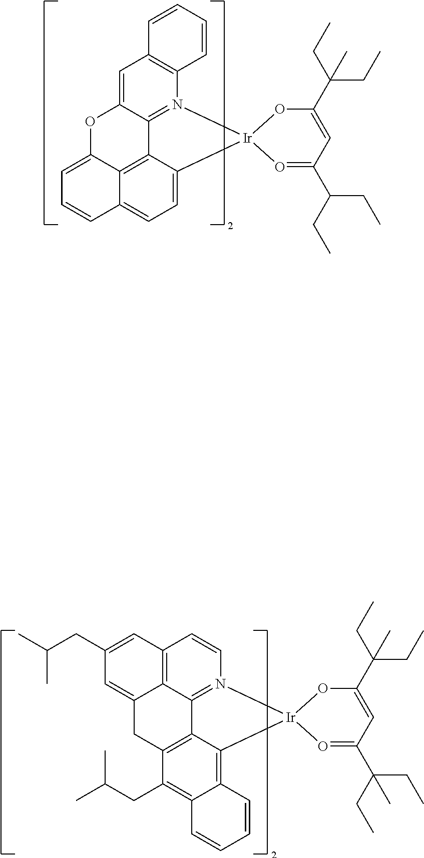

containing the complexes. These compounds have a narrow full width at half maximum, but the device efficiency and lifetime still need to be further improved to meet the growing market demand. Therefore, the applicant still hopes to further develop new materials that can improve the performance of organic electroluminescent devices.

### SUMMARY

The present disclosure has been completed to solve the above-mentioned issues, and an objective of the present disclosure is to provide a high-performance organic electroluminescent device and a novel material capable of realizing such an organic electroluminescent device.

To achieve the aforementioned objective, the present applicant has repeatedly conducted in-depth studies and as a result, found that a high-performance organic electroluminescent device can be obtained by using a metal iridium complex containing a structure represented by the following formula (1) as a ligand.

One of the objectives of the present disclosure is to provide a metal iridium complex, which has the advantages of high photochemical and electrochemical stability, narrow half width at half maximum, high color saturation, high luminous efficiency, and long device lifetime, and can be used in organic electroluminescent devices. Especially as a red light-emitting dopant, it has the potential to be applied in the OLED industry.

A metal iridium complex has a general formula of Ir(La)(Lb)(Lc), and includes a structural formula of formula (1),

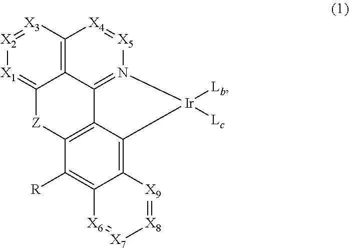

wherein

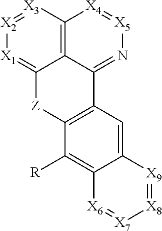

is a ligand La;
wherein Z is independently selected from CR_{A}R_{B}
wherein X₁-X₉ are each independently N or CR₀, and adjacent substituents R₀ are optionally connected to form a ring;
wherein X₁-X₅ have at least two adjacent CR₀ groups which can be connected to each other to form an aromatic ring with 6 to 30 carbon atoms or a heteroaromatic ring with 3 to 30 carbon atoms;
wherein R₀, R, R_{A}, and R_{B} are each independently selected from the group consisting of hydrogen, deuterium, halogen, a substituted or unsubstituted alkyl with 1 to 10 main-chain carbon atoms, a substituted or unsubstituted cycloalkyl with 3 to 20 ring-forming carbon atoms, a substituted or unsubstituted heteroalkyl with 1 to 10 main-chain carbon atoms, a substituted or unsubstituted heterocycloalkyl with 3 to 20 ring-forming carbon atoms, a substituted or unsubstituted C3-C30 alkylsilyl, a substituted or unsubstituted C3-C30 alkylgermyl, a substituted or unsubstituted C1-C10 alkoxy, a substituted or unsubstituted C7-C30 aralkyl, a substituted or unsubstituted C6-C30 aryloxy, a substituted or unsubstituted C2-C20 alkenyl, a substituted or unsubstituted C2-C20 alkynyl, a substituted or unsubstituted C6-C30 aryl, a substituted or unsubstituted C3-C30 heteroaryl, a substituted or unsubstituted C3-C30 arylsilyl, a substituted or unsubstituted C0-C20 alkylamino, cyano, isocyano, and phosphino;
wherein substituents in R₀, R, R_{A}, and R_{B} refer to being substituted with deuterium, F, Cl, Br, C1-C4 alkyl, C1-C4 alkoxy, C3-C6 cycloalkyl, C1-C4 alkyl-substituted amino, C6-C10 aryl, C1-C4 alkyl-substituted C6-C10 aryl, cyano, isocyano, or phosphino;
wherein a heteroatom in the heteroalkyl, heterocycloalkyl, heteroaromatic ring or heteroaryl group is at least one of S, O, Se, B, P, N, Si and Ge;
wherein Lb and Lc are each monoanionic bidentate ligands; alternatively, two of La, Lb and Lc are arbitrarily connected to each other to form a multidentate ligand, or La, Lb and Lc are connected through a single group; and
wherein the structural formula of Lb and/or Lc is represented by ligand La

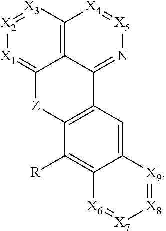

As for the metal iridium complex in some embodiments of the present disclosure, the ligand La has one of the structural formulas represented by formula (2) to formula (19) below:

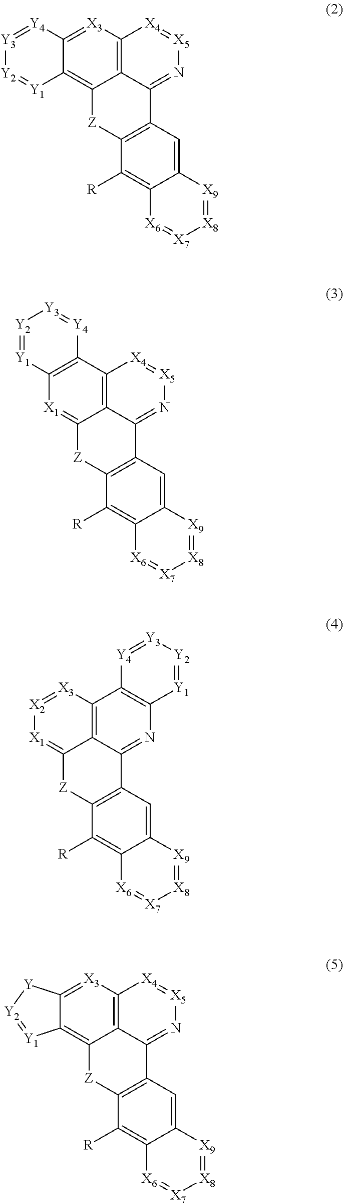

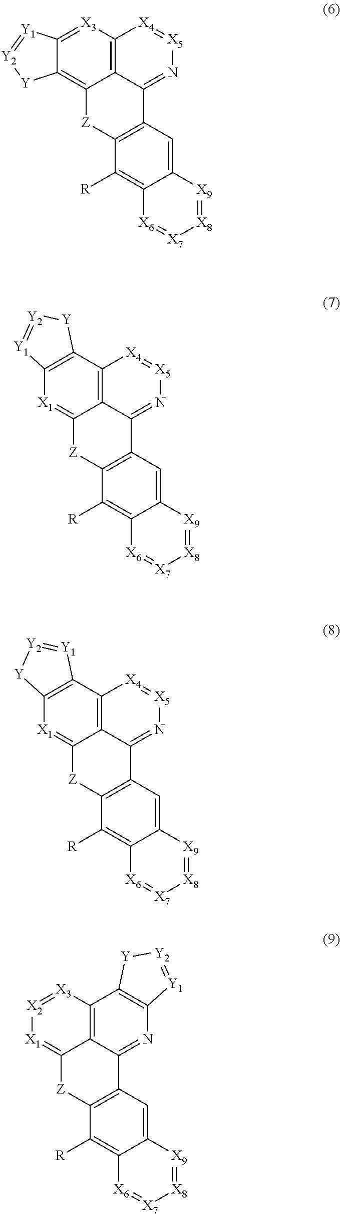

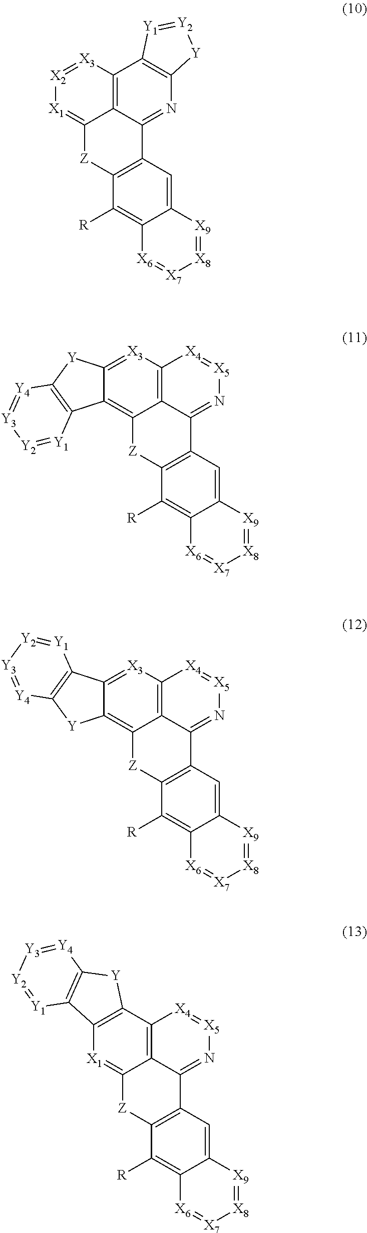

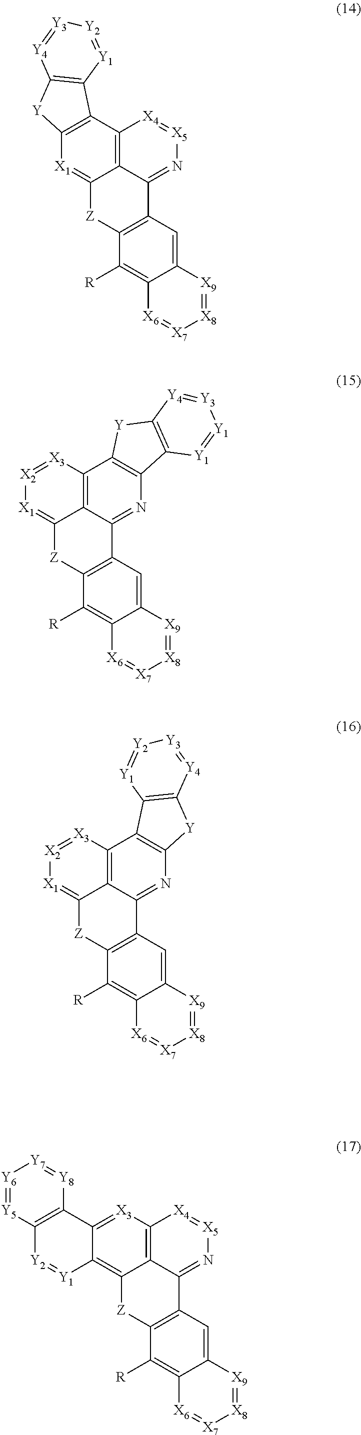

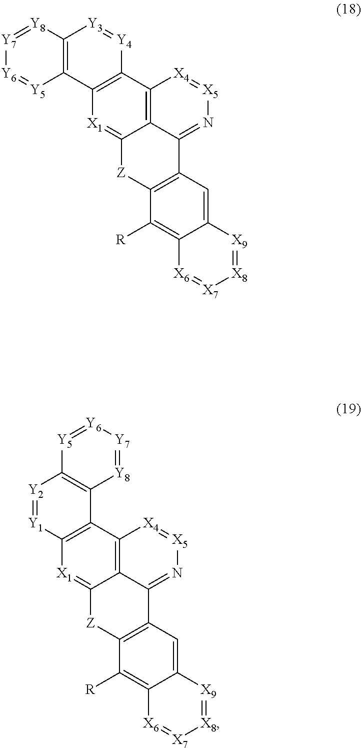

wherein Y is selected from the group consisting of O, S, Se, CR_{A}R_{B}, SiR_{A}R_{B}, GER_{A}R_{B}, NR_{A}R_{B}, BR_{A}R_{B}, and PR_{A}R_{B};
wherein Y₁-Y₈ are each independently N or CR₀; alternatively, adjacent substituents R₀ in CR₀ of Y₁-Y₈ are optionally connected to form a ring; and
wherein X₁-X₉, R₀, R, R_{A}, R_{B}, and Z are as defined above.

As for the metal iridium complex in some embodiments of the present disclosure, Lb has a structure shown in formula (21):

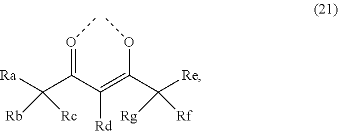

wherein a dotted line indicates a position connected to the metal iridium Ir; and
wherein Rₐ-R_{g} are each independently selected from the group consisting of hydrogen, deuterium, halogen, a substituted or unsubstituted alkyl with 1 to 10 main-chain carbon atoms, a substituted or unsubstituted cycloalkyl with 3 to 20 ring-forming carbon atoms, a substituted or unsubstituted heteroalkyl with 1 to 10 main-chain carbon atoms, and a substituted or unsubstituted heterocycloalkyl with 3 to 20 ring-forming carbon atoms; alternatively, two of Rₐ, R_{b}, and R_{c} are connected to form an alicyclic structure, and two of Rₑ, R_{f}, and R_{g} are connected to form an alicyclic structure; and wherein substituents in Rₐ-R_{g} each refers to being substituted with deuterium, F, Cl, Br, C1-C4 alkyl, C1-C4 alkoxy, C3-C6 cycloalkyl, C1-C4 alkyl-substituted amino, cyano, isocyano, or phosphino.

Rₐ, R_{b}, R_{c}, Rₑ, R_{f}, and R_{g} are each independently selected from the group consisting of hydrogen, deuterium, halogen, a substituted or unsubstituted alkyl with 1 to 10 main-chain carbon atoms, and a substituted or unsubstituted cycloalkyl with 3 to 20 ring carbon atoms; alternatively, two of Rₐ, R_{b}, and R_{c} are connected to each other to form an aliphatic ring structure, and two of Rₑ, R_{f}, and R_{g} are connected to each other to form an aliphatic ring structure; Rₐ is selected from the group consisting of hydrogen, deuterium, halogen, a substituted or unsubstituted alkyl with 1 to 10 main-chain carbon atoms, wherein substituents in Rₐ-R_{g} each refers to being substituted with deuterium, F, Cl, Br, C1-C4 alkyl, or C3-C6 cycloalkyl.

Rₐ, R_{b}, and R_{c} are the same as Rₑ, R_{f}, and R_{g}, respectively.

As for the metal iridium complex in some embodiments of the present disclosure, R is selected from the group consisting of alkyl with 1 to 10 carbon atoms, a substituted or unsubstituted cycloalkyl with 3 to 20 ring-forming carbon atoms, a substituted or unsubstituted C3-C30 alkylsilyl, and a substituted or unsubstituted C3-C30 alkylgermyl.

As for the metal iridium complex in some embodiments of the present disclosure, the ligand La has the following structural formula (22):

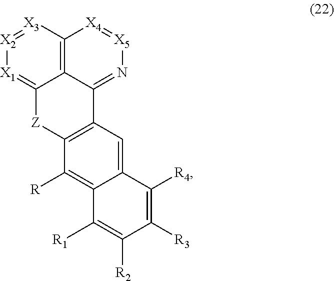

wherein X₁-X₅, R₀, R, and Z are as defined above; R₁-R₄ are each independently selected from the group consisting of hydrogen, deuterium, halogen, a substituted or unsubstituted alkyl with 1 to 10 main-chain carbon atoms, a substituted or unsubstituted cycloalkyl with 3 to 20 ring-forming carbon atoms, a substituted or unsubstituted heteroalkyl with 1 to 10 main-chain carbon atoms, a substituted or unsubstituted heterocycloalkyl with 3 to 20 ring-forming carbon atoms, a substituted or unsubstituted C3-C30 alkylsilyl, a substituted or unsubstituted C1-C10 alkoxy, a substituted or unsubstituted C7-C30 aralkyl, a substituted or unsubstituted C6-C30 aryloxy, a substituted or unsubstituted C6-C30 aryl, a substituted or unsubstituted C3-C30 heteroaryl, a substituted or unsubstituted C3-C30 arylsilyl, a substituted or unsubstituted C0-C20 alkylamino, cyano, isocyano, and phosphino; adjacent substituents in R₁-R₄ are optionally connected to form a ring, and substituents in R₁-R₄ refer to being substituted with deuterium, F, Cl, Br, C1-C4 alkyl, C1-C4 alkoxy, C3-C6 cycloalkyl, C1-C4 alkyl-substituted amino, C6-C10 aryl, C1-C4 alkyl-substituted C6-C10 aryl, cyano, or isocyano.

As for the metal iridium complex in some embodiments of the present disclosure, the ligand La has one of the following structural formula (23)-formula (24):

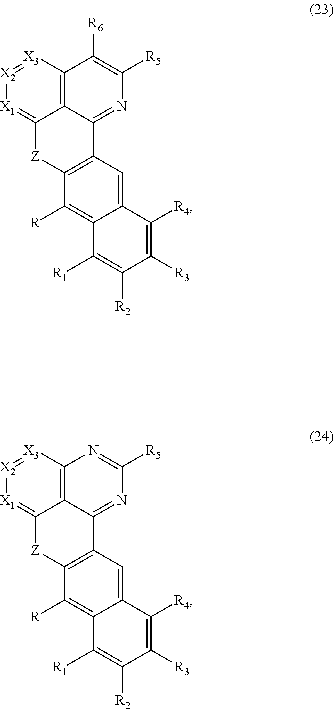

wherein X₁-X₃ are each independently N or CR₀, and two adjacent CR₀ groups among X₁-X₃ may be connected to each other to form an aromatic ring with 6 to 30 carbon atoms or a heteroaromatic ring with 3 to 30 carbon atoms; and
wherein R₀, R, and Z are as defined above; R₁-R₆ are each independently selected from the group consisting of hydrogen, deuterium, halogen, a substituted or unsubstituted alkyl with 1 to 8 main-chain carbon atoms, a substituted or unsubstituted cycloalkyl with 3 to 10 ring-forming carbon atoms, a substituted or unsubstituted heteroalkyl with 1 to 8 main-chain carbon atoms, a substituted or unsubstituted heterocycloalkyl with 3 to 10 ring-forming carbon atoms, a substituted or unsubstituted C3-C20 alkylsilyl, a substituted or unsubstituted C1-C8 alkoxy, a substituted or unsubstituted C7-C20 aralkyl, a substituted or unsubstituted C6-C20 aryloxy, a substituted or unsubstituted C6-C20 aryl, a substituted or unsubstituted C3-C20 heteroaryl, a substituted or unsubstituted C3-C20 arylsilyl, a substituted or unsubstituted C0-C10 alkylamino, cyano, isocyano, and phosphino; alternatively, adjacent substituents in R₁-R₄, R₅-R₆ are optionally connected to form a ring, wherein substituents in R₁-R₆ refer to being substituted with deuterium, F, Cl, Br, C1-C4 alkyl, C1-C4 alkoxy, C3-C6 cycloalkyl, C1-C4 alkyl-substituted amino, C6-C10 aryl, C1-C4 alkyl-substituted C6-C10 aryl, cyano, or isocyano.

In the metal iridium complex according to some embodiments of the present disclosure, in the ligand La, X₁-X₃ are each independently N or CR₀; Z is independently selected from CR_{A}R_{B}; R, R_{A}, R_{B}, and R₁-R₆ are each independently selected from the group consisting of hydrogen, deuterium, halogen, a substituted or unsubstituted alkyl with 1 to 10 main-chain carbon atoms, a substituted or unsubstituted cycloalkyl with 3 to 20 ring-forming carbon atoms, a substituted or unsubstituted heteroalkyl with 1 to 10 main-chain carbon atoms, a substituted or unsubstituted heterocycloalkyl with 3 to 20 ring-forming carbon atoms, a substituted or unsubstituted C3-C30 alkylsilyl, a substituted or unsubstituted C7-C30 aralkyl, and a substituted or unsubstituted C6-C30 aryloxy; two adjacent CR₀ groups are connected to each other to form an aromatic ring with 6 to 30 carbon atoms or a heteroaromatic ring with 3 to 30 carbon atoms, or R₅-R₆ are connected to each other to form an aromatic ring with 6 to 30 carbon atoms or a heteroaromatic ring with 3 to 30 carbon atoms.

In the metal iridium complex according to some embodiments of the present disclosure, Lc and La have a same structure, and are formed a structure of (La)₂Ir(Lb).

As for the metal iridium complex in some embodiments of the present disclosure, La is independently selected from one of the following structural formulas, or one of the following structural formulas in which the hydrogen atom(s) is/are partially or completely deuterated, or one of the following structural formulas in which the hydrogen atom(s) is/are partially or completely fluorinated:

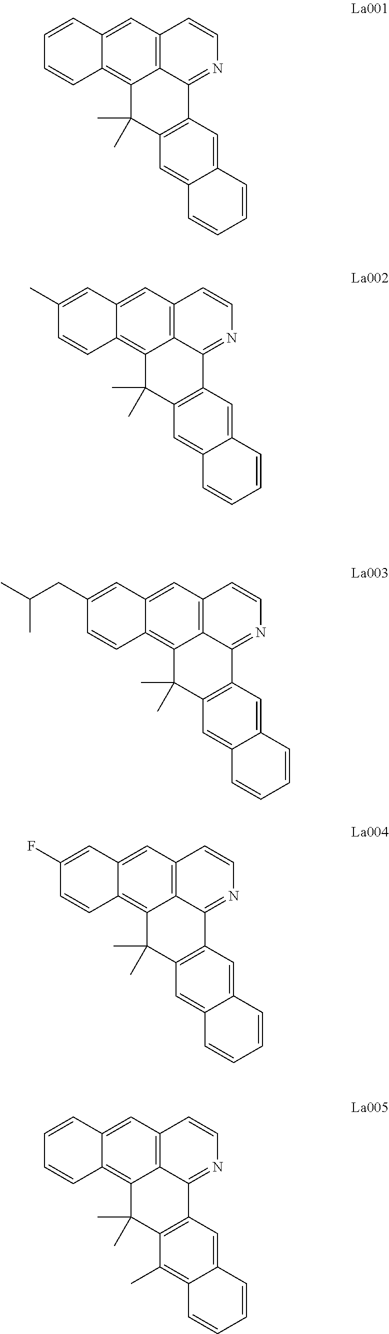 [SMILES: CC1(C)c2cc3ccccc3cc2-c2nccc3cc4ccccc4c1c23 ; Cc1ccc2c3c4c(nccc4cc2c1)-c1cc2ccccc2cc1C3(C)C ; CC(C)Cc1ccc2c3c4c(nccc4cc2c1)-c1cc2ccccc2cc1C3(C)C ; CC1(C)c2cc3ccccc3cc2-c2nccc3cc4cc(F)ccc4c1c23 ; Cc1c2c(cc3ccccc13)-c1nccc3cc4ccccc4c(c13)C2(C)C]

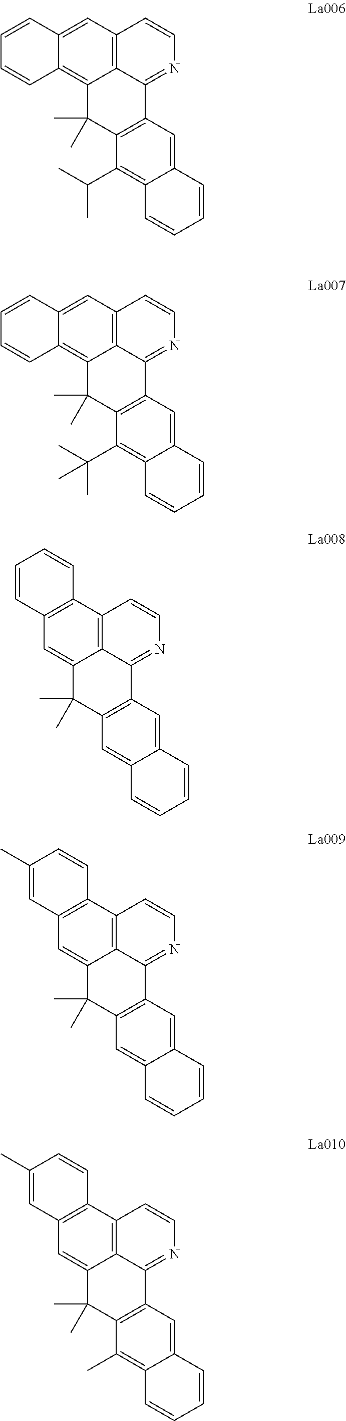 [SMILES: CC(C)c1c2c(cc3ccccc13)-c1nccc3cc4ccccc4c(c13)C2(C)C ; CC(C)(C)c1c2c(cc3ccccc13)-c1nccc3cc4ccccc4c(c13)C2(C)C ; CC1(C)c2cc3ccccc3cc2-c2nccc3c2c1cc1ccccc13 ; Cc1ccc2c(c1)cc1c3c(nccc32)-c2cc3ccccc3cc2C1(C)C ; Cc1ccc2c(c1)cc1c3c(nccc32)-c2cc3ccccc3c(C)c2C1(C)C]

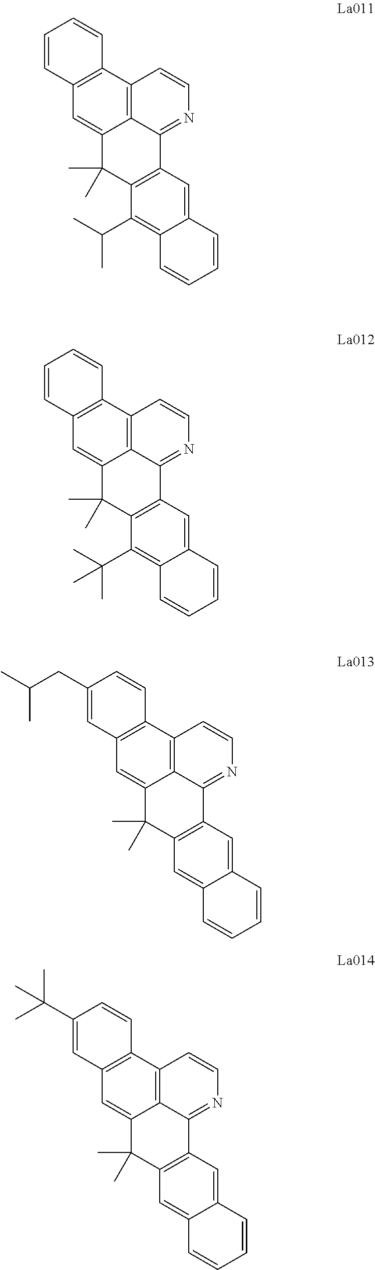 [SMILES: CC(C)c1c2c(cc3ccccc13)-c1nccc3c1c(cc1ccccc13)C2(C)C ; CC(C)(C)c1c2c(cc3ccccc13)-c1nccc3c1c(cc1ccccc13)C2(C)C ; CC(C)Cc1ccc2c(c1)cc1c3c(nccc32)-c2cc3ccccc3cc2C1(C)C ; CC(C)(C)c1ccc2c(c1)cc1c3c(nccc32)-c2cc3ccccc3cc2C1(C)C]

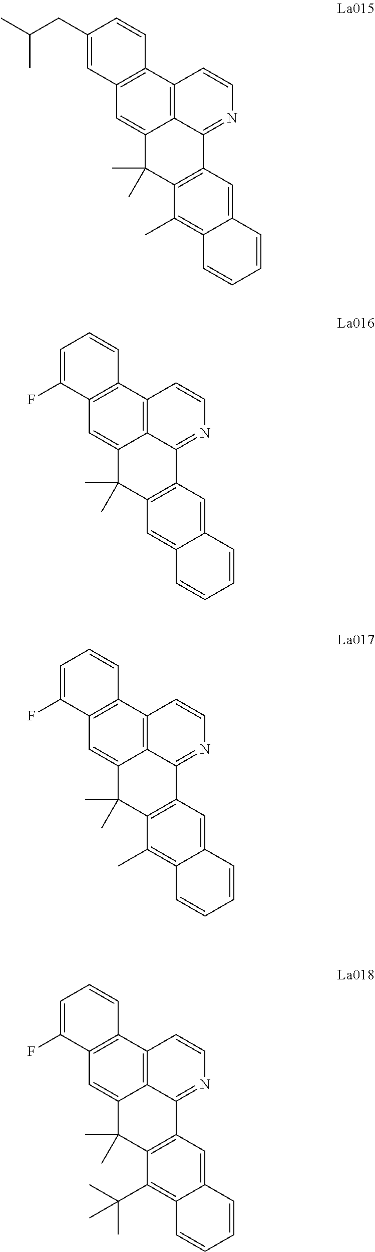 [SMILES: Cc1c2c(cc3ccccc13)-c1nccc3c1c(cc1cc(CC(C)C)ccc13)C2(C)C ; CC1(C)c2cc3ccccc3cc2-c2nccc3c2c1cc1c(F)cccc13 ; Cc1c2c(cc3ccccc13)-c1nccc3c1c(cc1c(F)cccc13)C2(C)C ; CC(C)(C)c1c2c(cc3ccccc13)-c1nccc3c1c(cc1c(F)cccc13)C2(C)C]

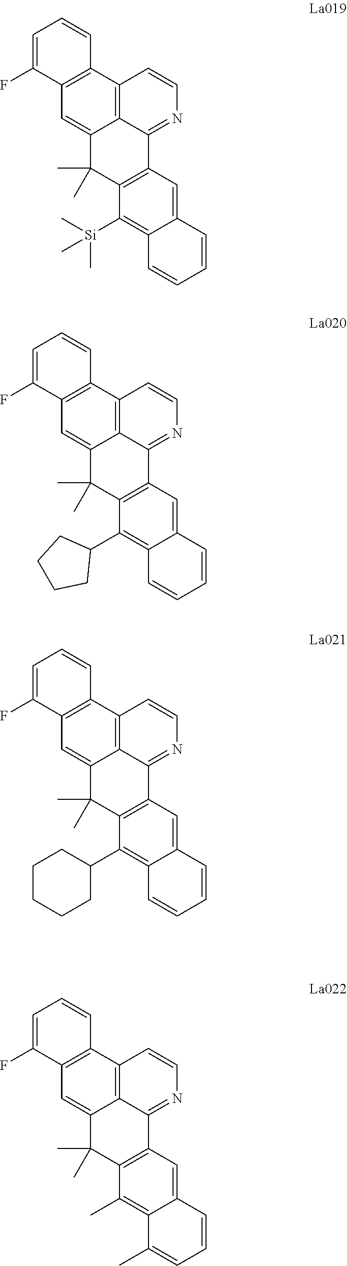 [SMILES: CC1(C)c2c(cc3ccccc3c2[Si](C)(C)C)-c2nccc3c2c1cc1c(F)cccc13 ; CC1(C)c2c(cc3ccccc3c2C2CCCC2)-c2nccc3c2c1cc1c(F)cccc13 ; CC1(C)c2c(cc3ccccc3c2C2CCCCC2)-c2nccc3c2c1cc1c(F)cccc13 ; Cc1cccc2cc3c(c(C)c12)C(C)(C)c1cc2c(F)cccc2c2ccnc-3c12]

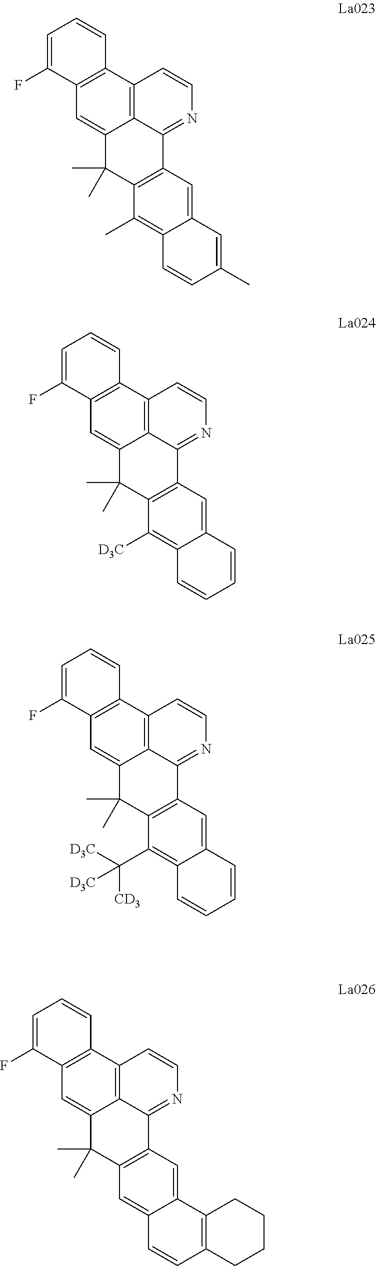 [SMILES: Cc1ccc2c(C)c3c(cc2c1)-c1nccc2c1c(cc1c(F)cccc12)C3(C)C ; [2H]C([2H])([2H])c1c2c(cc3ccccc13)-c1nccc3c1c(cc1c(F)cccc13)C2(C)C ; [2H]C([2H])([2H])C(c1c2c(cc3ccccc13)-c1nccc3c1c(cc1c(F)cccc13)C2(C)C)(C([2H])([2H])[2H])C([2H])([2H])[2H] ; CC1(C)c2cc3ccc4c(c3cc2-c2nccc3c2c1cc1c(F)cccc13)CCCC4]

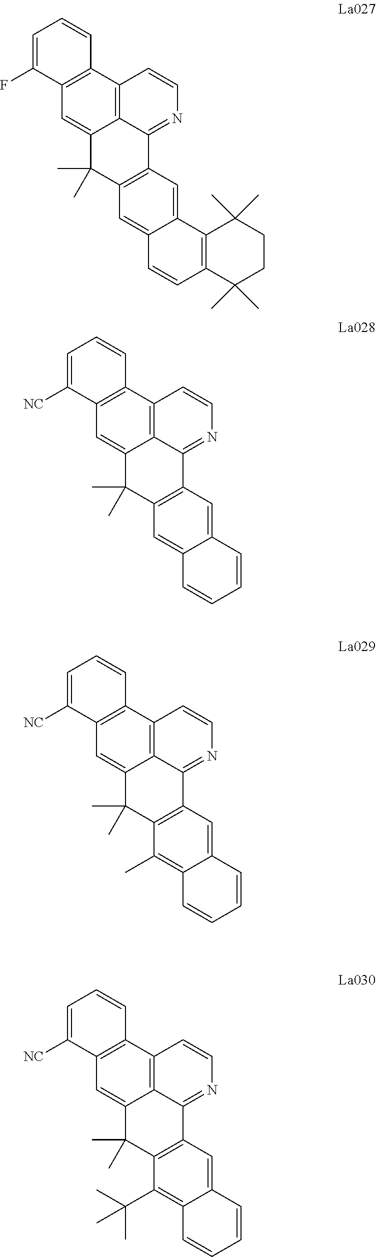 [SMILES: CC1(C)CCC(C)(C)c2c1ccc1cc3c(cc21)-c1nccc2c1c(cc1c(F)cccc12)C3(C)C ; CC1(C)c2cc3ccccc3cc2-c2nccc3c2c1cc1c(C#N)cccc13 ; Cc1c2c(cc3ccccc13)-c1nccc3c1c(cc1c(C#N)cccc13)C2(C)C ; CC(C)(C)c1c2c(cc3ccccc13)-c1nccc3c1c(cc1c(C#N)cccc13)C2(C)C]

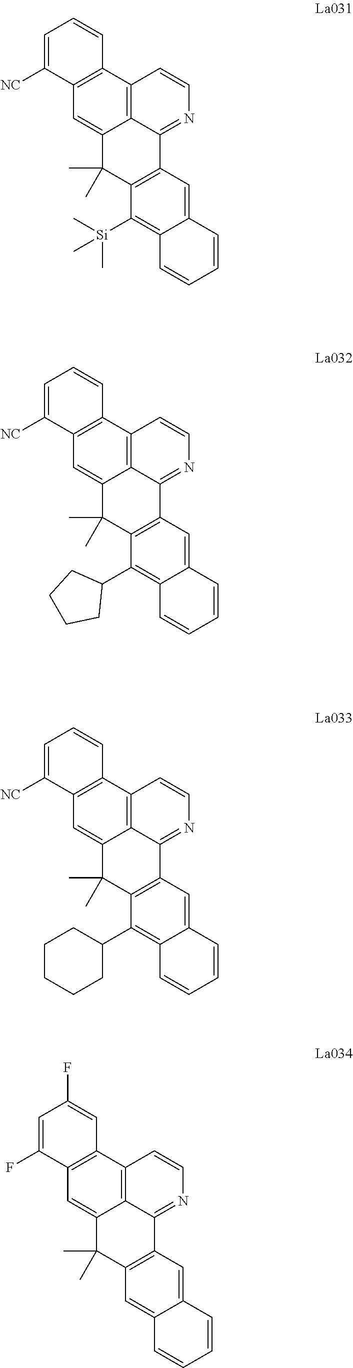 [SMILES: CC1(C)c2c(cc3ccccc3c2[Si](C)(C)C)-c2nccc3c2c1cc1c(C#N)cccc13 ; CC1(C)c2c(cc3ccccc3c2C2CCCC2)-c2nccc3c2c1cc1c(C#N)cccc13 ; CC1(C)c2c(cc3ccccc3c2C2CCCCC2)-c2nccc3c2c1cc1c(C#N)cccc13 ; CC1(C)c2cc3ccccc3cc2-c2nccc3c2c1cc1c(F)cc(F)cc13]

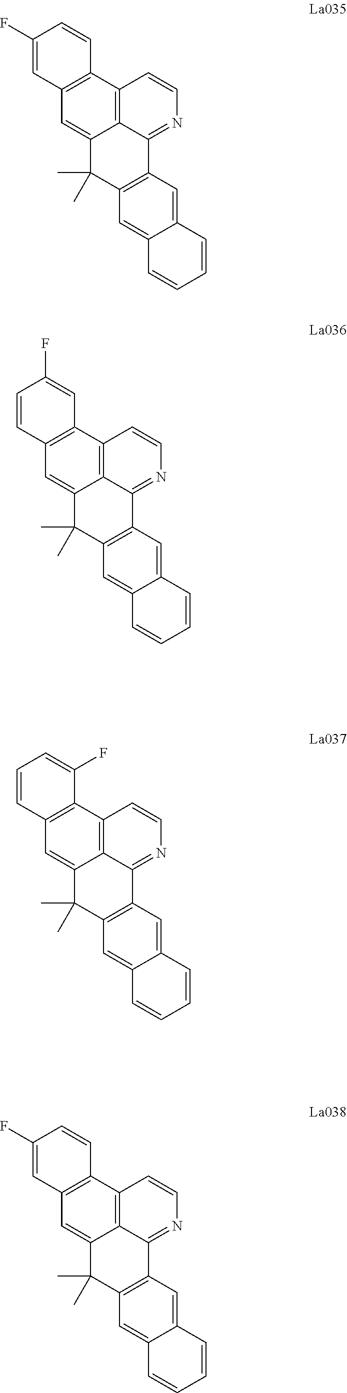 [SMILES: CC1(C)c2cc3ccccc3cc2-c2nccc3c2c1cc1cc(F)ccc13 ; CC1(C)c2cc3ccccc3cc2-c2nccc3c2c1cc1ccc(F)cc13 ; CC1(C)c2cc3ccccc3cc2-c2nccc3c2c1cc1cccc(F)c13 ; CC1(C)c2cc3ccccc3cc2-c2nccc3c2c1cc1cc(F)ccc13]

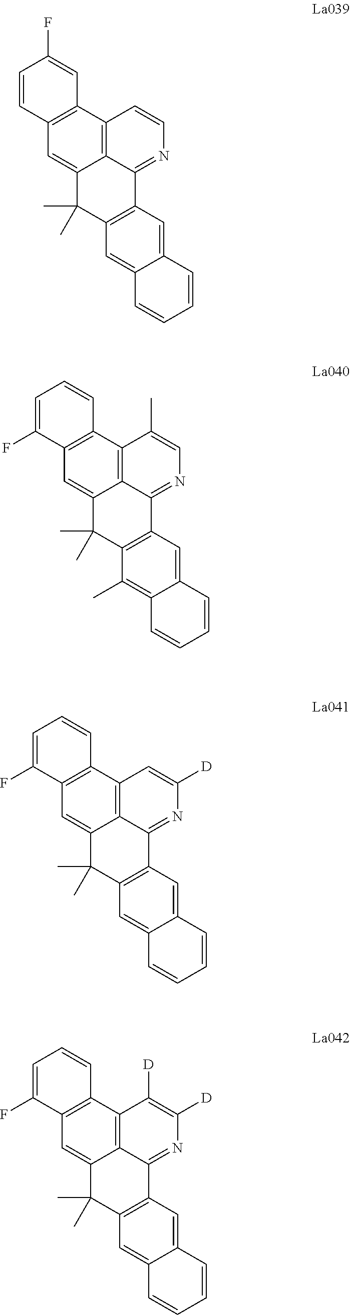 [SMILES: CC1(C)c2cc3ccccc3cc2-c2nccc3c2c1cc1ccc(F)cc13 ; Cc1c2c(cc3ccccc13)-c1ncc(C)c3c1c(cc1c(F)cccc13)C2(C)C ; [2H]c1cc2c3c(cc4c(F)cccc42)C(C)(C)c2cc4ccccc4cc2-c3n1 ; [2H]c1nc2c3c(cc4c(F)cccc4c3c1[2H])C(C)(C)c1cc3ccccc3cc1-2]

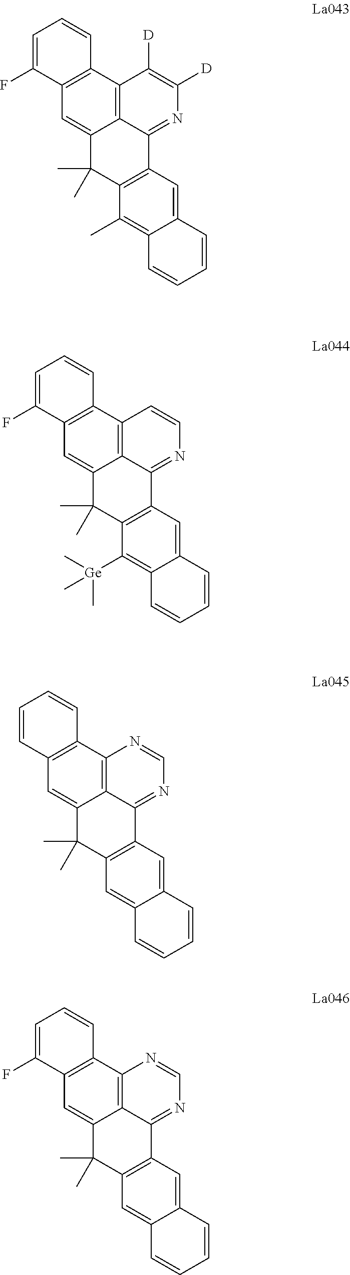

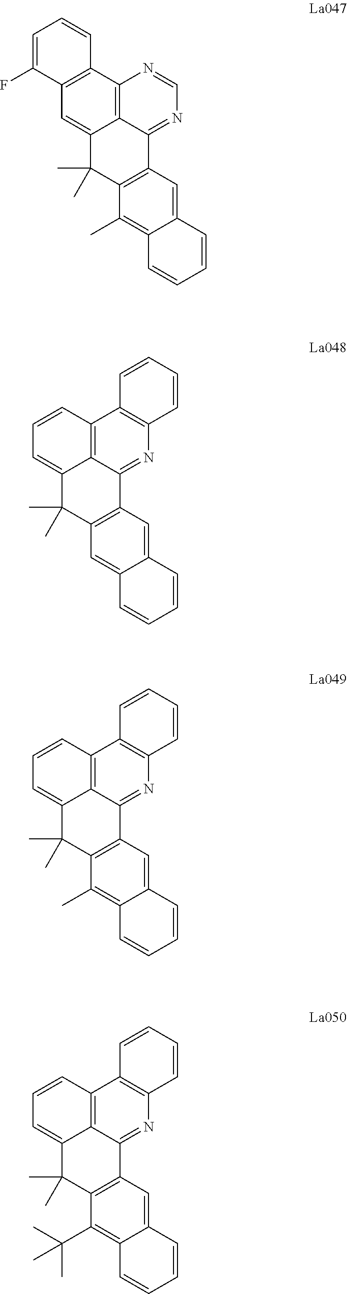 [SMILES: Cc1c2c(cc3ccccc13)-c1ncnc3c1c(cc1c(F)cccc13)C2(C)C ; CC1(C)c2cc3ccccc3cc2-c2nc3ccccc3c3cccc1c23 ; Cc1c2c(cc3ccccc13)-c1nc3ccccc3c3cccc(c13)C2(C)C ; CC(C)(C)c1c2c(cc3ccccc13)-c1nc3ccccc3c3cccc(c13)C2(C)C]

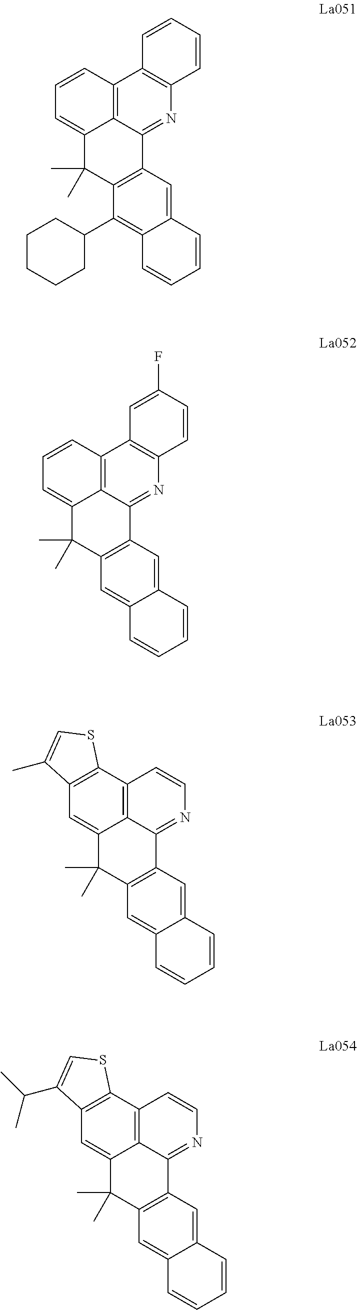 [SMILES: CC1(C)c2c(cc3ccccc3c2C2CCCCC2)-c2nc3ccccc3c3cccc1c23 ; CC1(C)c2cc3ccccc3cc2-c2nc3ccc(F)cc3c3cccc1c23 ; Cc1csc2c1cc1c3c(nccc32)-c2cc3ccccc3cc2C1(C)C ; CC(C)c1csc2c1cc1c3c(nccc32)-c2cc3ccccc3cc2C1(C)C]

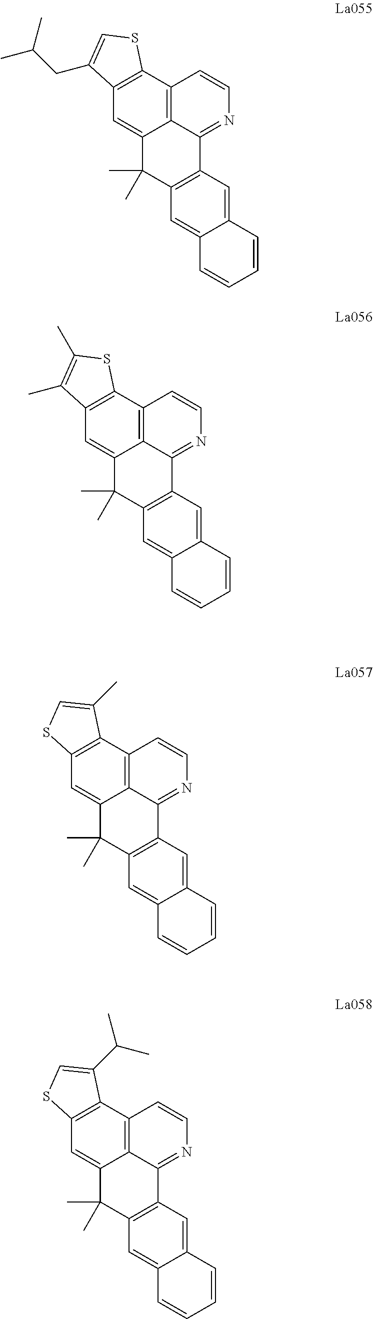 [SMILES: CC(C)Cc1csc2c1cc1c3c(nccc32)-c2cc3ccccc3cc2C1(C)C ; Cc1sc2c(cc3c4c(nccc42)-c2cc4ccccc4cc2C3(C)C)c1C ; Cc1csc2cc3c4c(nccc4c12)-c1cc2ccccc2cc1C3(C)C ; CC(C)c1csc2cc3c4c(nccc4c12)-c1cc2ccccc2cc1C3(C)C]

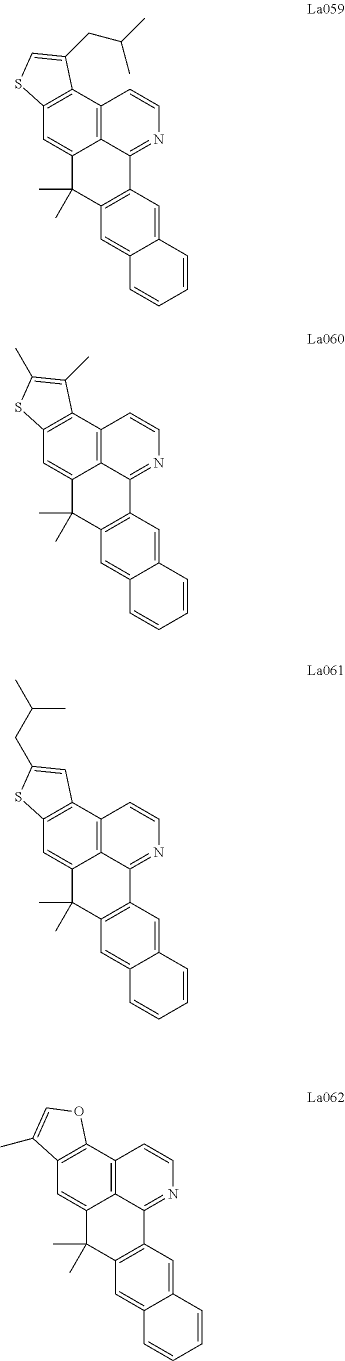 [SMILES: CC(C)Cc1csc2cc3c4c(nccc4c12)-c1cc2ccccc2cc1C3(C)C ; Cc1sc2cc3c4c(nccc4c2c1C)-c1cc2ccccc2cc1C3(C)C ; CC(C)Cc1cc2c(cc3c4c(nccc42)-c2cc4ccccc4cc2C3(C)C)s1 ; Cc1coc2c1cc1c3c(nccc32)-c2cc3ccccc3cc2C1(C)C]

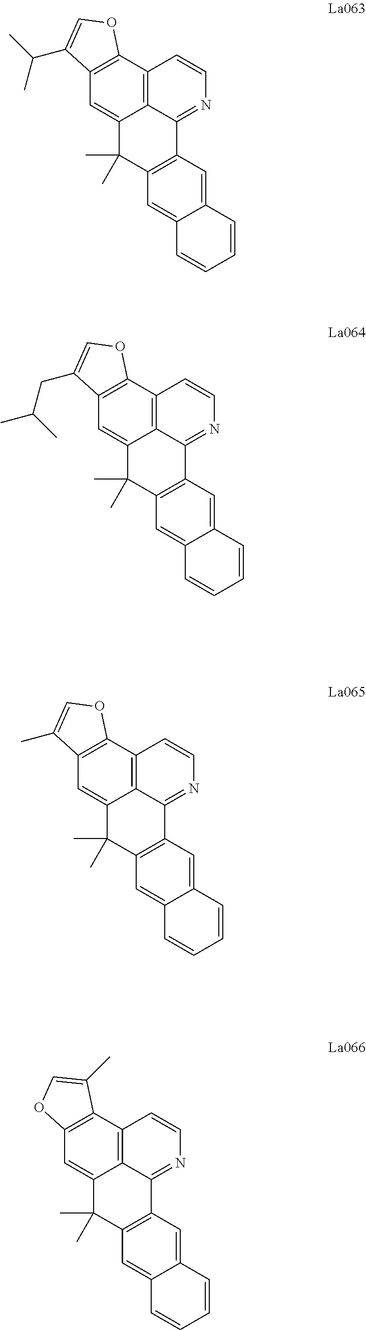 [SMILES: CC(C)c1coc2c1cc1c3c(nccc32)-c2cc3ccccc3cc2C1(C)C ; CC(C)Cc1coc2c1cc1c3c(nccc32)-c2cc3ccccc3cc2C1(C)C ; Cc1coc2c1cc1c3c(nccc32)-c2cc3ccccc3cc2C1(C)C ; Cc1coc2cc3c4c(nccc4c12)-c1cc2ccccc2cc1C3(C)C]

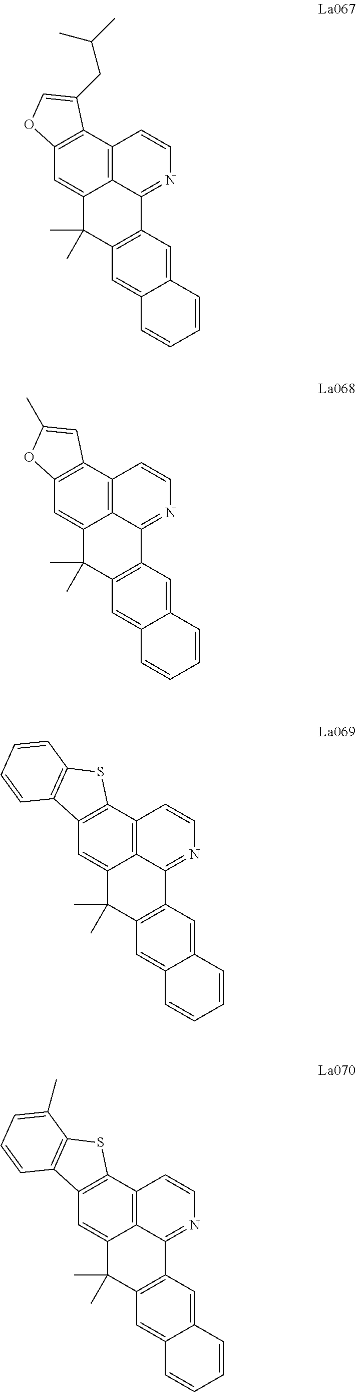 [SMILES: CC(C)Cc1coc2cc3c4c(nccc4c12)-c1cc2ccccc2cc1C3(C)C ; Cc1cc2c(cc3c4c(nccc42)-c2cc4ccccc4cc2C3(C)C)o1 ; CC1(C)c2cc3ccccc3cc2-c2nccc3c2c1cc1c2ccccc2sc31 ; Cc1cccc2c1sc1c3ccnc4c3c(cc21)C(C)(C)c1cc2ccccc2cc1-4]

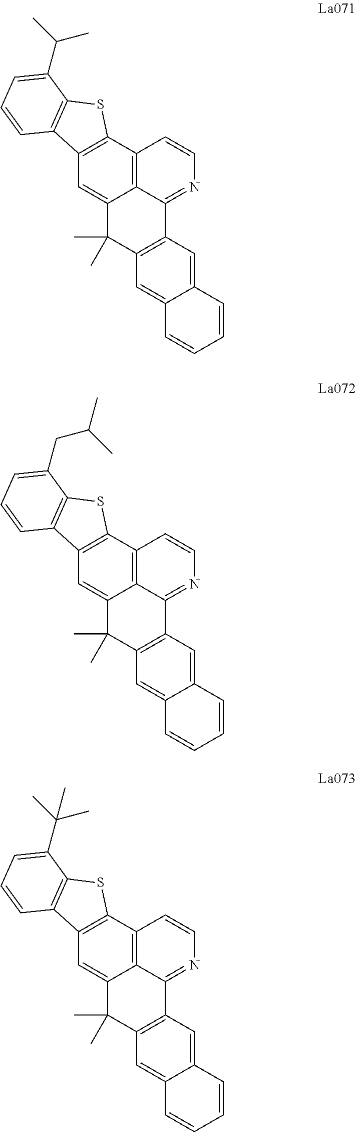 [SMILES: CC(C)c1cccc2c1sc1c3ccnc4c3c(cc21)C(C)(C)c1cc2ccccc2cc1-4 ; CC(C)Cc1cccc2c1sc1c3ccnc4c3c(cc21)C(C)(C)c1cc2ccccc2cc1-4 ; CC(C)(C)c1cccc2c1sc1c3ccnc4c3c(cc21)C(C)(C)c1cc2ccccc2cc1-4]

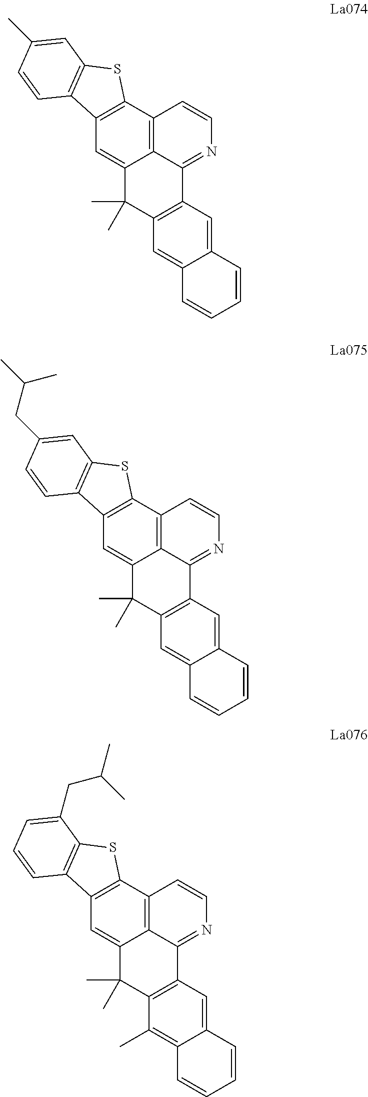 [SMILES: Cc1ccc2c(c1)sc1c3ccnc4c3c(cc21)C(C)(C)c1cc2ccccc2cc1-4 ; CC(C)Cc1ccc2c(c1)sc1c3ccnc4c3c(cc21)C(C)(C)c1cc2ccccc2cc1-4 ; Cc1c2c(cc3ccccc13)-c1nccc3c1c(cc1c4cccc(CC(C)C)c4sc31)C2(C)C]

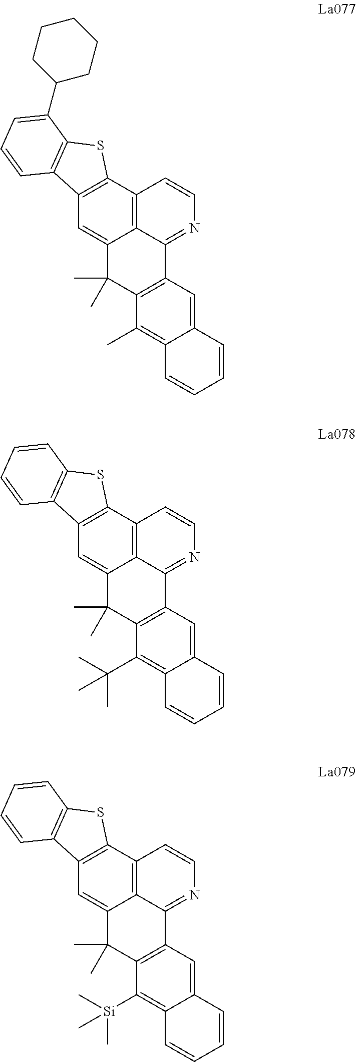 [SMILES: Cc1c2c(cc3ccccc13)-c1nccc3c1c(cc1c4cccc(C5CCCCC5)c4sc31)C2(C)C ; CC(C)(C)c1c2c(cc3ccccc13)-c1nccc3c1c(cc1c4ccccc4sc31)C2(C)C ; CC1(C)c2c(cc3ccccc3c2[Si](C)(C)C)-c2nccc3c2c1cc1c2ccccc2sc31]

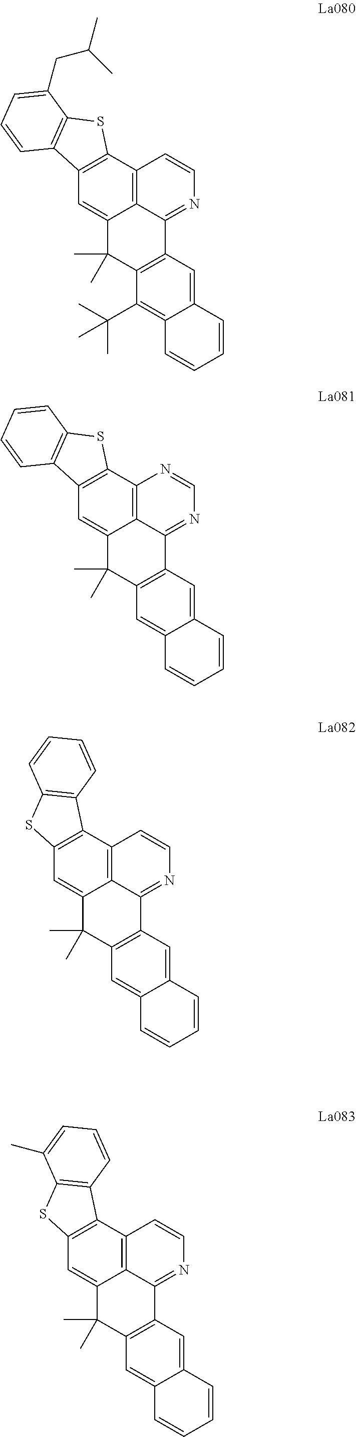 [SMILES: CC(C)Cc1cccc2c1sc1c3ccnc4c3c(cc21)C(C)(C)c1c-4cc2ccccc2c1C(C)(C)C ; CC1(C)c2cc3ccccc3cc2-c2ncnc3c2c1cc1c2ccccc2sc13 ; CC1(C)c2cc3ccccc3cc2-c2nccc3c2c1cc1sc2ccccc2c13 ; Cc1cccc2c1sc1cc3c4c(nccc4c12)-c1cc2ccccc2cc1C3(C)C]

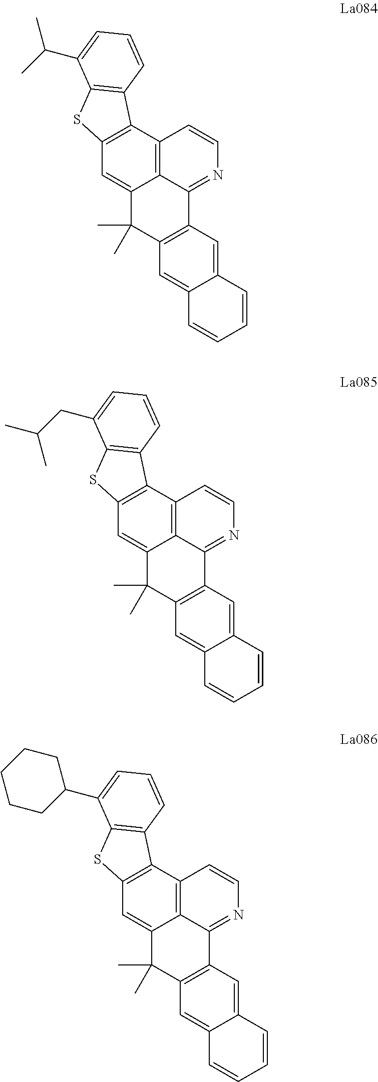 [SMILES: CC(C)c1cccc2c1sc1cc3c4c(nccc4c12)-c1cc2ccccc2cc1C3(C)C ; CC(C)Cc1cccc2c1sc1cc3c4c(nccc4c12)-c1cc2ccccc2cc1C3(C)C ; CC1(C)c2cc3ccccc3cc2-c2nccc3c2c1cc1sc2c(C4CCCCC4)cccc2c13]

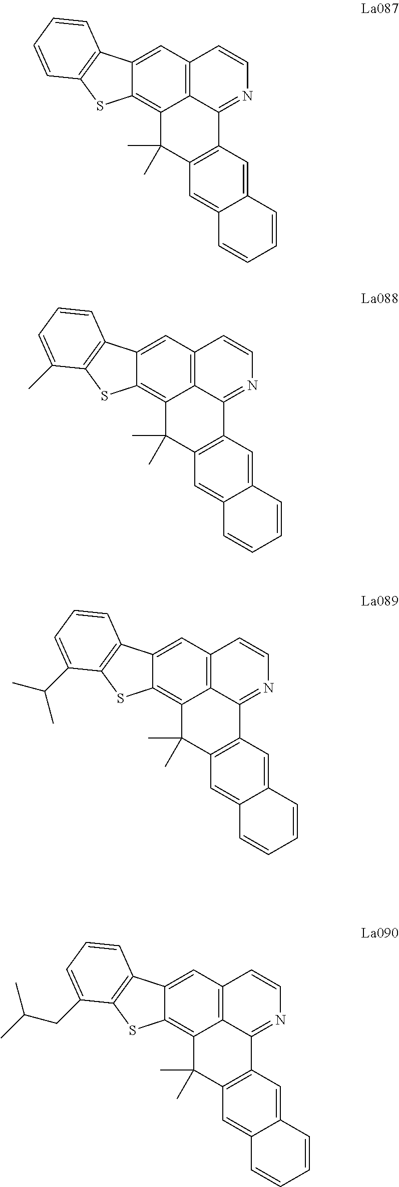 [SMILES: CC1(C)c2cc3ccccc3cc2-c2nccc3cc4c(sc5ccccc54)c1c23 ; Cc1cccc2c1sc1c3c4c(nccc4cc12)-c1cc2ccccc2cc1C3(C)C ; CC(C)c1cccc2c1sc1c3c4c(nccc4cc12)-c1cc2ccccc2cc1C3(C)C ; CC(C)Cc1cccc2c1sc1c3c4c(nccc4cc12)-c1cc2ccccc2cc1C3(C)C]

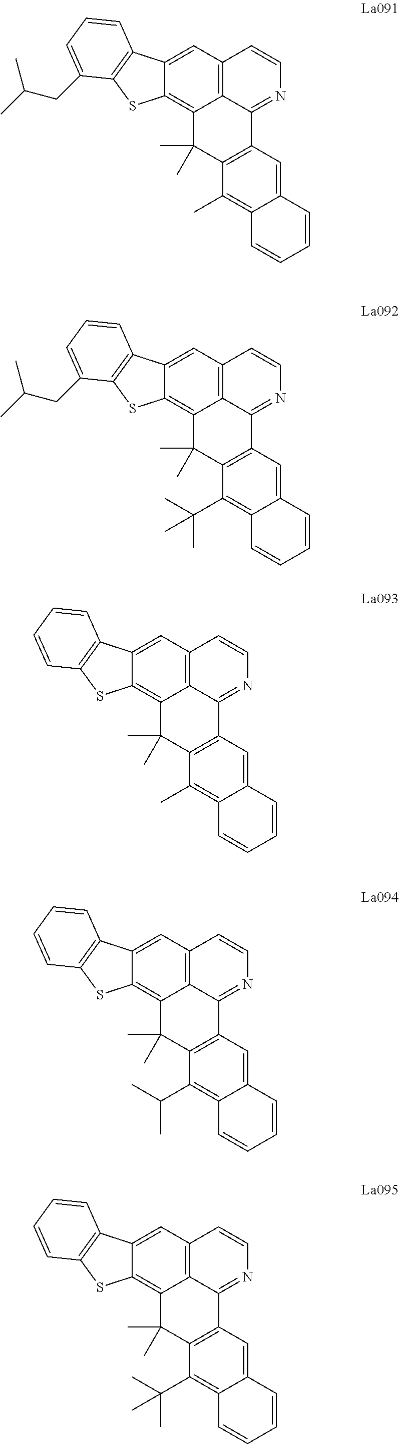 [SMILES: Cc1c2c(cc3ccccc13)-c1nccc3cc4c(sc5c(CC(C)C)cccc54)c(c13)C2(C)C ; CC(C)Cc1cccc2c1sc1c3c4c(nccc4cc12)-c1cc2ccccc2c(C(C)(C)C)c1C3(C)C ; Cc1c2c(cc3ccccc13)-c1nccc3cc4c(sc5ccccc54)c(c13)C2(C)C ; CC(C)c1c2c(cc3ccccc13)-c1nccc3cc4c(sc5ccccc54)c(c13)C2(C)C ; CC(C)(C)c1c2c(cc3ccccc13)-c1nccc3cc4c(sc5ccccc54)c(c13)C2(C)C]

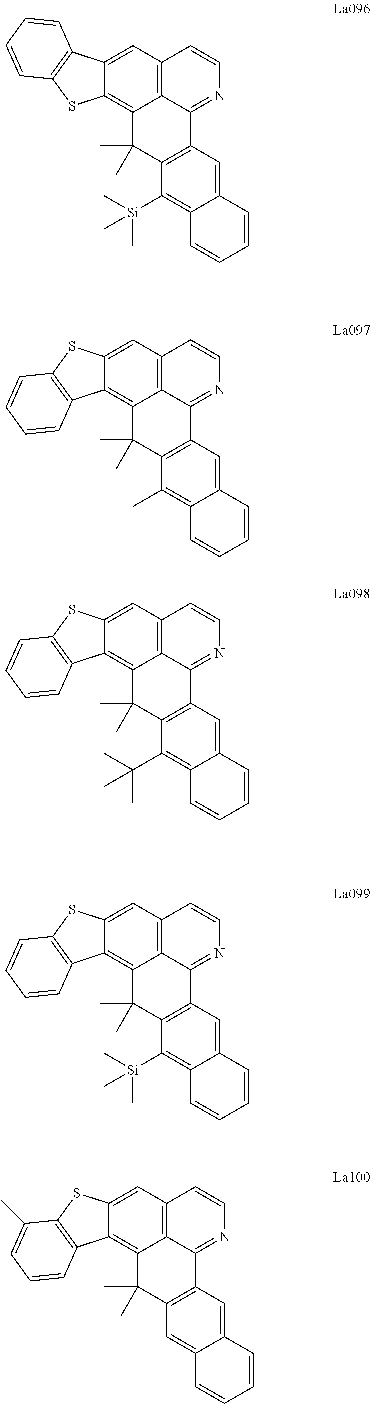 [SMILES: CC1(C)c2c(cc3ccccc3c2[Si](C)(C)C)-c2nccc3cc4c(sc5ccccc54)c1c23 ; Cc1c2c(cc3ccccc13)-c1nccc3cc4sc5ccccc5c4c(c13)C2(C)C ; CC(C)(C)c1c2c(cc3ccccc13)-c1nccc3cc4sc5ccccc5c4c(c13)C2(C)C ; CC1(C)c2c(cc3ccccc3c2[Si](C)(C)C)-c2nccc3cc4sc5ccccc5c4c1c23 ; Cc1cccc2c1sc1cc3ccnc4c3c(c12)C(C)(C)c1cc2ccccc2cc1-4]

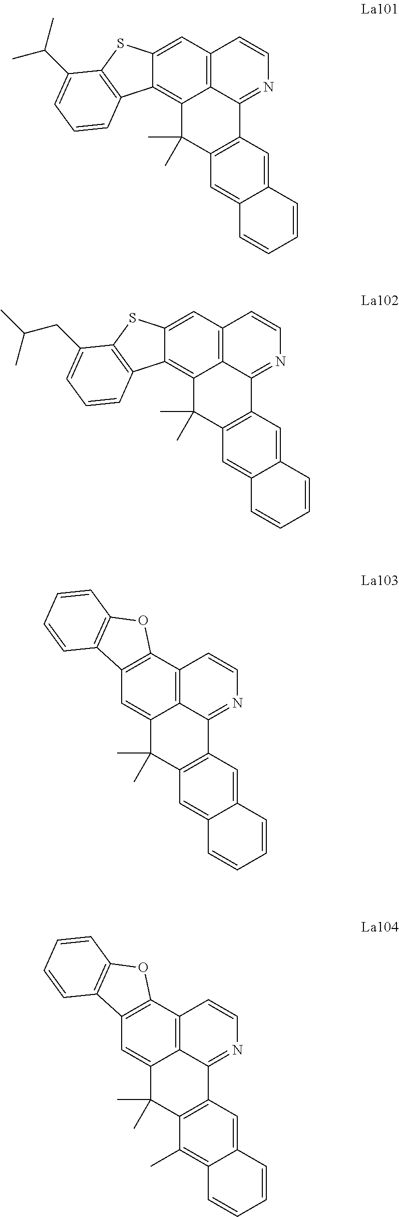 [SMILES: CC(C)c1cccc2c1sc1cc3ccnc4c3c(c12)C(C)(C)c1cc2ccccc2cc1-4 ; CC(C)Cc1cccc2c1sc1cc3ccnc4c3c(c12)C(C)(C)c1cc2ccccc2cc1-4 ; CC1(C)c2cc3ccccc3cc2-c2nccc3c2c1cc1c2ccccc2oc31 ; Cc1c2c(cc3ccccc13)-c1nccc3c1c(cc1c4ccccc4oc31)C2(C)C]

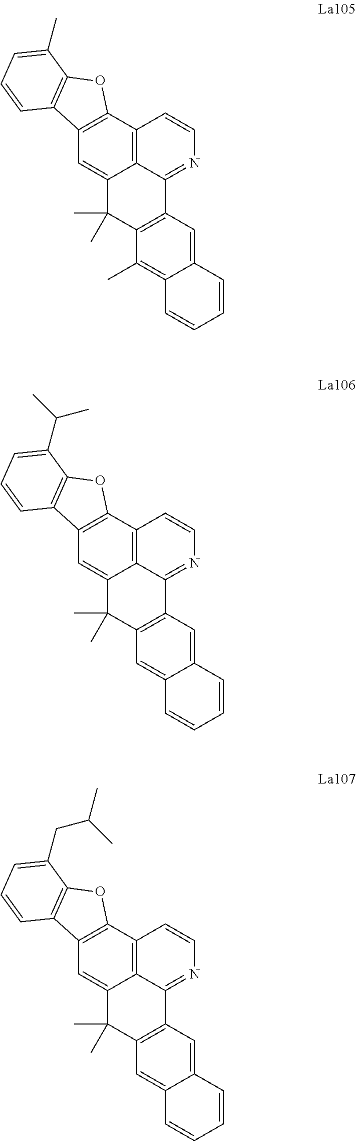 [SMILES: Cc1c2c(cc3ccccc13)-c1nccc3c1c(cc1c4cccc(C)c4oc31)C2(C)C ; CC(C)c1cccc2c1oc1c3ccnc4c3c(cc21)C(C)(C)c1cc2ccccc2cc1-4 ; CC(C)Cc1cccc2c1oc1c3ccnc4c3c(cc21)C(C)(C)c1cc2ccccc2cc1-4]

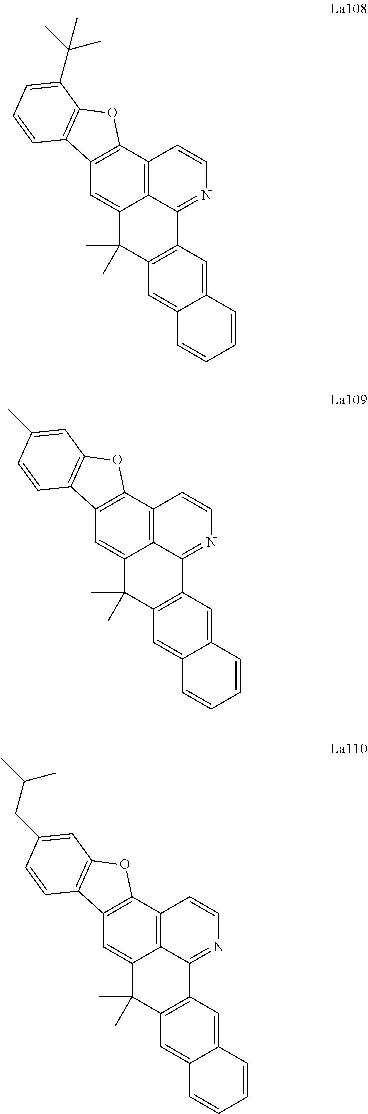 [SMILES: CC(C)(C)c1cccc2c1oc1c3ccnc4c3c(cc21)C(C)(C)c1cc2ccccc2cc1-4 ; Cc1ccc2c(c1)oc1c3ccnc4c3c(cc21)C(C)(C)c1cc2ccccc2cc1-4 ; CC(C)Cc1ccc2c(c1)oc1c3ccnc4c3c(cc21)C(C)(C)c1cc2ccccc2cc1-4]

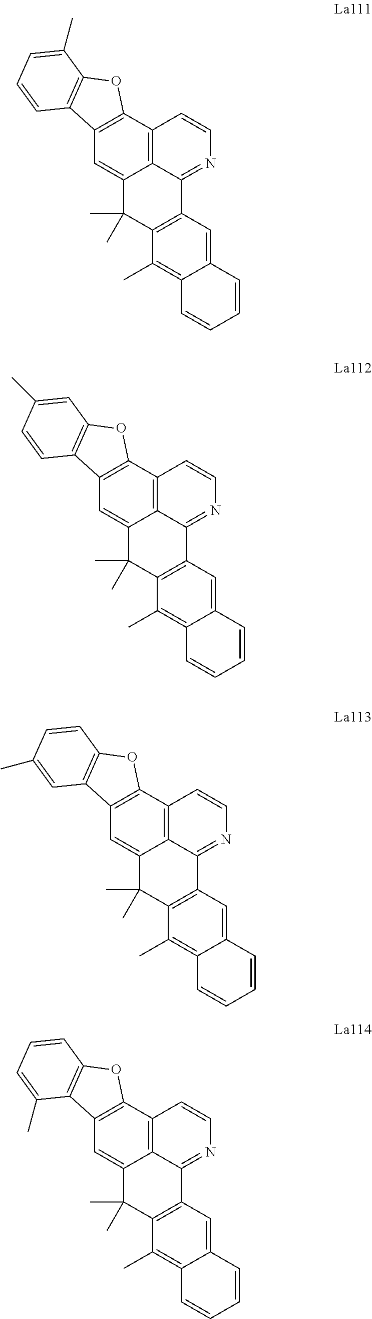 [SMILES: Cc1c2c(cc3ccccc13)-c1nccc3c1c(cc1c4cccc(C)c4oc31)C2(C)C ; Cc1ccc2c(c1)oc1c3ccnc4c3c(cc21)C(C)(C)c1c-4cc2ccccc2c1C ; Cc1ccc2oc3c4ccnc5c4c(cc3c2c1)C(C)(C)c1c-5cc2ccccc2c1C ; Cc1c2c(cc3ccccc13)-c1nccc3c1c(cc1c3oc3cccc(C)c31)C2(C)C]

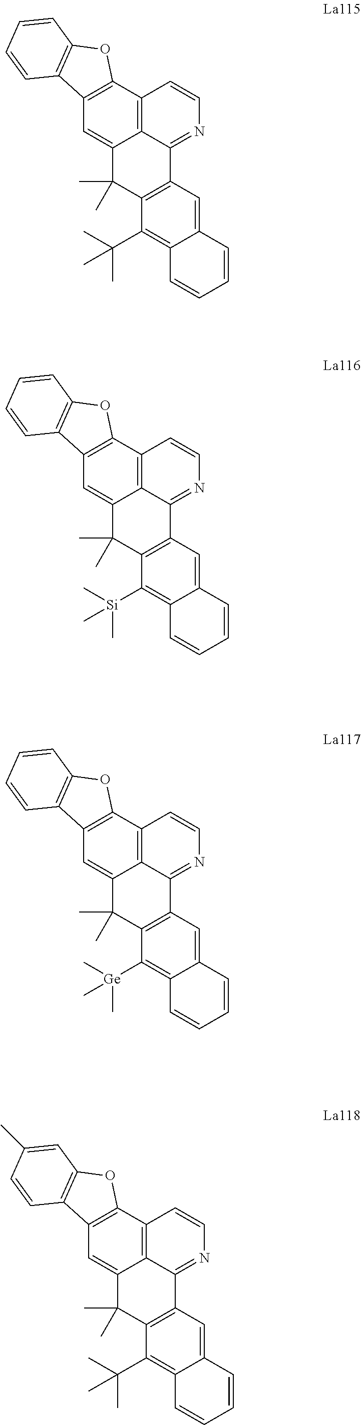

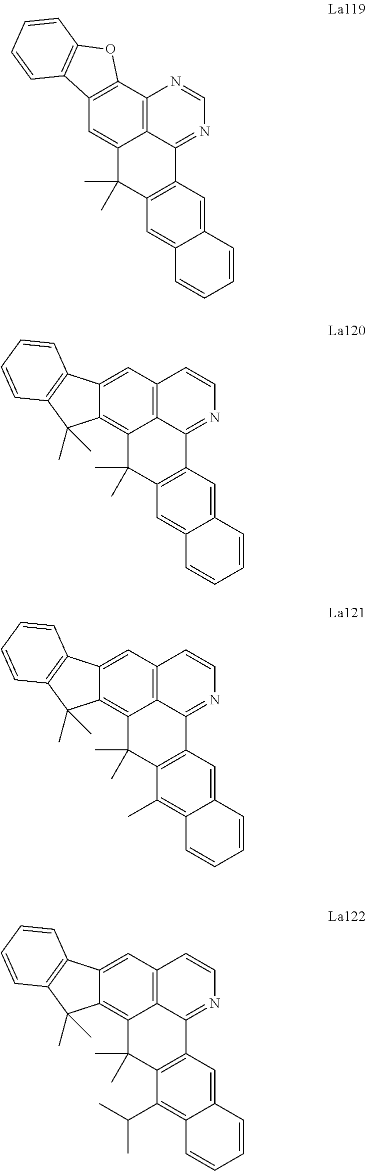 [SMILES: CC1(C)c2cc3ccccc3cc2-c2ncnc3c2c1cc1c2ccccc2oc13 ; CC1(C)c2ccccc2-c2cc3ccnc4c3c(c21)C(C)(C)c1cc2ccccc2cc1-4 ; Cc1c2c(cc3ccccc13)-c1nccc3cc4c(c(c13)C2(C)C)C(C)(C)c1ccccc1-4 ; CC(C)c1c2c(cc3ccccc13)-c1nccc3cc4c(c(c13)C2(C)C)C(C)(C)c1ccccc1-4]

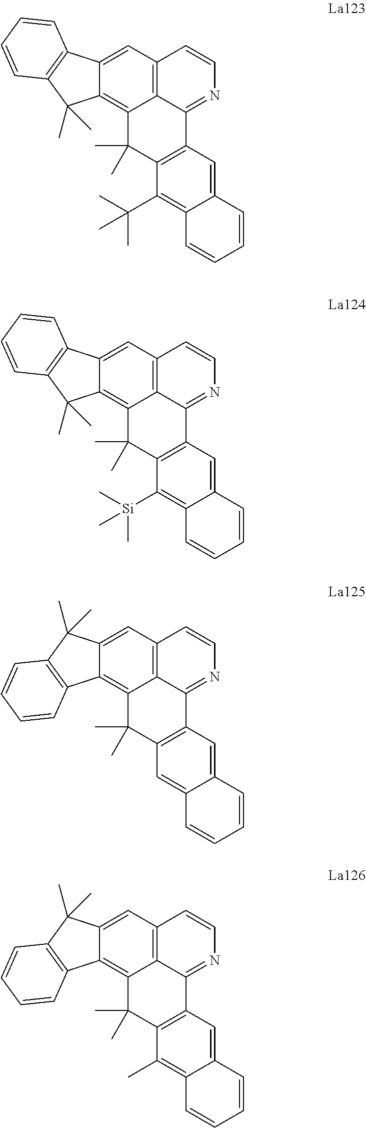 [SMILES: CC(C)(C)c1c2c(cc3ccccc13)-c1nccc3cc4c(c(c13)C2(C)C)C(C)(C)c1ccccc1-4 ; CC1(C)c2ccccc2-c2cc3ccnc4c3c(c21)C(C)(C)c1c-4cc2ccccc2c1[Si](C)(C)C ; CC1(C)c2ccccc2-c2c1cc1ccnc3c1c2C(C)(C)c1cc2ccccc2cc1-3 ; Cc1c2c(cc3ccccc13)-c1nccc3cc4c(c(c13)C2(C)C)-c1ccccc1C4(C)C]

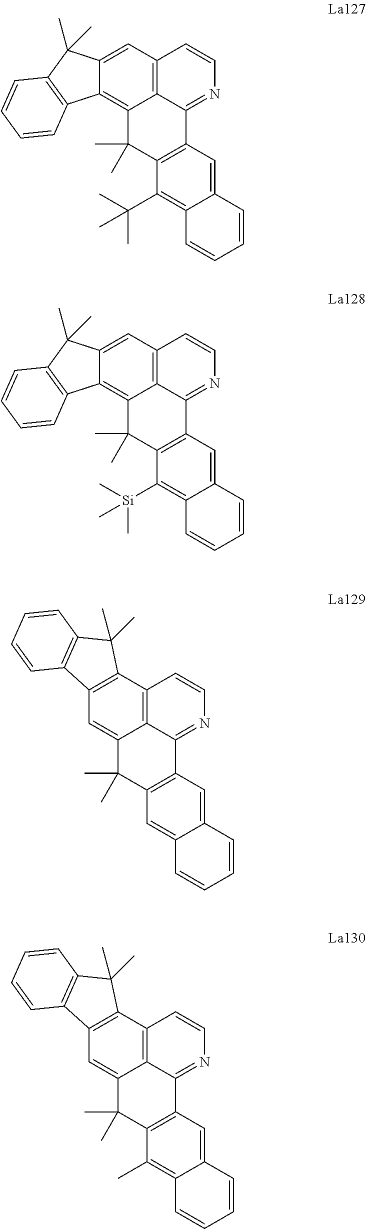 [SMILES: CC(C)(C)c1c2c(cc3ccccc13)-c1nccc3cc4c(c(c13)C2(C)C)-c1ccccc1C4(C)C ; CC1(C)c2ccccc2-c2c1cc1ccnc3c1c2C(C)(C)c1c-3cc2ccccc2c1[Si](C)(C)C ; CC1(C)c2ccccc2-c2cc3c4c(nccc4c21)-c1cc2ccccc2cc1C3(C)C ; Cc1c2c(cc3ccccc13)-c1nccc3c4c(cc(c13)C2(C)C)-c1ccccc1C4(C)C]

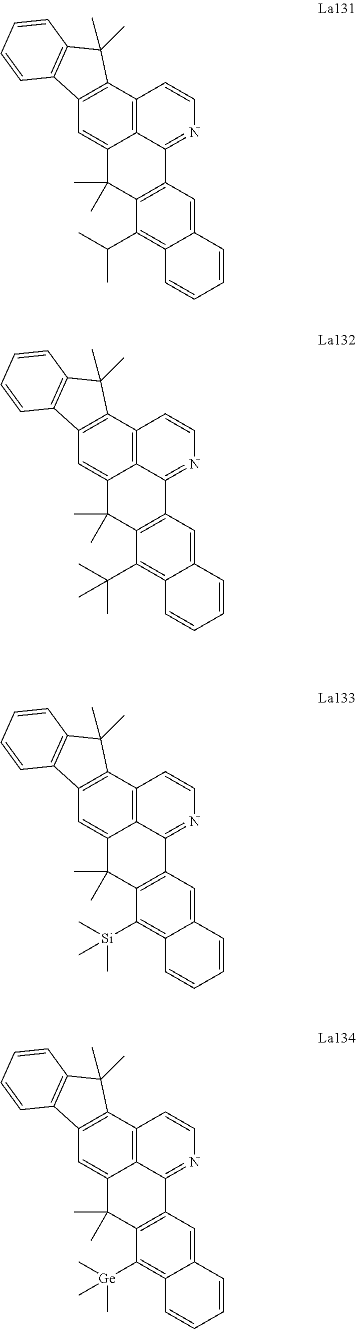

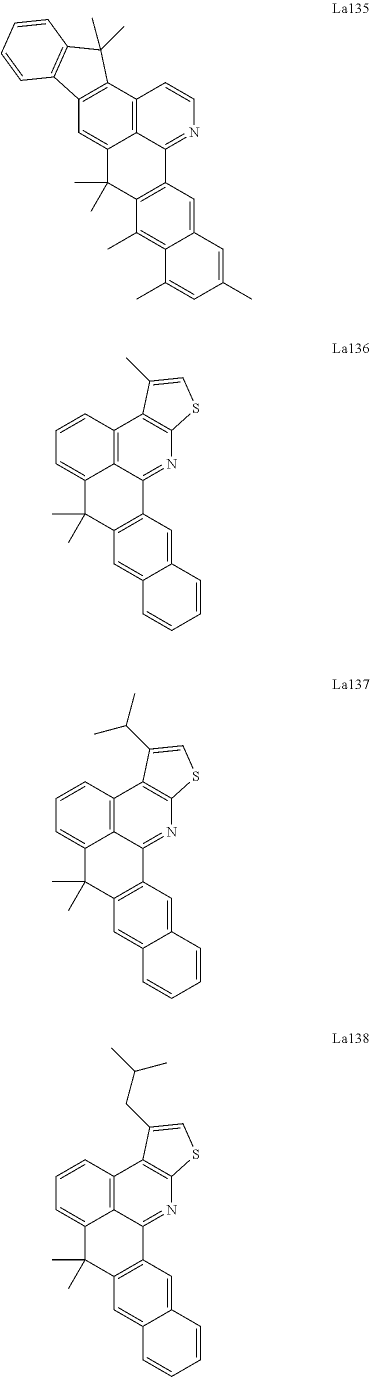

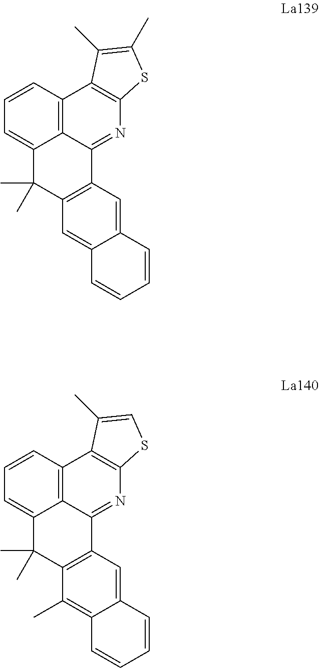 [SMILES: Cc1sc2nc3c4c(cccc4c2c1C)C(C)(C)c1cc2ccccc2cc1-3 ; Cc1c2c(cc3ccccc13)-c1nc3scc(C)c3c3cccc(c13)C2(C)C]

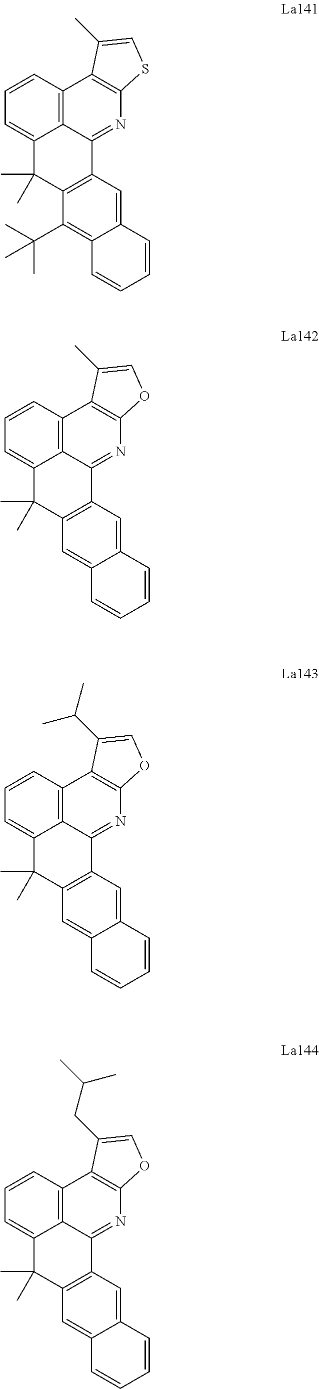 [SMILES: Cc1csc2nc3c4c(cccc4c12)C(C)(C)c1c-3cc2ccccc2c1C(C)(C)C ; Cc1coc2nc3c4c(cccc4c12)C(C)(C)c1cc2ccccc2cc1-3 ; CC(C)c1coc2nc3c4c(cccc4c12)C(C)(C)c1cc2ccccc2cc1-3 ; CC(C)Cc1coc2nc3c4c(cccc4c12)C(C)(C)c1cc2ccccc2cc1-3]

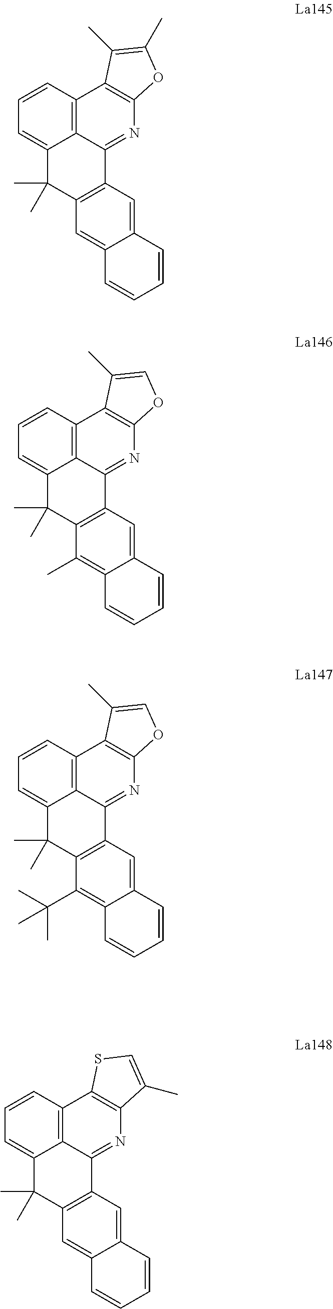

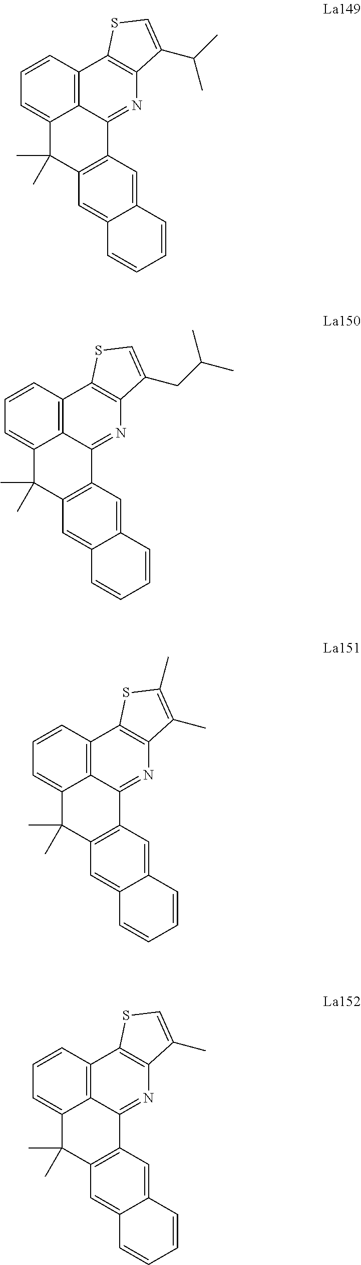

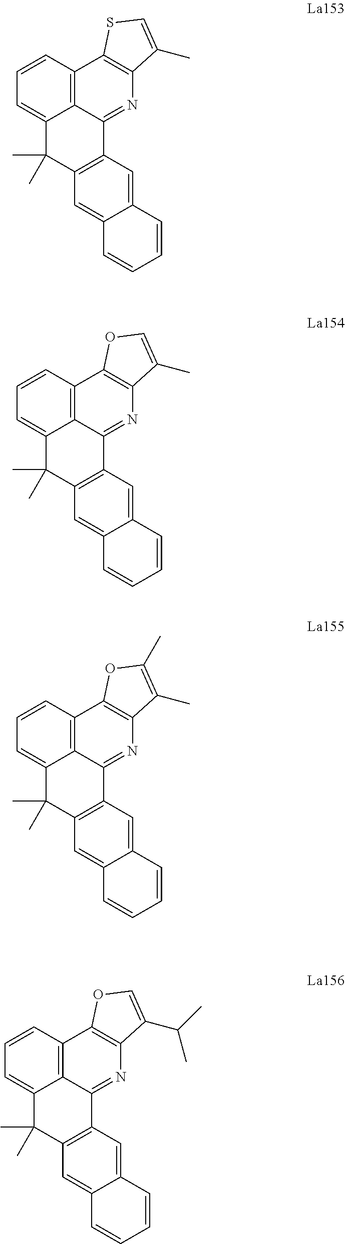

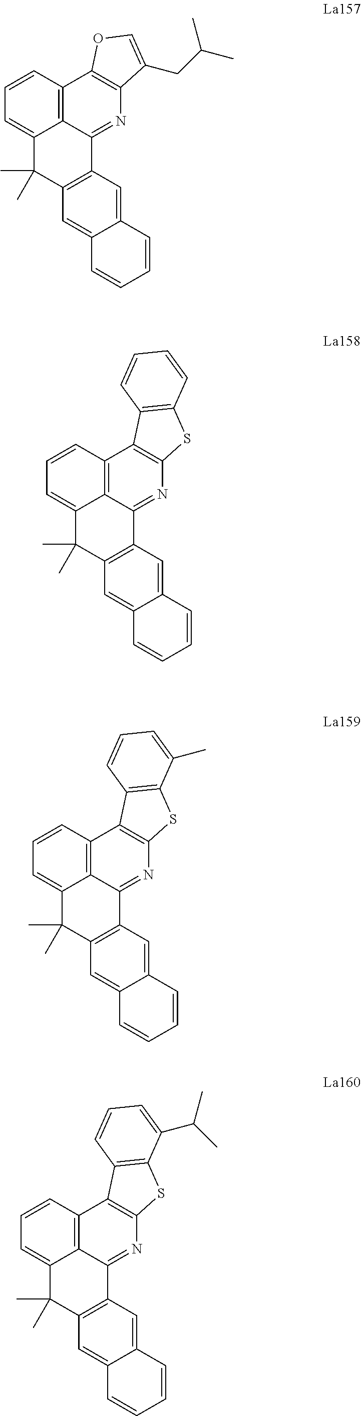

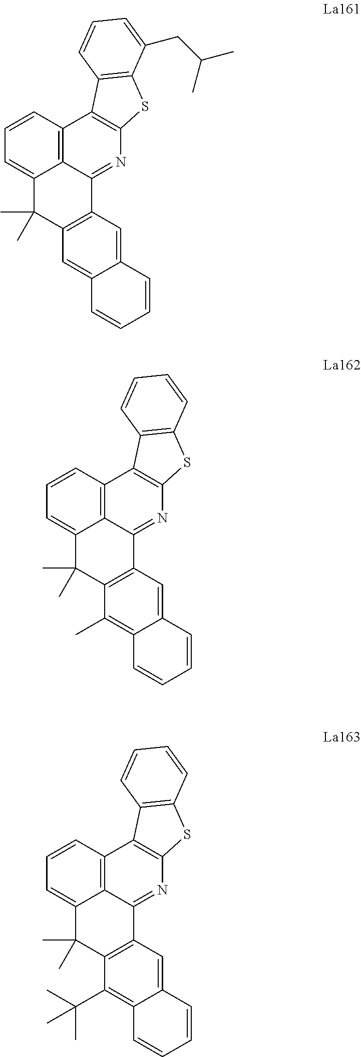

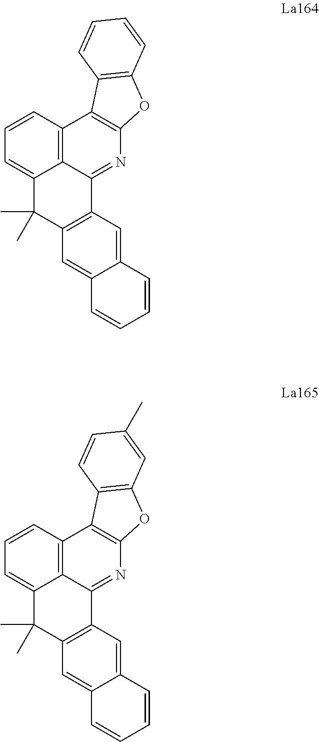 [SMILES: CC1(C)c2cc3ccccc3cc2-c2nc3oc4ccccc4c3c3cccc1c23 ; Cc1ccc2c(c1)oc1nc3c4c(cccc4c12)C(C)(C)c1cc2ccccc2cc1-3]

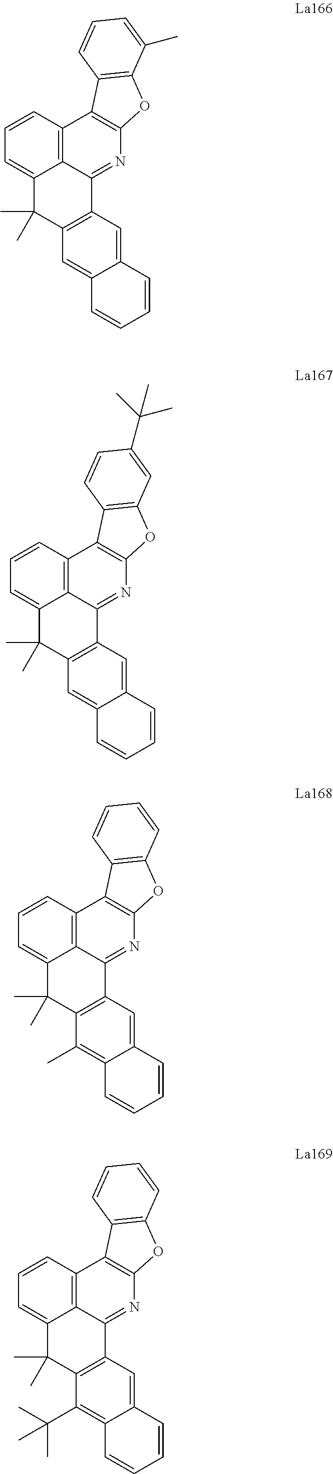

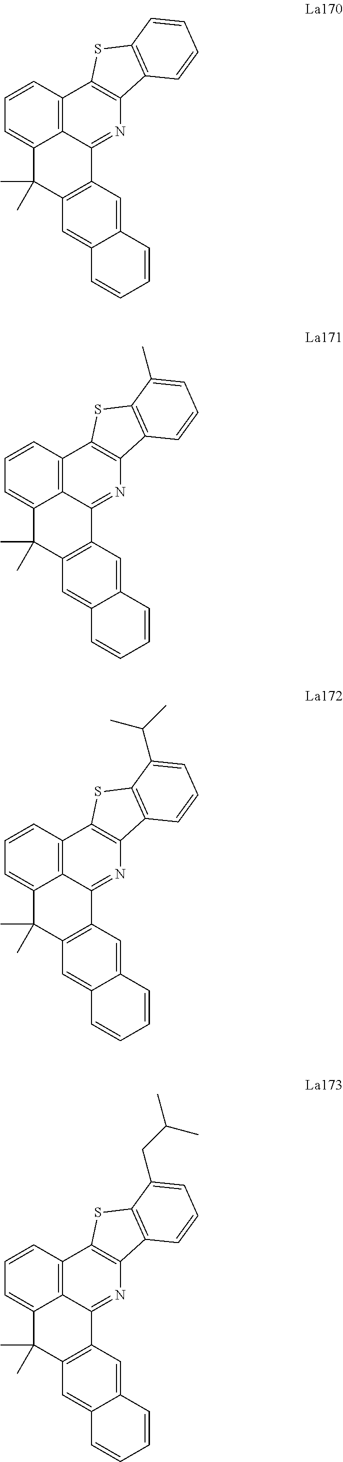 [SMILES: CC1(C)c2cc3ccccc3cc2-c2nc3c4ccccc4sc3c3cccc1c23 ; Cc1cccc2c1sc1c3cccc4c3c(nc21)-c1cc2ccccc2cc1C4(C)C ; CC(C)c1cccc2c1sc1c3cccc4c3c(nc21)-c1cc2ccccc2cc1C4(C)C ; CC(C)Cc1cccc2c1sc1c3cccc4c3c(nc21)-c1cc2ccccc2cc1C4(C)C]

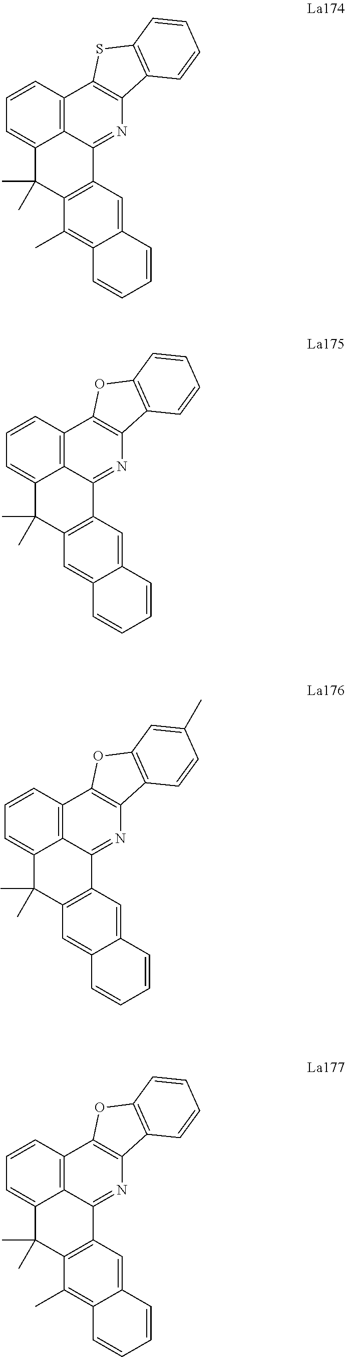

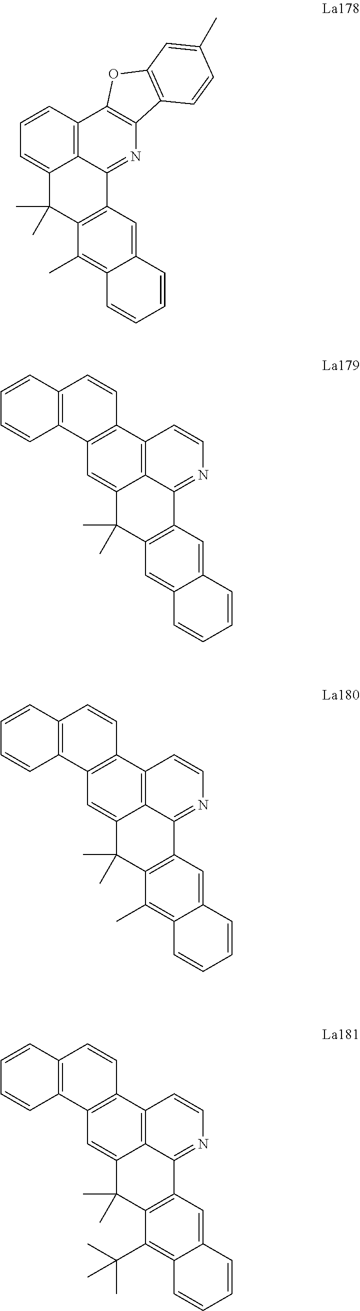

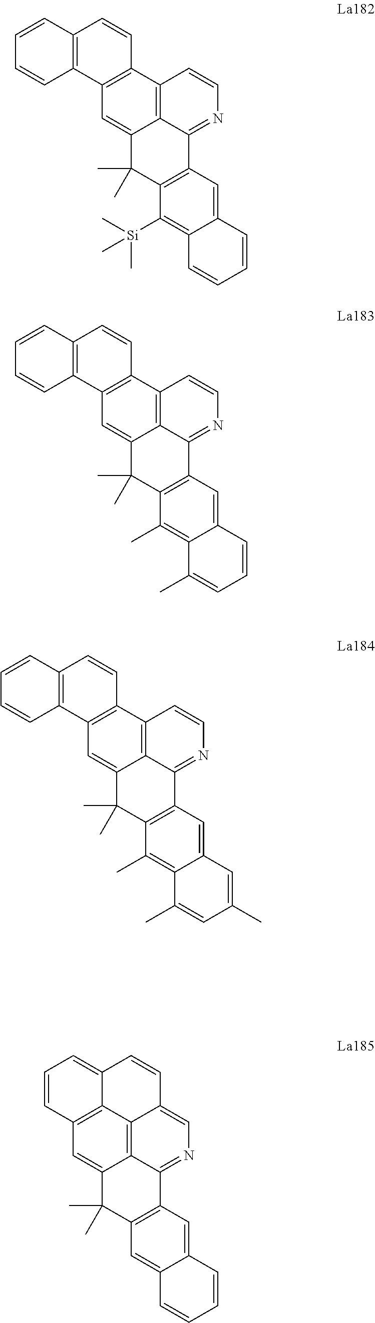 [SMILES: CC1(C)c2c(cc3ccccc3c2[Si](C)(C)C)-c2nccc3c2c1cc1c2ccccc2ccc31 ; Cc1cccc2cc3c(c(C)c12)C(C)(C)c1cc2c4ccccc4ccc2c2ccnc-3c12 ; Cc1cc(C)c2c(C)c3c(cc2c1)-c1nccc2c1c(cc1c4ccccc4ccc21)C3(C)C ; CC1(C)c2cc3ccccc3cc2-c2ncc3ccc4cccc5cc1c2c3c45]

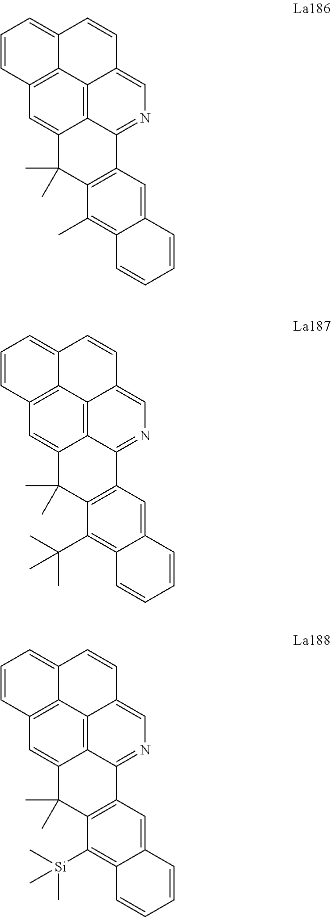 [SMILES: Cc1c2c(cc3ccccc13)-c1ncc3ccc4cccc5cc(c1c3c45)C2(C)C ; CC(C)(C)c1c2c(cc3ccccc13)-c1ncc3ccc4cccc5cc(c1c3c45)C2(C)C ; CC1(C)c2c(cc3ccccc3c2[Si](C)(C)C)-c2ncc3ccc4cccc5cc1c2c3c45]

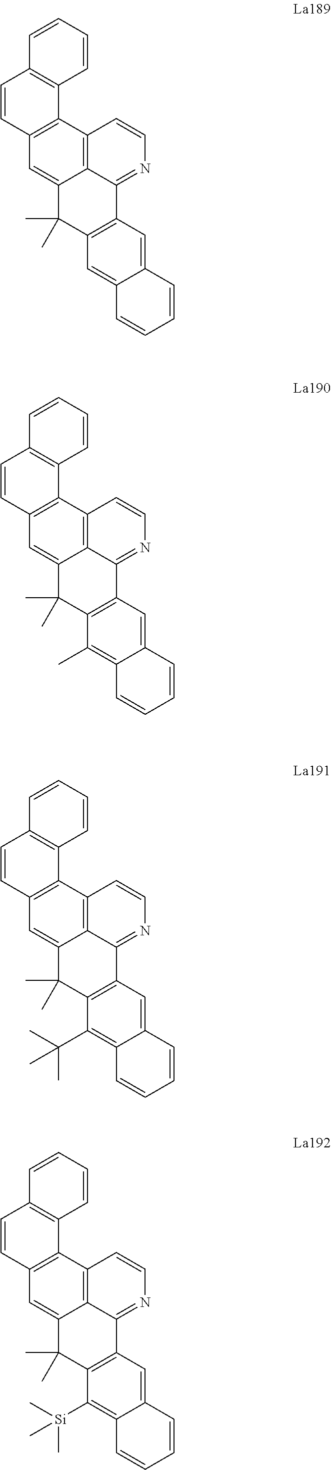 [SMILES: CC1(C)c2cc3ccccc3cc2-c2nccc3c2c1cc1ccc2ccccc2c13 ; Cc1c2c(cc3ccccc13)-c1nccc3c1c(cc1ccc4ccccc4c13)C2(C)C ; CC(C)(C)c1c2c(cc3ccccc13)-c1nccc3c1c(cc1ccc4ccccc4c13)C2(C)C ; CC1(C)c2c(cc3ccccc3c2[Si](C)(C)C)-c2nccc3c2c1cc1ccc2ccccc2c13]

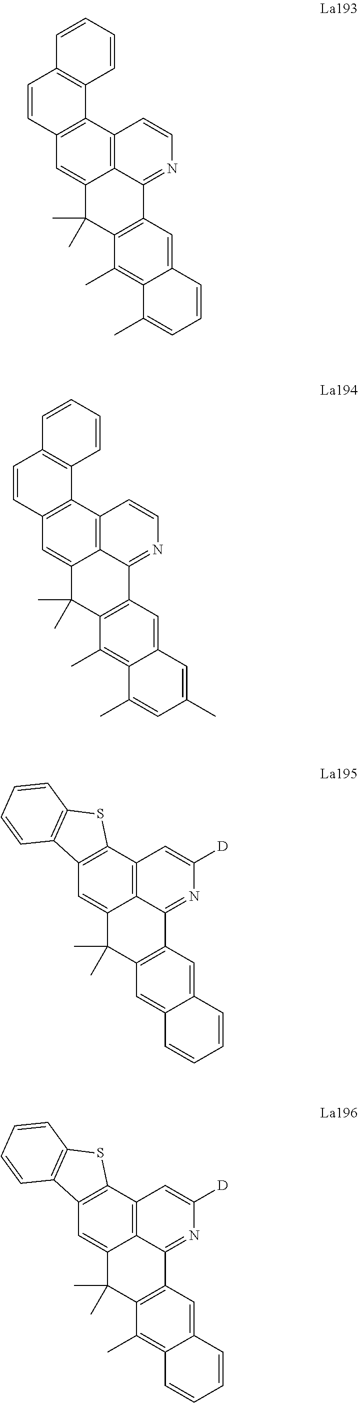 [SMILES: Cc1cccc2cc3c(c(C)c12)C(C)(C)c1cc2ccc4ccccc4c2c2ccnc-3c12 ; Cc1cc(C)c2c(C)c3c(cc2c1)-c1nccc2c1c(cc1ccc4ccccc4c12)C3(C)C ; [2H]c1cc2c3c(cc4c5ccccc5sc24)C(C)(C)c2cc4ccccc4cc2-c3n1 ; [2H]c1cc2c3c(cc4c5ccccc5sc24)C(C)(C)c2c(cc4ccccc4c2C)-c3n1]

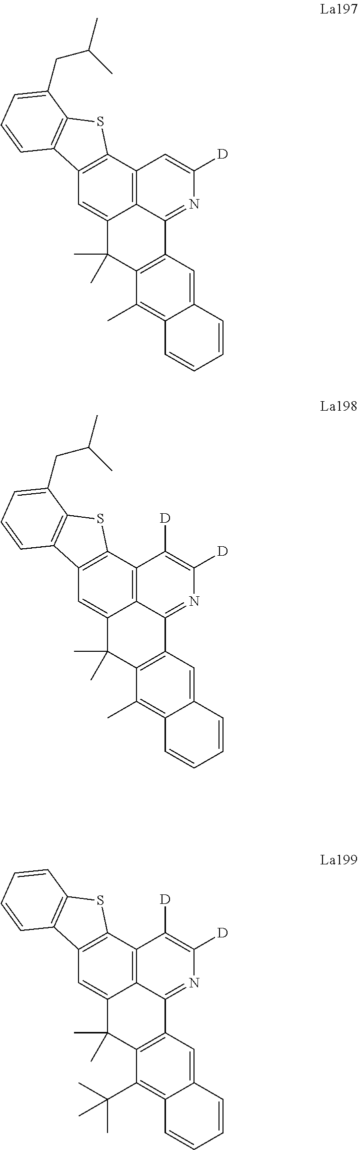 [SMILES: [2H]c1cc2c3c(cc4c5cccc(CC(C)C)c5sc24)C(C)(C)c2c(cc4ccccc4c2C)-c3n1 ; [2H]c1nc2c3c(cc4c5cccc(CC(C)C)c5sc4c3c1[2H])C(C)(C)c1c-2cc2ccccc2c1C ; [2H]c1nc2c3c(cc4c5ccccc5sc4c3c1[2H])C(C)(C)c1c-2cc2ccccc2c1C(C)(C)C]

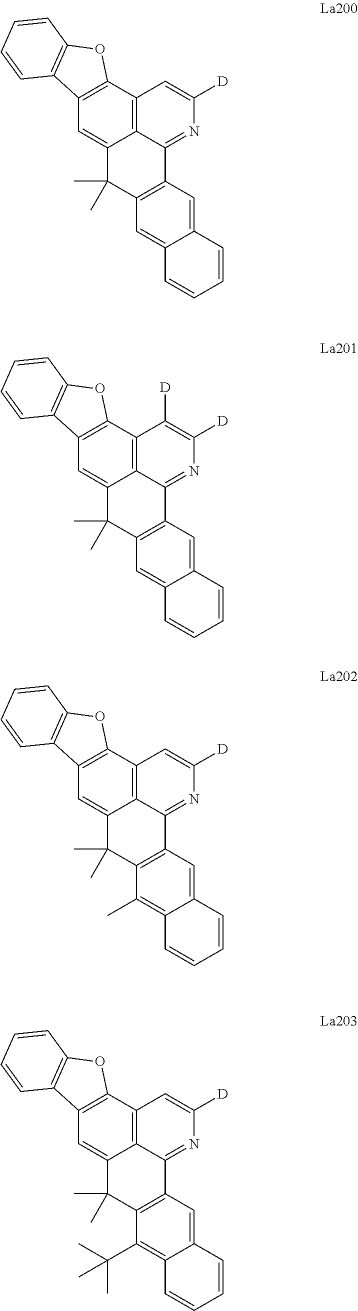 [SMILES: [2H]c1cc2c3c(cc4c5ccccc5oc24)C(C)(C)c2cc4ccccc4cc2-c3n1 ; [2H]c1nc2c3c(cc4c5ccccc5oc4c3c1[2H])C(C)(C)c1cc3ccccc3cc1-2 ; [2H]c1cc2c3c(cc4c5ccccc5oc24)C(C)(C)c2c(cc4ccccc4c2C)-c3n1 ; [2H]c1cc2c3c(cc4c5ccccc5oc24)C(C)(C)c2c(cc4ccccc4c2C(C)(C)C)-c3n1]

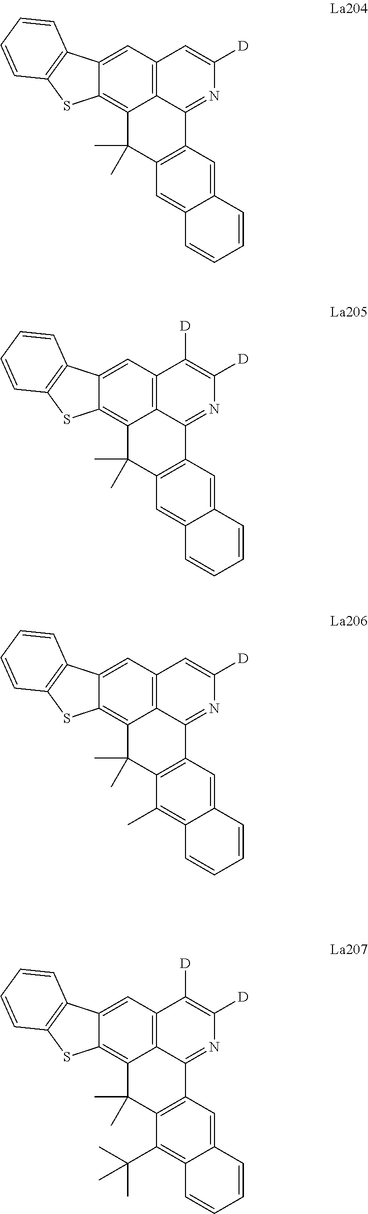 [SMILES: [2H]c1cc2cc3c(sc4ccccc43)c3c2c(n1)-c1cc2ccccc2cc1C3(C)C ; [2H]c1nc2c3c(c4sc5ccccc5c4cc3c1[2H])C(C)(C)c1cc3ccccc3cc1-2 ; [2H]c1cc2cc3c(sc4ccccc43)c3c2c(n1)-c1cc2ccccc2c(C)c1C3(C)C ; [2H]c1nc2c3c(c4sc5ccccc5c4cc3c1[2H])C(C)(C)c1c-2cc2ccccc2c1C(C)(C)C]

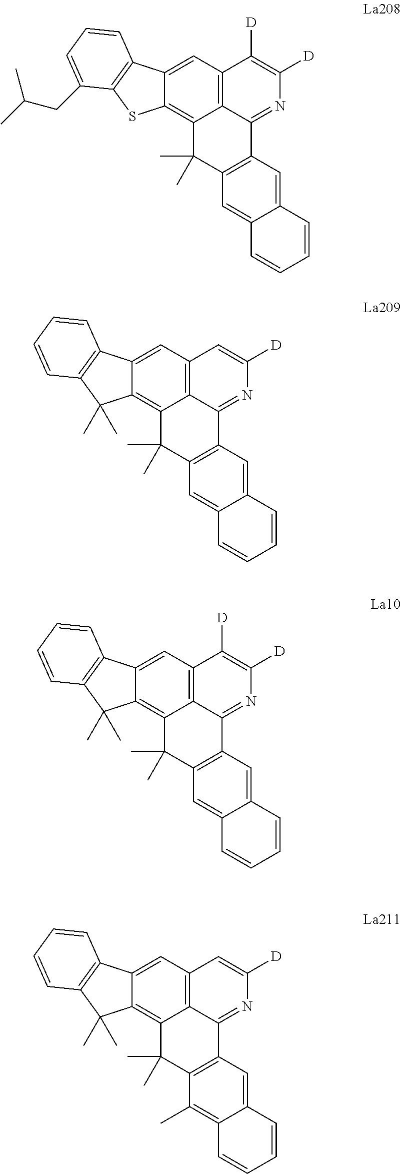 [SMILES: [2H]c1nc2c3c(c4sc5c(CC(C)C)cccc5c4cc3c1[2H])C(C)(C)c1cc3ccccc3cc1-2 ; [2H]c1cc2cc3c(c4c2c(n1)-c1cc2ccccc2cc1C4(C)C)C(C)(C)c1ccccc1-3 ; [2H]c1nc2c3c(c4c(cc3c1[2H])-c1ccccc1C4(C)C)C(C)(C)c1cc3ccccc3cc1-2 ; [2H]c1cc2cc3c(c4c2c(n1)-c1cc2ccccc2c(C)c1C4(C)C)C(C)(C)c1ccccc1-3]

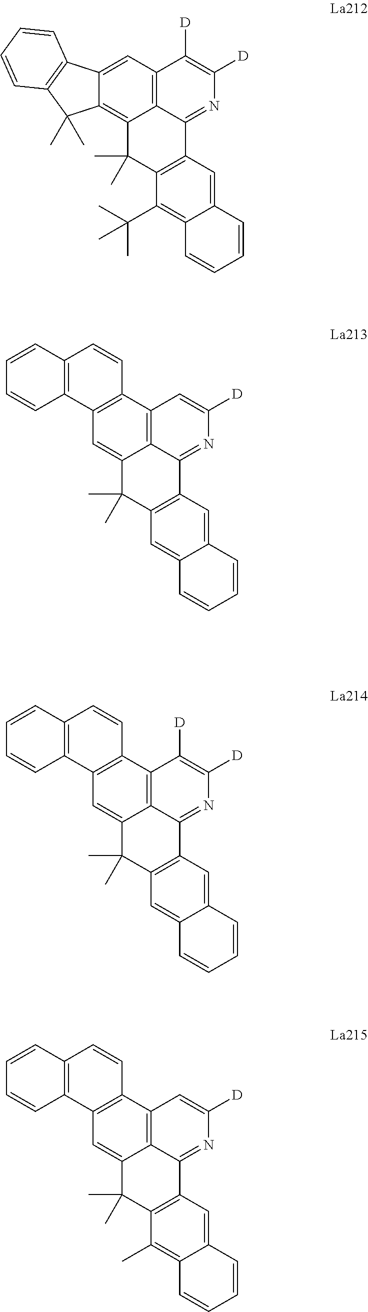 [SMILES: [2H]c1nc2c3c(c4c(cc3c1[2H])-c1ccccc1C4(C)C)C(C)(C)c1c-2cc2ccccc2c1C(C)(C)C ; [2H]c1cc2c3c(cc4c5ccccc5ccc24)C(C)(C)c2cc4ccccc4cc2-c3n1 ; [2H]c1nc2c3c(cc4c5ccccc5ccc4c3c1[2H])C(C)(C)c1cc3ccccc3cc1-2 ; [2H]c1cc2c3c(cc4c5ccccc5ccc24)C(C)(C)c2c(cc4ccccc4c2C)-c3n1]

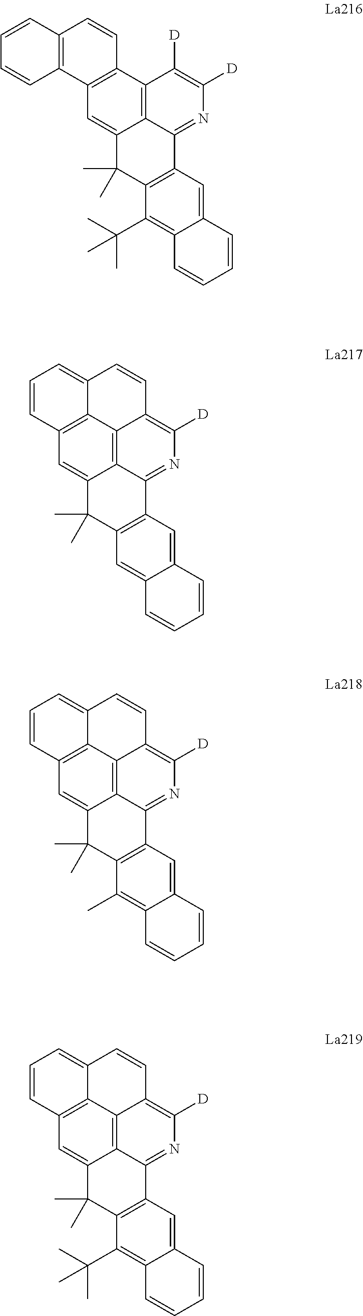 [SMILES: [2H]c1nc2c3c(cc4c5ccccc5ccc4c3c1[2H])C(C)(C)c1c-2cc2ccccc2c1C(C)(C)C ; [2H]c1nc2c3c(cc4cccc5ccc1c3c54)C(C)(C)c1cc3ccccc3cc1-2 ; [2H]c1nc2c3c(cc4cccc5ccc1c3c54)C(C)(C)c1c-2cc2ccccc2c1C ; [2H]c1nc2c3c(cc4cccc5ccc1c3c54)C(C)(C)c1c-2cc2ccccc2c1C(C)(C)C]

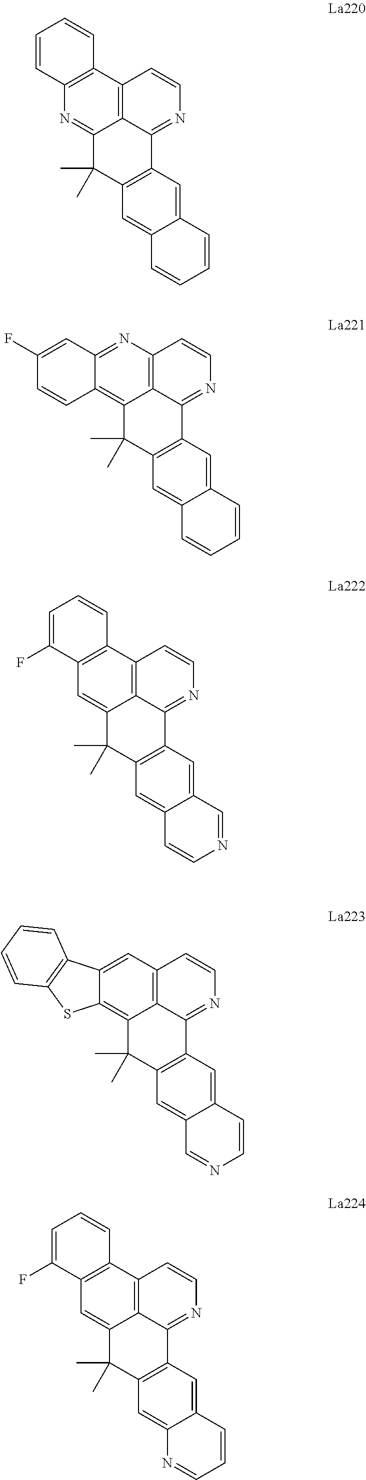 [SMILES: CC1(C)c2cc3ccccc3cc2-c2nccc3c2c1nc1ccccc13 ; CC1(C)c2cc3ccccc3cc2-c2nccc3nc4cc(F)ccc4c1c23 ; CC1(C)c2cc3ccncc3cc2-c2nccc3c2c1cc1c(F)cccc13 ; CC1(C)c2cc3cnccc3cc2-c2nccc3cc4c(sc5ccccc54)c1c23 ; CC1(C)c2cc3ncccc3cc2-c2nccc3c2c1cc1c(F)cccc13]

As for the metal iridium complex in some embodiments of the present disclosure, Lb is independently selected from one of the following structural formulas, or one of the following structural formulas in which the hydrogen atom(s) is/are partially or completely deuterated, or one of the following structural formulas in which the hydrogen atom(s) is/are partially or completely fluorinated:

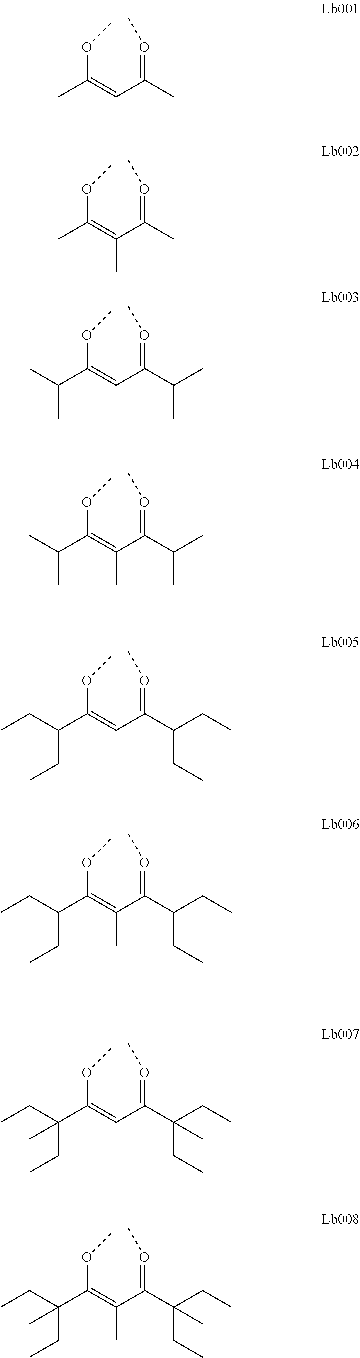

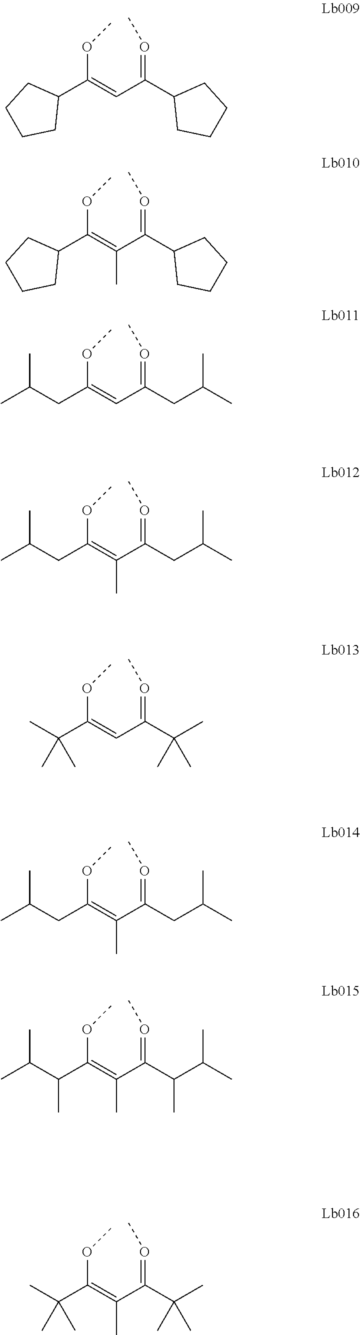

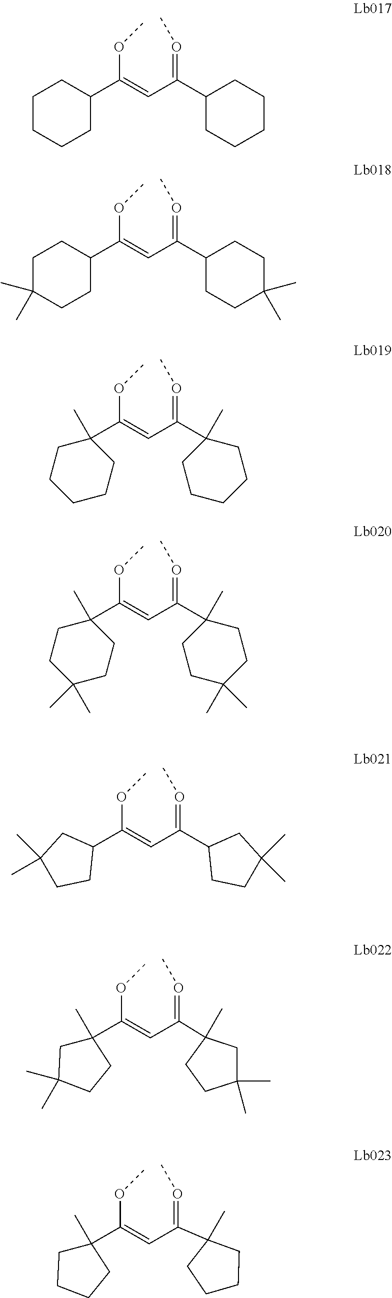

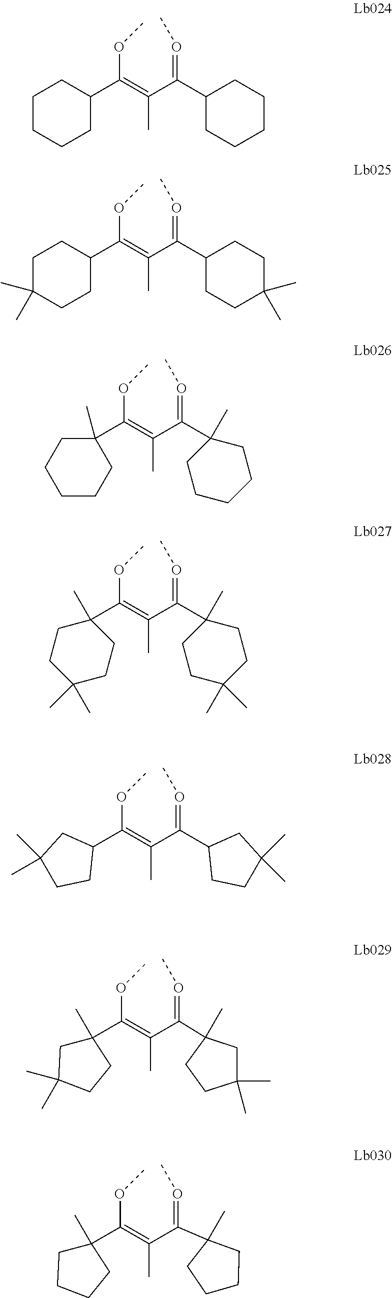

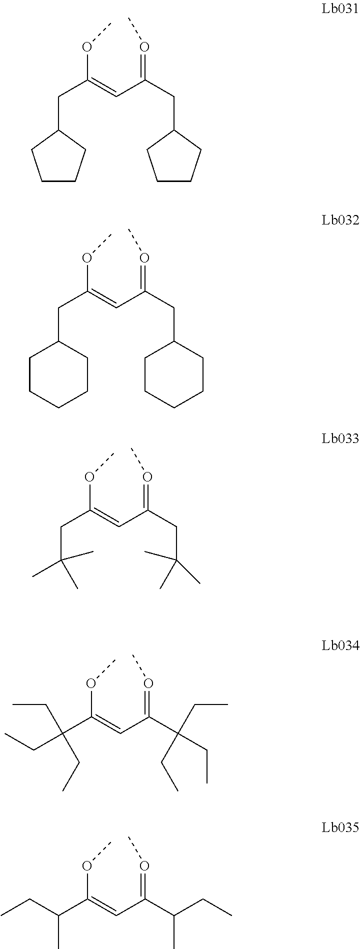

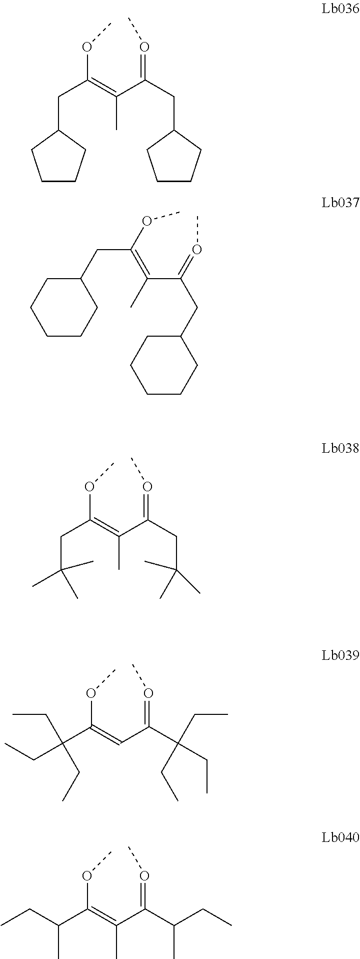

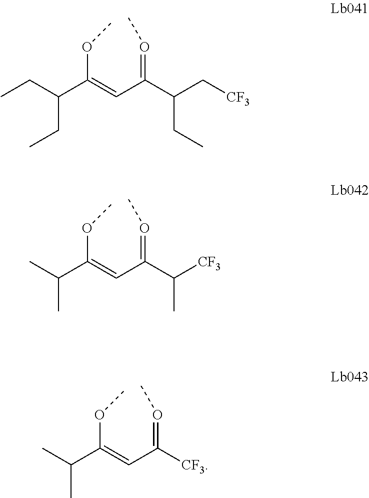

Another objective of the present disclosure is to provide an electroluminescent device, which includes a cathode, an anode and an organic layer arranged between the cathode and the anode, wherein the organic layer includes the metal iridium complex.

The organic layer includes a light-emitting layer, and the metal iridium complex serves as a doping material for the light-emitting layer, preferably a red light-emitting doping material.

The material of the present disclosure has advantages of high photochemical and electrochemical stability, narrow full width at half maximum, high color saturation, high luminous efficiency, and long device lifetime. The material of the present disclosure, as a phosphorescent material, can convert triplet excited states into light, thereby improving the luminous efficiency of organic electroluminescent devices and reducing energy consumption.

### BRIEF DESCRIPTION OF THE DRAWINGS

FIG. 1 is the ¹HNMR spectrum of compound La016;

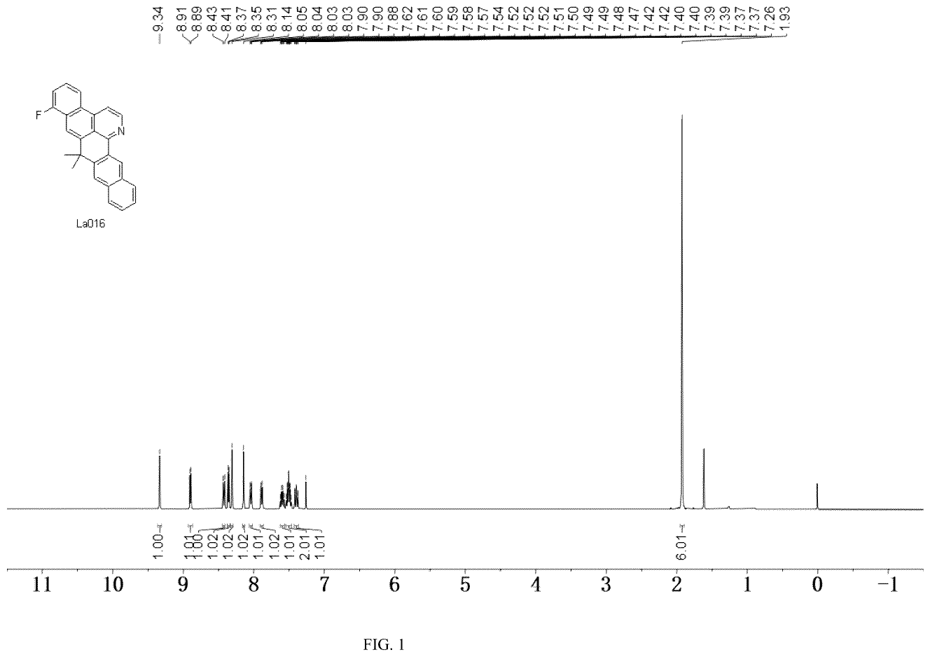

FIG. 2 is the ¹HNMR spectrum of compound Ir(La016)₂(Lb007); and

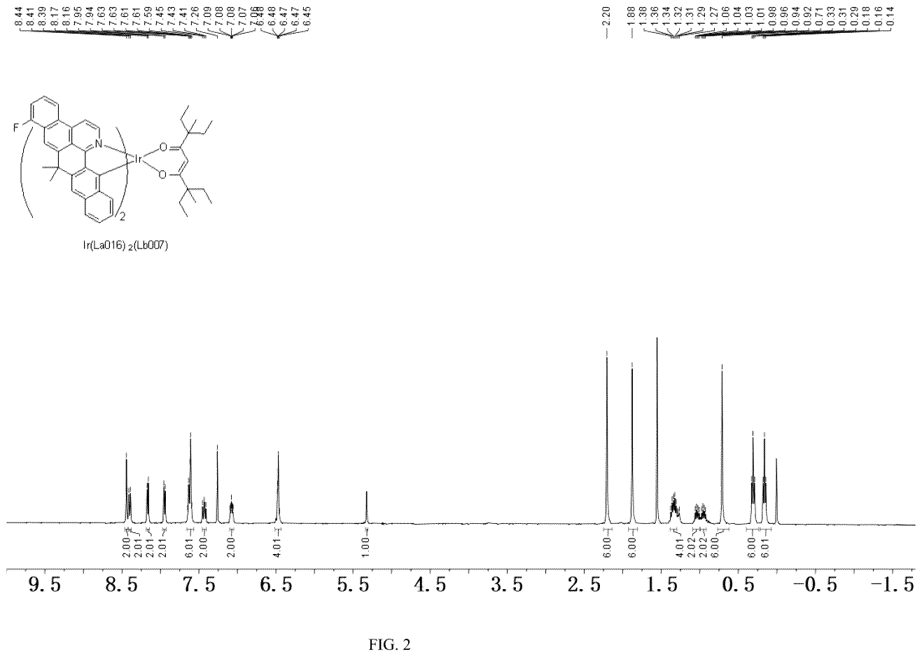

FIG. 3 is the UV-PL spectrum of compound Ir(La016)₂(Lb007).

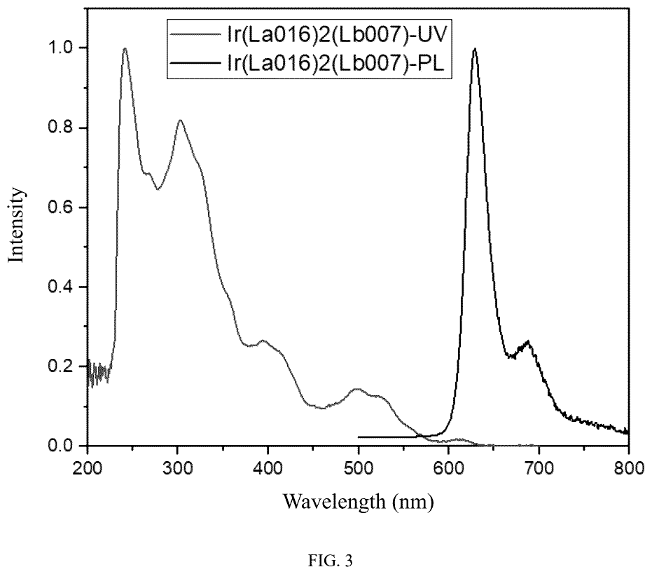

### DETAILED DESCRIPTION

A metal iridium complex has a general formula of Ir(La)(Lb)(Lc), and includes a structural formula of formula (1),

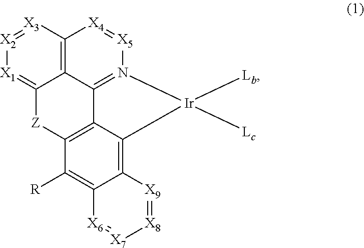

wherein

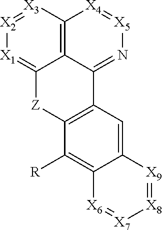

is a ligand La;
wherein Z is independently selected from CR_{A}R_{B};
wherein X₁-X₉ are each independently N or CR₀, and adjacent substituents R₀ are optionally connected to form a ring;
wherein X₁-X₅ have at least two adjacent CR₀ groups which may be connected to each other to form an aromatic ring with 6 to 30 carbon atoms or a heteroaromatic ring with 3 to 30 carbon atoms;
wherein R₀, R, R_{A}, and R_{B} are each independently selected from the group consisting of hydrogen, deuterium, halogen, a substituted or unsubstituted alkyl with 1 to 10 main-chain carbon atoms, a substituted or unsubstituted cycloalkyl with 3 to 20 ring-forming carbon atoms, a substituted or unsubstituted heteroalkyl with 1 to 10 main-chain carbon atoms, a substituted or unsubstituted heterocycloalkyl with 3 to 20 ring-forming carbon atoms, a substituted or unsubstituted C3-C30 alkylsilyl, a substituted or unsubstituted C3-C30 alkylgermyl, a substituted or unsubstituted C1-C10 alkoxy, a substituted or unsubstituted C7-C30 aralkyl, a substituted or unsubstituted C6-C30 aryloxy, a substituted or unsubstituted C2-C20 alkenyl, a substituted or unsubstituted C2-C20 alkynyl, a substituted or unsubstituted C6-C30 aryl and fused-ring aryl, a substituted or unsubstituted C3-C30 heteroaryl and fused-ring heteroaryl, a substituted or unsubstituted C3-C30 arylsilyl, a substituted or unsubstituted C0-C20 alkylamino, cyano, isocyano, and phosphino;
wherein substituents in R₀, R, R_{A}, and R_{B} refer to being substituted with deuterium, F, Cl, Br, C1-C4 alkyl, C1-C4 alkoxy, C3-C6 cycloalkyl, C1-C4 alkyl-substituted amino, C6-C10 aryl, C1-C4 alkyl-substituted C6-C10 aryl, cyano, isocyano, or phosphino;
wherein a heteroatom in the heteroalkyl, heterocycloalkyl or heteroaryl group is at least one of S, O, Se, P, B, N, Si and Ge;
wherein Lb and Lc are each monoanionic bidentate ligands; alternatively, two of La, Lb and Lc are arbitrarily connected to each other to form a multidentate ligand, or La, Lb and Lc are connected through a single group; and
wherein the structural formula of Lb and/or Lc is represented by ligand La

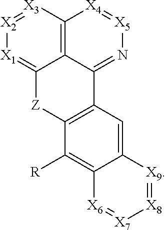

In accordance with the metal iridium complex in some embodiments of the present disclosure, the ligand La has one of the following structural formula (2) to formula (19):

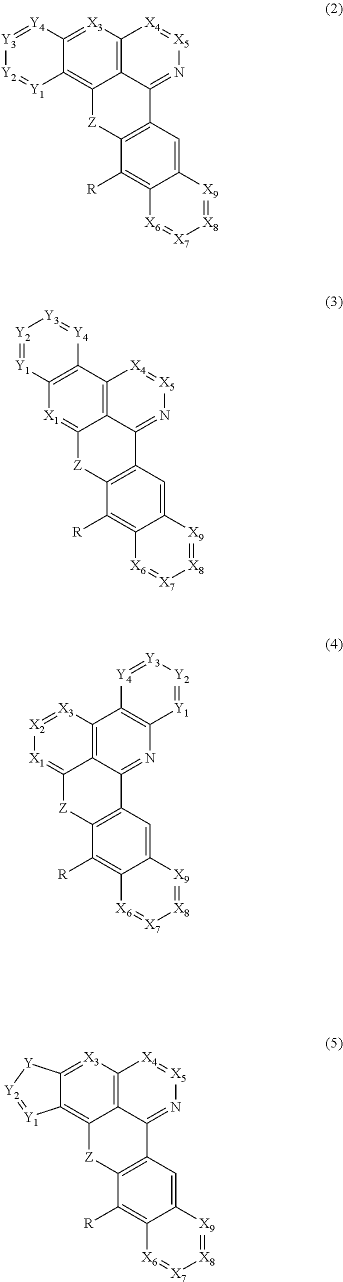

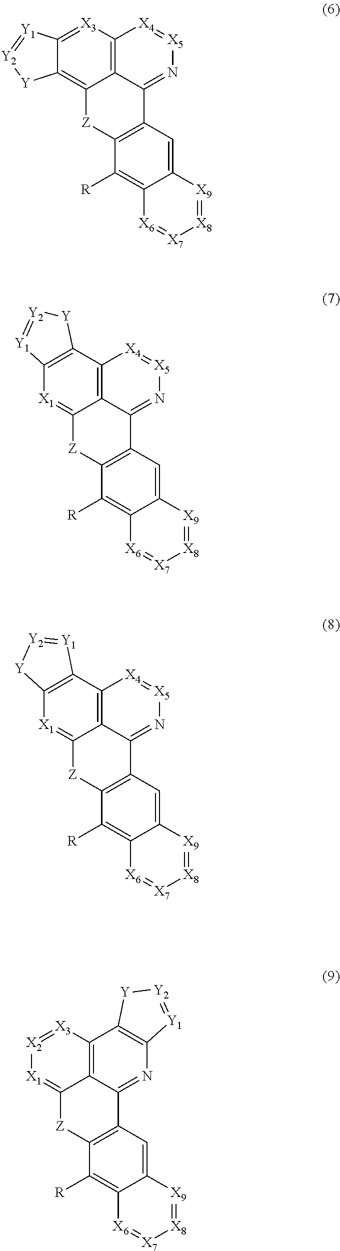

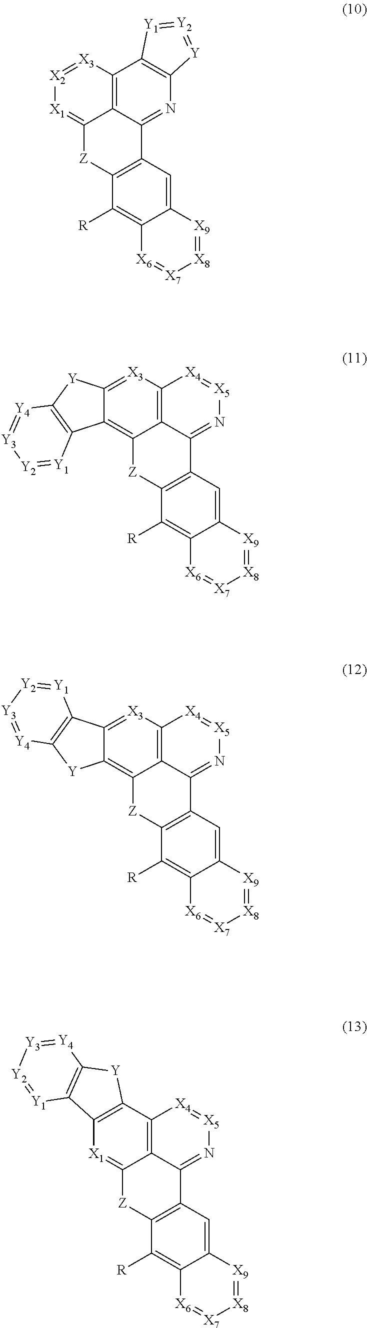

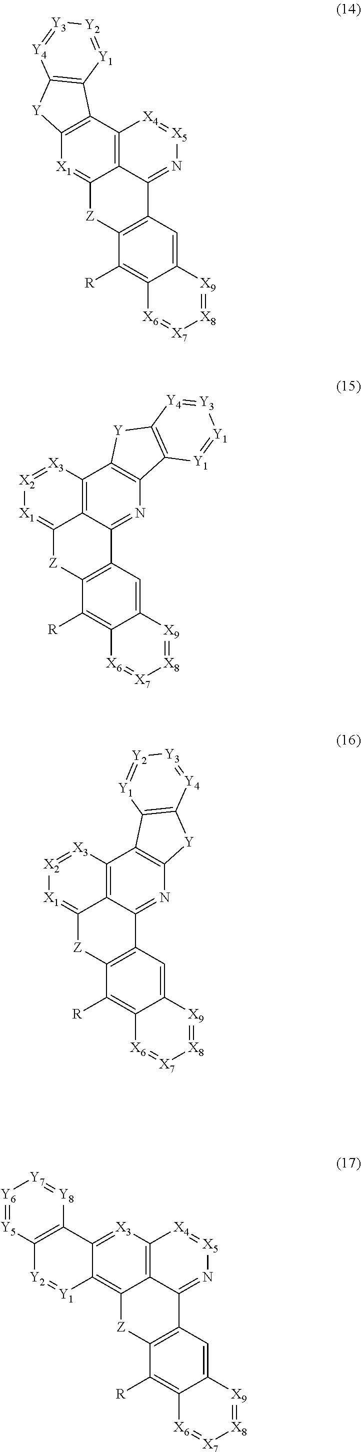

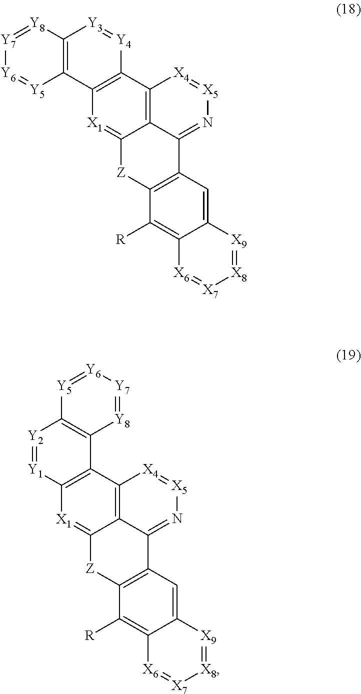

wherein Y is selected from the group consisting of O, S, Se, CR_{A}R_{B}, SIR_{A}R_{B}, GER_{A}R_{B}, NR_{A}R_{B}, BR_{A}R_{B}, and PR_{A}R_{B};
wherein Y₁-Y₈ are each independently N or CR₀, and adjacent substituents R₀ are optionally connected to form a ring; and
wherein X₁-X₉, R₀, R, R_{A}, R_{B}, and Z are as defined above.

In accordance with the metal iridium complex in some embodiments of the present disclosure, Lb has a structure shown in formula (21):

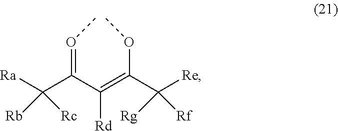

wherein a dotted line indicates a position connected to the metal iridium Ir; and
wherein Rₐ-R_{g} are each independently selected from the group consisting of hydrogen, deuterium, halogen, a substituted or unsubstituted alkyl with 1 to 10 main-chain carbon atoms, a substituted or unsubstituted cycloalkyl with 3 to 20 ring-forming carbon atoms, a substituted or unsubstituted heteroalkyl with 1 to 10 main-chain carbon atoms, and a substituted or unsubstituted heterocycloalkyl with 3 to 20 ring-forming carbon atoms; alternatively, two of Rₐ, R_{b}, and R_{c} are connected to form an alicyclic structure, and two of Rₑ, R_{f}, and R_{g} are connected to form an alicyclic structure; wherein substituents in Rₐ-R_{g} each refers to being substituted with deuterium, F, Cl, Br, C1-C4 alkyl, C1-C4 alkoxy, C3-C6 cycloalkyl, or C1-C4 alkyl-substituted amino, cyano, isocyano, or phosphino.

In accordance with the metal iridium complex in some embodiments of the present disclosure, Lc and La have a same structure, and are formed a structure of (La)₂Ir(Lb).
Rₐ, R_{b}, and R_{c} are the same as Rₑ, R_{f}, and R_{g}, respectively.
Rₐ, R_{b}, R_{c}, Rₑ, R_{f}, and R_{g} are each independently selected from the group consisting of hydrogen, deuterium, halogen, a substituted or unsubstituted alkyl with 1 to 10 main-chain carbon atoms, and a substituted or unsubstituted cycloalkyl with 3 to 20 ring-forming carbon atoms; alternatively, two of Rₐ, R_{b}, and R_{c} are connected to form an alicyclic structure, and two of Rₑ, R_{f}, and R_{g} are connected to form an alicyclic structure; Rₐ is selected from the group consisting of hydrogen, deuterium, halogen, and a substituted or unsubstituted alkyl with 1 to 10 main-chain carbon atoms, and wherein substituents in Rₐ-R_{g} each refers to being substituted with deuterium, F, Cl, Br, C1-C4 alkyl, or C3-C6 cycloalkyl.

In accordance with the metal iridium complex in some embodiments of the present disclosure, R is selected from the group consisting of hydrogen, a substituted or unsubstituted alkyl with 1 to 10 carbon atoms, a substituted or unsubstituted cycloalkyl with 3 to 20 ring-forming carbon atoms, a substituted or unsubstituted C3-C30 alkylsilyl, and a substituted or unsubstituted C3-C30 alkylgermyl.

In accordance with the metal iridium complex in some embodiments of the present disclosure, the ligand La has the structural formula of the formula (22) below:

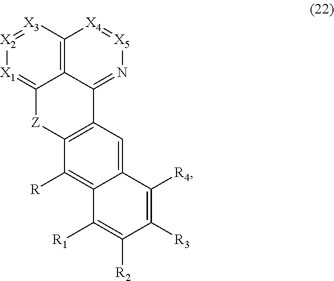

wherein X₁-X₅, R₀, R, and Z are as defined above; R₁-R₄ are each independently selected from the group consisting of hydrogen, deuterium, halogen, a substituted or unsubstituted alkyl with 1 to 10 main-chain carbon atoms, a substituted or unsubstituted cycloalkyl with 3 to 20 ring-forming carbon atoms, a substituted or unsubstituted heteroalkyl with 1 to 10 main-chain carbon atoms, a substituted or unsubstituted heterocycloalkyl with 3 to 20 ring-forming carbon atoms, a substituted or unsubstituted C3-C30 alkylsilyl, a substituted or unsubstituted C1-C10 alkoxy, a substituted or unsubstituted C7-C30 aralkyl, a substituted or unsubstituted C6-C30 aryloxy, a substituted or unsubstituted C6-C30 aryl, a substituted or unsubstituted C3-C30 heteroaryl, a substituted or unsubstituted C3-C30 arylsilyl, a substituted or unsubstituted C0-C20 alkylamino, cyano, isocyano, and phosphino, and adjacent substituents in R₁-R₄ are optionally connected to form a ring.

In accordance with the metal iridium complex in some embodiments of the present disclosure, the ligand La has one of the structural formulas represented by formula (23)-formula (24) below:

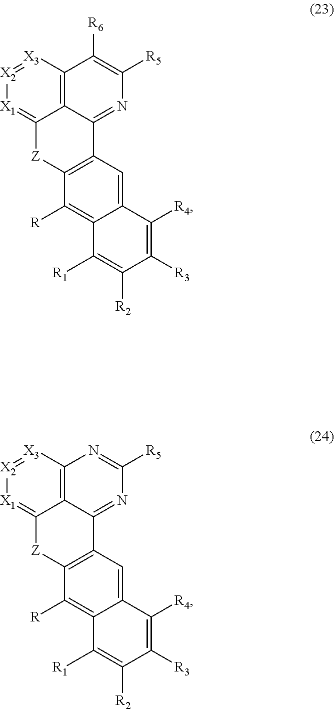

wherein X₁-X₃ are each independently N or CR₀, and two adjacent CR₀ groups among X₁-X₃ may be connected to each other to form an aromatic ring with 6 to 30 carbon atoms or a heteroaromatic ring with 3 to 30 carbon atoms; and
wherein R₀, R, and Z are as defined above; R₁-R₆ are each independently selected from the group consisting of hydrogen, deuterium, halogen, a substituted or unsubstituted alkyl with 1 to 8 main-chain carbon atoms, a substituted or unsubstituted cycloalkyl with 3 to 10 ring-forming carbon atoms, a substituted or unsubstituted heteroalkyl with 1 to 8 main-chain carbon atoms, a substituted or unsubstituted heterocycloalkyl with 3 to 10 ring-forming carbon atoms, a substituted or unsubstituted C3-C20 alkylsilyl, a substituted or unsubstituted C1-C8 alkoxy, a substituted or unsubstituted C7-C20 aralkyl, a substituted or unsubstituted C6-C20 aryloxy, a substituted or unsubstituted C6-C20 aryl, a substituted or unsubstituted C3-C20 heteroaryl, a substituted or unsubstituted C3-C20 arylsilyl, a substituted or unsubstituted C0-C10 alkylamino, cyano, and isocyano; and adjacent substituents in R₁-R₄ and R₅-R₆ are optionally connected to form a ring.

Hereinafter, examples of each group in the compound represented by formula (1) are described.

It should be noted that in this description, the term “a to b carbon atoms” in the expression “a substituted or unsubstituted X group with a to b carbon atoms” refers to the number of carbon atoms when the X group is unsubstituted, excluding the number of carbon atoms of the substituents when the X group is substituted.

C1-C10 alkyl is a linear or branched alkyl group, by way of example, methyl, ethyl, propyl, isopropyl, n-butyl, isobutyl, sec-butyl, tert-butyl, n-pentyl and isomers thereof, n-hexyl and isomers thereof, n-heptyl and isomers thereof, n-octyl and isomers thereof, n-nonyl and isomers thereof, n-decyl and isomers thereof, etc. In some embodiments of the present disclosure, the alkyl group is methyl, ethyl, propyl, isopropyl, n-butyl, isobutyl, sec-butyl, and tert-butyl. In some embodiments of the present disclosure, the alkyl group is propyl, isopropyl, isobutyl, sec-butyl, and tert-butyl.

C3-C20 cycloalkyl include, by way of example, cyclopropyl, cyclobutyl, cyclopentyl, cyclohexyl, 1-adamantyl, 2-adamantyl, 1-norbornyl, 2-norbornyl, and the like. In some embodiments of the present disclosure, the cycloalkyl group is cyclopentyl or cyclohexyl.

C2-C10 alkenyl include, by way of example, vinyl, propenyl, allyl, 1-butadienyl, 2-butadienyl, 1-hexatrienyl, 2-hexatrienyl, and 3-hexatrienyl. In some embodiments of the present disclosure, the alkenyl group is propenyl or allyl.

C1-C10 heteroalkyl is linear or branched alkyl, cycloalkyl, etc., which contains atoms other than carbon and hydrogen, and include, by way of example, mercaptomethylmethanyl, methoxymethanyl, ethoxymethanyle, tert-butoxymethanyl, N,N-dimethylmethanyl, epoxybutanyl, epoxypentanyl, epoxyhexanyl, etc. In some embodiments of the present disclosure, the heteroalkyl group is methoxymethanyl or epoxypentanyl.

Aryl includes monocyclic aryl, fused-ring aryl, or non-fused-ring aryl, and specific examples of aryl are phenyl, naphthalenyl, anthracenyl, phenanthrenyl, tetraphenyl, pyrenyl, chrysenyl, benzo[c]phenanthrenyl, benzo[g]chrysenyl, fluorenyl, benzofluorenyl, dibenzofluorenyl, biphenyl, terphenyl, quaterphenyl, fluoranthenyl, and the like. In some embodiments of the present disclosure, phenyl and naphthalenyl are included.

Heteroaryl includes monocyclic heteroaryl, fused-ring heteroaryl group or non-fused-ring heteroaryl. Specific examples of heteroaryl include, by way of pyrrolyl, pyrazinyl, pyridyl, pyrimidinyl, triazinyl, indolyl, isoindolyl, imidazolyl, furyl, benzofuranyl, isobenzofuranyl, dibenzofuranyl, dibenzothioenyl, azadibenzofuranyl, azadibenzothioenyl, diazadibenzofuranyl, diazadibenzothioenyl, quinolyl, isoquinolyl, quinoxalinyl, carbazolyl, phenanthridinyl, acridinyl, phenanthrolinyl, phenazinyl, phenothiazinyl, phenoxazinyl, oxazolinyl, oxadiazolyl, furazanyl, thienyl, benzothienyl, dihydroacridinyl, azacarbazolyl, diazacarbazolyl, quinazolinyl, and the like. In some embodiments of the present disclosure, the heteroaryl includes pyridyl, pyrimidinyl, triazinyl, dibenzofuranyl, dibenzothienyl, azadibenzofuranyl, azadibenzothienyl, diazadibenzofuranyl, diazadibenzothienyl, carbazolyl, azacarbazolyl, and diazacarbazolyl.

The adjacent substituents R₀ are optionally connected to form a ring, which may be an aromatic ring, a heteroaromatic ring, or an alicyclic ring. For example, two R₀ groups on adjacent X1 and X2 are bonded to each other and to the C atoms on the aryl or heteroaryl group where X1 and X2 are located to form an aromatic ring, a heteroaromatic ring, or an alicyclic ring. Similarly, an aromatic ring, a heteroaromatic ring, or an alicyclic ring is formed between X2 and X3, between X3 and X4, between X4 and X5, between X6 and X7, between X7 and X8, and between X8 and X9. Likewise, adjacent substituents in R₁-R₄ and in R₅-R₆ are optionally connected to form an aromatic ring, a heteroaromatic ring, or an alicyclic ring.

The following examples are only for the convenience of understanding of the present disclosure and should not be regarded as specific limitations to the present disclosure.

Raw materials, solvents, etc., involved in the synthesis of compounds in the present disclosure are all purchased from suppliers well known to those skilled in the art, such as Alfa and Acros.

### Synthesis of Ligand La008

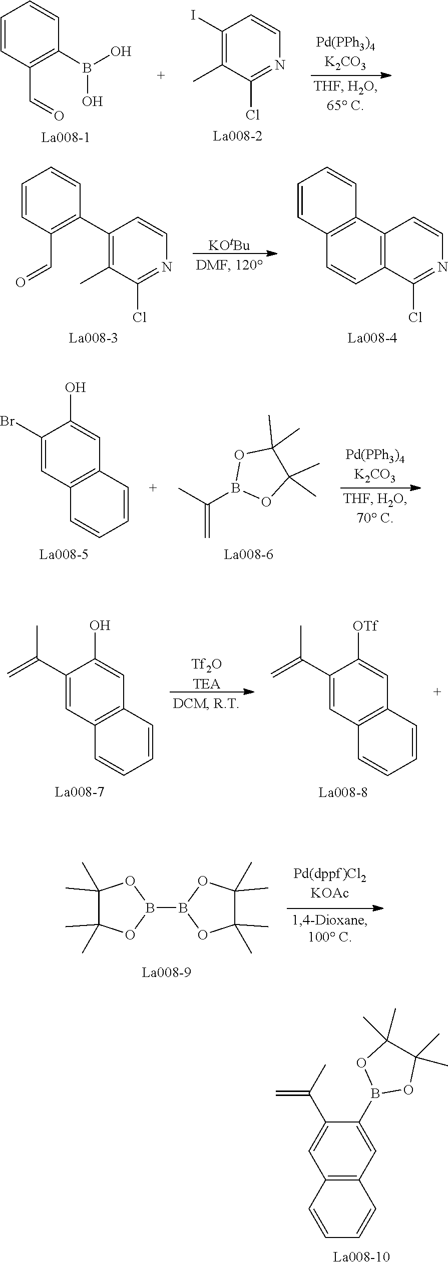

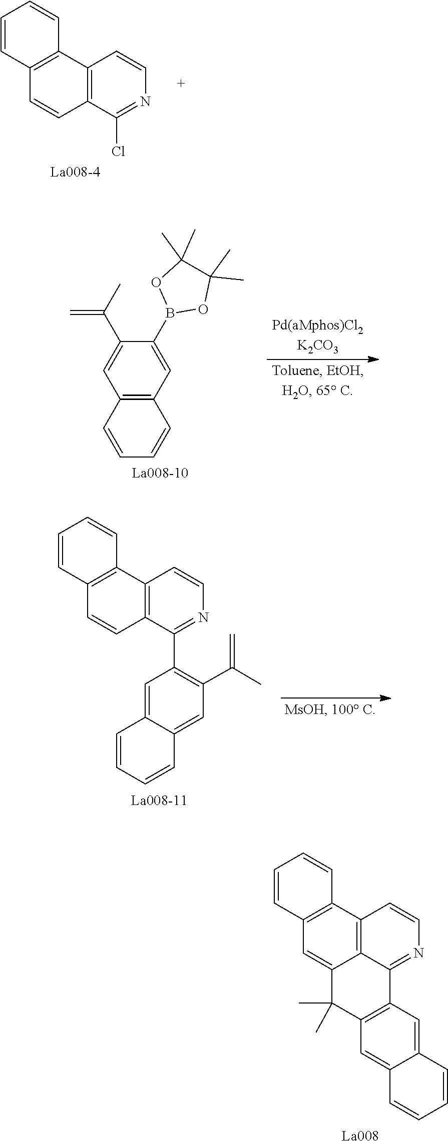

### Synthesis of Compound La008-3

Compound La008-1 (50.00 g, 333.47 mmol), La008-2 (84.52 g, 333.47 mmol), tetrakis(triphenylphosphine) palladium (3.85 g, 3.33 mmol), potassium carbonate (92.17 g, 666.93 mmol), tetrahydrofuran (750 mL) and deionized water (250 mL) were added to a 2,000 mL three-necked round-bottom flask, and the flask was evacuated and displaced with nitrogen 3 times. Under nitrogen protection, the mixture was stirred at 65° C. for 3 hours. TLC monitoring (the developing solvent was ethyl acetate:petroleum ether=1:20) showed that the raw material La008-2 was reacted completely.

After cooling to room temperature, the organic solvent was removed by concentration under reduced pressure. Ethyl acetate (800 mL) was added, and the mixture was washed with deionized water (3×300 mL). After standing for liquid separation, the organic phase was concentrated under reduced pressure at 65° C., and then separated by silica gel column chromatography (200-300 mesh silica gel, the eluent being ethyl acetate:petroleum ether=1:30). After elution, concentration under reduced pressure was conducted at 65° C. for 1 hour to obtain a white solid, which was Compound La008-3 (63.70 g, purity: 99.67%, yield: 82.45%), with a mass spectrum: 232.05 (M+H).

### Synthesis of Compound La008-4

Compound La008-3 (62.00 g, 267.61 mmol), potassium tert-butoxide (60.06 g, 535.22 mmol), and N, N-dimethylformamide (900 mL) were added to a 2,000 mL three-necked round-bottom flask, and the flask was evacuated and displaced with nitrogen 3 times. Under nitrogen protection, the mixture was stirred at 120° C. for 6 hours. TLC monitoring (the developing solvent was ethyl acetate: petroleum ether=1:10) showed that the raw material La008-3 was reacted completely.

The N, N-dimethylformamide was directly removed by concentration. Ethyl acetate (600 mL) was added, and the mixture was washed with deionized water (3×300 mL). After standing for liquid separation, the organic phase was concentrated, and then separated by silica gel column chromatography (200-300 mesh silica gel, the eluent being ethyl acetate:petroleum ether=1:30). Concentration was conducted to obtain a white solid, which was Compound La008-4 (37.74 g, purity: 99.86%, yield: 66.00%), with a mass spectrum: 214.04 (M+H).

### Synthesis of Compound La008-7

Compounds La008-5 (40.00 g, 179.32 mmol), La008-6 (36.16 g, 215.18 mmol), tetrakis(triphenylphosphine) palladium (2.07 g, 1.79 mmol), potassium carbonate (49.56 g, 358.63 mmol), tetrahydrofuran (600 mL) and deionized water (200 mL) were added to a 2,000 ml three-necked round-bottom flask, and the flask was evacuated and displaced with nitrogen 3 times. Under nitrogen protection, the mixture was stirred at 70° C. for 1 hour. TLC monitoring (the developing solvent was ethyl acetate:petroleum ether=1:20) showed that the raw material La008-5 was reacted completely.

After cooling to room temperature, the organic solvent was removed by concentration under reduced pressure. Ethyl acetate (500 mL) was added, and the mixture was washed with deionized water (3×150 mL). After standing for liquid separation, the organic phase was concentrated under reduced pressure at 65° C., and then separated by silica gel column chromatography (200-300 mesh silica gel, the eluent being ethyl acetate:petroleum ether=1:30). After elution, concentration under reduced pressure was conducted at 65° C. for 1 hour to obtain a light brown oily liquid, which was Compound La008-7 (28.29 g, purity: 99.53%, yield: 85.62%), with a mass spectrum: 185.28 (M+H).

### Synthesis of Compound La008-8

Compound La008-7 (27.00 g, 146.55 mmol), dichloromethane (350 mL) and triethylamine (29.65 g, 293.10 mmol) were added to a 1,000 ml three-necked round-bottom flask, and the flask was evacuated and displaced with nitrogen 3 times. Under nitrogen protection, the system was cooled to 0° C., and trifluoromethanesulfonic anhydride (53.74 g, 190.51 mmol) was added dropwise via a constant-pressure dropping funnel. The addition was completed over 30 minutes, and the mixture was stirred at this temperature for 30 minutes. TLC monitoring (the developing solvent was ethyl acetate: petroleum ether=1:20) showed that the raw material La008-7 was reacted completely. 100 mL of deionized water was added to the system, and the mixture was allowed to stand for liquid separation. The organic phase was concentrated under reduced pressure at 65° C. and then separated by silica gel column chromatography (200-300 mesh silica gel, where the eluent is petroleum ether). After elution, the mixture was concentrated under reduced pressure at 65° C. for 1 hour to obtain a light yellow oily liquid, which was compound La008-8 (41.72 g, purity: 99.32%, yield: 90.00%), with a mass spectrum: 317.02 (M+H).

### Synthesis of Compound La008-10

Compound La008-8 (38.00 g, 120.14 mmol), La008-9 (36.61 g, 144.17 mmol), 1,1-bis(diphenylphosphino) ferrocene palladium (II) dichloride (1.74 g, 2.40 mmol), potassium acetate (23.58 g, 240.28 mmol), and 1,4-dioxane (400 mL) were added to a 1,000 mL three-necked round-bottom flask, and the flask was evacuated and displaced with nitrogen 3 times. Under nitrogen protection, the system was heated to 80° C. and reacted for 4 hours. TLC monitoring (the developing solvent was ethyl acetate:petroleum ether=1:20) showed that the raw material La008-8 was reacted completely.

1,4-Dioxane was removed by concentration. Ethyl acetate (500 mL) was added, and the mixture was washed with deionized water (3×200 mL). After standing for liquid separation, the organic phase was concentrated under reduced pressure at 65° C., and then separated by silica gel column chromatography (200-300 mesh silica gel, the eluent being ethyl acetate:petroleum ether=1:30). After elution, concentration was conducted under reduced pressure at 65° C. for 1 hour to obtain a white solid, which was Compound La008-10 (26.74 g, purity: 98.55%, yield: 75.64%), with a mass spectrum: 295.22 (M+H).

### Synthesis of Compound La008-11

Compound La008-4 (18.00 g, 84.24 mmol), La008-10 (26.02 g, 88.46 mmol), bis(4-dimethylaminophenyl di-tert-butylphosphino) palladium (II) dichloride (1.19 g, 1.68 mmol), potassium carbonate (23.28 g, 168.48 mol), toluene (270 mL), ethanol (90 mL) and deionized water (90 mL) were added to a 1,000 mL three-necked flask, and the flask was evacuated and displaced with nitrogen 3 times. Under nitrogen protection, the mixture was heated to 65° C. and stirred for 5 hours. TLC monitoring (the developing solvent being ethyl acetate:petroleum ether=1:15) showed that the raw material La008-4 was reacted completely.

After cooling to room temperature, the organic solvent was removed by concentration under reduced pressure. Ethyl acetate (600 mL) was added, and the mixture was washed with deionized water (3×200 mL). After standing for liquid separation, the organic phase was concentrated, and then separated by silica gel column chromatography (200-300 mesh silica gel, the eluent being ethyl acetate:petroleum ether=1:25). Concentration was conducted to obtain a white solid, which was Compound La008-11 (24.24 g, purity: 99.45%, yield: 83.31%), with a mass spectrum: 346.16 (M+H).

### Synthesis of Compound La008

Compound La008-11 (20.00 g, 57.90 mmol) and methanesulfonic acid (200 mL) were added to a 500 mL three-necked flask, and the flask was evacuated and displaced with nitrogen 3 times. Under nitrogen protection, the mixture was heated to 100° C. and stirred for 6 hours. TLC monitoring (the developing solvent being ethyl acetate:petroleum ether=1:15) showed that the raw material La008-11 was reacted completely.

After cooling to 5° C., 200 mL of deionized water was added to quench the reaction, and the precipitated solid was filtered by suction. The filter cake was washed with deionized water (200 mL) to obtain a white solid. Crystallization was performed using 15 volumes of toluene and 5 volumes of methanol. The precipitated solid was filtered by suction, and the filter cake was vacuum-dried at 90° C. for 5 hours to obtain a white solid, which was compound La008 (11.03 g, purity: 99.86%, yield: 55.14%), with a mass spectrum: 346.16 (M+H).

### Synthesis of Compound Ir(La008)₂(Lb005)

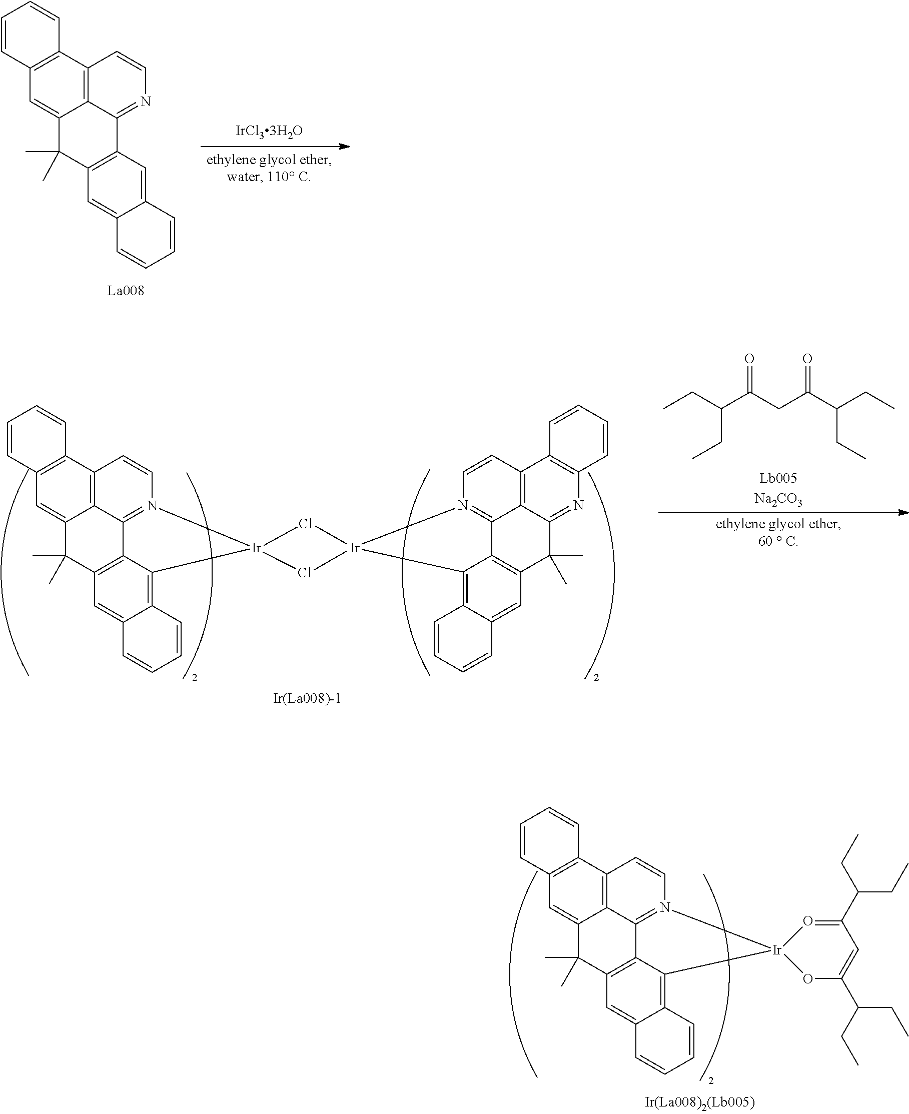

### Synthesis of Compound Ir(La008)-1

Compound La008 (10.00 g, 29.00 mmol) and iridium trichloride trihydrate (3.40 g, 9.66 mmol) were added to a 500 mL three-necked round-bottom flask. Ethylene glycol ether (130 mL) and deionized water (42 ml) were added. The flask was evacuated and displaced with nitrogen 3 times, and the mixture was then heated to 110° C. and stirred under reflux for 24 hours.

After cooling to room temperature, methanol (150 mL) was added, and the mixture was slurried at room temperature for 1 hour. The mixture was then filtered by suction, and the filter cake was washed with methanol (50 mL). The solid was vacuum-dried at 80° C. to obtain compound Ir(La008)-1 (6.86 g, yield: 77.51%). The obtained compound was used directly in the next step without purification.

### Synthesis of Compound Ir(La008)₂(Lb005)

Compound Ir(La008)-1 (6.60 g, 3.60 mmol), Lb005 (3.82 g, 18.00 mmol), sodium carbonate (3.81 g, 36.00 mmol), and ethylene glycol ether (66 mL) were added to a 250 mL single-necked round-bottom flask, and the flask was evacuated and displaced with nitrogen 3 times. Under nitrogen protection, the mixture was stirred at 60° C. for 24 hours. TLC monitoring (the developing solvent was methanol:dichloromethane=1:100) showed that Ir(La008)-1 was reacted completely.

After cooling to room temperature, methanol (100 mL) was added and the mixture was slurried at room temperature for 1.5 hours. The mixture was then filtered by suction, and the filter cake was dissolved in dichloromethane (100 mL) and filtered through 300-400 mesh silica gel (50 g). The filtrate was washed with deionized water (3×50 mL) and concentrated under reduced pressure at 60° C. to obtain a red solid. The red solid was recrystallized twice with toluene and methanol to obtain compound Ir(La008)₂(Lb005) (3.44 g, purity: 99.83%, yield: 43.77%). 3.44 g of crude Ir(La008)₂(Lb005) was purified by sublimation to obtain sublimated pure Ir(La008)₂(Lb005) (2.48 g, purity: 99.80%, yield: 72.10%), with a mass spectrum: 1093.44 (M+H).

¹H NMR (400 MHZ, CDCl₃) δ 8.40 (dd, J=6.0, 3.4 Hz, 2H), 8.29 (d, J=2.2 Hz, 2H), 8.24-8.19 (m, 2H), 8.18-8.14 (m, 3H), 8.13 (s, 1H), 7.95 (m, 2H), 7.89-7.83 (m, 2H), 7.55-7.49 (m, 4H), 7.46 (m, 2H), 7.33 (m, 2H), 7.27 (d, J=9.5 Hz, 2H), 4.79 (s, 1H), 2.71 (m, 2H), 1.67-1.54 (m, 16H), 1.42-1.28 (m, 4H), 0.95-0.83 (m, 12H).

### Synthesis of Ligand La013

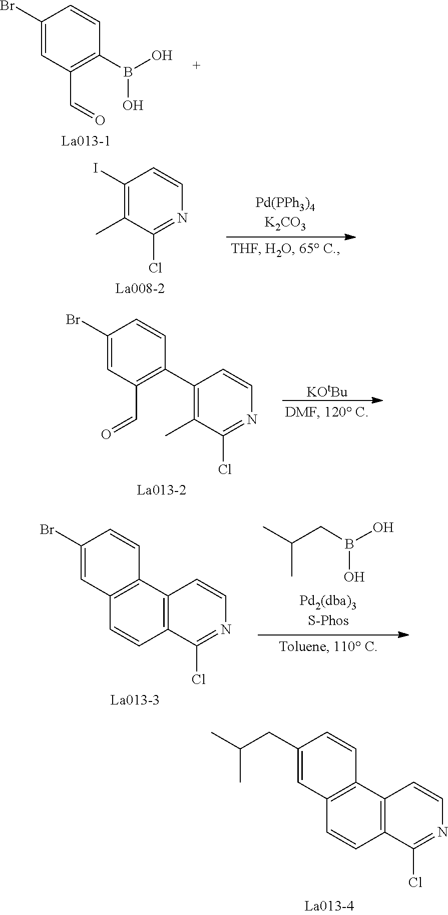

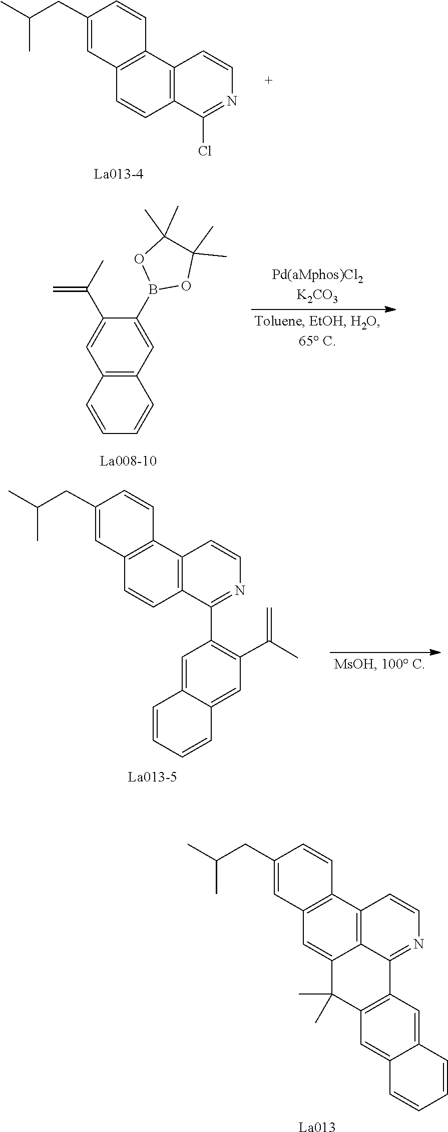

### Synthesis of Compound La013-2

Referring to the synthesis and purification method for compound La008-3, only by changing the corresponding raw materials, target compound La013-2 (65.04 g, purity: 99.68%, yield: 83.22%) was obtained, with a mass spectrum: 310.08 (M+H).

### Synthesis of Compound La013-3

Referring to the synthesis and purification method for compound La008-4, only by changing the corresponding raw materials, target compound La013-3 (38.59 g, purity: 99.74%, yield: 65.42%) was obtained, with a mass spectrum: 292.04 (M+H).

### Synthesis of Compound La013-4

Compound La013-3 (36.00 g, 123.05 mmol), isobutylboric acid (25.09 g, 246.10 mmol), tris(dibenzylideneacetone) dipalladium (2.25 g, 2.46 mmol), 2-dicyclohexylphosphine-2′,6′-dimethoxy-biphenyl (2.09 g, 4.92 mmol), potassium phosphate (52.24 g, 246.10 mmol), and toluene (550 mL) were added to a 1,000 mL three-necked round-bottom flask, and the flask was evacuated and displaced with nitrogen 3 times. Under nitrogen protection, the mixture was stirred at 110° C. for 2 hours. TLC monitoring (the developing solvent being ethyl acetate:petroleum ether=1:10) showed the raw material La013-3 was reacted completely.

After cooling to room temperature, ethyl acetate (200 mL) was added, and the mixture was washed with deionized water (3×300 mL). After standing for liquid separation, the organic phase was concentrated and then separated by silica gel column chromatography (200-300 mesh silica gel, the eluent is ethyl acetate:petroleum ether=1:20). Concentration was conducted to obtain a white sugar-like solid, which was compound La013-4 (24.92 g, purity: 99.83%, yield: 75.06), with a mass spectrum: 270.12 (M+H).

### Synthesis of Compound La013-5

Referring to the synthesis and purification method for compound La008-11, only by changing the corresponding raw materials, target compound La013-5 (35.07 g, purity: 99.74%, yield: 85.06%) was obtained, with a mass spectrum: 402.22 (M+H).

### Synthesis of Compound La013

Referring to the synthesis and purification method for compound La008, only by changing the corresponding raw materials, target compound La013 (25.12 g, purity: 99.75%, yield: 64.33%) was obtained, with a mass spectrum: 402.22 (M+H).

### Synthesis of Compound Ir(La013)₂(Lb005)

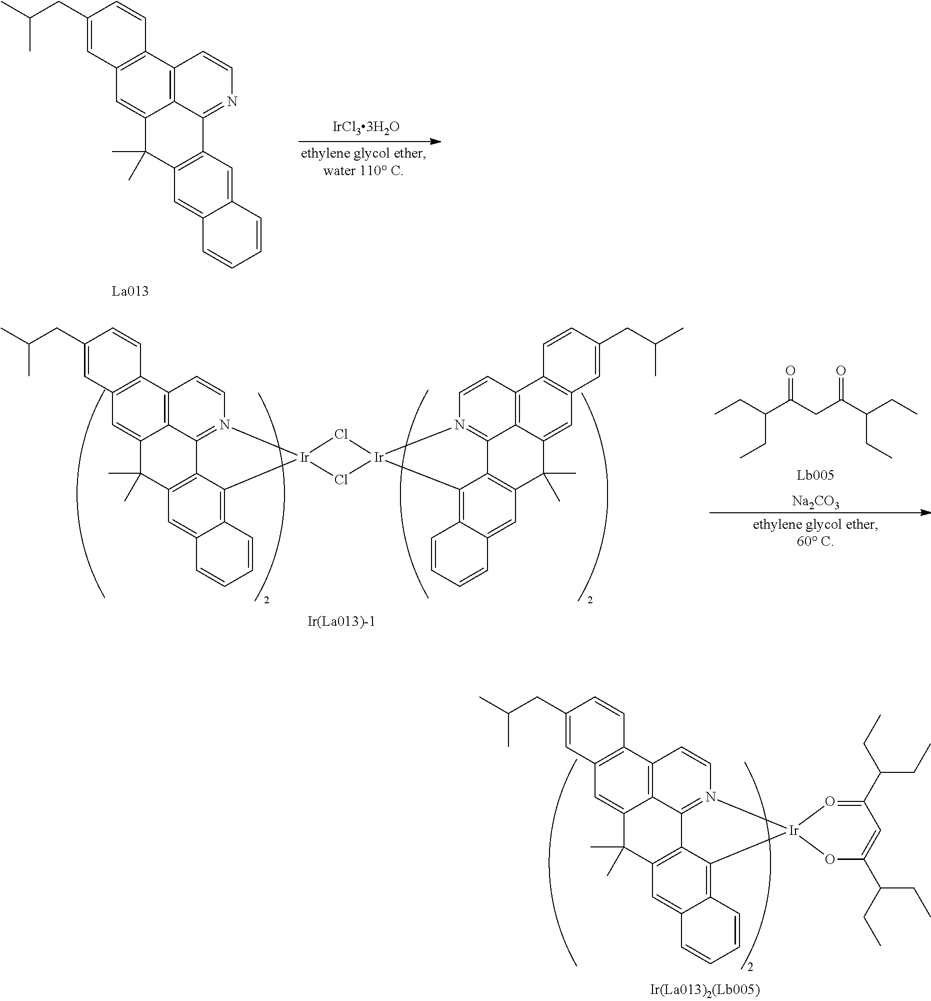

### Synthesis of Compound Ir(La013)-1

Referring to the synthesis and purification method for compound Ir(La008)-1, only by changing the corresponding raw materials, compound Ir(La013)-1 (10.65 g, yield: 76.21%) was obtained, which was used directly in the next step without purification.

### Synthesis of Compound Ir(La013)₂(Lb005)

Referring to the synthesis and purification method for compound Ir(La008)₂(Lb005), only by changing the corresponding raw materials, a red solid as compound Ir(La013)₂(Lb005) (6.04 g, purity: 99.78%, yield: 47.77%) was obtained. 6.04 g of crude Ir(La013)₂(Lb005) was purified by sublimation to obtain sublimated pure Ir(La013)₂(Lb005) (3.95 g, purity: 99.75%, yield: 61.59%), with a mass spectrum: 1205.52 (M+H).

¹H NMR (400 MHZ, CDCl₃) δ 8.56 (d, J=2.2 Hz, 2H), 8.24-8.19 (m, 2H), 8.18-8.14 (m, 3H), 8.13 (s, 1H), 7.88-7.82 (m, 4H), 7.60 (m, 2H), 7.46 (m, 2H), 7.33 (m, 2H), 7.27 (d, J=9.5 Hz, 2H), 7.20 (m, 2H), 4.79 (s, 1H), 2.71 (m, 2H), 2.62 (dt, J=7.0, 0.9 Hz, 4H), 1.92 (m, 2H), 1.69-1.50 (m, 16H), 1.45-1.26 (m, 4H), 0.91-0.84 (m, 24H).

### Synthesis of Ligand La016

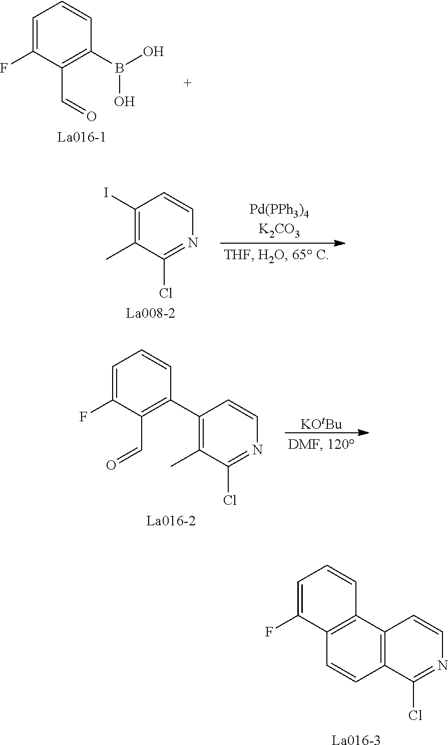

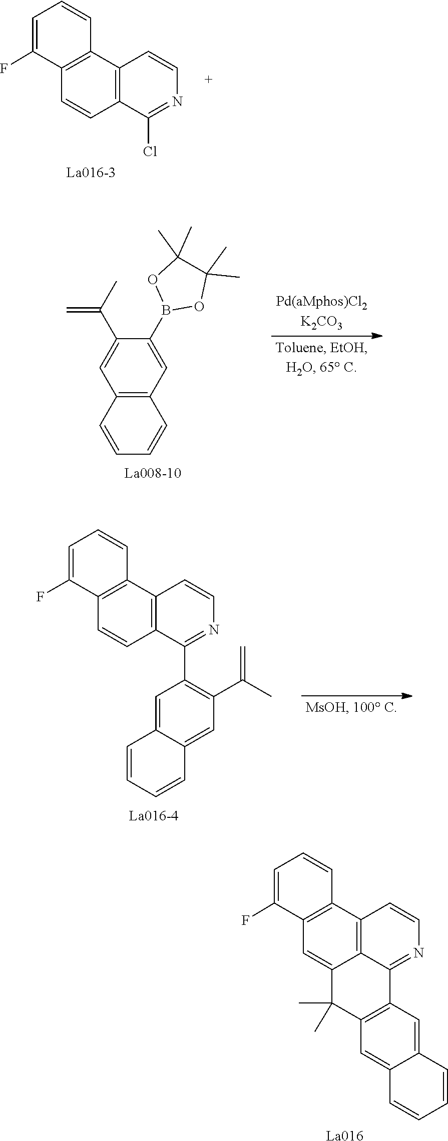

### Synthesis of Compound La016-2

Referring to the synthesis and purification method for compound La008-3, only by changing the corresponding raw materials, target compound La016-2 (40.21 g, purity: 99.84%, yield: 85.26%) was obtained, with a mass spectrum: 250.05 (M+H).

### Synthesis of Compound La016-3

Referring to the synthesis and purification method for compound La008-4, only by changing the corresponding raw materials, target compound La016-3 (23.00 g, purity: 99.71%, yield: 63.62%) was obtained, with a mass spectrum: 232.14 (M+H).

### Synthesis of Compound La016-4

Referring to the synthesis and purification method for compound La008-11, only by changing the corresponding raw materials, target compound La016-4 (18.62 g, purity: 99.46%, yield: 84.51%) was obtained, with a mass spectrum: 364.14 (M+H).

### Synthesis of Compound La016

Referring to the synthesis and purification method for compound La008, only by changing the corresponding raw materials, target compound La016 (10.03 g, purity: 99.87%, yield: 56.03%) was obtained, with a mass spectrum: 364.14 (M+H).

¹H NMR (400 MHZ, CDCl₃) δ 9.34 (s, 1H), 8.91 (d, J=5.6 Hz, 1H), 8.43 (d, J=8.3 Hz, 1H), 8.37 (d, J=5.6 Hz, 1H), 8.31 (s, 1H), 8.14 (s, 1H), 8.05-8.03 (m, 1H), 7.90-7.88 (m, 1H), 7.62-7.57 (m, 1H), 7.54-7.47 (m, 2H), 7.42-7.37 (m, 1H), 1.93 (s, 6H).

### Synthesis of Compound Ir(La016)₂(Lb005)

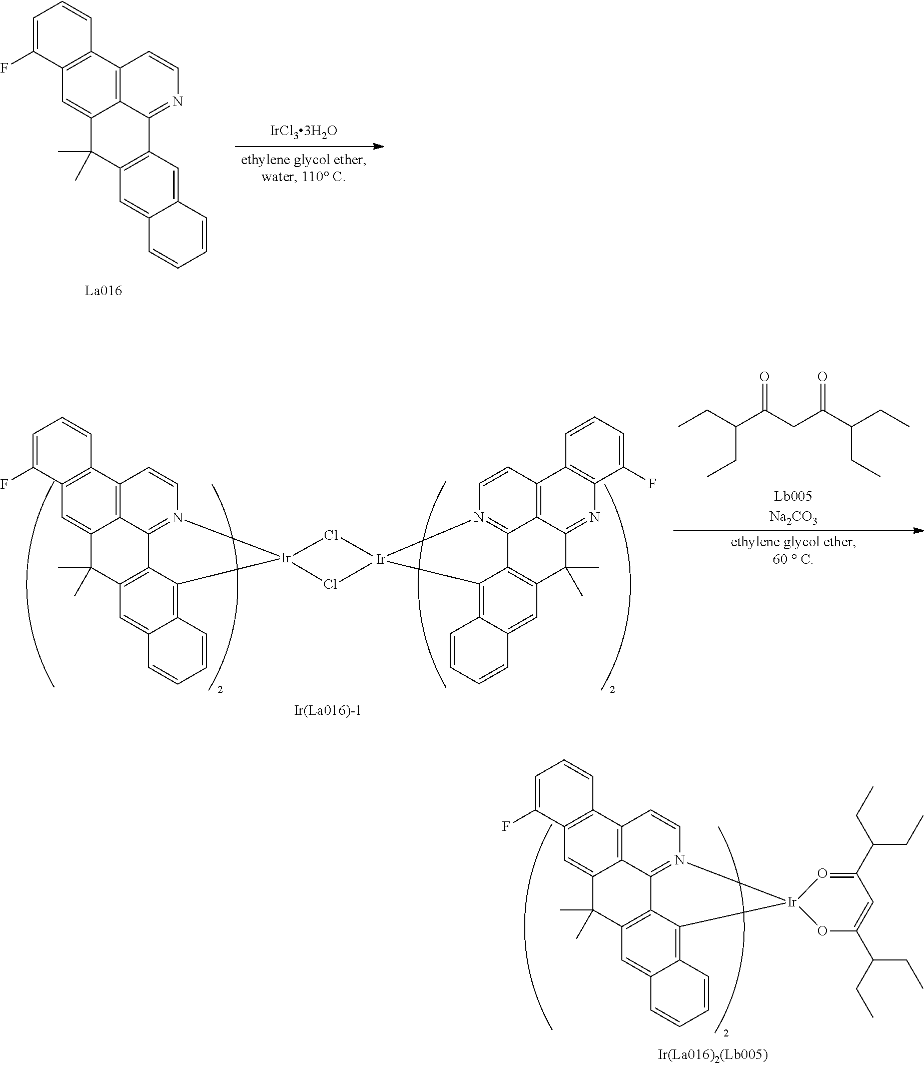

### Synthesis of Compound Ir(La016)-1

Referring to the synthesis and purification method for compound Ir(La008)-1, only by changing the corresponding raw materials, compound Ir(La016)-1 (7.06 g, yield: 78.05%) was obtained, which was used directly in the next step without purification.

### Synthesis of Compound Ir(La016)₂(Lb005)

Referring to the synthesis and purification method for compound Ir(La008)₂(Lb005), only by changing the corresponding raw materials, a red solid as compound Ir(La016)₂(Lb005) (4.68 g, purity: 99.85%, yield: 48.06%) was obtained. 4.68 g of crude Ir(La016)₂(Lb005) was purified by sublimation to obtain sublimated pure Ir(La016)₂(Lb005) (3.02 g, purity: 99.81%, yield: 64.53%), with a mass spectrum: 1129.40 (M+H).

¹H NMR (400 MHZ, CDCl₃) δ 8.62 (s, 2H), 8.34 (dd, J=7.6, 0.8 Hz, 2H), 8.24-8.18 (m, 4H), 8.16 (d, J=2.2 Hz, 2H), 7.88-7.82 (m, 2H), 7.53 (t, J=7.6 Hz, 2H), 7.46 (td, J=7.4, 1.5 Hz, 2H), 7.33 (td, J=7.2, 1.1 Hz, 2H), 7.29-7.23 (m, 4H), 4.79 (s, 1H), 2.71 (m, 2H), 1.67-1.55 (m, 16H), 1.42-1.30 (m, 4H), 0.90-0.86 (m, 12H).

### Synthesis of Compound Ir(La016)₂(Lb007)

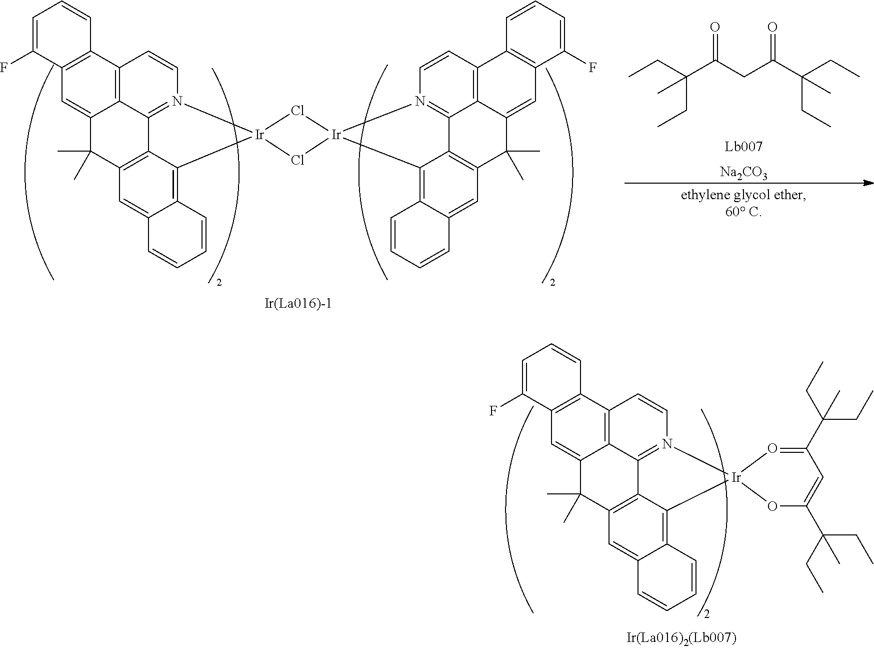

### Synthesis of Compound Ir(La016)₂(Lb007)

Referring to the synthesis and purification method of compound Ir(La008)₂(Lb005), only by changing the corresponding raw materials, a red solid as compound Ir(La016)₂(Lb007) (5.36 g, purity: 99.88%, yield: 49.06%) was obtained. 5.36 g of crude Ir(La016)₂(Lb007) was purified by sublimation to obtain sublimated pure Ir(La016)₂(Lb007) (3.48 g, purity: 99.85%, yield: 64.93%) was obtained, with a mass spectrum: 1157.42 (M+H).

¹H NMR (400 MHZ, CDCl₃) δ 8.44 (s, 2H), 8.41 (d, J=8.3 Hz, 2H), 8.17 (d, J=6.5 Hz, 2H), 7.95 (d, J=6.6 Hz, 2H), 7.65-7.59 (m, 6H), 7.45-7.40 (m, 2H), 7.10-7.06 (m, 2H), 6.48-6.45 (m, 4H), 5.32 (s, 1H), 2.20 (s, 6H), 1.88 (s, 6H), 1.38-1.27 (m, 4H), 1.06-1.01 (m, 2H), 0.98-0.92 (m, 2H), 0.71 (s, 6H), 0.31 (t, J=7.4 Hz, 6H), 0.16 (t, J=7.3 Hz, 6H).

### Synthesis of Ligand La018

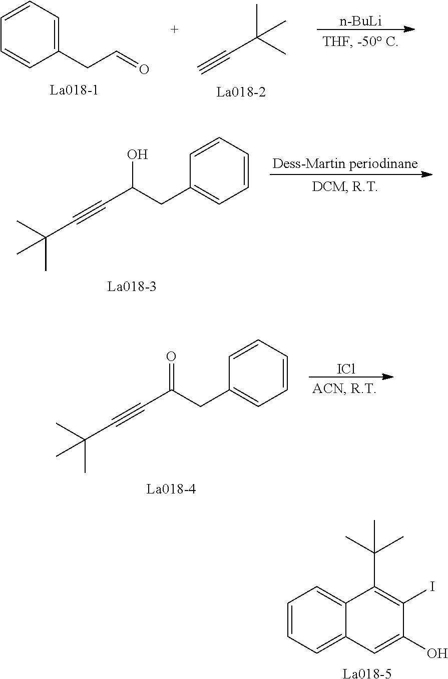

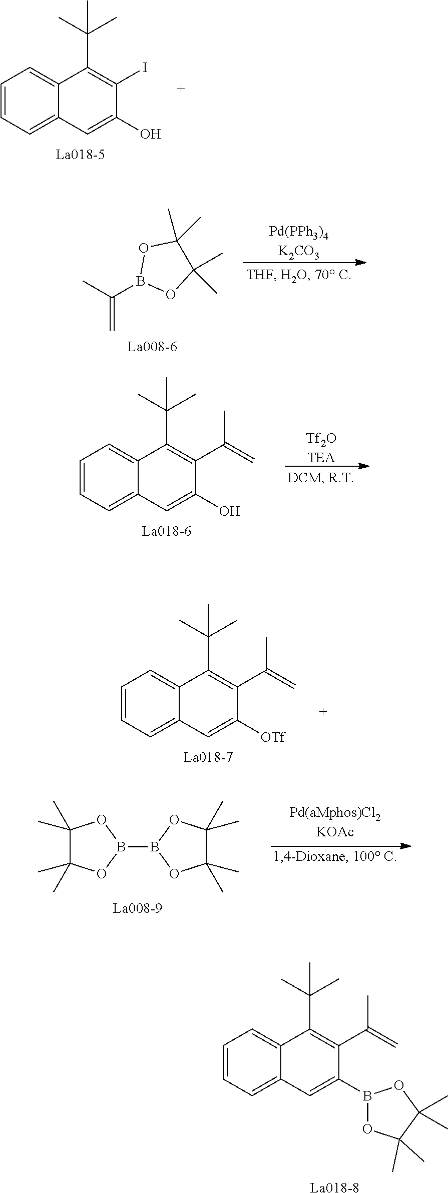

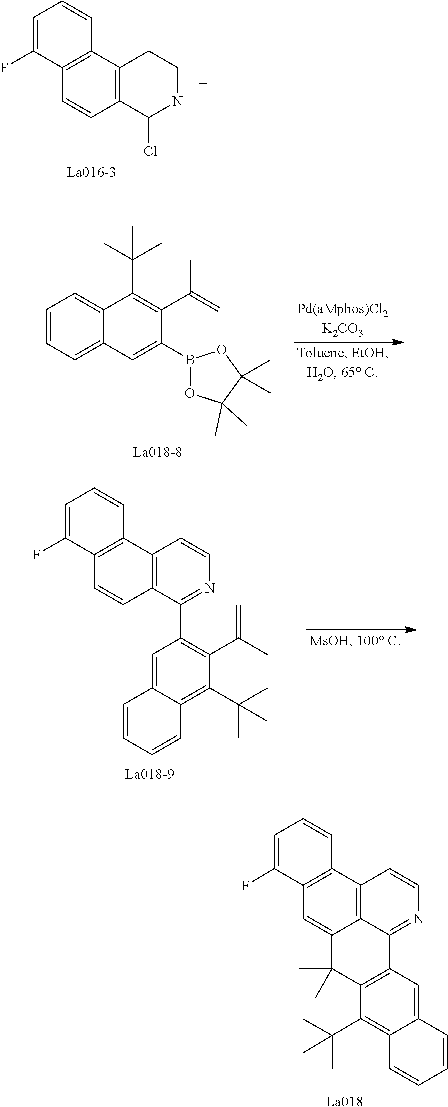

### Synthesis of Compound La018-3

Compound La018-2 (41.02 g, 499.37 mmol) and tetrahydrofuran (410 mL) were added to a 2,000 mL three-necked round-bottom flask, and the flask was evacuated and displaced with nitrogen three times. Under nitrogen protection, the system was cooled to −50° C. After the internal temperature dropped to the specified value, a solution of n-butyllithium (313 mL, 1.6 mol/L in n-hexane) was dropwise added. The addition was completed within 1 hour, and the mixture was stirred at −50° C. for 1 hour. La018-1 (30.00 g, 249.69 mmol) dissolved in 150 mL was add dropwise to the above low temperature system. The addition was completed in 30 minutes, and stirring was continued for another 30 minutes. TLC monitoring (the developing solvent was ethyl acetate:petroleum ether=1:15) showed that the raw material La018-1 was reacted completely.

Deionized water (100 mL) was added dropwise to the system for quenching the reaction, and the mixture was heated to room temperature and concentrated under reduced pressure to remove the organic solvent. Ethyl acetate (900 mL) was then added and washed with deionized water (3×300 mL). The mixture was allowed to stand for separation. The organic phase was concentrated under reduced pressure at 65° C. and separated by silica gel column chromatography (200-300 mesh silica gel, the eluent is ethyl acetate:petroleum ether=1:25). After elution, concentration was conducted under reduced pressure at 65° C. for 1 hour to obtain a light yellow liquid, which was compound La018-3 (43.14 g, purity: 99.76%, yield: 85.41%), with a mass spectrum: 203.12 (M+H).

### Synthesis of Compound La018-4

Compound La018-3 (40.00 g, 197.73 mmol) and dichloromethane (800 mL) were added to a 2,000 mL three-necked round-bottom flask and stirred at room temperature. Dess-Martin periodinane (88.05 g, 207.61 mmol) was added in batches over 1 hour. The mixture was then stirred at room temperature for 2 hours. TLC and monitoring (the developing solvent was ethyl acetate:petroleum ether=1:10) showed that the raw material La018-3 was reacted completely.

The mixture was washed with deionized water (3×400 mL), and allowed to stand for liquid separation. The organic phase was concentrated under reduced pressure at 65° C., and then separated by silica gel column chromatography (200-300 mesh silica gel, the eluent is ethyl acetate:petroleum ether=1:20). After elution, the mixture was concentrated under reduced pressure at 65° C. for 1 hour to obtain a light yellow liquid, which was compound La018-4 (35.66 g, purity: 99.88%, yield: 90.05%), with a mass spectrum: 201.02 (M+H).

### Synthesis of Compound La018-5

Compound La018-4 (32.00 g, 159.78 mmol) and acetonitrile (350 mL) were added to a 1,000 mL three-necked round-bottom flask, and the flask was evacuated replaced with nitrogen three times. lodine monochloride (51.88 g, 319.55 mmol) was then added dropwise at room temperature. The addition was completed over 15 minutes. The mixture was then stirred at room temperature for 4 hours. TLC monitoring (the developing solvent was ethyl acetate:petroleum ether=1:15) showed that the raw material La018-4 was reacted completely.

Saturated aqueous sodium bisulfite solution (100 mL) was added to quench the reaction, and the mixture was stirred at room temperature for 30 minutes. The organic phase was removed by concentration. To this mixture, ethyl acetate (600 mL) was added, and the mixture was washed with deionized water (3×250 mL). The mixture was allowed to stand for liquid separation, and the organic phase was concentrated under reduced pressure at 65° C. and then separated by silica gel column chromatography (200-300 mesh silica gel, the eluent is ethyl acetate:petroleum ether=1:25). After elution, concentration was conduction under reduced pressure at 65° C. for 1 hour to obtain a white liquid, which was compound La018-5 (36.51 g, purity: 99.80%, yield: 70.06%), with a mass spectrum: 327.02 (M+H).

### Synthesis of Compound La018-6

Referring to the synthesis and purification method for compound La008-7, only by changing the corresponding raw materials, compound La018-6 (26.51g, purity: 99.00%, yield: 85.14%) was obtained, with a mass spectrum: 241.06 (M+H).

### Synthesis of Compound La018-7

Referring to the synthesis and purification method for compound La008-8, only by changing the corresponding raw materials, compound La018-7 (38.09 g, purity: 99.52%, yield: 88.67%) was obtained, with a mass spectrum: 373.12 (M+H).

### Synthesis of Compound La018-8

Referring to the synthesis and purification method for compound La008-10, only by changing the corresponding raw materials, compound La018-8 (25.33 g, purity: 98.75%, yield: 80.06%) was obtained, with a mass spectrum: 351.22 (M+H).

### Synthesis of Compound La018-9

Referring to the synthesis and purification method for compound La008-11, only by changing the corresponding raw materials, compound La018-9 (30.05 g, purity: 99.66%, yield: 84.11%) was obtained, with a mass spectrum: 420.20 (M+H).

### Synthesis of Compound La018

Referring to the synthesis and purification method for compound La008, only by changing the corresponding raw materials, compound La018 (21.03 g, purity: 99.81%, yield: 56.26%) was obtained, with a mass spectrum: 420.20 (M+H).

### Synthesis of Compound Ir(La018)₂(Lb005)

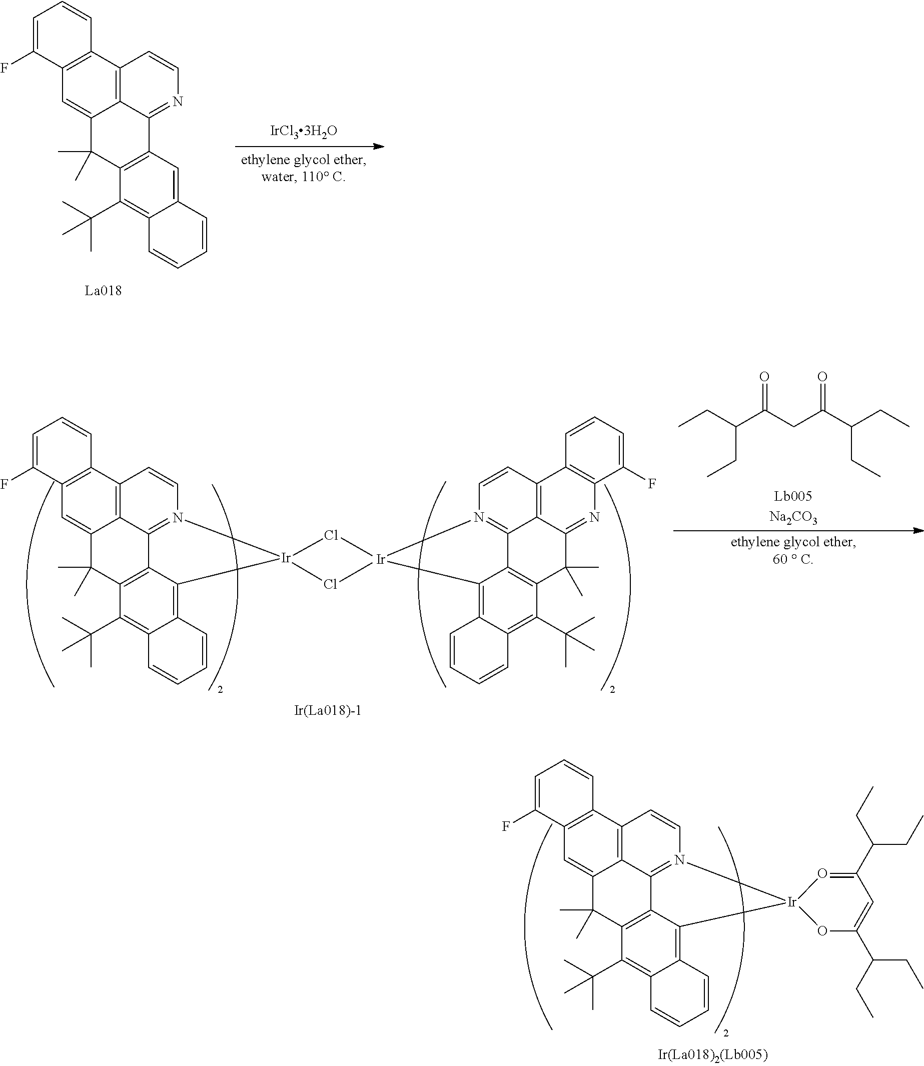

### Synthesis of Compound Ir(La018)-1

Referring to the synthesis and purification method for compound Ir(La008)-1, only by changing the corresponding raw materials, compound Ir(La018)-1 (14.65 g, yield: 78.78%) was obtained, which was used directly in the next step without purification.

### Synthesis of Compound Ir(La018)₂(Lb005)

Referring to the synthesis and purification method for compound Ir(La008)₂(Lb005), only by changing the corresponding raw materials, a red solid as compound Ir(La018)₂(Lb005) (8.95 g, purity: 99.89%, yield: 56.51%) was obtained. 8.95 g of crude Ir(La018)₂(Lb005) was purified by sublimation to obtain sublimated pure Ir(La018)₂(Lb005) (6.74 g, purity: 99.83%, yield: 75.31%), with a mass spectrum: 1241.54 (M+H).

¹H NMR (400 MHZ, CDCl₃) δ 8.53 (s, 2H), 8.34 (dd, J=7.6, 0.8 Hz, 2H), 8.23-8.15 (m, 4H), 7.82 (dd, J=6.8, 1.6 Hz, 2H), 7.53 (t, J=7.6 Hz, 2H), 7.47 (m, 2H), 7.37 (td, J=7.6, 1.3 Hz, 2H), 7.29-7.23 (m, 4H), 4.79 (s, 1H), 2.71 (m, 2H), 1.67-1.54 (m, 4H), 1.51 (s, 12H), 1.38 (s, 22H), 0.90-0.85 (m, 12H).

### Synthesis of Ligand La029

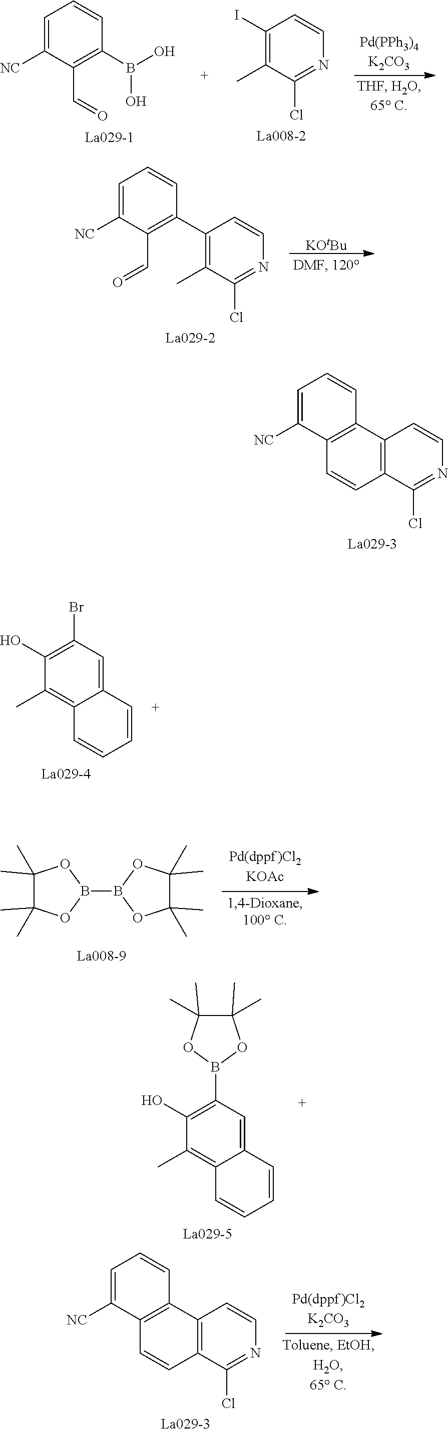

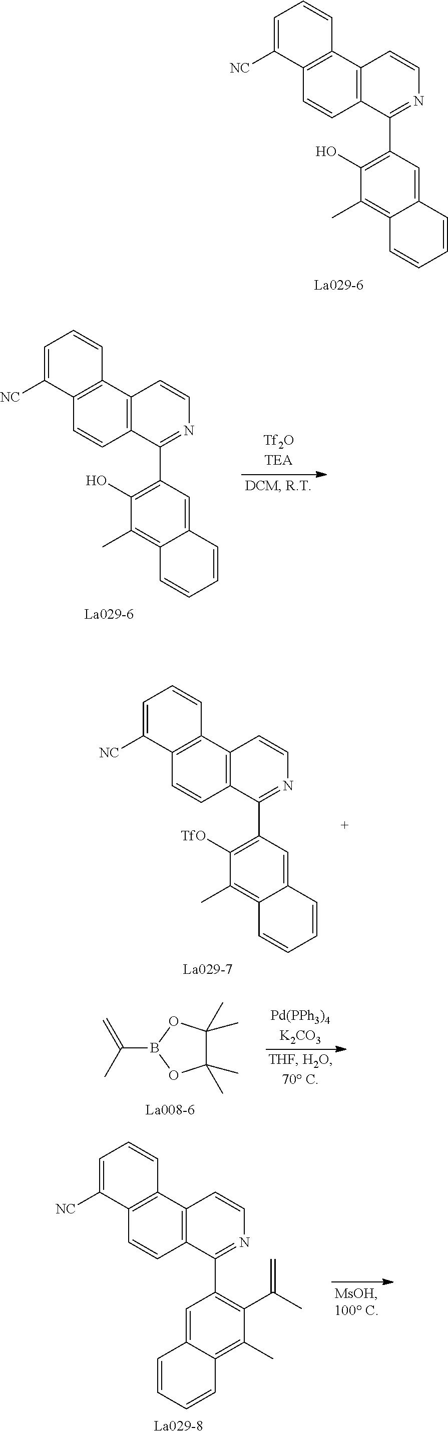

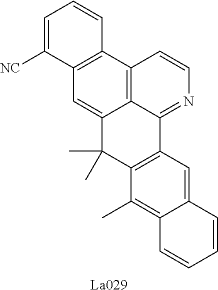 [SMILES: Cc1c2c(cc3ccccc13)-c1nccc3c1c(cc1c(C#N)cccc13)C2(C)C ; "La029"]

### Synthesis of Compound La029-2

Referring to the synthesis and purification method for compound La008-3, only by changing the corresponding raw materials, target compound La029-2 (35.12 g, purity: 99.62%, yield: 83.52%) was obtained, with a mass spectrum: 257.06 (M+H).

### Synthesis of Compound La029-3

Referring to the synthesis and purification method for compound La008-4, only by changing the corresponding raw materials, target compound La029-3 (26.06 g, purity: 99.75%, yield: 67.16%) was obtained, Mass spectrum: 239.14 (M+H).

### Synthesis of Compound La029-5

Referring to the synthesis and purification method for compound La008-10, only by changing the corresponding raw materials, target compound La029-5 (32.85 g, purity: 98.02%, yield: 76.45%) was obtained, with a mass spectrum: 285.12 (M+H).

### Synthesis of Compound La029-6

Referring to the synthesis and purification method for compound La008-11, only by changing the corresponding raw materials, target compound La029-6 (30.25 g, purity: 99.53%, yield: 82.12%) was obtained, with a mass spectrum: 361.14 (M+H).

### Synthesis of Compound La029-7

Referring to the synthesis and purification method for compound La008-8, only by changing the corresponding raw materials, target compound La029-7 (43.33 g, purity: 99.62%, yield: 89.56%) was obtained, with a mass spectrum: 493.06 (M+H).

### Synthesis of Compound La029-8

Referring to the synthesis and purification method for compound La008-7, only by changing the corresponding raw materials, target compound La029-8 (31.23 g, purity: 99.68%, yield: 84.23%) was obtained, with a mass spectrum: 385.12 (M+H).

### Synthesis of Compound La029

Referring to the synthesis and purification method for compound La008, only by changing the corresponding raw materials, target compound La029 (16.02 g, purity: 99.89%, yield: 54.33%) was obtained, with a mass spectrum: 385.12 (M+H).

### Synthesis of Compound Ir(La029)₂(Lb005)

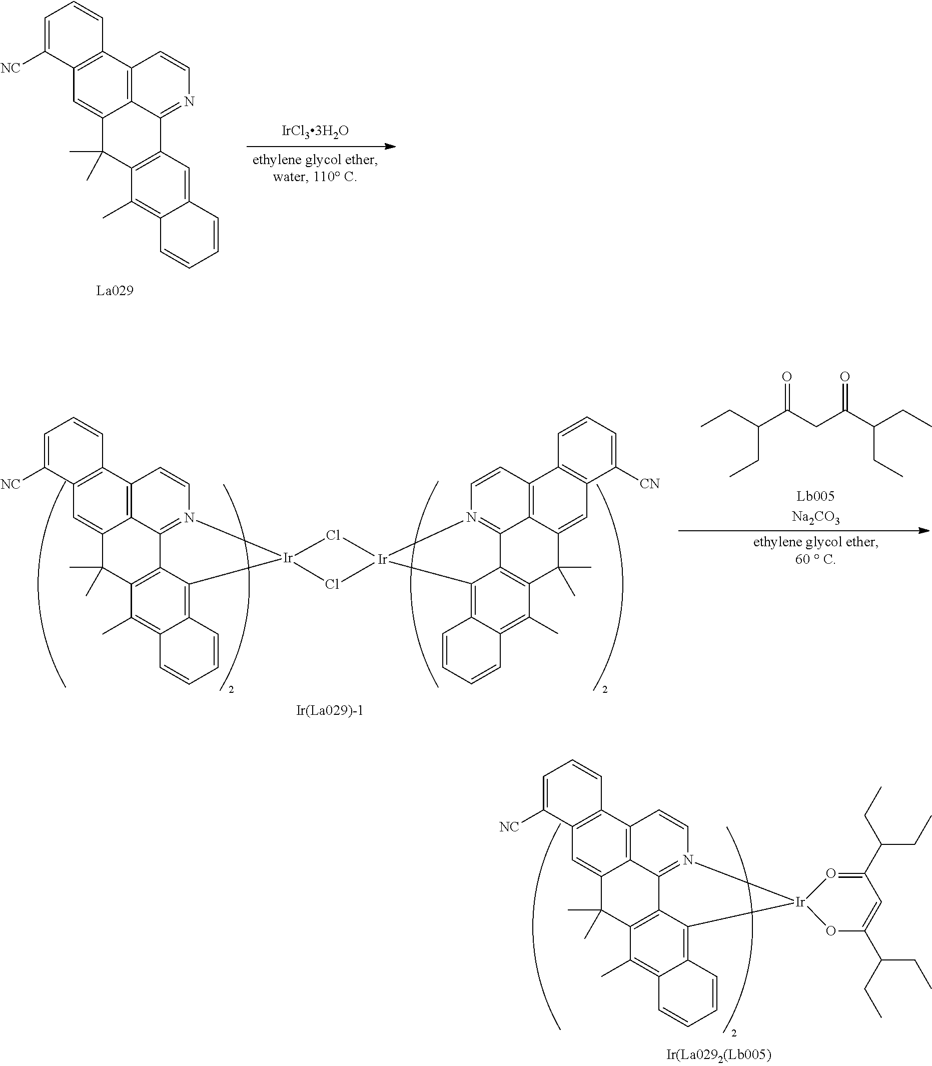

### Synthesis of Compound Ir(La029)-1

Referring to the synthesis and purification method for compound Ir(La008)-1, only by changing the corresponding raw materials, compound Ir(La029)-1 (13.63 g, yield: 72.11%) was obtained, which was used directly in the next step without purification.

### Synthesis of Compound Ir(La029)₂(Lb005)

Referring to the synthesis and purification method for compound Ir(La008)₂(Lb005), only by changing the corresponding raw materials, a red solid as compound Ir(La029)₂(Lb005) (9.85 g, purity: 99.88%, yield: 43.56%) was obtained. 9.85 g of crude Ir(La029)₂(Lb005) was sublimed and purified to obtain sublimated pure Ir(La029)₂(Lb005) (7.41 g, purity: 99.84%, yield: 75.23%), with a mass spectrum: 1171.22 (M+H).

¹H NMR (400 MHZ, CDCl₃) δ 8.52-8.47 (m, 4H), 8.36 (dd, J=7.4, 1.5 Hz, 2H), 8.20 (d, J=9.5 Hz, 2H), 7.84 (dd, J=7.7, 1.5 Hz, 2H), 7.71 (dd, J=6.8, 1.3 Hz, 2H), 7.52 (t, J=6.6 Hz, 2H), 7.46-7.33 (m, 4H), 7.27 (d, J=9.5 Hz, 2H), 4.82 (s, 1H), 2.73-2.68 (m, 2H), 2.34 (s, 6H), 1.67-1.54 (m, 16H), 1.42-1.30 (m, 4H), 0.92-0.87 (m, 12H).

### Synthesis of Ligand La048

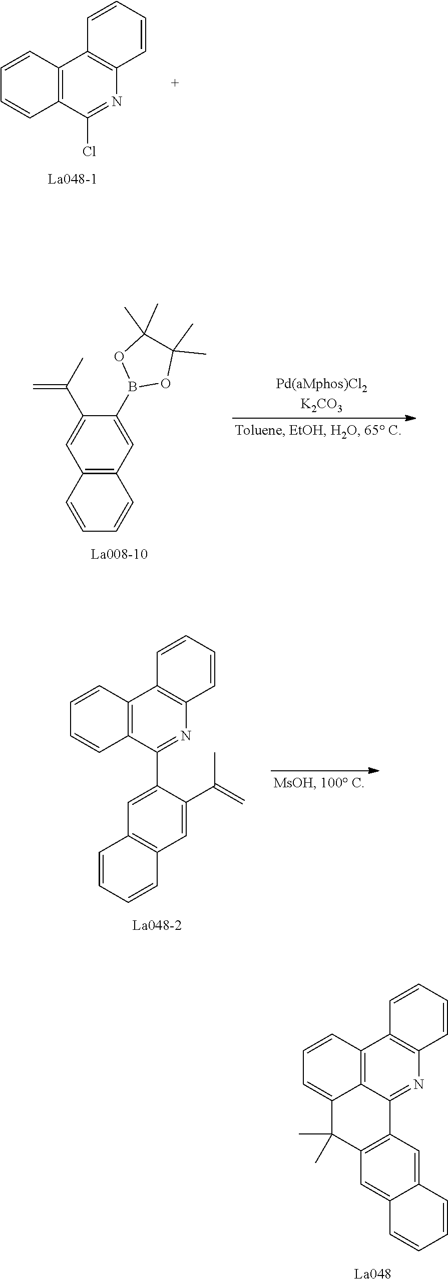

### Synthesis of Compound La048-2

Referring to the synthesis and purification method for compound La008-11, only by changing the corresponding raw materials, target compound La048-2 (25.45 g, purity: 99.51%, yield: 84.76%) was obtained, with a mass spectrum: 346.16 (M+H).

### Synthesis of Compound La048

Referring to the synthesis and purification method for compound La008, only by changing the corresponding raw materials, target compound La048 (14.65 g, purity: 99.89%, yield: 56.12%) was obtained, with a mass spectrum: 346.16 (M+H).

### Synthesis of Compound Ir(La048)₂(Lb007)

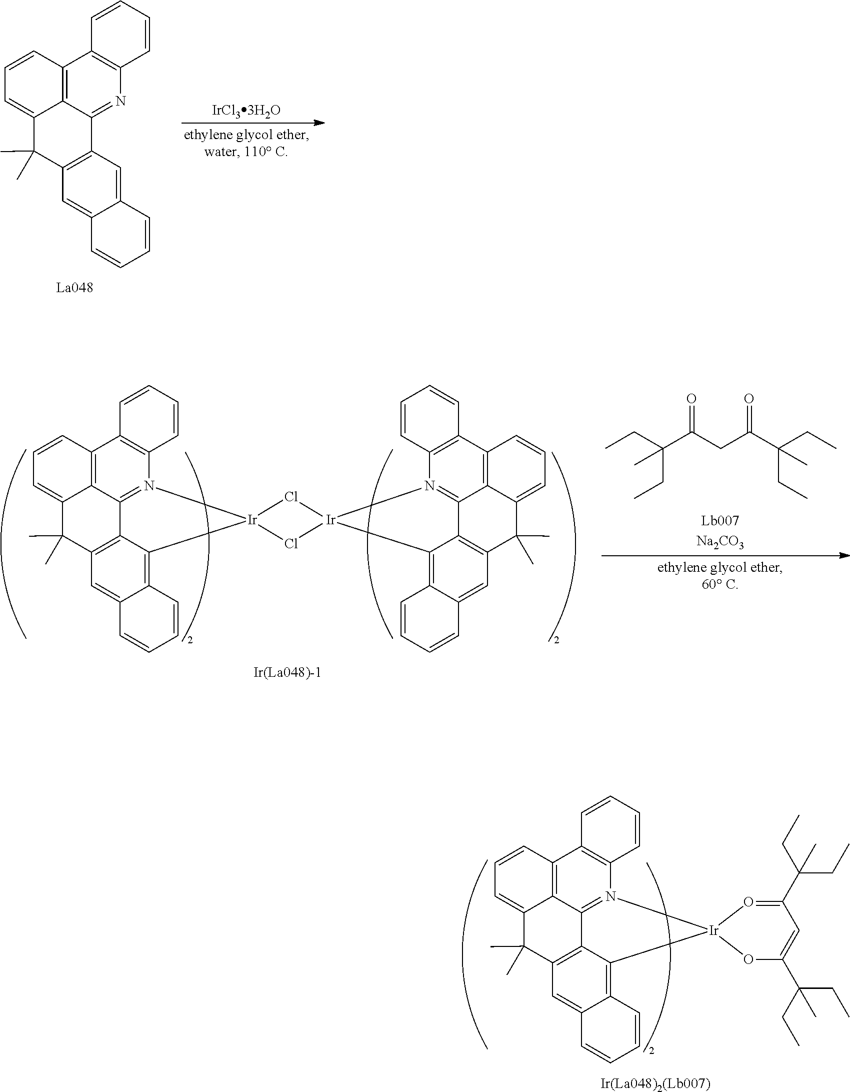

### Synthesis of Compound Ir(La048)-1

Referring to the synthesis and purification method for compound Ir(La008)-1, only by changing the corresponding raw materials, compound Ir(La048)-1 (15.22 g, yield: 75.21%) was obtained, which was used directly in the next step without purification.

### Synthesis of Compound Ir(La048)₂(Lb007)

Referring to the synthesis and purification method for compound Ir(La008)₂(Lb005), only by changing the corresponding raw materials, a red solid as compound Ir(La048)₂(Lb007) (8.95 g, purity: 99.80%, yield: 45.45%) was obtained. 8.95 g of crude Ir(La048)₂(Lb007) was purified by sublimation to obtain sublimated pure Ir(La048)₂(Lb007) (6.62 g, purity: 99.75%, yield: 73.97%), with a mass spectrum: 1121.42 (M+H).

¹H NMR (400 MHZ, CDCl₃) δ 8.63 (dd, J=7.3, 1.3 Hz, 2H), 8.28 (dd, J=7.7, 1.4 Hz, 2H), 8.24-8.19 (m, 2H), 8.18-8.10 (m, 4H), 7.88-7.82 (m, 2H), 7.53 (dd, J=7.5, 1.1 Hz, 2H), 7.50-7.39 (m, 6H), 7.37-7.29 (m, 4H), 4.82 (s, 1H), 1.68-1.57 (m, 16H), 1.43-1.33 (m, 4H), 1.05 (d, J=15.2 Hz, 6H), 0.88-0.82 (m, 12H).

### Synthesis of Ligand La055

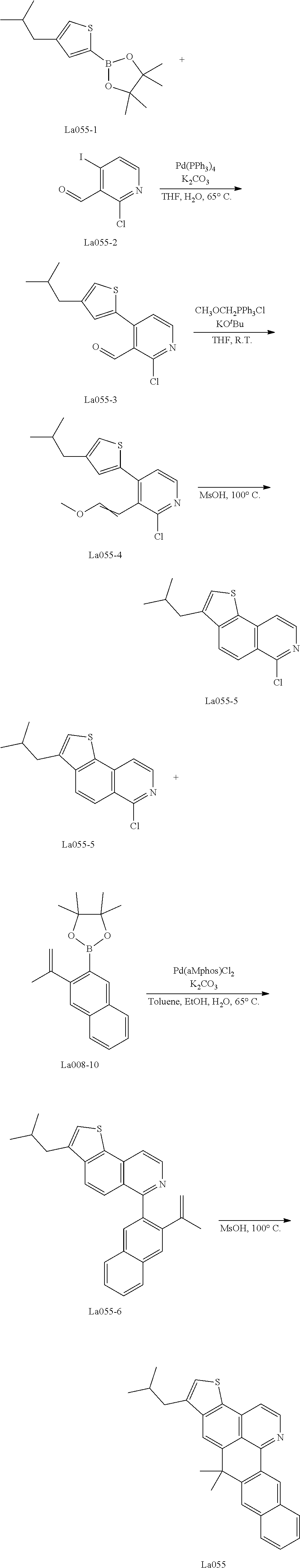

### Synthesis of Compound La055-3

Referring to the synthesis and purification method for compound La008-3, only by changing the corresponding raw materials, target compound La055-3 (38.42 g, purity: 99.42%, yield: 78.08%) was obtained, with a mass spectrum: 280.05 (M+H).

### Synthesis of Compound La055-4

Compound La055-3 (35.00 g, 125.10 mmol), (methoxymethyl)triphenylphosphonium chloride (85.77 g, 250.20 mmol), potassium tert-butoxide (28.07 g, 250.20 mmol), and tetrahydrofuran (530 mL) were added to a 2,000 ml three-necked round-bottom flask, and the flask was evacuated and replaced with nitrogen three times. Under nitrogen protection, the mixture was stirred at room temperature for 4 hours. TLC monitoring (the developing solvent was ethyl acetate:petroleum ether=1:10) showed that the raw material La055-3 was reacted completely.

200 mL of deionized water was slowly added to the system to quench the reaction, and the organic solvent was concentrated under reduced pressure. Ethyl acetate (800 mL) was then added, and the mixture was washed with deionized water (3×300 ml). After standing for liquid separation, the organic phase was concentrated under reduced pressure at 65° C. and then separated by silica gel column chromatography (200-300 mesh silica gel, the eluent is ethyl acetate:petroleum ether=1:20). After elution, concentration was conducted under reduced pressure at 65° C. for 1 hour to obtain a white solid compound La055-4 (33.89 g, purity: 99.75%, yield: 88.00%), with a mass spectrum: 308.06 (M+H).

### Synthesis of Compound La055-5

Referring to the synthesis and purification method for compound La008, only by changing the corresponding raw materials, target compound La055-5 (22.32 g, purity: 99.62%, yield: 83.03%) was obtained, with a mass spectrum: 276.05 (M+H).

### Synthesis of Compound La055-6

Referring to the synthesis and purification method for compound La008-11, only by changing the corresponding raw materials, target compound La055-6 (24.89 g, purity: 99.73%, yield: 84.21%) was obtained. mass spectrum: 408.16 (M+H).

### Synthesis of Compound La055

Referring to the synthesis and purification method for compound La008, only by changing the corresponding raw materials, target compound La055 (11.44 g, purity: 99.81%, yield: 52.01%) was obtained, with a mass spectrum: 408.16 (M+H).

### Synthesis of Compound Ir(La055)₂(Lb005)

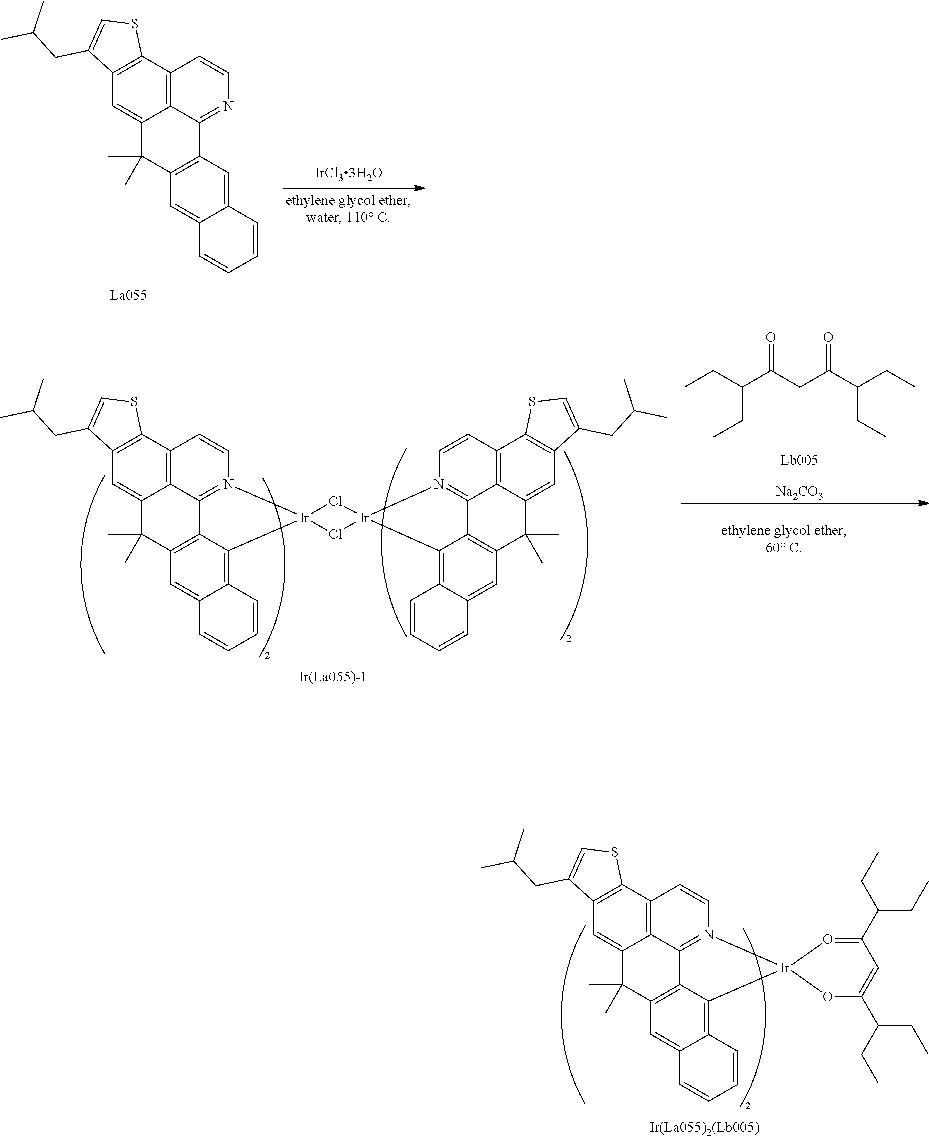

### Synthesis of Compound Ir(La055)-1

Referring to the synthesis and purification method for compound Ir(La008)-1, only by changing the corresponding raw materials, compound Ir(La055)-1 (17.77 g, yield: 74.04%) was obtained, which was used directly in the next step without purification.

### Synthesis of Compound Ir(La055)₂(Lb005)

Referring to the synthesis and purification method for compound Ir(La008)₂(Lb005), only by changing the corresponding raw materials, a red solid as compound Ir(La055)₂(Lb005) (8.06 g, purity: 99.84%, yield: 46.56%) was obtained. 8.06 g of crude Ir(La055)₂(Lb005) was purified by sublimation to obtain sublimated pure Ir(La055)₂(Lb005) (5.55 g, purity: 99.78%, yield: 68.86%), with a mass spectrum: 1217.46 (M+H).

¹H NMR (400 MHZ, CDCl₃) δ 8.44 (d, J=9.0 Hz, 2H), 8.24-8.19 (m, 4H), 8.16 (d, J=2.3 Hz, 2H), 7.88-7.82 (m, 2H), 7.46-7.33 (m, 4H), 7.25 (d, J=9.1 Hz, 2H), 7.06 (m 2H), 4.72 (s, 1H), 2.73-2.66 (m, 6H), 1.93 (dt, J=13.7, 6.8 Hz, 2H), 1.67-1.55 (m, 16H), 1.36-1.34 (m, 4H), 0.92-0.84 (m, 24H).

### Synthesis of Ligand La070

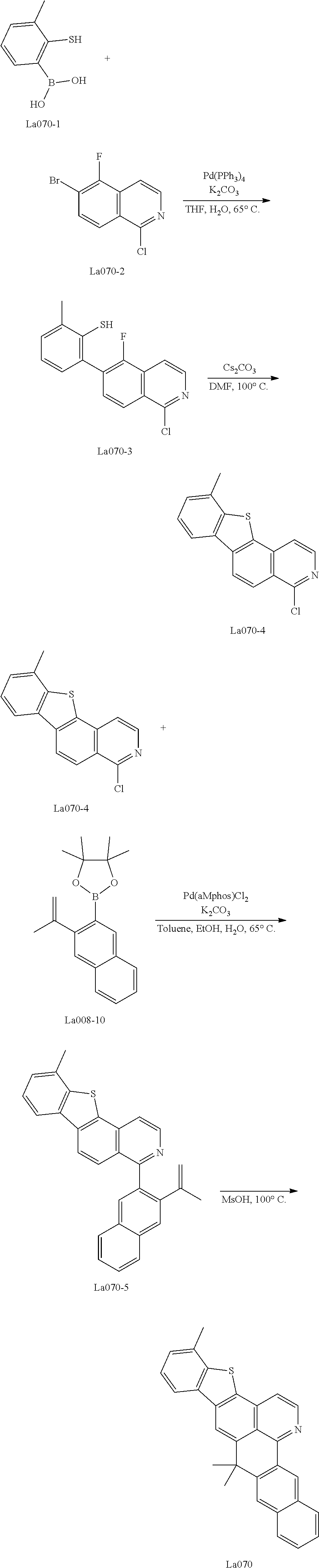

### Synthesis of Compound La070-3

Referring to the synthesis and purification method for compound La008-3, only by changing the corresponding raw materials, target compound La070-3 (32.22 g, purity: 99.53%, yield: 80.65%) was obtained, with a mass spectrum: 304.03 (M+H).

### Synthesis of Compound La070-4

Compound La070-3 (30.00 g, 98.76 mmol), cesium carbonate (64.35 g, 197.51 mmol), and N, N-dimethylformamide (450 mL) were added to a 1,000 ml three-necked round-bottom flask. The flask was evacuated and replaced with nitrogen three times. Under nitrogen protection, the mixture was heated to 100° C. and stirred for 2 hours. TLC monitoring (the developing solvent was ethyl acetate: petroleum ether=1:15) showed that the raw material La070-3 was reacted completely.

The organic solvent was removed by concentration under reduced pressure. Ethyl acetate (600 mL) was added, and the mixture was washed with deionized water (3×200 mL). The mixture was allowed to stand for liquid separation, and the organic phase was concentrated under reduced pressure at 65° C. and then separated by silica gel column chromatography (200-300 mesh silica gel, the eluent is ethyl acetate:petroleum ether=1:30). After elution, concentration was conducted under reduced pressure at 65° C. for 1 hour to obtain a white solid, which was compound La070-4 (21.19 g, purity: 99.85%, yield: 75.60%), with a mass spectrum: 284.02 (M+H).

### Synthesis of Compound La070-5

Referring to the synthesis and purification method for compound La008-11, only by changing the corresponding raw materials, target compound La070-5 (18.06 g, purity: 99.86%, yield: 83.54%) was obtained, with a mass spectrum: 416.12 (M+H).

### Synthesis of Compound La070

Referring to the synthesis and purification method for compound La008, only by changing the corresponding raw materials, target compound La070 (10.02 g, purity: 99.78%, yield: 54.33%) was obtained, with a mass spectrum: 416.12 (M+H).

### Synthesis of Compound Ir(La070)₂(Lb005)

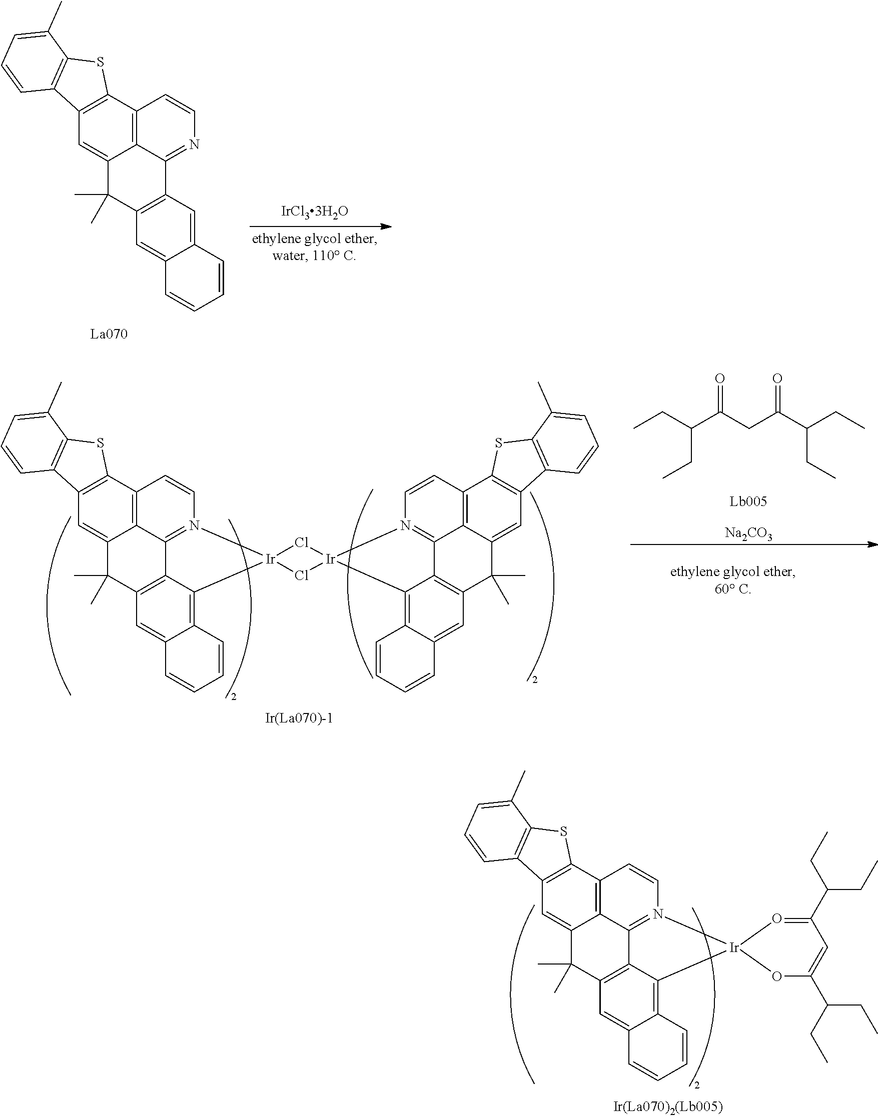

### Synthesis of Compound Ir(La070)-1

Referring to the synthesis and purification method for compound Ir(La008)-1, only by changing the corresponding raw materials, compound Ir(La070)-1 (14.33 g, yield: 72.11%) was obtained, which was used directly in the next step without purification.

### Synthesis of Compound Ir(La070)₂(Lb005)

Referring to the synthesis and purification method for compound Ir(La008)₂(Lb005), only by changing the corresponding raw materials, a red solid as compound Ir(La070)₂(Lb005) (7.62 g, purity: 99.80%, yield: 47.62%) was obtained.7.62 g of crude Ir(La070)₂(Lb005) was purified by sublimation to obtain sublimated pure Ir(La070)₂(Lb005) (5.35 g, purity: 99.78%, yield: 70.21%), with a mass spectrum: 1233.40 (M+H).

¹H NMR (400 MHz, CDCl₃) δ 8.37 (d, J=9.1 Hz, 2H), 8.28-8.14 (m, 8H), 7.88-7.82 (m, 2H), 7.46-7.42 (m, 2H), 7.38-7.30 (m, 4H), 7.28-7.22 (m, 4H), 4.72 (s, 1H), 2.71-2.69 (m, 2H), 2.60 (d, J=0.7 Hz, 6H), 1.68-1.54 (m, 16H), 1.43-1.28 (m, 4H), 0.88-0086 (m, 12H).

### Synthesis of Compound Ir(La070)₂(Lb031)

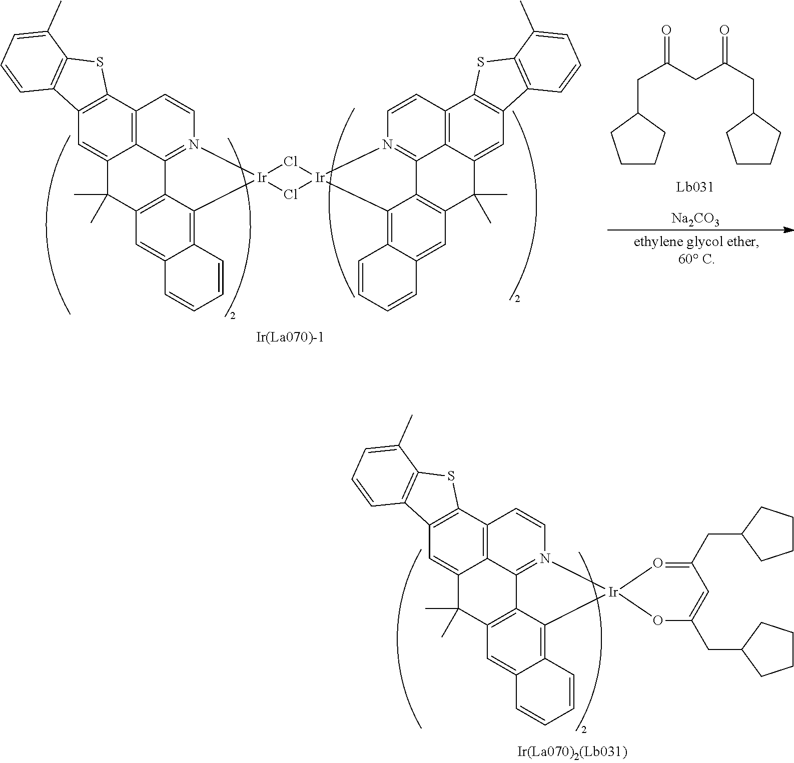

### Synthesis of Compound Ir(La070)₂(Lb031)

Referring to the synthesis and purification method for compound Ir(La008)₂(Lb005), only by changing the corresponding raw materials, a red solid as compound Ir(La070)₂(Lb031) (8.33 g, purity: 99.82%, yield: 48.52%) was obtained. 8.33 g of crude Ir(La070)₂(Lb031) was purified by sublimation to obtain sublimated pure Ir(La070)₂(Lb031) (6.14 g, purity: 99.78%, yield: 73.71%), with a mass spectrum: 1257.40 (M+H).

¹H NMR (400 MHZ, CDCl₃) δ 8.37 (d, J=9.2 Hz, 2H), 8.28-8.14 (m, 8H), 7.88-7.82 (m, 2H), 7.46 (td, J=7.4, 1.5 Hz, 2H), 7.38-7.30 (m, 4H), 7.28-7.22 (m, 4H), 4.51 (s, 1H), 2.60 (d, J=0.7 Hz, 6H), 2.50 (m, 4H), 1.88-1.76 (m, 2H), 1.63-1.55 (m, 13H), 1.55-1.50 (m, 6H), 1.49 (m, 1H), 1.46-1.37 (m, 4H), 1.35-1.21 (m, 4H).

### Synthesis of Ligand La079

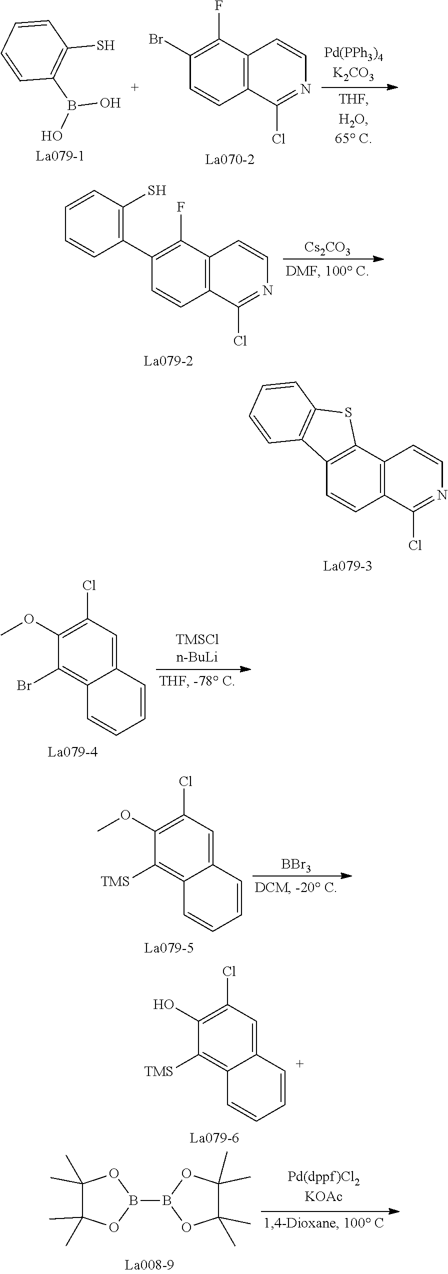

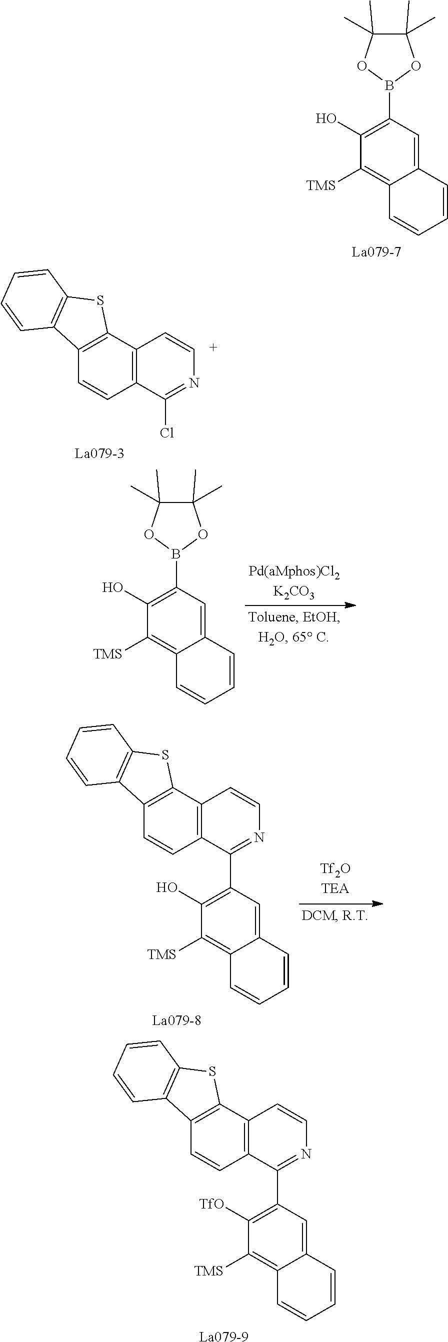

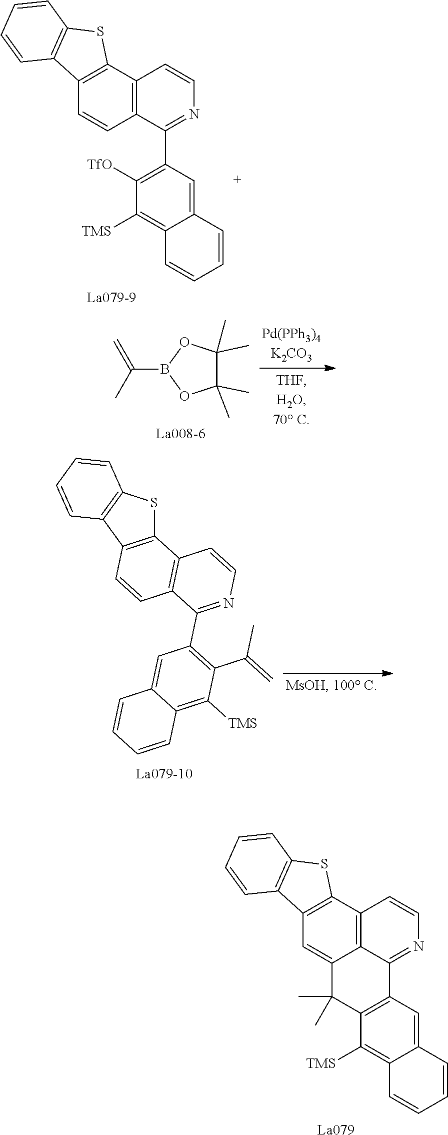

### Synthesis of Compound La079-2

Referring to the synthesis and purification method for compound La008-3, only by changing the corresponding raw materials, target compound La079-2 (40.56 g, purity: 99.64%, yield: 85.48%) was obtained, with a mass spectrum: 290.20 (M+H).

### Synthesis of Compound La079-3

Referring to the synthesis and purification method for compound La070-4, only by changing the corresponding raw materials, target compound La079-3 (35.41 g, purity: 99.83%, yield: 86.56%) was obtained, with a mass spectrum: 270.02 (M+H).

### Synthesis of Compound La079-5

Compound La079-4 (35.00 g, 128.90 mmol) and tetrahydrofuran (350 mL) were added to a 1,000 mL three-necked round-bottom flask, and the flask was evacuated and replaced with nitrogen three times. Under nitrogen protection, the system was cooled to −78° C. After the internal temperature dropped to the specified value, a solution of n-butyllithium (88.70 mL, 1.6 mol/L in n-hexane, 141.79 mmol) was added dropwise. The addition was completed within 40 minutes, and the mixture was stirred at −70° C. for 1 hour. Trimethylsilyl chloride (28.00 g, 257.80 mmol) was added dropwise to the above low temperature system using a constant-pressure dropping funnel. The addition was completed over 15 minutes and the mixture was stirred for 1 hour. TLC monitoring (the developing solvent was ethyl acetate:petroleum ether=1:20) showed that the raw material La079-4 was reacted completely.

Deionized water (100 mL) was added dropwise to the system to quench the reaction, and the mixture was heated to room temperature and concentrated under reduced pressure to remove the organic solvent. Ethyl acetate (600 mL) was added, and the mixture was washed with deionized water (3×200 mL). The mixture was allowed to stand for liquid separation. The organic phase was concentrated under reduced pressure at 65° C. and then separated by silica gel column chromatography (200-300 mesh silica gel, the eluent is ethyl acetate:petroleum ether=1:35). After elution, the mixture was concentrated under reduced pressure at 65° C. for 1 hour to obtain a light yellow liquid, which was compound La079-5 (23.23 g, purity: 99.87%, yield: 68.06%), with a mass spectrum: 265.06 (M+H).

### Synthesis of Compound La079-6

Compound La079-5 (23.00 g, 86.85 mmol) and dichloromethane (300 mL) were added to a 500 mL three-necked round-bottom flask, and the flask was evacuated and replaced with nitrogen three times. Under nitrogen protection, the system was cooled to −20° C. After the internal temperature dropped to the specified value, boron tribromide (26.11 g, 104.22 mmol) was added dropwise over 30 minutes. The mixture was stirred at −20° C. for 1 hour, and TLC monitoring (the developing solvent was ethyl acetate:petroleum ether=1:10) showed that the raw material La079-5 was reacted completely.

Deionized water (100 mL) was added dropwise to the system to quench the reaction, and the mixture was cooled to room temperature. The mixture was allowed to stand for liquid separation, and washed with deionized water (3×150 mL). The mixture was allowed to stand for liquid separation, and the organic phase was concentrated under reduced pressure at 65° C. and then separated by silica gel column chromatography (200-300 mesh silica gel, the eluent is ethyl acetate:petroleum ether=1:20). After elution, the mixture was concentrated under reduced pressure at 65° C. for 1 hour to obtain a light yellow liquid, which was compound La079-6 (20.70 g, purity: 99.90%, yield: 95.02%), with a mass spectrum: 251.06 (M+H).

### Synthesis of Compound La079-7

Referring to the synthesis and purification method of compound La008-10, only by changing the corresponding raw materials, target compound La079-7 (18.61 g, purity: 99.78%, yield: 77.06%) was obtained, with a mass spectrum: 343.18 (M+H).

### Synthesis of Compound La079-8

Referring to the synthesis and purification method for compound La008-11, only by changing the corresponding raw materials, target compound La079-8 (17.24 g, purity: 99.82%, yield: 82.45%) was obtained, with a mass spectrum: 450.12 (M+H).

### Synthesis of Compound La079-9

Referring to the synthesis and purification method for compound La008-8, only by changing the corresponding raw materials, target compound La079-9 (28.05 g, purity: 99.85%, yield: 92.22%) was obtained, with a mass spectrum: 582.08 (M+H).

### Synthesis of Compound La079-10

Referring to the synthesis and purification method for compound La008-11, only by changing the corresponding raw materials, target compound La079-10 (31.58 g, purity: 99.81%, yield: 79.69%) was obtained, with a mass spectrum: 474.16 (M+H).

### Synthesis of Compound La079

Referring to the synthesis and purification method for compound La008, only by changing the corresponding raw materials, target compound La079 (15.23 g, purity: 99.64%, yield: 55.87%) was obtained, with a mass spectrum: 474.16 (M+H).

### Synthesis of Compound Ir(La079)₂(Lb005)

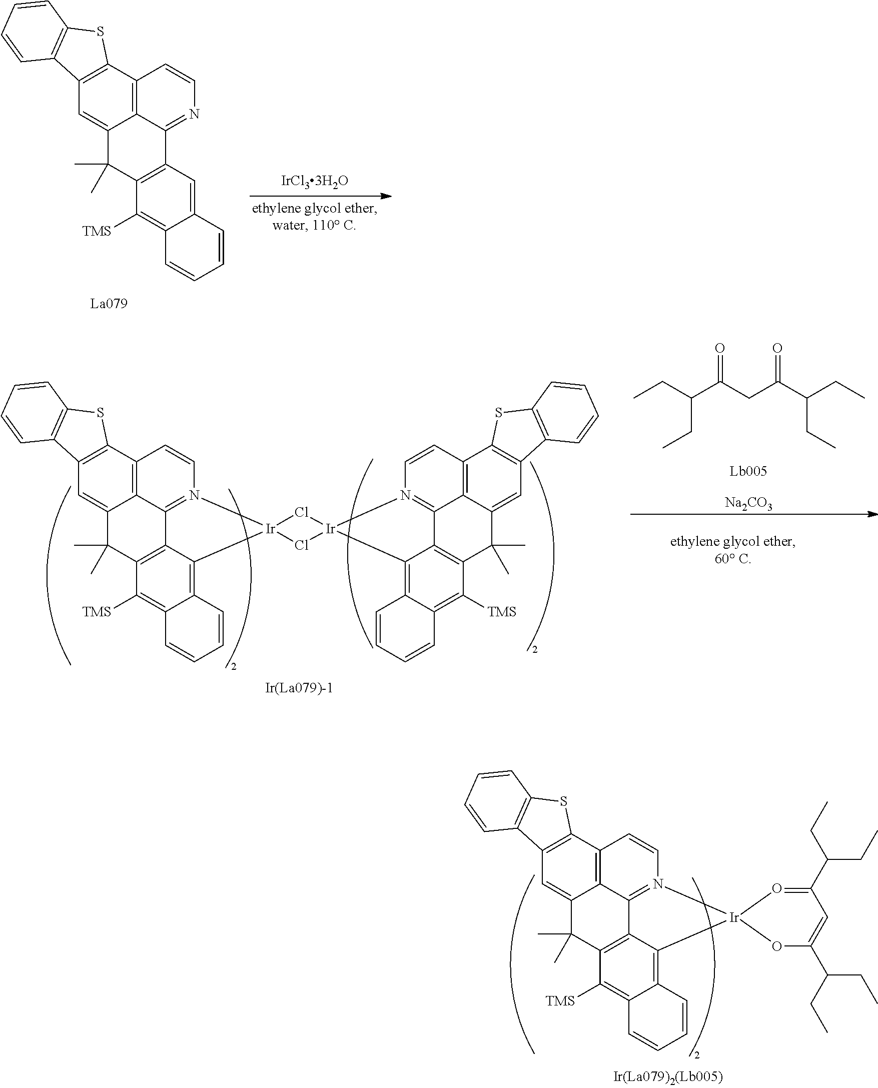

### Synthesis of Compound Ir(La079)-1

Referring to the synthesis and purification method for compound Ir(La008)-1, only by changing the corresponding raw materials, compound Ir(La070)-1 (18.96 g, yield: 74.19%) was obtained, which was used directly in the next step without purification.

### Synthesis of Compound Ir(La079)₂(Lb005)

Referring to the synthesis and purification method for compound Ir(La008)₂(Lb005), only by changing the corresponding raw materials, a red solid as compound Ir(La079)₂(Lb005) (10.00 g, purity: 99.79%, yield: 46.52%) was obtained. 10.00 g of crude Ir(La079)₂(Lb005) was purified by sublimation to obtain sublimated pure Ir(La070)₂(Lb005) (7.35 g, purity: 99.71%, yield: 73.50%), with a mass spectrum: 1349.44 (M+H).

¹H NMR (400 MHZ, CDCl₃) δ 8.37 (d, J=9.2 Hz, 2H), 8.26-8.21 (m, 2H), 8.20-8.15 (m, 2H), 8.09 (s, 2H), 7.94-7.89 (m, 2H), 7.88-7.83 (m, 2H), 7.54-7.47 (m, 4H), 7.38-7.30 (m, 4H), 7.25 (d, J=9.2 Hz, 2H), 4.72 (s, 1H), 2.71 (m, 2H), 1.68 (s, 6H), 1.66-1.54 (m, 10H), 1.43-1.30 (m, 4H), 0.92-0.88 (m, 12H), 0.46 (s, 18H).

### Synthesis of Ligand La090

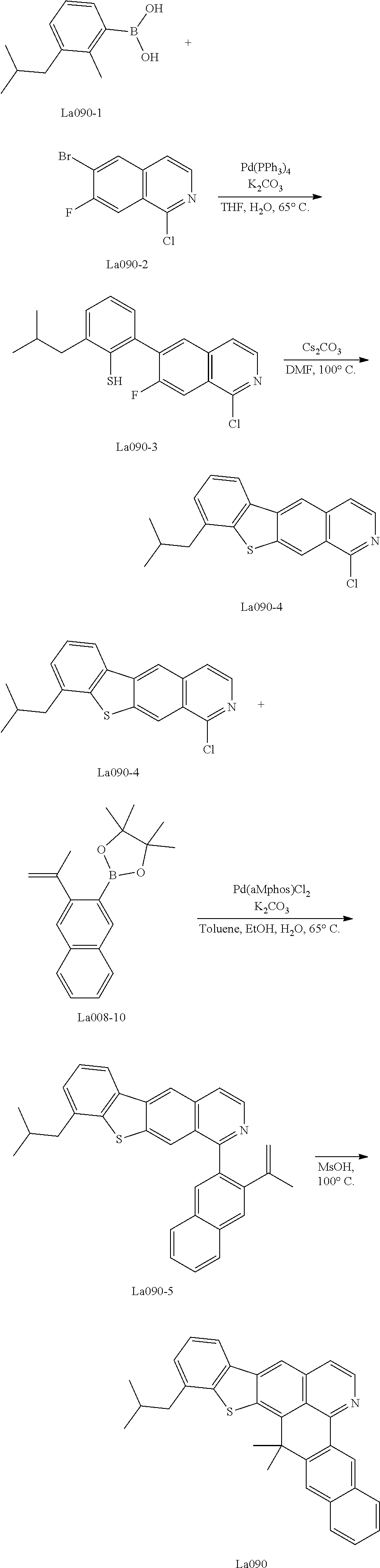

### Synthesis of Compound La090-3

Referring to the synthesis and purification method for compound La008-3, only by changing the corresponding raw materials, target compound La090-3 (33.25 g, purity: 99.56%, yield: 82.11%), with a mass spectrum: 346.08 (M+H).

### Synthesis of Compound La090-4

Referring to the synthesis and purification method for compound La070-4, only by changing the corresponding raw materials, target compound La090-4 (24.25 g, purity: 99.71%, yield: 74.32%) was obtained, with a mass spectrum: 326.06 (M+H).

### Synthesis of Compound La090-5

Referring to the synthesis and purification method for compound La008-11, only by changing the corresponding raw materials, target compound La090-5 (28.79 g, purity: 99.83%, yield: 85.41%) was obtained, with a mass spectrum: 458.20 (M+H).

### Synthesis of Compound La090

Referring to the synthesis and purification method for compound La008, only by changing the corresponding raw materials, target compound La090 (16.55 g, purity: 99.78%, yield: 52.11%) was obtained, with a mass spectrum: 458.20 (M+H).

### Synthesis of Compound Ir(La090)₂(Lb005)

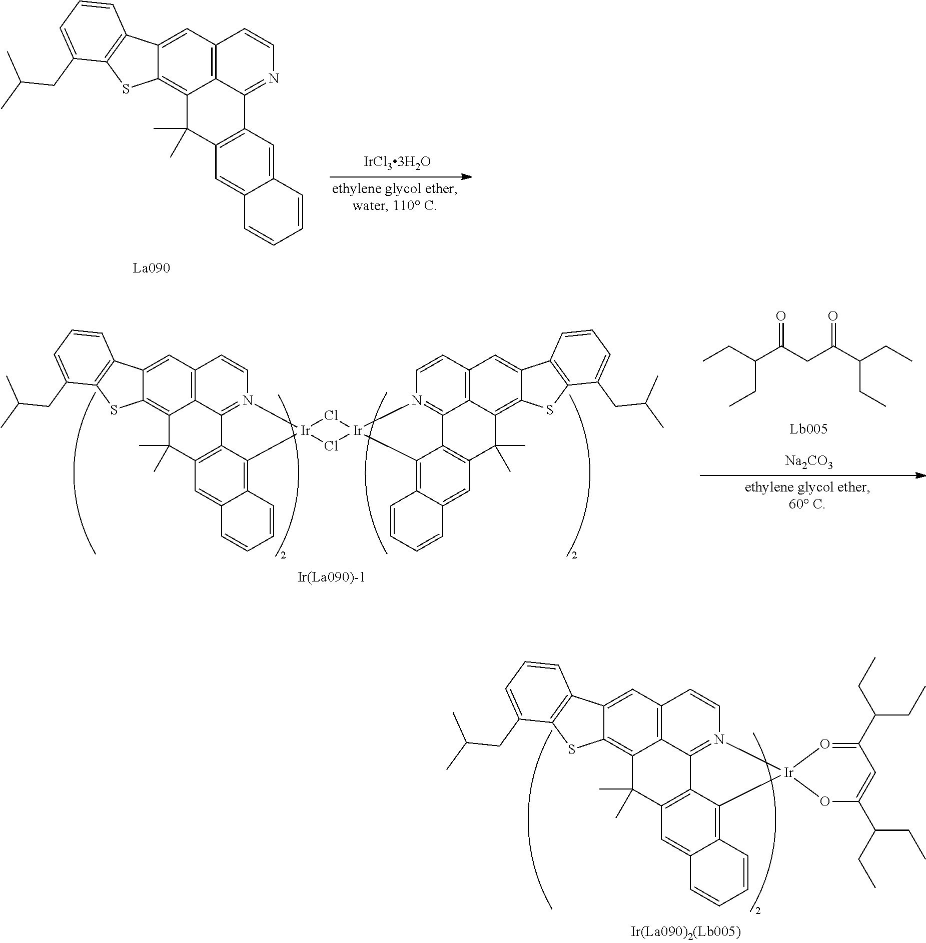

### Synthesis of Compound Ir(La090)-1

Referring to the synthesis and purification method for compound Ir(La008)-1, only by changing the corresponding raw materials, compound Ir(La090)-1 (18.96 g, yield: 72.43%) was obtained, which was used directly in the next step without purification.

### Synthesis of Compound Ir(La090)₂(Lb005)

Referring to the synthesis and purification method for compound Ir(La008)₂(Lb005), only by changing the corresponding raw materials, a red solid as compound Ir(La090)₂(Lb005) (8.53 g, purity: 99.78%, yield: 42.45%) was obtained. 8.53 g of crude Ir(La090)₂(Lb005) was purified by sublimation to obtain sublimated pure Ir(La090)₂(Lb005) (6.51 g, purity: 99.68%, yield: 76.31%), with a mass spectrum: 1317.42 (M+H).

¹H NMR (400 MHZ, CDCl₃) δ 8.45 (d, J=2.5 Hz, 2H), 8.24-8.20 (m, 2H), 8.20-8.15 (m, 2H), 8.02 (d, J=2.1 Hz, 2H), 7.93 (dd, J=9.3, 2.2 Hz, 2H), 7.88-7.82 (m, 2H), 7.46 (m, 2H), 7.38-7.33 (m, 4H), 7.33-7.26 (m, 2H), 7.10 (m, 2H), 4.82 (s, 1H), 2.75-2.66 (m, 6H), 1.90-1.88 (m, 2H), 1.67-1.60 (m, 9H), 1.60-1.54 (m, 1H), 1.52 (s, 6H), 1.43-1.28 (m, 4H), 0.92-0.84 (m, 24H).

### Synthesis of Ligand La095

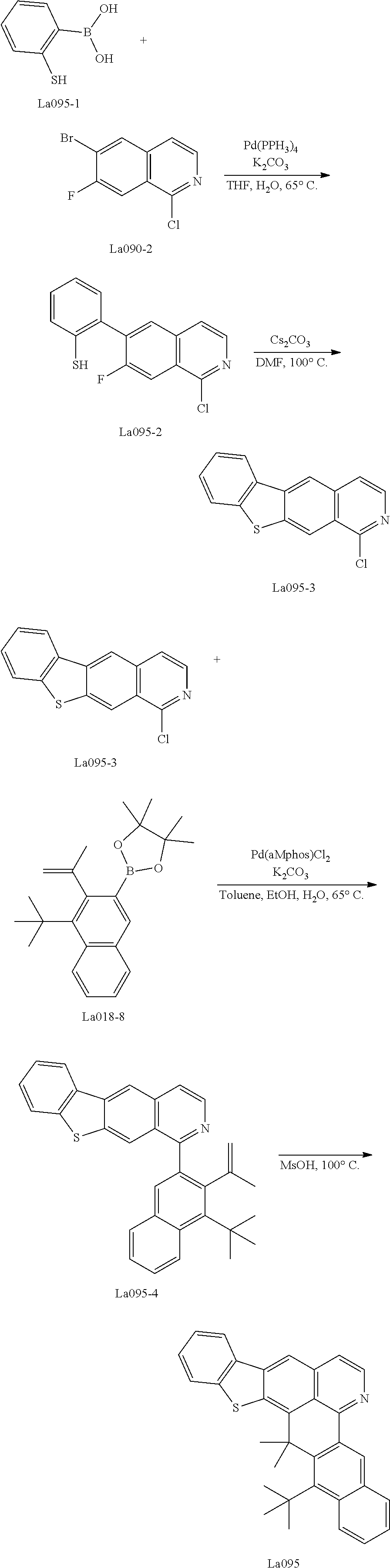

### Synthesis of Compound La095-2

Referring to the synthesis and purification method for compound La008-3, only by changing the corresponding raw materials, target compound La095-2 (36.98 g, purity: 99.76%, yield: 86.11%) was obtained, with a mass spectrum: 290.01 (M+H).

### Synthesis of Compound La095-3

Referring to the synthesis and purification method for compound La070-4, only by changing the corresponding raw materials, target compound La095-3 (25.08 g, purity: 99.68%, yield: 74.32%) was obtained, with a mass spectrum: 270.02 (M+H).

### Synthesis of Compound La095-4

Referring to the synthesis and purification method for compound La008-11, only by changing the corresponding raw materials, target compound La095-4 (18.77 g, purity: 99.73%, yield: 82.51%) was obtained, with a mass spectrum: 458.20 (M+H).

### Synthesis of Compound La095

Referring to the synthesis and purification method for compound La008, only by changing the corresponding raw materials, target compound La095 (10.09 g, purity: 99.86%, yield: 54.99%) was obtained, with a mass spectrum: 458.20 (M+H).

### Synthesis of Compound Ir(La095)₂(Lb005)

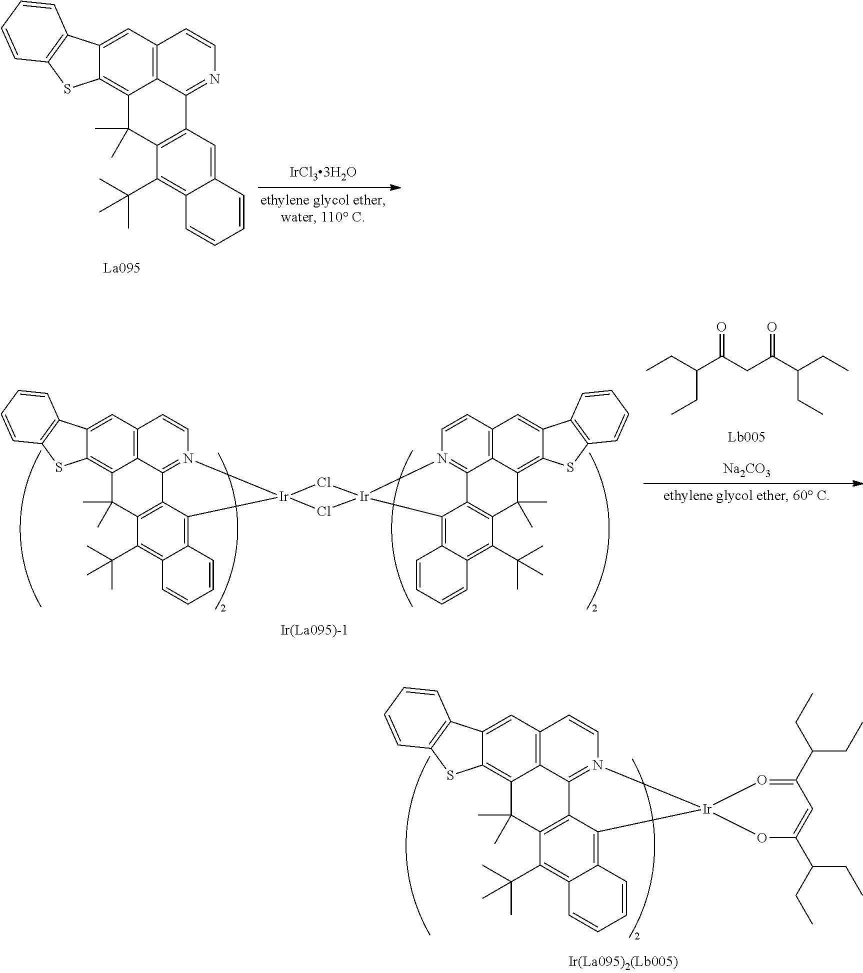

### Synthesis of Compound Ir(La095)-1

Referring to the synthesis and purification method for compound Ir(La008)-1, only by changing the corresponding raw materials, compound Ir(La095)-1 (15.44 g, yield: 68.98%) was obtained, which was used directly in the next step without purification.

### Synthesis of Compound Ir(La095)₂(Lb005)

Referring to the synthesis and purification method for compound Ir(La008)₂(Lb005), only by changing the corresponding raw materials, a red solid as compound Ir(La095)₂(Lb005) (7.22 g, purity: 99.86%, yield: 45.55%) was obtained. 7.22 g of crude Ir(La095)₂(Lb005) was sublimed and purified to obtain sublimated pure Ir(La095)₂(Lb005) (5.67 g, purity: 99.68%, yield: 78.53%), with a mass spectrum: 1317.40 (M+H).

¹H NMR (400 MHZ, CDCl₃) δ 8.53 (d, J=2.4 Hz, 2H), 8.26-8.21 (m, 2H), 8.18 (dd, J=7.3, 1.5 Hz, 2H), 7.96-7.89 (m, 4H), 7.82 (dd, J=6.8, 1.6 Hz, 2H), 7.54-7.50 (m, 2H), 7.50-7.44 (m, 4H), 7.40-7.32 (m, 4H), 4.78 (s, 1H), 2.71-2.68 (m, 2H), 1.67-1.55 (m, 4H), 1.51 (s, 6H), 1.47 (s, 6H), 1.38 (s, 22H), 0.88-0.86 (qm, 12H).

### Synthesis of Compound Ir(La095)₂(Lb043)

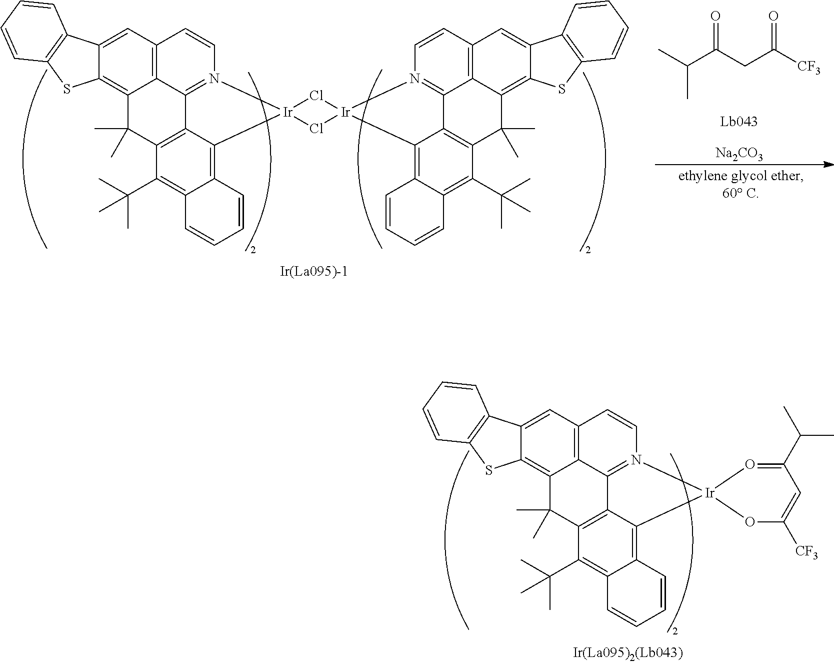

### Synthesis of Compound Ir(La095)₂(Lb043)

Referring to the synthesis and purification method for compound Ir(La008)₂(Lb005), only by changing the corresponding raw materials, a red solid compound Ir(La095)₂(Lb043) (6.21 g, purity: 99.80%, yield: 41.12%) was obtained. 6.21 g of crude Ir(La095)₂(Lb043) was purified by sublimation to obtain sublimated pure Ir(La095)₂(Lb043) (4.22 g, purity: 99.71%, yield: 67.96%), with a mass spectrum: 1287.37 (M+H).

¹H NMR (400 MHZ, CDCl₃) δ 8.53 (d, J=2.4 Hz, 2H), 8.24 (m, 2H), 8.18 (dd, J=7.3, 1.5 Hz, 2H), 7.96-7.89 (m, 4H), 7.82 (dd, J=6.8, 1.5 Hz, 2H), 7.55-7.44 (m, 6H), 7.40-7.32 (m, 4H), 4.64 (s, 1H), 2.79-2.76 (m, 1H), 1.51 (s, 6H), 1.47 (s, 6H), 1.38 (s, 18H), 1.07 (d, J=6.1 Hz, 6H).

### Synthesis of Ligand La103

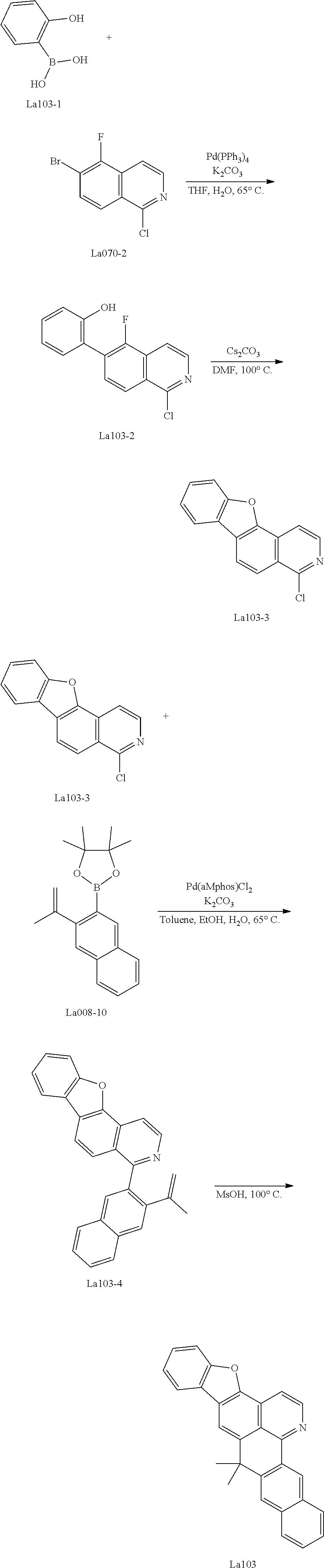

### Synthesis of Compound La103-2

Referring to the synthesis and purification method for compound La008-3, only by changing the corresponding raw materials, target compound La103-2 (38.01 g, purity: 99.73%, yield: 82.77%) was obtained, with a mass spectrum: 274.04 (M+H).

### Synthesis of Compound La103-3

Referring to the synthesis and purification method for compound La070-4, only by changing the corresponding raw materials, target compound La103-3 (31.02 g, purity: 99.81%, yield: 75.45%) was obtained, with a mass spectrum: 254.04 (M+H).

### Synthesis of Compound La103-4

Referring to the synthesis and purification method for compound La008-11, only by changing the corresponding raw materials, target compound La103-4 (38.21 g, purity: 99.75%, yield: 79.91%) was obtained, with a mass spectrum: 386.15 (M+H).

### Synthesis of Compound La103

Referring to the synthesis and purification method for compound La008, o only by changing the corresponding raw materials, target compound La103 (16.77 g, purity: 99.81%, yield: 54.23%) was obtained, with a mass spectrum: 386.15 (M+H).

### Synthesis of Compound Ir(La103)₂(Lb005)

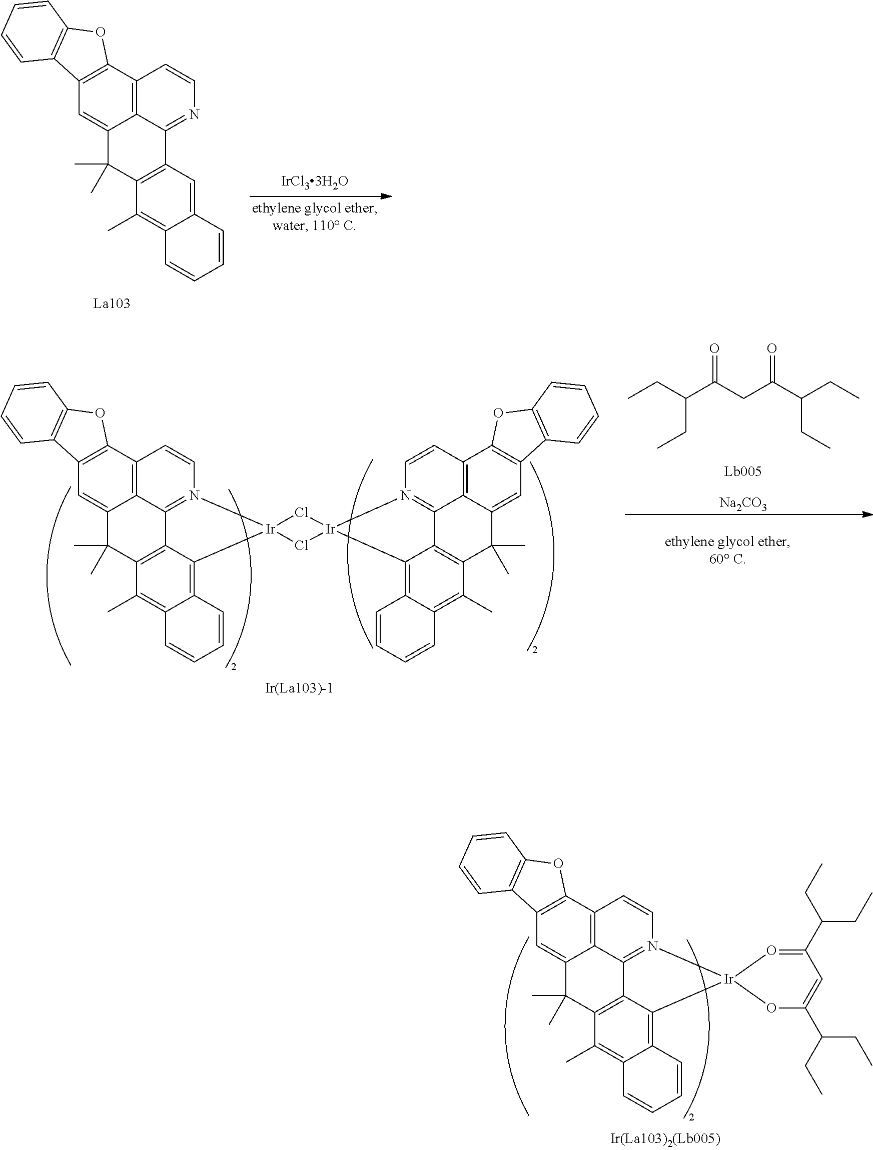

### Synthesis of Compound Ir(La103)-1

Referring to the synthesis and purification method for compound Ir(La008)-1, only by changing the corresponding raw materials, compound Ir(La103)-1 (18.96 g, yield: 76.68%) was obtained, which was used directly in the next step without purification.

### Synthesis of Compound Ir(La103)₂(Lb005)

Referring to the synthesis and purification method for compound Ir(La008)₂(Lb005), only by changing the corresponding raw materials, a red solid as compound Ir(La103)₂(Lb005) (9.84 g, purity: 99.79%, yield: 42.41%) was obtained. 9.84 g of crude Ir(La103)₂(Lb005) was purified by sublimation to obtain sublimated pure Ir(La103)₂(Lb005) (7.35 g, purity: 99.68%, yield: 74.70%), with a mass spectrum: 1173.42 (M+H).

¹H NMR (400 MHz, CDCl₃) δ 8.70 (s, 2H), 8.24-8.19 (m, 2H), 8.16 (d, J=2.3 Hz, 2H), 8.01-7.95 (m, 2H), 7.88-7.81 (m, 4H), 7.66-7.61 (m, 2H), 7.50-7.39 (m, 6H), 7.33 (m, 2H), 7.23 (d, J=10.8 Hz, 2H), 4.79 (s, 1H), 2.71-2.67 (m, 2H), 1.68-1.54 (m, 16H), 1.43-1.28 (m, 4H), 0.88-0.85 (m, 12H).

### Synthesis of Ligand La112

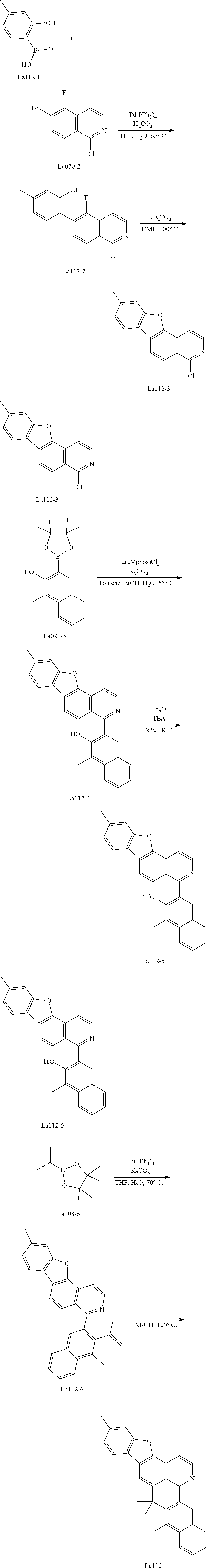

### Synthesis of Compound La112-2

Referring to the synthesis and purification method for compound La008-3, only by changing the corresponding raw materials, target compound La112-2 (32.12 g, purity: 99.88%, yield: 80.14%) was obtained, with a mass spectrum: 288.04 (M+H).

### Synthesis of Compound La112-3

Referring to the synthesis and purification method for compound La070-4, only by changing the corresponding raw materials, target compound La112-3 (22.01 g, purity: 99.75%, yield: 76.56%) was obtained, with a mass spectrum: 268.05 (M+H).

### Synthesis of Compound La112-4

Referring to the synthesis and purification method for compound La008-11, only by changing the corresponding raw materials, target compound La112-4 (28.11 g, purity: 99.68%, yield: 80.03%) was obtained, with a mass spectrum: 390.10 (M+H).

### Synthesis of Compound La112-4

Referring to the synthesis and purification method for compound La008-8, only by changing the corresponding raw materials, target compound La112-4 (40.56 g, purity: 99.79%, yield: 92.11%) was obtained, with a mass spectrum: 522.08 (M+H).

### Synthesis of Compound La112-6

Referring to the synthesis and purification method for compound La008-7, only by changing the corresponding raw materials, target compound La112-6 (29.89 g, purity: 99.84%, yield: 86.46%) was obtained, with a mass spectrum: 414.16 (M+H).

### Synthesis of Compound La112

Referring to the synthesis and purification method for compound La008, only by changing the corresponding raw materials, target compound La112 (14.53 g, purity: 99.74%, yield: 52.63%) was obtained, with a mass spectrum: 414.16 (M+H).

### Synthesis of Compound Ir(La112)₂(Lb005)

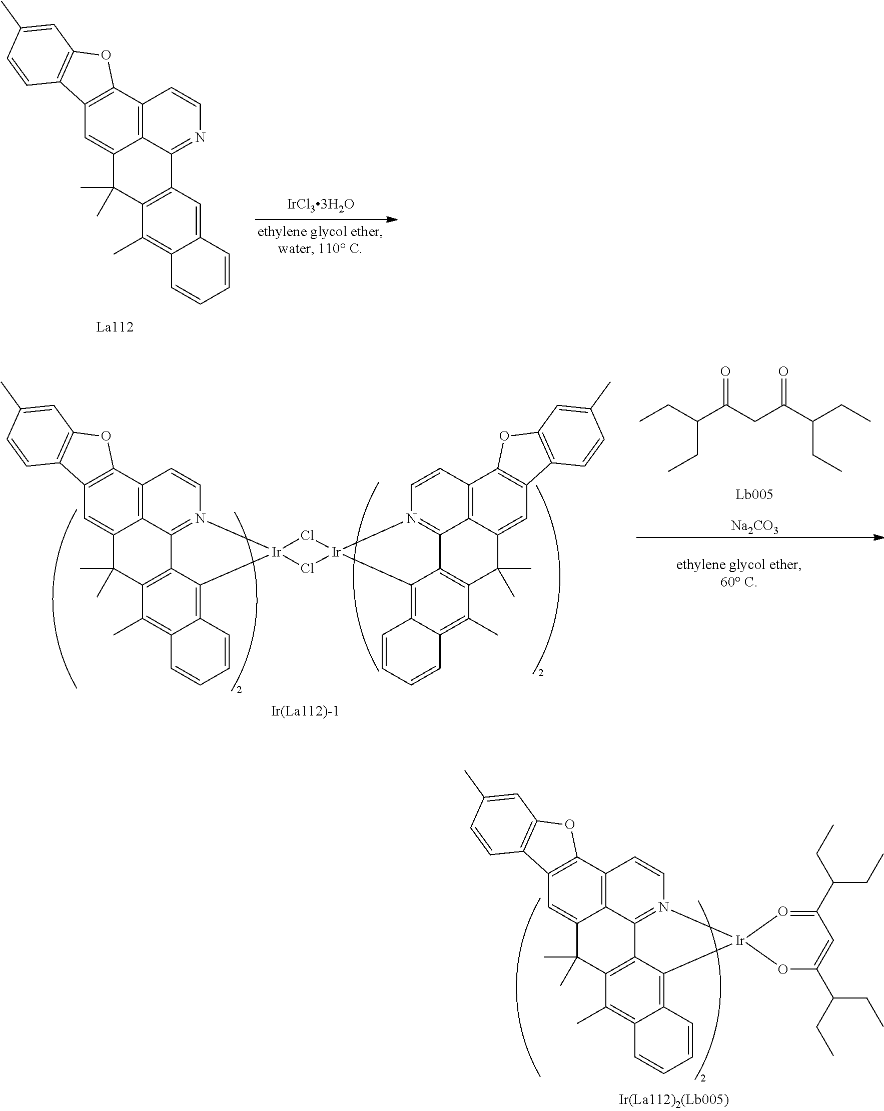

### Synthesis of Compound Ir(La112)-1

Referring to the synthesis and purification method for compound Ir(La008)-1, only by changing the corresponding raw materials, compound Ir(La112)-1 (12.65 g, yield: 72.11%) was obtained, which was used directly in the next step without purification.

### Synthesis of Compound Ir(La112)₂(Lb005)

Referring to the synthesis and purification method for compound Ir(La008)₂(Lb005), only by changing the corresponding raw materials, a red solid compound Ir(La112)₂(Lb005) (6.53 g, purity: 99.74%, yield: 42.12%) was obtained. 6.53 g of crude Ir(La112)₂(Lb005) was purified by sublimation to obtain sublimated pure Ir(La112)₂(Lb005) (4.45 g, purity: 99.70%, yield: 68.15%), with a mass spectrum: 1229.46 (M+H).

¹H NMR (400 MHz, CDCl₃) δ 8.64 (s, 2H), 8.36-8.34 (m, 2H), 8.04 (d, J=7.8 Hz, 2H), 7.87-7.81 (m, 4H), 7.46-7.33 (m, 4H), 7.23 (d, J=10.8 Hz, 2H), 7.19-7.13 (m, 2H), 6.90-6.86 (m, 2H), 4.79 (s, 1H), 2.71-6.68 (m, 2H), 2.34 (d, J=8.7 Hz, 12H), 1.67-1.54 (m, 16H), 1.43-1.28 (m, 4H), 0.90-0.87 (m, 12H).

### Synthesis of Compound Ir(La112)₂(Lb007)

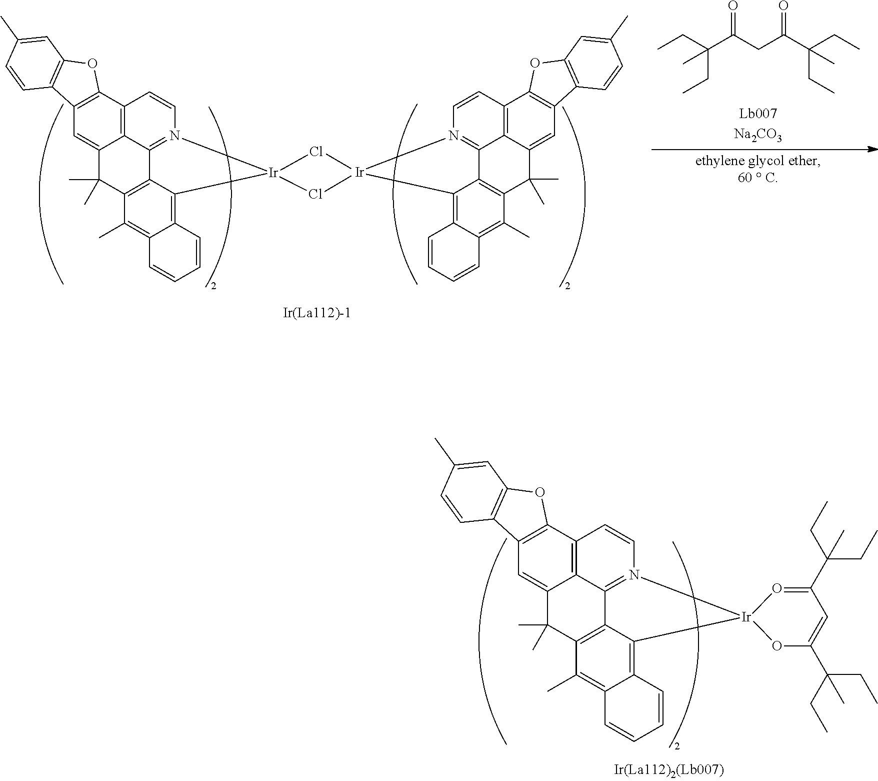

### Synthesis of Compound Ir(La112)₂(Lb007)

Referring to the synthesis and purification method for compound Ir(La008)₂(Lb005), only by changing the corresponding raw materials, a red solid as compound Ir(La112)₂(Lb007) (7.05 g, purity: 99.78%, yield: 43.25%) was obtained. 7.05 g of crude Ir(La112)₂(Lb007) was purified by sublimation to obtain sublimated pure Ir(La112)₂(Lb007) (5.35 g, purity: 99.70%, yield: 75.89%), with a mass spectrum: 1257.20 (M+H).

¹H NMR (400 MHZ, CDCl₃) δ 8.63 (s, 2H), 8.36 (dd, J=7.4, 1.5 Hz, 2H), 8.04 (d, J=7.8 Hz, 2H), 7.87-7.81 (m, 4H), 7.46-7.33 (m, 4H), 7.23 (d, J=10.8 Hz, 2H), 7.16 (m, 2H), 6.90-6.86 (m, 2H), 5.83 (s, 1H), 2.34 (d, J=8.7 Hz, 12H), 1.69-1.57 (m, 4H), 1.56 (s, 12H), 1.44-1.32 (m, 4H), 1.05 (d, J=15.2 Hz, 6H), 0.88-0.82 (m, 12H).

### Synthesis of Ligand La132

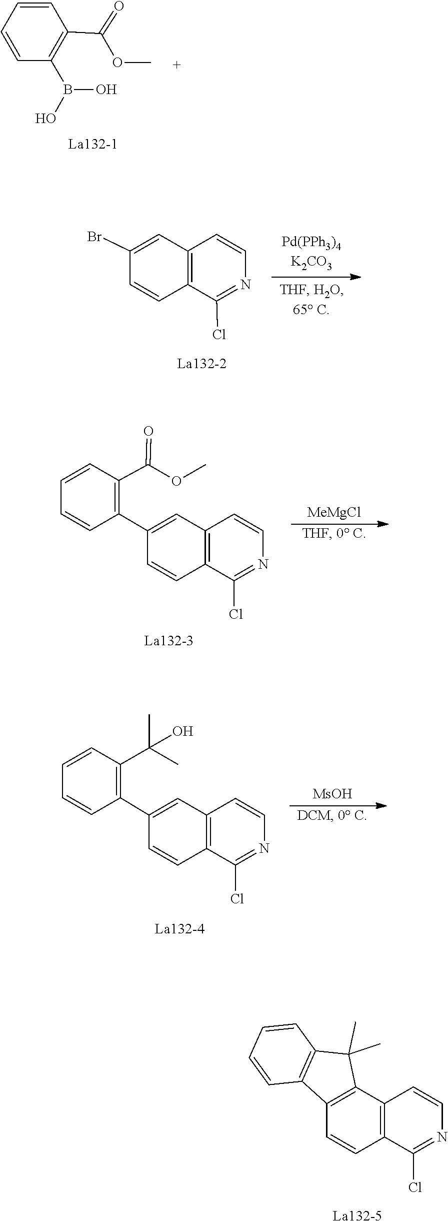

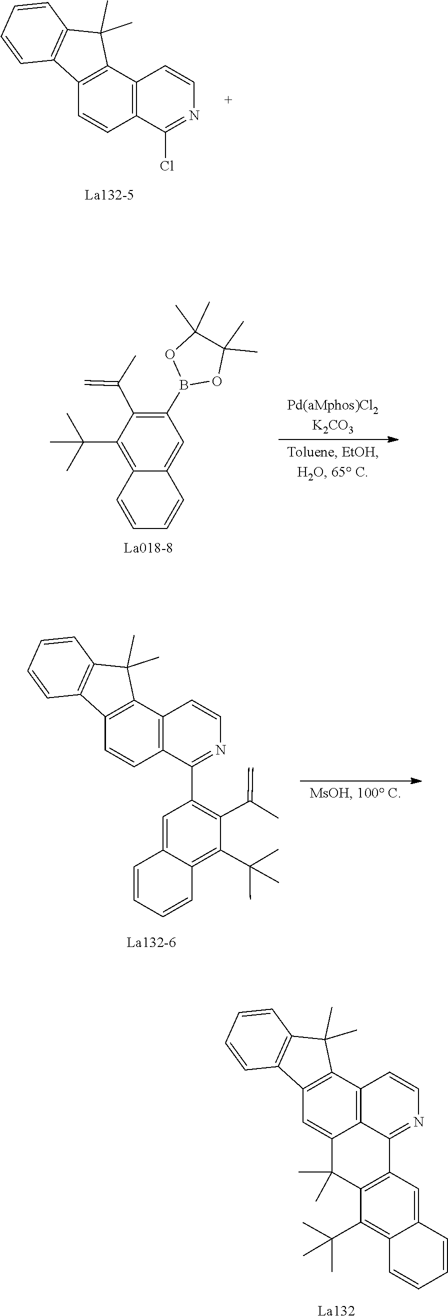

### Synthesis of Compound La132-3

Referring to the synthesis and purification method for compound La008-3, only by changing the corresponding raw materials, target compound La132-3 (40.52 g, purity: 99.80%, yield: 82.66%) was obtained, with a mass spectrum: 298.02 (M+H).

### Synthesis of Compound La132-4

Compound La132-3 (35.00 g, 117.55 mmol) and tetrahydrofuran (350 mL) were added to a 1,000 mL three-necked round-bottom flask, and the flask was evacuated and replaced with nitrogen three times. Under nitrogen protection, the system was cooled to 0° C. After the internal temperature dropped to the specified value, a solution of methylmagnesium chloride (86.21 ml, 3 mol/L in tetrahydrofuran, 258.62 mmol) was added dropwise. The addition was completed over 1 hour. The mixture was stirred at 0° C. for 1 hour. TLC monitoring (the developing solvent was ethyl acetate: petroleum ether=1:15) showed that the raw material La132-3 was reacted completely.

An aqueous hydrochloric acid solution (133 mL, 4 mol/L, 530.00 mmol) was added dropwise to the system to quench the reaction. The organic solvent was removed by concentration under reduced pressure, and ethyl acetate (700 ml) was added. The mixture was then washed with deionized water (3× 300 ml). After standing for liquid separation, the organic phase was concentrated under reduced pressure at 65° C. and then separated by silica gel column chromatography (200-300 mesh silica gel, the eluent is ethyl acetate:petroleum ether=1:30). After elution, the mixture was concentrated under reduced pressure at 65° C. for 1 hour to obtain a light yellow liquid, which was compound La132-4 20) (28.74 g, purity: 99.79%, yield: 82.11%), with a mass spectrum: 298.08 (M+H).

### Synthesis of Compound La132-5

Compound La132-4 (25.00 g, 83.95 mmol) and dichloromethane (250 mL) were added to a 500 mL three-necked round-bottom flask, and the flask was evacuated and replaced with nitrogen three times. Under nitrogen protection, the system was cooled to 0° C. After the internal temperature dropped to the specified value, methanesulfonic acid (16.14 g, 167.91 mmol) was added dropwise. The mixture was stirred at 0° C. for 1 hour. TLC monitoring (the developing solvent was ethyl acetate: petroleum ether=1:25) showed that the raw material La132-3 was reacted completely. 100 ml of deionized water was added to the system to quench the reaction. After standing for liquid separation, the organic solvent was removed by concentration under reduced pressure. The mixture was then separated by silica gel column chromatography (200-300 mesh silica gel, the eluent is ethyl acetate:petroleum ether=1:25), and then concentrated under reduced pressure at 65° C. for 1 hour to obtain a light yellow liquid, which was compound La132-5 (20.07 g, purity: 99.83%, yield: 85.47%), with a mass spectrum: 280.08 (M+H).

### Synthesis of Compound La132-6

Referring to the synthesis and purification method for compound La008-11, only by changing the corresponding raw materials, target compound La132-6 (27.60 g, purity: 99.80%, yield: 82.56%) was obtained, with a mass spectrum: 468.26 (M+H).

### Synthesis of Compound La132

Referring to the synthesis and purification method for compound La008, only by changing the corresponding raw materials, target compound La132 (12.44 g, purity: 99.73%, yield: 51.01%) was obtained, with a mass spectrum: 468.26 (M+H).

### Synthesis of Compound Ir(La132)₂(Lb005)

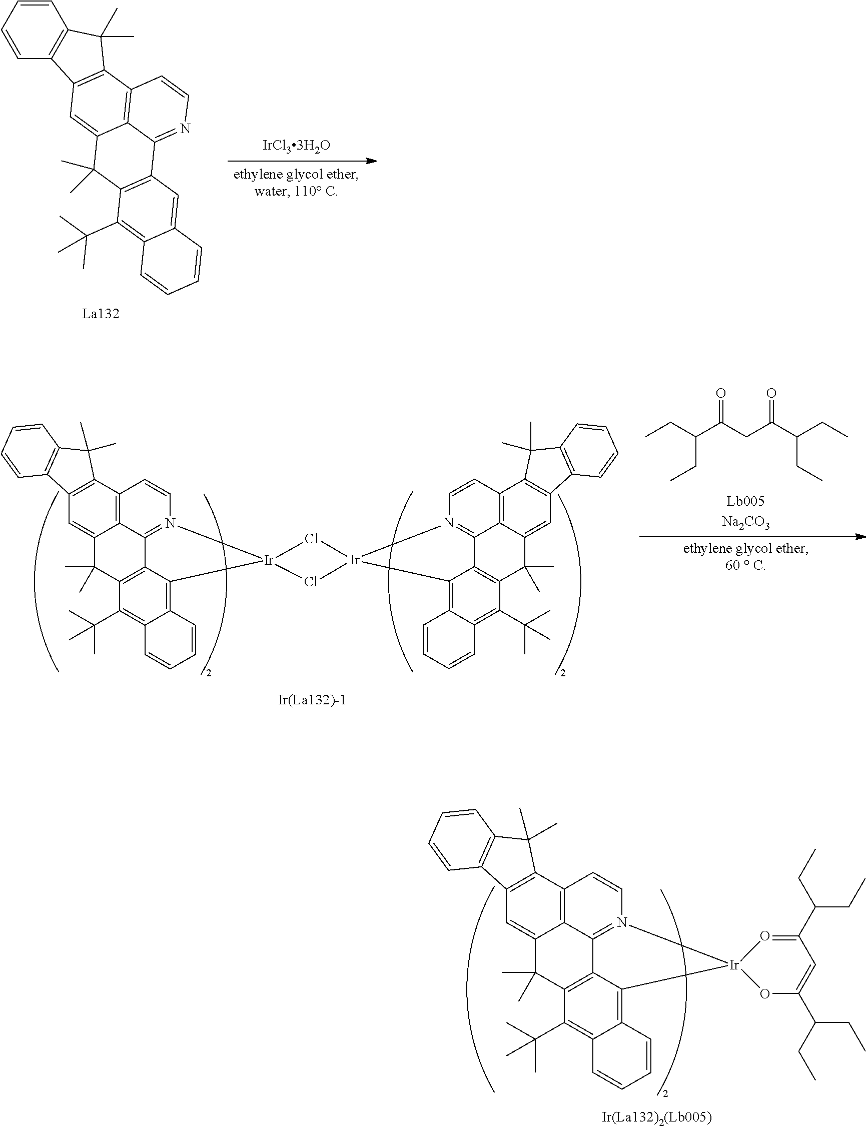

### Synthesis of Compound Ir(La132)-1

Referring to the synthesis and purification method for compound Ir(La008)-1, only by changing the corresponding raw materials, compound Ir(La132)-1 (10.67 g, yield: 74.22%) was obtained, which was used directly in the next step without purification.

### Synthesis of Compound Ir(La132)₂(Lb005)

Referring to the synthesis and purification method for compound Ir(La008)₂(Lb005), only by changing the corresponding raw materials, a red solid as compound Ir(La132)₂(Lb005) (5.89 g, purity: 99.87%, yield: 41.01%) was obtained. 5.89 g of crude Ir(La132)₂(Lb005) was purified by sublimation to obtain sublimated pure Ir(La132)₂(Lb005) (4.22 g, purity: 99.77%, yield: 71.65%), with a mass spectrum: 1337.24 (M+H).

¹H NMR (400 MHZ, CDCl₃) δ 8.26 (s, 2H), 8.21-8.12 (m, 4H), 8.00-7.95 (m, 2H), 7.82 (dd, J=6.8, 1.6 Hz, 2H), 7.58 (dd, J=7.3, 1.5 Hz, 2H), 7.51-7.44 (m, 4H), 7.40-7.33 (m, 6H), 4.79 (s, 1H), 2.71 (m, 2H), 1.75 (s, 12H), 1.68-1.54 (m, 4H), 1.51 (s, 12H), 1.38 (s, 22H), 0.91-0.88 (m, 12H).

### Synthesis of Ligand La162

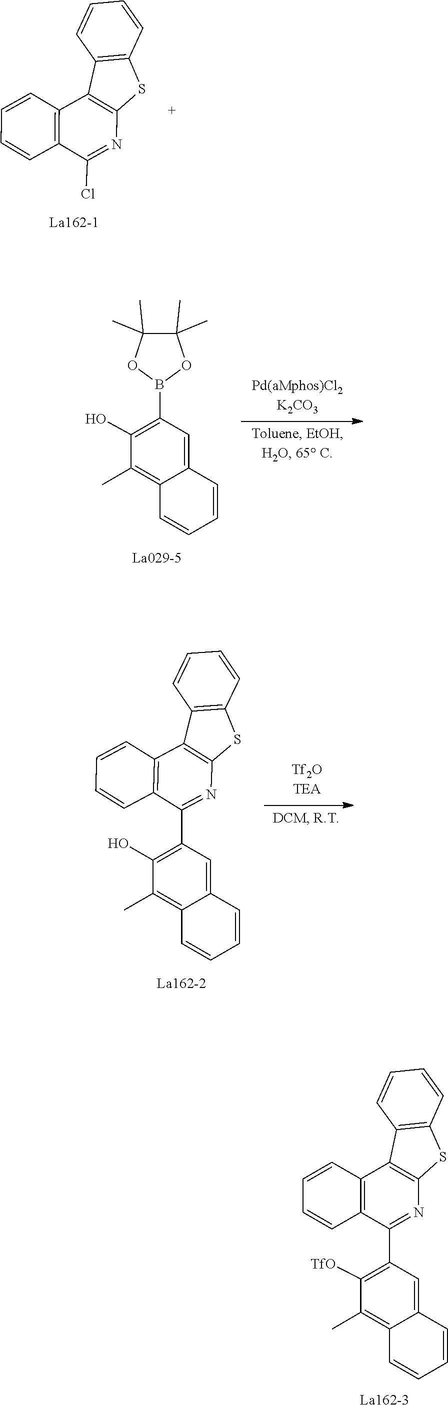

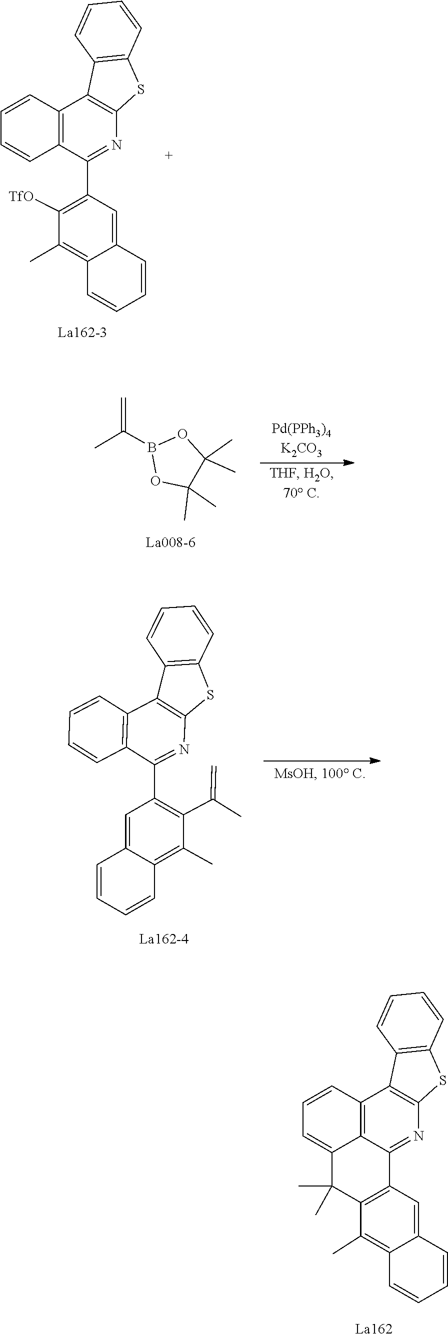

### Synthesis of Compound La162-2

Referring to the synthesis and purification method for compound La008-11, only by changing the corresponding raw materials, target compound La162-2 (22.90 g, purity: 99.85%, yield: 81.60%) was obtained, with a mass spectrum: 392.10 (M+H).

### Synthesis of Compound La162-3

Referring to the synthesis and purification method for compound La008-8, only by changing the corresponding raw materials, target compound La162-3 (35.23, purity: 99.75%, yield: 88.97%) was obtained, with a mass spectrum: 524.06 (M+H).

### Synthesis of Compound La162-4

Referring to the synthesis and purification method for compound La008-7, only by changing the corresponding raw materials, target compound La162-4 (20.67, purity: 99.68%, yield: 82.69%) was obtained, with a mass spectrum: 416.14 (M+H).

### Synthesis of Compound La162

Referring to the synthesis and purification method for compound La008, only by changing the corresponding raw materials, target compound La162 (11.34, purity: 99.78%, yield: 50.05%) was obtained, with a mass spectrum: 416.14 (M+H).

### Synthesis of Compound Ir(La162)₂(Lb005)

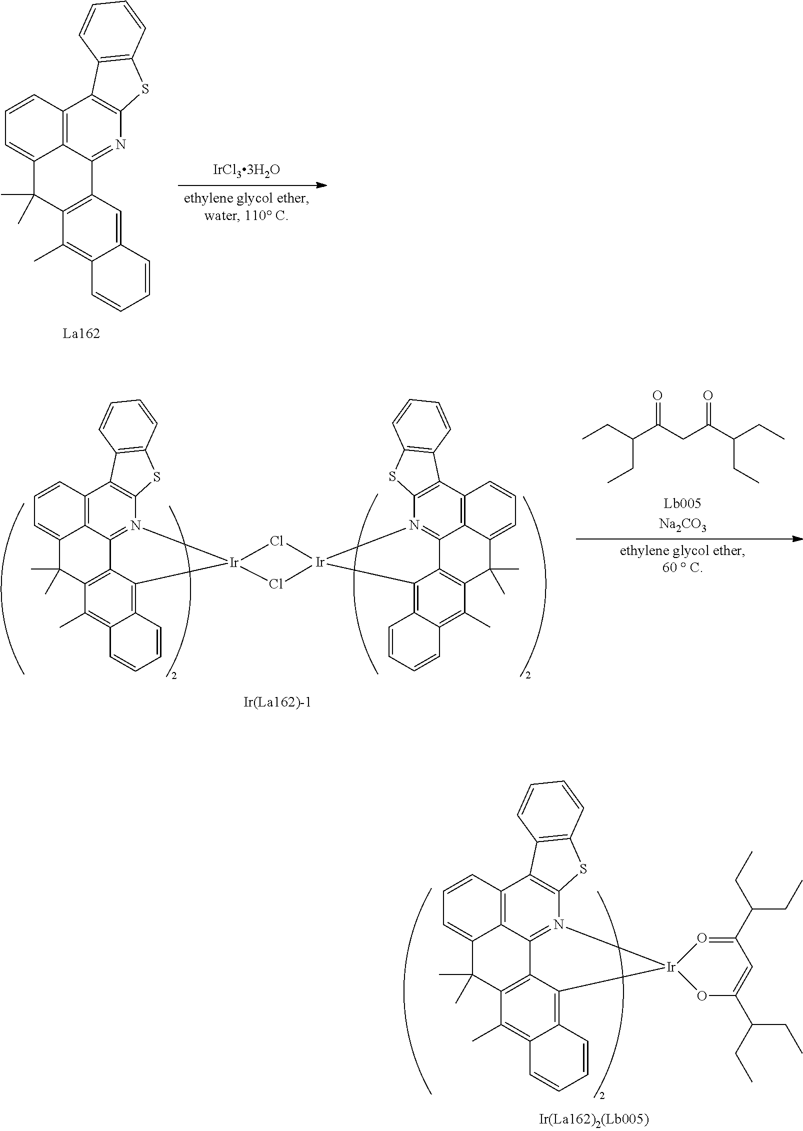

### Synthesis of Compound Ir(La162)-1

Referring to the synthesis and purification method for compound Ir(La008)-1, only by changing the corresponding raw materials, compound Ir(La162)-1 (16.88 g, yield: 71.09%) was obtained, which was used directly in the next step without purification.

### Synthesis of Compound Ir(La162)₂(Lb005)

Referring to the synthesis and purification method for compound Ir(La008)₂(Lb005), only by changing the corresponding raw materials, a red solid as compound Ir(La162)₂(Lb005) (9.93 g, purity: 99.87%, yield: 43.78%) was obtained. 9.93 g of crude Ir(La162)₂(Lb005) was purified by sublimation to obtain sublimated pure Ir(La162)₂(Lb005) (7.75 g, purity: 99.80%, yield: 78.04%), with a mass spectrum: 1233.40 (M+H).

¹H NMR (400 MHZ, CDCl₃) δ 8.41-8.34 (m, 4H), 8.22-8.15 (m, 2H), 7.91-7.81 (m, 4H), 7.56-7.47 (m, 6H), 7.46-7.33 (m, 6H), 4.72 (s, 1H), 2.71-2.68 (m, 2H), 2.34 (s, 6H), 1.68-1.54 (m, 4H), 1.52 (s, 12H), 1.43-1.28 (m, 4H), 0.88-0.86 (m, 12H).

### Synthesis of Ligand La175

### Substitute Specification-Clean Copy

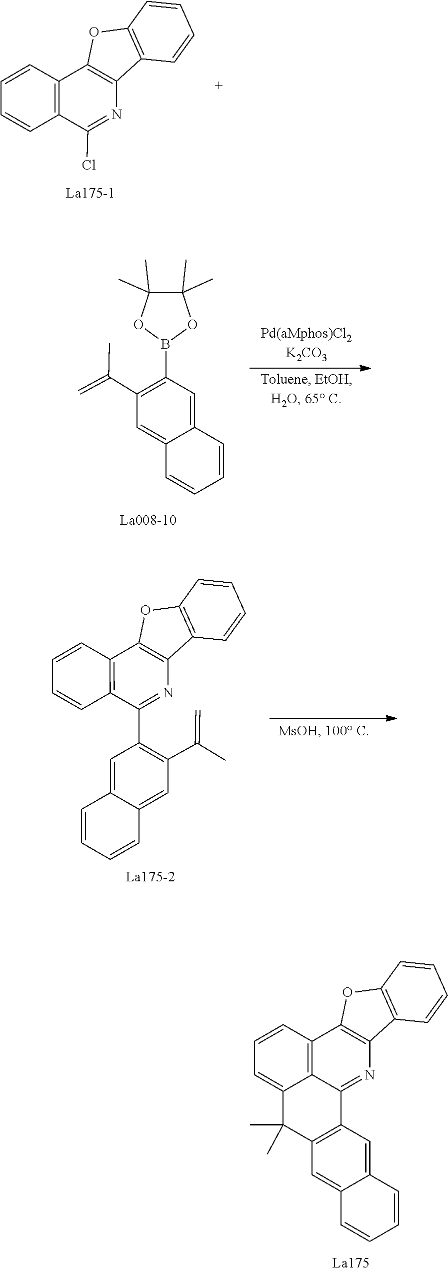

### Synthesis of Compound La175-2

Referring to the synthesis and purification method for compound La008-11, only by changing the corresponding raw materials, target compound La175-2 (18.56 g, purity: 99.81%, yield: 82.05%) was obtained, with a mass spectrum: 386.16 (M+H).

### Synthesis of Compound La175

Referring to the synthesis and purification method for compound La008, only by changing the corresponding raw materials, target compound La175 (8.90, purity: 99.77%, yield: 50.00%) was obtained, with a mass spectrum: 386.16 (M+H).

### Synthesis of Compound Ir(La175)₂(Lb005)

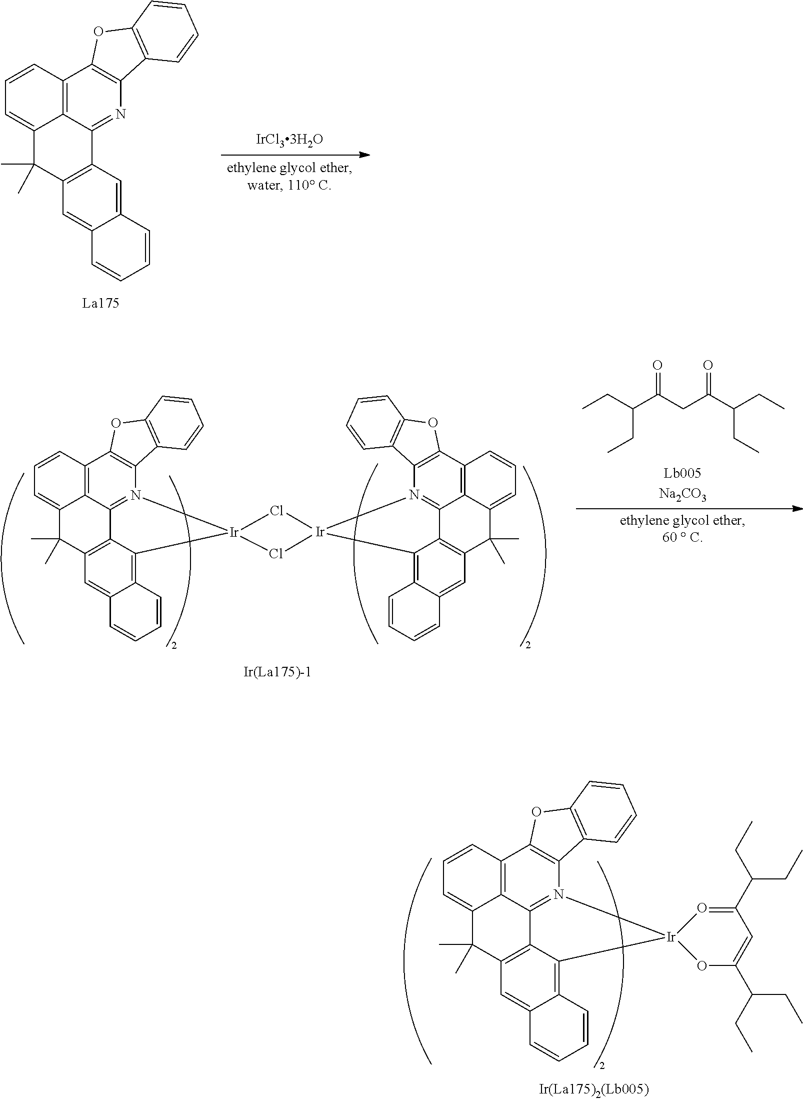

### Synthesis of Compound Ir(La175)-1

Referring to the synthesis and purification method for compound Ir(La008)-1, only by changing the corresponding raw materials, compound Ir(La175)-1 (12.44 g, yield: 72.57%) was obtained, which was used directly in the next step without purification.

### Synthesis of Compound Ir(La175)₂(Lb005)

Referring to the synthesis and purification method for compound Ir(La008)₂(Lb005), only by changing the corresponding raw materials, a red solid as compound Ir(La175)₂(Lb005) (7.66 g, purity: 99.83%, yield: 40.00%) was obtained. 7.66 g of crude Ir(La175)₂(Lb005) was purified by sublimation to obtain sublimated pure Ir(La175)₂(Lb005) (4.77 g, purity: 99.80%, yield: 62.28%), with a mass spectrum: 1173.42 (M+H).

¹H NMR (400 MHZ, CDCl₃) δ 8.24-8.19 (m, 2H), 8.16 (d, J=2.3 Hz, 2H), 7.97 (dd, J=9.5, 1.4 Hz, 2H), 7.89-7.82 (m, 4H), 7.56-7.54 (m, 4H), 7.50-7.30 (m, 10H), 4.79 (s, 1H), 2.71 (m, 2H), 1.68-1.54 (m, 16H), 1.43-1.28 (m, 4H), 0.89-0.86 (m, 12H).

### Synthesis of Ligand La181

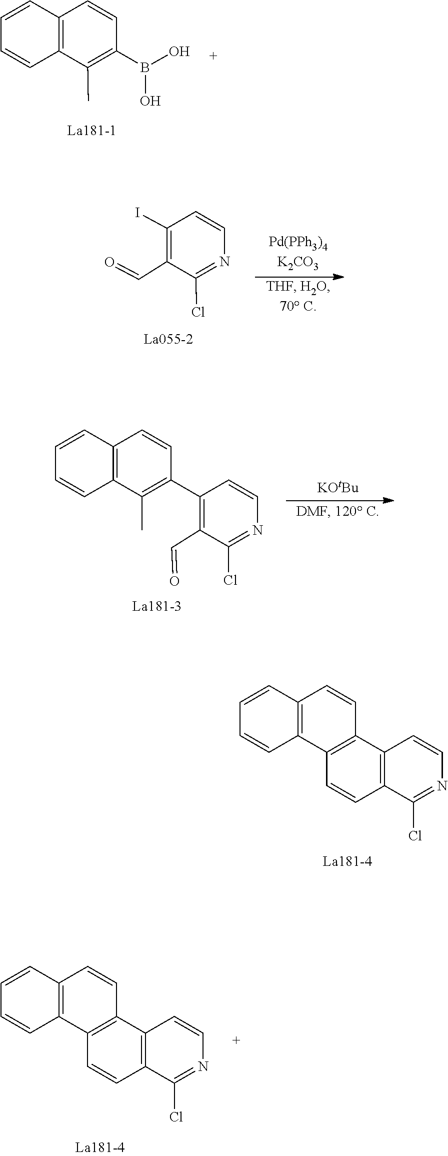

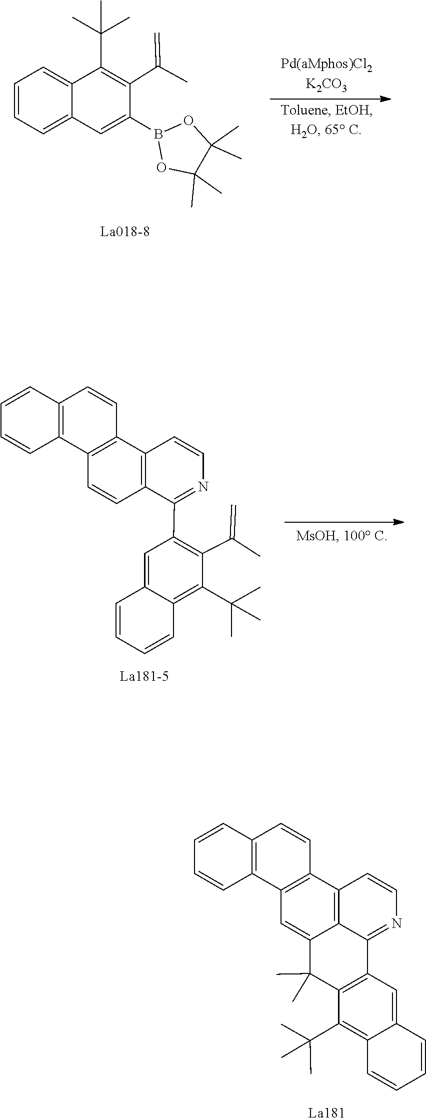

### Synthesis of Compound La181-3

Referring to the synthesis and purification method for compound La008-3, only by changing the corresponding raw materials, target compound La181-3 (28.88 g, purity: 99.74%, yield: 80.01%) was obtained, with a mass spectrum: 282.02 (M+H).

### Synthesis of Compound La181-4

Referring to the synthesis and purification method for compound La008-4, only by changing the corresponding raw materials, target compound La181-4 (12.35 g, purity: 99.79%, yield: 68.06%) was obtained, with a mass spectrum: 264.03 (M+H).

### Synthesis of Compound La181-5

Referring to the synthesis and purification method for compound La008-11, only by changing the corresponding raw materials, target compound La181-5 (19.25 g, purity: 99.83%, yield: 85.41%) was obtained, with a mass spectrum: 452.22 (M+H).

### Synthesis of Compound La181

Referring to the synthesis and purification method for compound La008, only by changing the corresponding raw materials, target compound La181 (9.33 g, purity: 99.80%, yield: 53.32%) was obtained, with a mass spectrum: 452.22 (M+H).

### Synthesis of Compound Ir(La181)₂(Lb005)

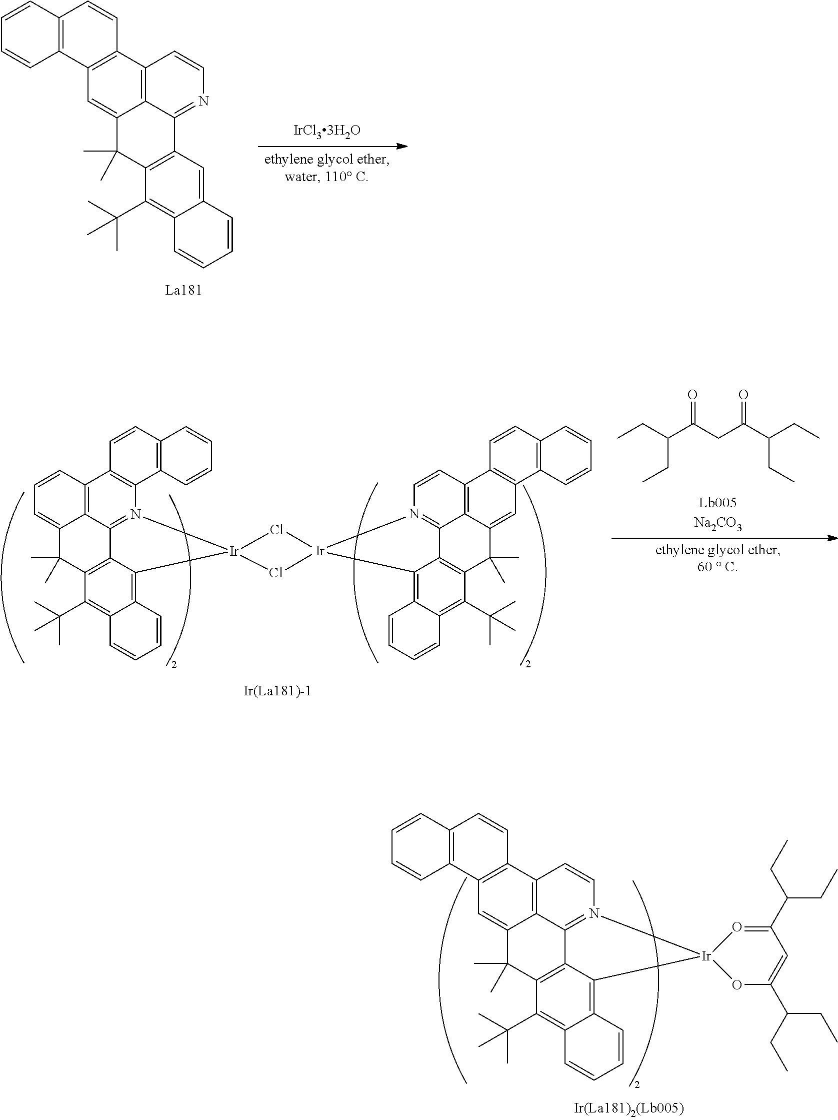

### Synthesis of Compound Ir(La181)-1

Referring to the synthesis and purification method for compound Ir(La008)-1, only by changing the corresponding raw materials, compound Ir(La181)-1 (15.35 g, yield: 73.33%) was obtained, which was used directly in the next step without purification.

### Synthesis of Compound Ir(La181)₂(Lb005)

Referring to the synthesis and purification method of compound Ir(La008)₂(Lb005), only by changing the corresponding raw materials, a red solid as compound Ir(La181)₂(Lb005) (8.55 g, purity: 99.80%, yield: 42.22%) was obtained. 8.55 g of crude Ir(La181)₂(Lb005) was purified by sublimation to obtain sublimated pure Ir(La181)₂(Lb005) (6.41 g, purity: 99.80%, yield: 74.97%), with a mass spectrum: 1305.52 (M+H).

¹H NMR (400 MHZ, CDCl₃) δ 8.59 (d, J=8.9 Hz, 2H), 8.54 (s, 2H), 8.45-8.40 (m, 2H), 8.23-8.15 (m, 4H), 7.96 (d, J=9.2 Hz, 2H), 7.92-7.87 (m, 2H), 7.82 (dd, J=6.9, 1.5 Hz, 2H), 7.56-7.44 (m, 6H), 7.37 (td, J=7.6, 1.3 Hz, 2H), 7.27 (d, J=9.5 Hz, 2H), 4.80 (s, 1H), 2.71-2.67 (m, 2H), 1.67-1.54 (m, 4H), 1.51 (s, 12H), 1.38 (s, 22H), 0.90-0.88 (m, 12H).

### Synthesis of Ligand La202

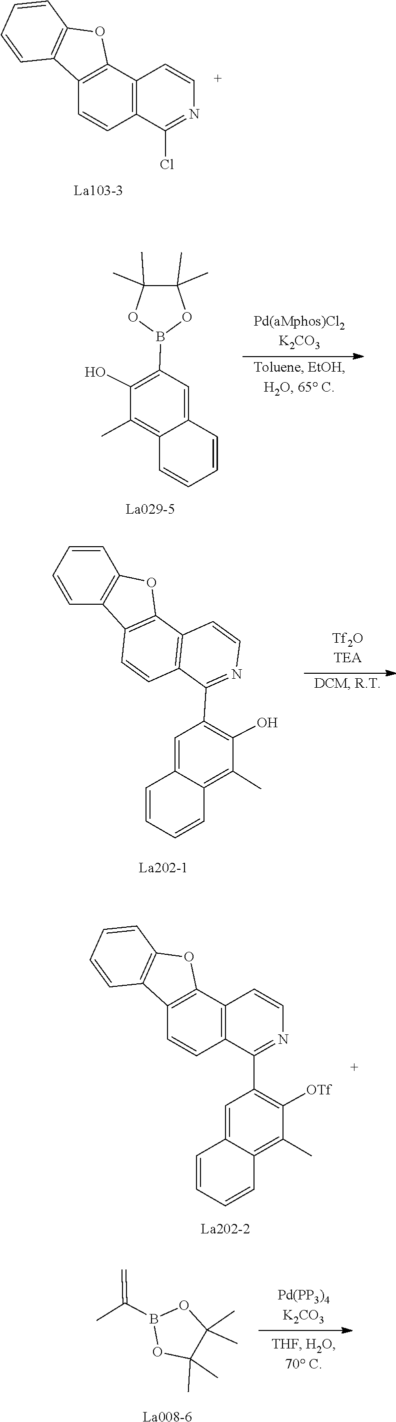

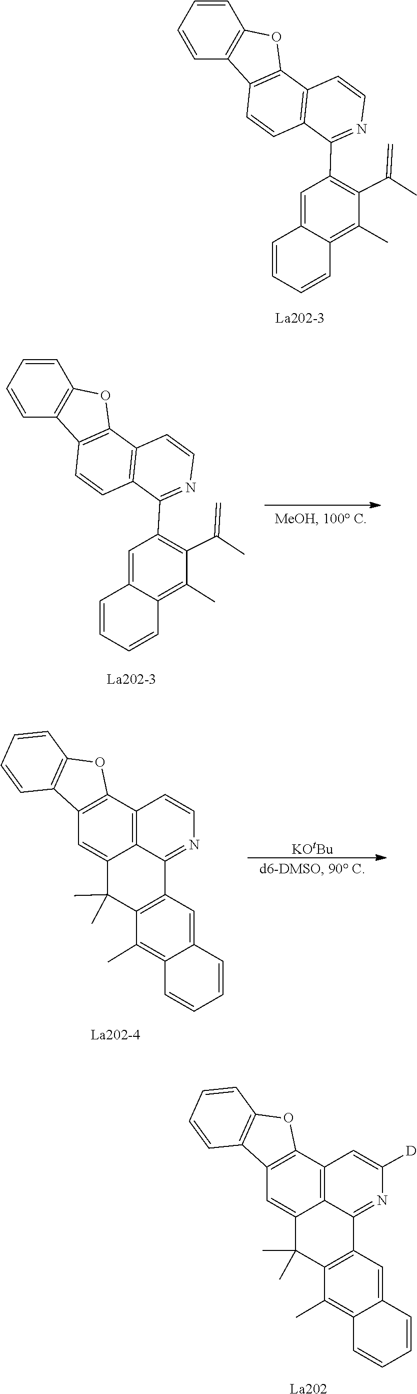

### Synthesis of Compound La202-1

Referring to the synthesis and purification method for compound La008-11, only by changing the corresponding raw materials, target compound La202-1 (35.06 g, purity: 99.74%, yield: 81.11%) was obtained, with a mass spectrum: 376.12 (M+H).

### Synthesis of Compound La202-2

Referring to the synthesis and purification method for compound La008-8, only by changing the corresponding raw materials, target compound La202-2 (46.56 g, purity: 99.76%, yield: 88.62%) was obtained, with a mass spectrum: 508.04 (M+H).

### Synthesis of Compound La202-3

Referring to the synthesis and purification method for compound La008-7, only by changing the corresponding raw materials, target compound La202-3 (37.06 g, purity: 99.83%, yield: 84.21%) was obtained, with a mass spectrum: 400.06 (M+H).

### Synthesis of Compound La202-4

Referring to the synthesis and purification method for compound La008, only by changing the corresponding raw materials, target compound La202-4 (18.52 g, purity: 99.78%, yield: 53.63%) was obtained, with a mass spectrum: 400.06 (M+H).

### Synthesis of Compound La202

Compound La202-4 (15.00 g, 37.55 mmol), potassium tert-butoxide (8.43 g, 75.10 mmol), and deuterated dimethyl sulfoxide (150 mL) were added to a 500 mL three-necked round-bottom flask, and the flask was evacuated and replaced with nitrogen three times. The mixture was heated to 90° C. and reacted overnight for 24 h. The reaction of La202-4 was monitored by NMR.

The reaction solution was added dropwise to deionized water (500 mL), and ethyl acetate (500 mL) was then added. The mixture was stirred at room temperature for 30 minutes. After liquid separation, the organic phase was washed with deionized water (3×150 mL). After liquid separation, the organic phase was concentrated and separated by silica gel column chromatography (200-300 mesh silica gel, the eluent is ethyl acetate:petroleum ether=1:10). Concentration was conducted to obtain a white solid, which was compound La202 (14.37 g, purity: 99.82%, deuterium substitution rate: 99.46%, yield: 95.55%), with a mass spectrum: 401.16 (M+H).

### Synthesis of Compound Ir(La202)₂(Lb005)

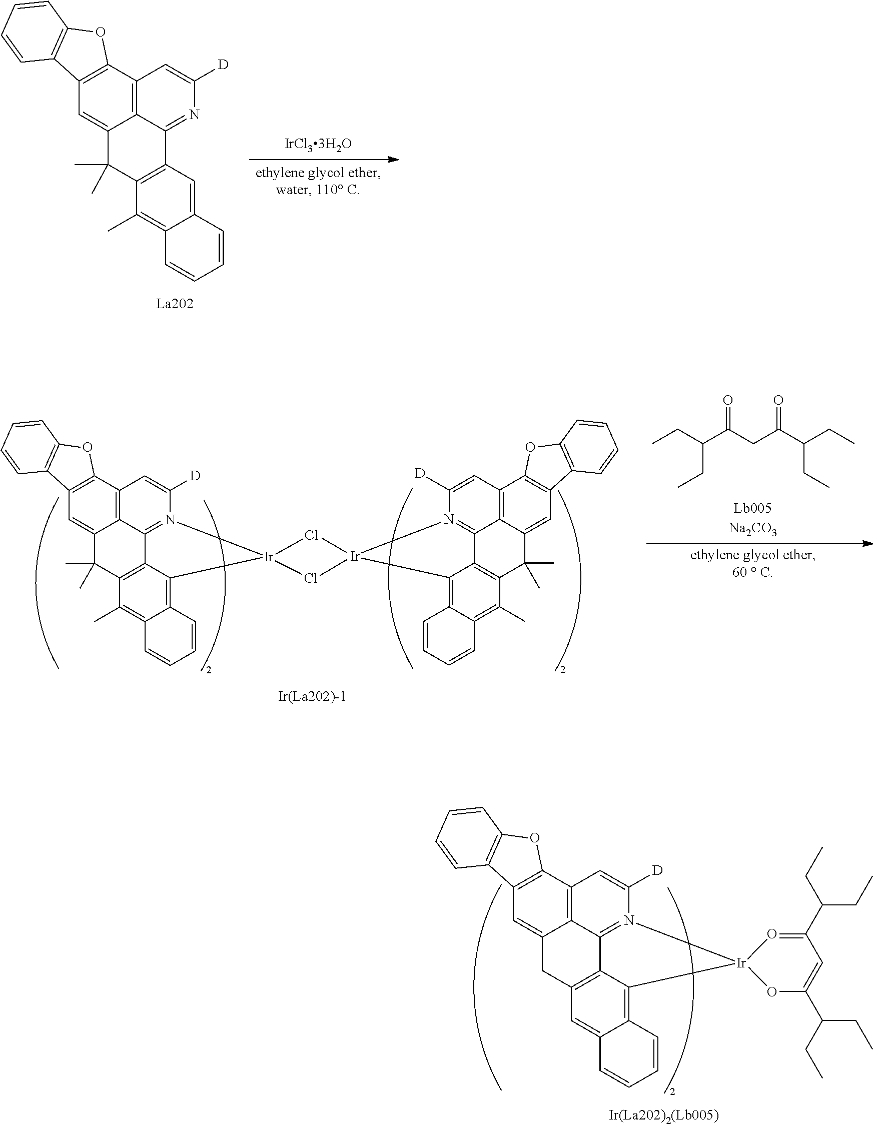

### Synthesis of Compound Ir(La202)-1

Referring to the synthesis and purification method for compound Ir(La008)-1, only by changing the corresponding raw materials, compound Ir(La202)-1 (16.56 g, yield: 7565%) was obtained, which was used directly in the next step without purification.

### Synthesis of Compound Ir(La202)₂(Lb005)

Referring to the synthesis and purification method of compound Ir(La008)₂(Lb005), only by changing the corresponding raw materials, a red solid as compound Ir(La202)₂(Lb005) (9.63 g, purity: 99.82%, yield: 43.13%) was obtained. 963 g of crude Ir(La202)₂(Lb005) was purified by sublimation to obtain sublimated pure Ir(La202)₂(Lb005) (7.56 g, purity: 99.80%, yield: 78.52%), with a mass spectrum: 1203.44 (M+H).

¹H NMR (400 MHZ, CDCl₃) δ 8.63 (s, 2H), 8.36 (dd, J=7.4, 1.5 Hz, 2H), 8.01-7.95 (m, 2H), 7.89 (s, 2H), 7.84 (m, 2H), 7.66-7.61 (m, 2H), 7.44-7.39 (m, 6H), 7.37-7.34 (m, 2H), 4.79 (s, 1H), 2.71-2.67 (m, 2H), 2.34 (s, 6H), 1.67-1.54 (m, 16H), 1.42-1.30 (m, 4H), 0.89-0.87 (m, 12H).

### Synthesis of Ligand La210

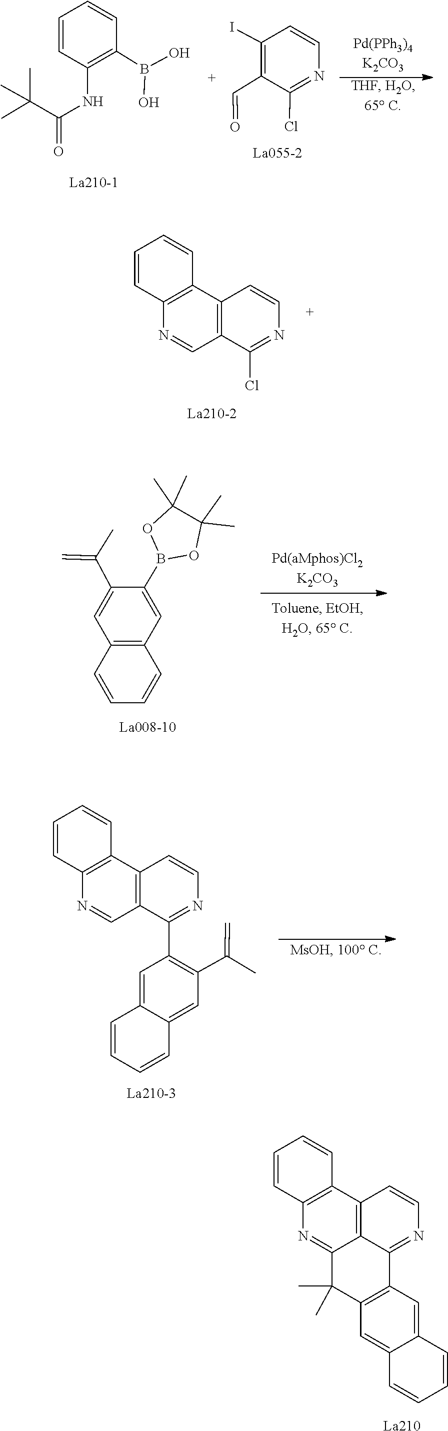

### Synthesis of Compound La210-2

Referring to the synthesis and purification method for compound La008-3, only by changing the corresponding raw materials and extending the reaction time to 15 hours, target compound La210-2 (20.03 g, purity: 99.74%, yield: 65.03%) was obtained, with a mass spectrum: 215.03 (M+H).

### Synthesis of Compound La210-3

Referring to the synthesis and purification method for compound La008-11, only by changing the corresponding raw materials, target compound La210-3 (18.65 g, purity: 99.65%, yield: 85.96%) was obtained, with a mass spectrum: 347.15 (M+H).

### Synthesis of Compound La2101

Referring to the synthesis and purification method for compound La008, only by changing the corresponding raw materials, target compound La210 (10.85 g, purity: 99.76%, yield: 60.00%) was obtained, with a mass spectrum: 347.15 (M+H).

### Synthesis of Compound Ir(La210)₂(Lb005)

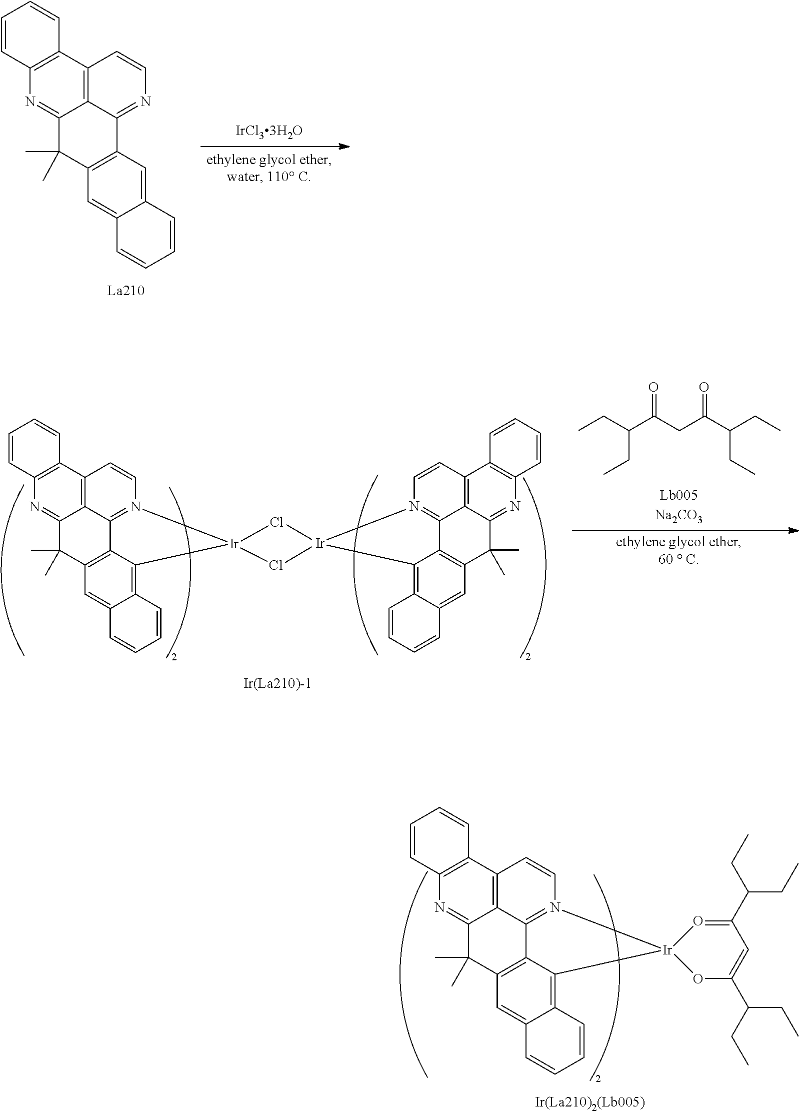

### Synthesis of Compound Ir(La210)-1

Referring to the synthesis and purification method for compound Ir(La008)-1, only by changing the corresponding raw materials, compound Ir(La210)-1 (12.63 g, yield: 76.36%) was obtained, which was used directly in the next step without purification.

### Synthesis of Compound Ir(La210)₂(Lb005)

Referring to the synthesis and purification method for compound Ir(La008)₂(Lb005), only by changing the corresponding raw materials, a red solid as compound Ir(La210)₂(Lb005) (8.33 g, purity: 99.82%, yield: 43.13%) was obtained. 8.33 g of crude Ir(La210)₂(Lb005) was sublimed and purified to obtain sublimated pure Ir(La210)₂(Lb005) (6.00 g, purity: 99.80%, yield: 72.03%), with a mass spectrum: 1095.41 (M+H).

¹H NMR (400 MHZ, CDCl₃) δ 8.33-8.27 (m, 2H), 8.25-8.17 (m, 6H), 8.02 (dd, J=7.5, 1.4 Hz, 2H), 7.88-7.82 (m, 2H), 7.69-7.62 (m, 2H), 7.52-7.43 (m, 4H), 7.33 (td, J=7.2, 1.1 Hz, 2H), 7.25 (d, J=9.5 Hz, 2H), 4.79 (s, 1H), 2.74-2.71 (m, 2H), 1.68 (s, 12H), 1.66-1.54 (m, 4H), 1.43-1.28 (m, 4H), 0.88-0.86 (m, 12H).

### Synthesis of Ligand La214

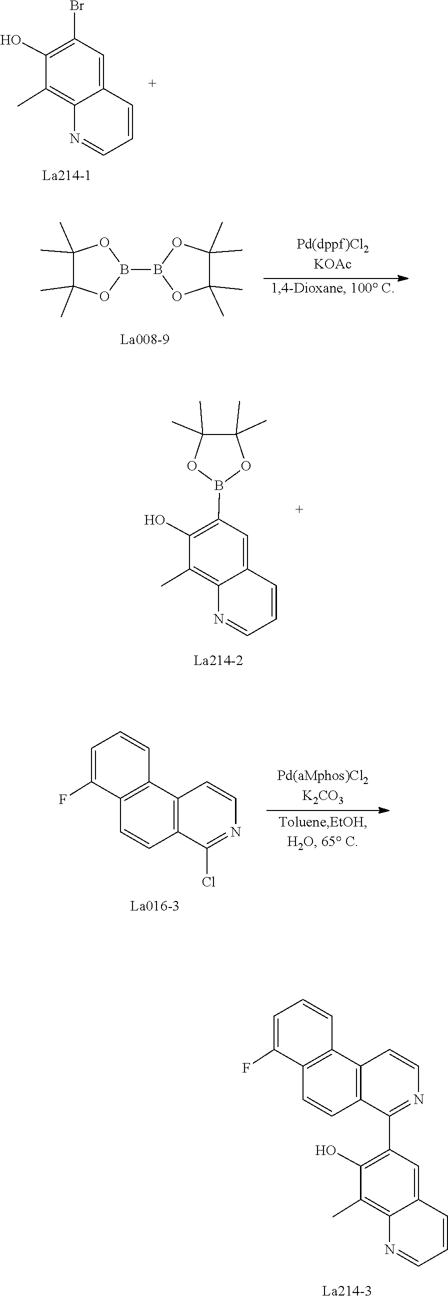

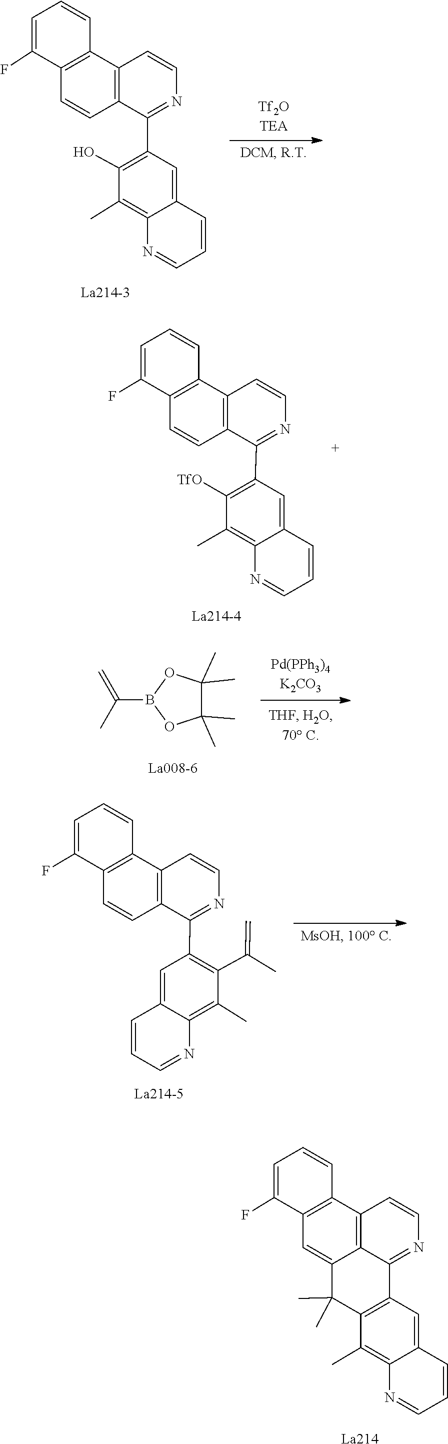

### Synthesis of Compound La214-2

Referring to the synthesis and purification method for compound La008-3, only by changing the corresponding raw materials, target compound La214-2 (25.96 g, purity: 99.33%, yield: 83.52%) was obtained, with a mass spectrum: 286.15 (M+H).

### Synthesis of Compound La214-3

Referring to the synthesis and purification method for compound La008-11, only by changing the corresponding raw materials, target compound La214-3 (22.11 g, purity: 99.45%, yield: 78.98%) was obtained, with a mass spectrum: 355.12 (M+H).

### Synthesis of Compound La214-4

Referring to the synthesis and purification method for compound La008-8, only by changing the corresponding raw materials, target compound La214-4 (19.88 g, purity: 99.60%, yield: 75.96%) was obtained, with a mass spectrum: 487.07 (M+H).

### Synthesis of Compound La214

Referring to the synthesis and purification method for compound La008, only by changing the corresponding raw materials, target compound La214 (18.75 g, purity: 99.78%, yield: 62.75%) was obtained, with a mass spectrum: 379.15 (M+H).

### Synthesis of Compound Ir(La214)₂(Lb005)

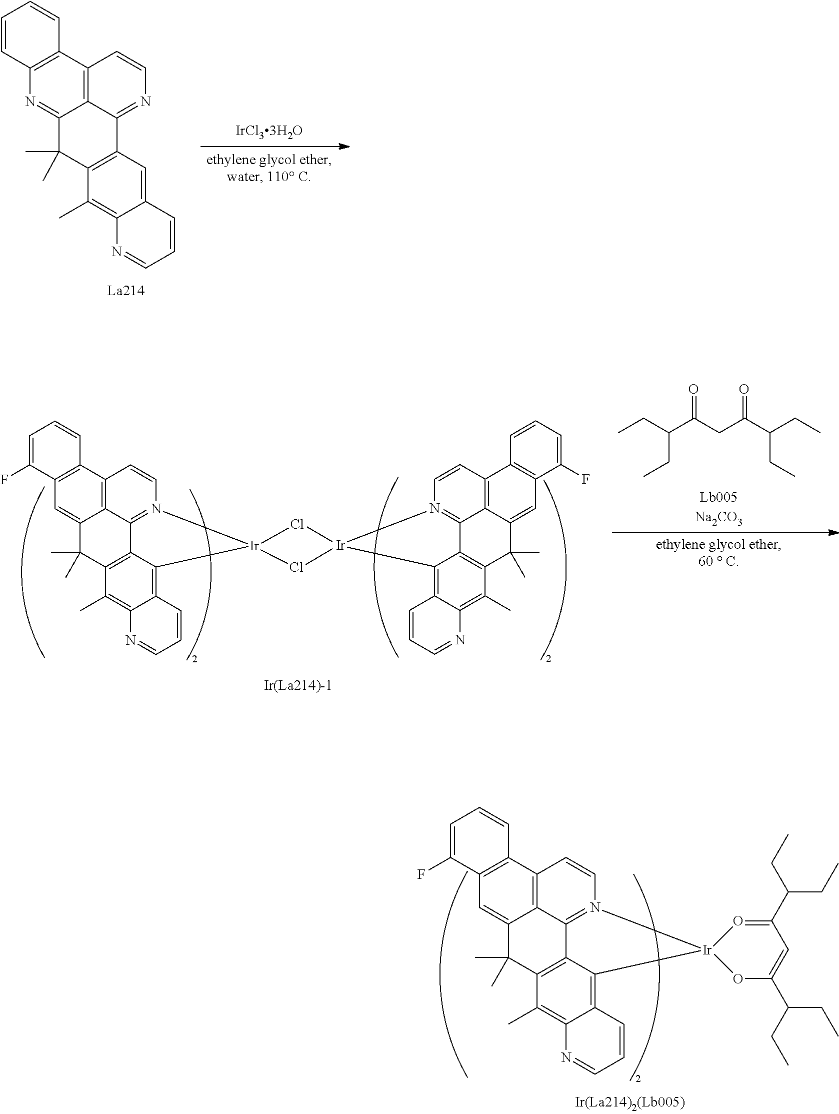

### Synthesis of Compound Ir(La214)-1

Referring to the synthesis and purification method of compound Ir(La008)-1, only by changing the corresponding raw materials, compound Ir(La214)-1 (14.63 g, yield: 77.06%) was obtained, which was used directly in the next step without purification.

### Synthesis of Compound Ir(La214)₂(Lb005)

Referring to the synthesis and purification method for compound Ir(La008)₂(Lb005), only by changing the corresponding raw materials, a red solid as compound Ir(La214)₂(Lb005) (10.52 g, purity: 99.80%, yield: 46.75%) was obtained. 10.52 g of crude Ir(La214)₂(Lb005) was sublimed and purified to obtain sublimated pure Ir(La214)₂(Lb005) (7.86 g, purity: 99.75%, yield: 74.71%), with a mass spectrum: 1159.41 (M+H).

¹H NMR (400 MHZ, CDCl₃) δ 8.78 (dd, J=4.1, 2.1 Hz, 2H), 8.53 (s, 2H), 8.46 (dd, J=7.4, 2.1 Hz, 2H), 8.34 (dd, J=7.6, 0.8 Hz, 2H), 8.20 (d, J=9.3 Hz, 2H), 7.53 (t, J=7.6 Hz, 2H), 7.29-7.20 (m, 6H), 4.79 (s, 1H), 2.92 (s, 6H), 2.74-2.68 (m, 2H), 1.68-1.54 (m, 16H), 1.43-1.28 (m, 4H), 0.88-0.85 (m, 12H).

### Example of Use: Manufacturing of Organic Electroluminescent Device

A 50 mm×50 mm×1.0 mm glass substrate with an ITO (1,000 Å) anode electrode was ultrasonically cleaned in ethanol for 10 minutes, dried at 150° C., and then treated with N₂ plasma for 30 minutes. The washed glass substrate was mounted on a substrate holder of a vacuum evaporation device. Firstly, compound HTM1 and P-dopant (at a ratio of 97%) were evaporated on the side of the glass substrate, on which there was an anode electrode wire by covering the electrode in a co-evaporation to form a thin film with a thickness of 100 Å, followed by immediately evaporation of a layer of HTM1 to form a thin film with a thickness of about 600 Å, and then evaporation of a layer of HTM2 on the HTM1 thin film to form a thin film with a thickness of 100 Å. Then, host material H1, host material H2 and a doping compound (at a ratio of 48.5%: 48.5%: 3%, comparative compound 5 X, or the compound of the present disclosure) were evaporated on the HTM2 film layer by means of co-evaporation again to form a film with a thickness of 400 Å. The ratio of the host materials to the doping material was 90%: 10%. ETL:LiQ (350 Å, the ratio was 50%: 50%) was evaporated on the luminous layer by means of co-evaporation. Yb (10 Å) was then evaporated on the electron transport layer material, and finally a layer of metal Ag (150 Å) was evaporated as an electrode.

| | | | | | Electron transport |
|---|---|---|---|---|---|
| Example | HIL | HTL | EBL | Emission layer | layer |
| A1 | HTM1:NDP-9 | HTM1 | HTM2 | H1:H2:Ir(La016)₂(Lb005) | ETL:LiQ |
| A2 | HTM1:NDP-9 | HTM1 | HTM2 | H1:H2:Ir(La016)₂(Lb007) | ETL:LiQ |
| A3 | HTM1:NDP-9 | HTM1 | HTM2 | H1:H2:Ir(La018)₂(Lb005) | ETL:LiQ |
| A4 | HTM1:NDP-9 | HTM1 | HTM2 | H1:H2:Ir(La029)₂(Lb005) | ETL:LiQ |
| A5 | HTM1:NDP-9 | HTM1 | HTM2 | H1:H2:Ir(La048)₂(Lb007) | ETL:LiQ |
| A6 | HTM1:NDP-9 | HTM1 | HTM2 | H1:H2:Ir(La055)₂(Lb005) | ETL:LiQ |
| A7 | HTM1:NDP-9 | HTM1 | HTM2 | H1:H2:Ir(La070)₂(Lb005) | ETL:LiQ |
| A8 | HTM1:NDP-9 | HTM1 | HTM2 | H1:H2:Ir(La070)₂(Lb031) | ETL:LiQ |
| A9 | HTM1:NDP-9 | HTM1 | HTM2 | H1:H2:Ir(La079)₂(Lb005) | ETL:LiQ |
| A10 | HTM1:NDP-9 | HTM1 | HTM2 | H1:H2:Ir(La090)₂(Lb005) | ETL:LiQ |
| A11 | HTM1:NDP-9 | HTM1 | HTM2 | H1:H2:Ir(La095)₂(Lb005) | ETL:LiQ |
| A12 | HTM1:NDP-9 | HTM1 | HTM2 | H1:H2:Ir(La095)₂(Lb043) | ETL:LiQ |
| A13 | HTM1:NDP-9 | HTM1 | HTM2 | H1:H2:Ir(La103)₂(Lb005) | ETL:LiQ |
| A14 | HTM1:NDP-9 | HTM1 | HTM2 | H1:H2:Ir(La112)₂(Lb005) | ETL:LiQ |
| A15 | HTM1:NDP-9 | HTM1 | HTM2 | H1:H2:Ir(La112)₂(Lb007) | ETL:LiQ |
| A16 | HTM1:NDP-9 | HTM1 | HTM2 | H1:H2:Ir(La132)₂(Lb005) | ETL:LiQ |
| A17 | HTM1:NDP-9 | HTM1 | HTM2 | H1:H2:Ir(La162)₂(Lb005) | ETL:LiQ |
| A18 | HTM1:NDP-9 | HTM1 | HTM2 | H1:H2:Ir(La175)₂(Lb005) | ETL:LiQ |
| A19 | HTM1:NDP-9 | HTM1 | HTM2 | H1:H2:Ir(La181)₂(Lb005) | ETL:LiQ |
| A20 | HTM1:NDP-9 | HTM1 | HTM2 | H1:H2:Ir(La202)₂(Lb005) | ETL:LiQ |
| A21 | HTM1:NDP-9 | HTM1 | HTM2 | H1:H2:Ir(La210)₂(Lb005) | ETL:LiQ |
| A22 | HTM1:NDP-9 | HTM1 | HTM2 | H1:H2:Ir(La214)₂(Lb005) | ETL:LiQ |
| Comparative | HTM1:NDP-9 | HTM1 | HTM2 | H1:H2:Comparative | ETL:LiQ |
| Example 1 | | | | compound 1 | |
| Comparative | HTM1:NDP-9 | HTM1 | HTM2 | H1:H2:Comparative | ETL:LiQ |
| Example 2 | | | | compound 2 | |
| Comparative | HTM1:NDP-9 | HTM1 | HTM2 | H1:H2:Comparative | ETL:LiQ |
| Example 3 | | | | compound 3 | |

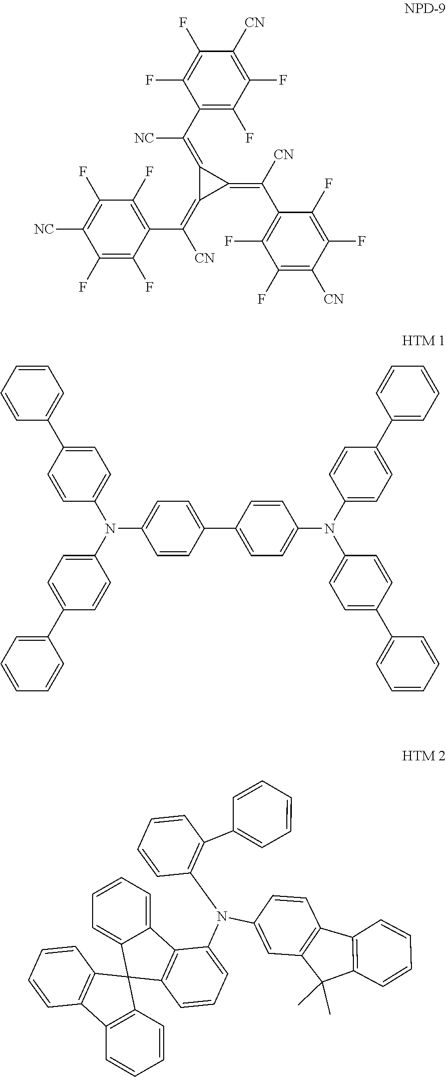 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; CC1(C)c2ccccc2-c2ccc(N(c3ccccc3-c3ccccc3)c3cccc4c3-c3ccccc3C43c4ccccc4-c4ccccc43)cc21]

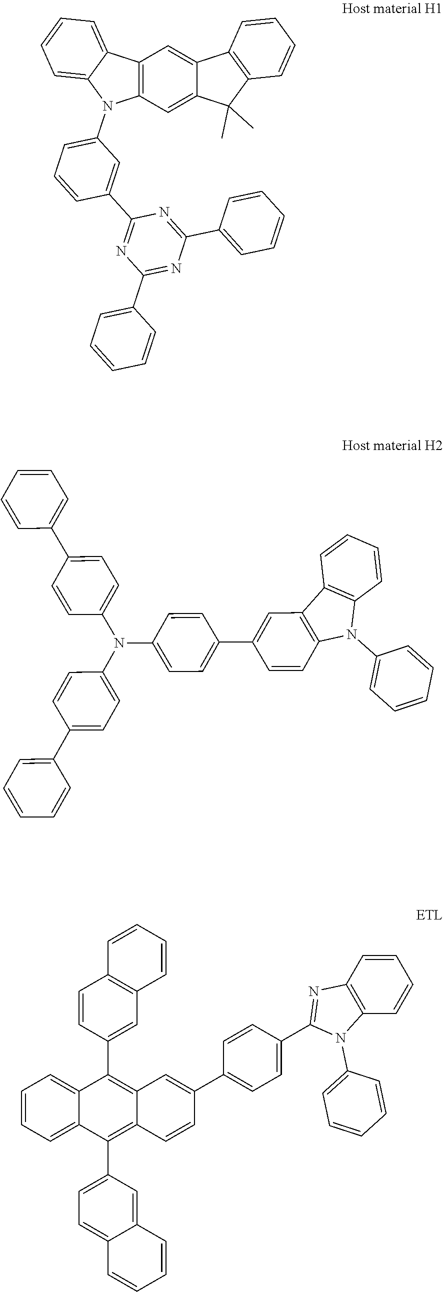 [SMILES: CC1(C)c2ccccc2-c2cc3c4ccccc4n(-c4cccc(-c5nc(-c6ccccc6)nc(-c6ccccc6)n5)c4)c3cc21 ; c1ccc(-c2ccc(N(c3ccc(-c4ccccc4)cc3)c3ccc(-c4ccc5c(c4)c4ccccc4n5-c4ccccc4)cc3)cc2)cc1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

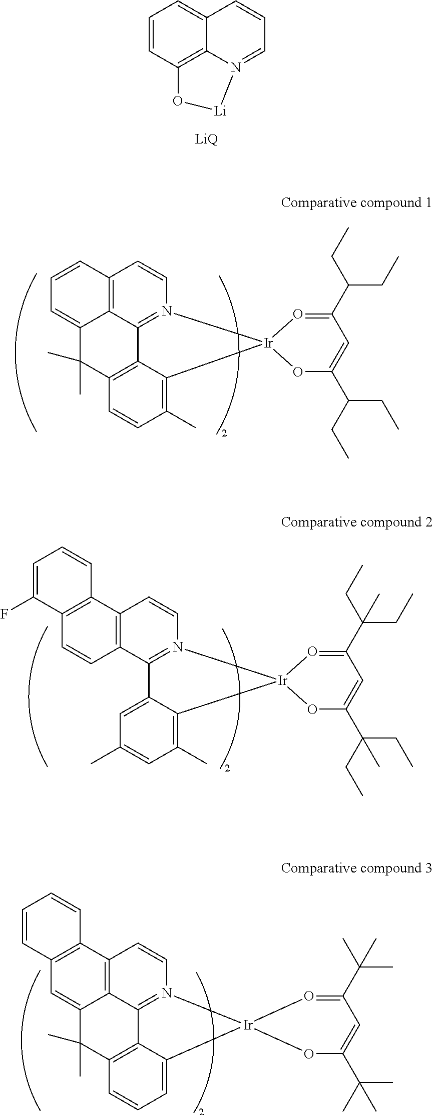

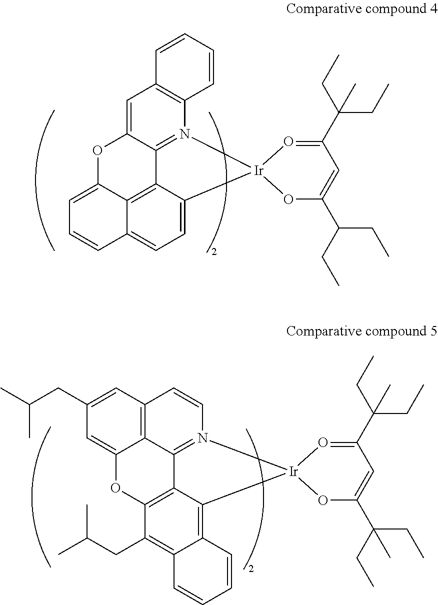

Evaluation: the above-mentioned devices were tested for device performance. In each of the examples and comparative examples, IVL data was measured by using a constant current power 5 supply (Keithley 2400), and luminescence spectrum was tested by using a spectral radiance luminance meter (CS 2000). In addition, the voltage value was measured, and the time when the test brightness was 95% of the initial brightness (LT95) was measured. The results were as follows: the current efficiency and device life were both calculated based on the value of Comparative compound 3 as 100%.

| | | Current | Peak | Full width | |
|---|---|---|---|---|---|
| | Starting | effi- | wave- | at half | |
| | voltage/ | ciency | length/ | maximum/ | LT95@ |
| | V | Cd/A | nm | nm | 5000 nits |
| Example A1 | 3.74 | 117 | 627 | 32 | 351 |
| Example A2 | 3.78 | 121 | 628 | 33 | 402 |
| Example A3 | 3.69 | 124 | 625 | 33 | 392 |
| Example A4 | 3.65 | 112 | 625 | 34 | 279 |
| Example A5 | 3.74 | 108 | 626 | 35 | 326 |
| Example A6 | 3.73 | 118 | 628 | 35 | 293 |
| Example A7 | 3.69 | 119 | 626 | 32 | 402 |
| Example A8 | 3.74 | 122 | 627 | 35 | 341 |
| Example A9 | 3.81 | 106 | 630 | 36 | 365 |
| Example A10 | 3.76 | 116 | 626 | 33 | 387 |
| Example A11 | 3.68 | 115 | 627 | 34 | 291 |
| Example A12 | 3.66 | 108 | 625 | 36 | 259 |
| Example A13 | 3.72 | 114 | 627 | 33 | 385 |
| Example A14 | 3.67 | 116 | 626 | 34 | 366 |
| Example A15 | 3.69 | 119 | 628 | 34 | 357 |
| Example A16 | 3.73 | 108 | 625 | 33 | 354 |
| Example A17 | 3.65 | 113 | 625 | 34 | 296 |
| Example A18 | 3.71 | 114 | 626 | 34 | 268 |
| Example A19 | 3.73 | 112 | 627 | 35 | 332 |
| Example A20 | 3.68 | 118 | 627 | 34 | 399 |
| Example A21 | 3.75 | 104 | 630 | 35 | 277 |
| Example A22 | 3.69 | 113 | 625 | 34 | 304 |
| Comparative | 4.32 | 79 | 604 | 49 | 89 |
| Example 1 | | | | | |
| Comparative | 3.94 | 105 | 622 | 52 | 169 |
| Example 2 | | | | | |
| Comparative | 4.07 | 100 | 611 | 39 | 100 |
| Example 3 | | | | | |
| Comparative | 3.88 | 85 | 626 | 37 | 76 |
| Example 4 | | | | | |
| Comparative | 3.91 | 93 | 623 | 35 | 87 |
| Example 5 | | | | | |

From the comparison of the data in the above table, it can be seen that the iridium complex prepared using a specific phenylisoquinoline-fused naphthyl as the ligand in the present disclosure has a strong rigid structure, which suppresses the vibration of the molecule. The compound has a narrow full width maximum. The organic electroluminescent devices in which the compound of the present disclosure serves as a doping agent all exhibit more superior performance in terms of driving voltage, luminous efficiency, and device lifetime as compared with comparative compounds 1-3 under the same device.

Compared with the existing technology, the present disclosure unexpectedly provides a better device luminous efficiency, improved lifetime, a narrow full width at half maximum, and more saturated red luminescence through a special collocation of substituents. The above results indicate that the compounds of the present disclosure have advantages of low sublimation temperature, high photochemical and electrochemical stability, high color saturation, high luminous efficiency, and long device lifetime, thus being applicable in organic electroluminescent devices. In particular, as a red light-emitting dopant, the compounds of the present disclosure have the potential to be applied to the OLED industry, especially for displays, lighting and automobile taillights.

1. A metal iridium complex having a general formula of Ir(La)(Lb)(Lc), comprising a structure of formula (1), 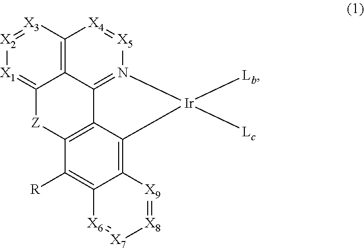
wherein La is 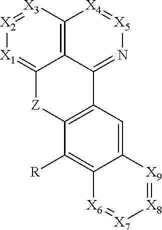
wherein Z is selected from CR_{A}R_{B}
wherein X₁-X₉ are each independently N or CR₀, and adjacent substituents R₀ are optionally connected to form a ring;
wherein X₁-X₅ have at least two adjacent CR₀ groups which are connected to each other to form an aromatic ring with 6 to 30 carbon atoms or a heteroaromatic ring with 3 to 30 carbon atoms;
wherein R₀, R, R_{A}, and R_{B} are each independently selected from the group consisting of hydrogen, deuterium, halogen, a substituted or unsubstituted alkyl with 1 to 10 main-chain carbon atoms, a substituted or unsubstituted cycloalkyl with 3 to 20 ring-forming carbon atoms, a substituted or unsubstituted heteroalkyl with 1 to 10 main-chain carbon atoms, a substituted or unsubstituted heterocycloalkyl with 3 to 20 ring-forming carbon atoms, a substituted or unsubstituted C3-C30 alkylsilyl, a substituted or unsubstituted C3-C30 alkylgermyl, a substituted or unsubstituted C1-C10 alkoxy, a substituted or unsubstituted C7-C30 aralkyl, a substituted or unsubstituted C6-C30 aryloxy, a substituted or unsubstituted C2-C20 alkenyl, a substituted or unsubstituted C2-C20 alkynyl, a substituted or unsubstituted C6-C30 aryl, a substituted or unsubstituted C3-C30 heteroaryl, a substituted or unsubstituted C3-C30 arylsilyl, a substituted or unsubstituted C0-C20 alkylamino, cyano, isocyano, and phosphino;
wherein substituents in R₀, R, R_{A}, and R_{B} refer to being substituted with deuterium, F, Cl, Br, C1-C4 alkyl, C1-C4 alkoxy, C3-C6 cycloalkyl, C1-C4 alkyl-substituted amino, C6-C10 aryl, C1-C4 alkyl-substituted C6-C10 aryl, cyano, isocyano, or phosphino;
wherein a heteroatom in the heteroalkyl, heterocycloalkyl, heteroaromatic ring or heteroaryl is at least one of S, O, Se, N, Si, Ge, B and P;
wherein Lb and Lc are each monoanionic bidentate ligands; alternatively, two of La, Lb and Lc are arbitrarily connected to each other to form a multidentate ligand, or La, Lb and Lc are connected through a single group; and
wherein Lb or Lc independently has a structural formula of represented by the ligand La

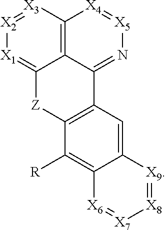

2. The metal iridium complex according to claim 1, wherein La has one of the following structural formula (2) to formula (19): 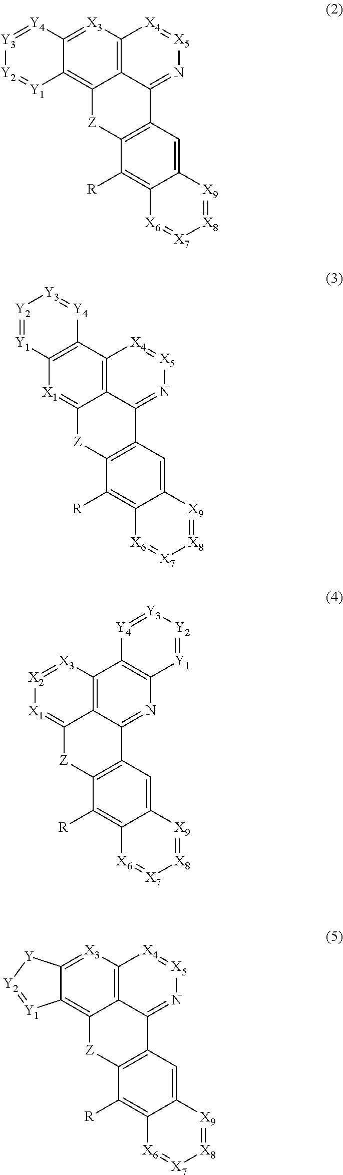 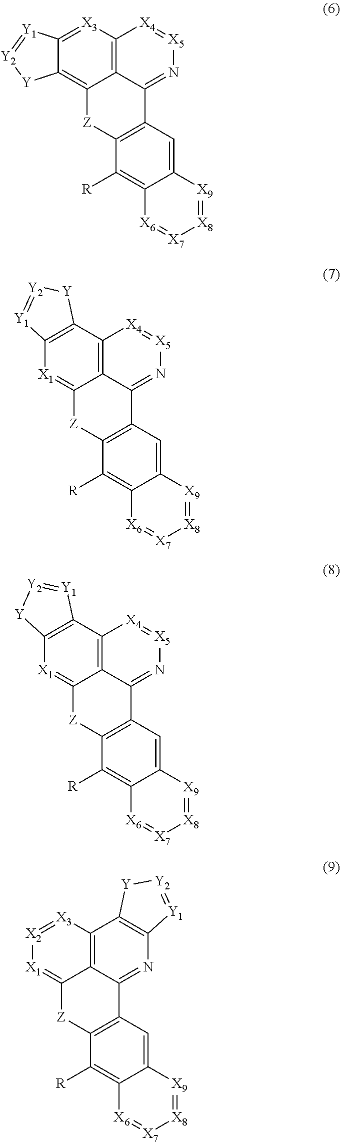 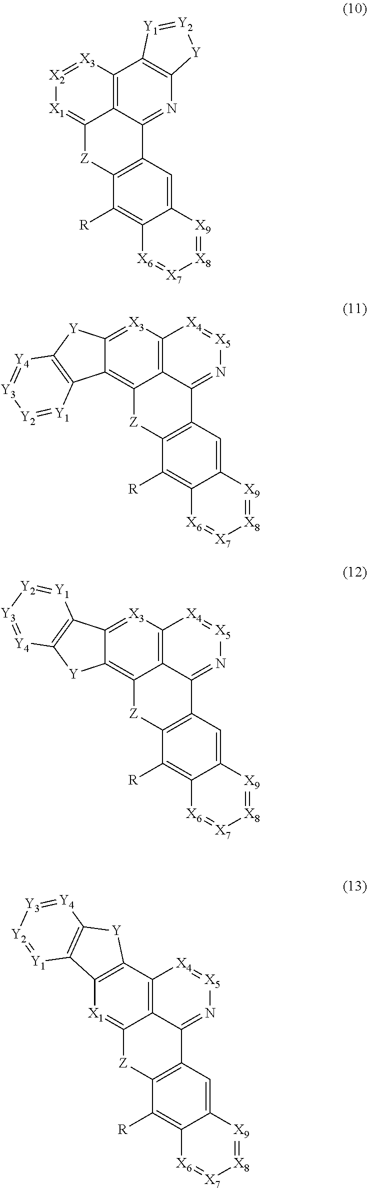 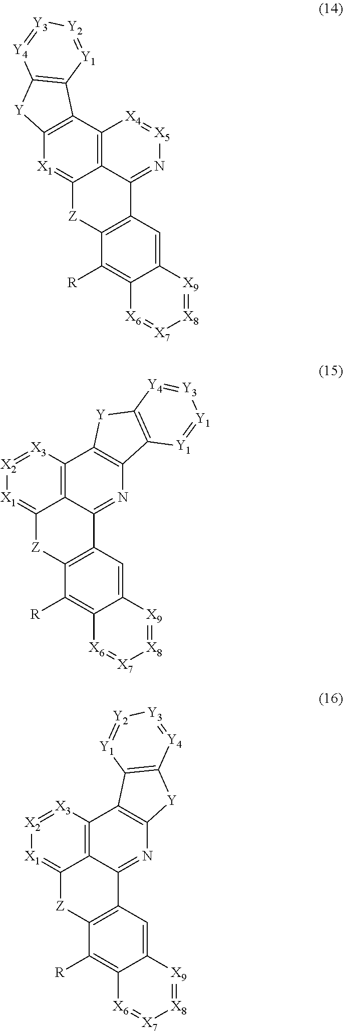 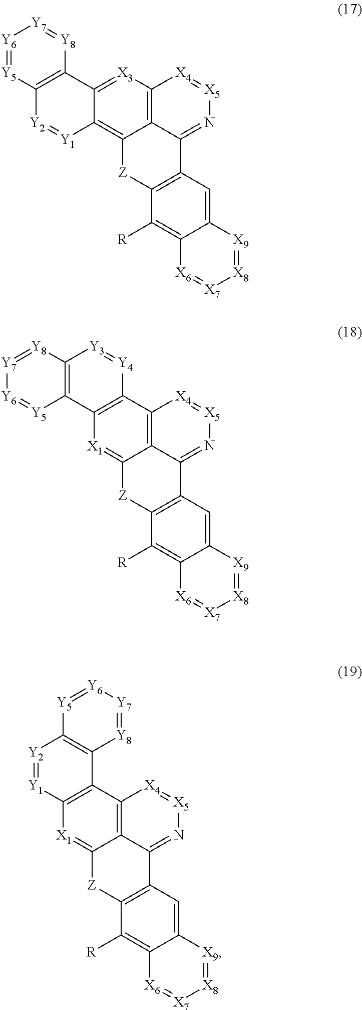
wherein Y is selected from the group consisting of O, S, Se, CR_{A}R_{B}, SiR_{A}R_{B}, GER_{A}R_{B}, NR_{A}R_{B}, BR_{A}R_{B}, and PR_{A}R_{B}, Y₁-Y₈ are each independently N or CR₀, and adjacent substituents R₀ are optionally connected to form a ring.

3. The metal iridium complex according to claim 1, wherein R is hydrogen, a substituted or unsubstituted alkyl with 1 to 10 carbon atoms, a substituted or unsubstituted cycloalkyl with 3 to 20 ring-forming carbon atoms, a substituted or unsubstituted C3-C30 alkylsilyl, or a substituted or unsubstituted C3-C30 alkylgermyl.

4. The metal iridium complex according to claim 1, wherein the ligand-La has the following structural formula (22): 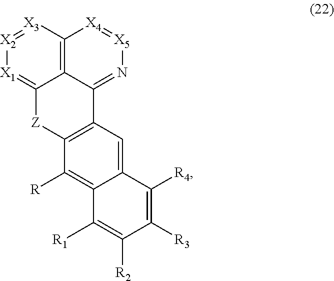
wherein R₁-R₄ are each independently selected from the group consisting of hydrogen, deuterium, halogen, a substituted or unsubstituted alkyl with 1 to 10 main-chain carbon atoms, a substituted or unsubstituted cycloalkyl with 3 to 20 ring-forming carbon atoms, a substituted or unsubstituted heteroalkyl with 1 to 10 main-chain carbon atoms, a substituted or unsubstituted heterocycloalkyl with 3 to 20 ring-forming carbon atoms, a substituted or unsubstituted C3-C30 alkylsilyl, a substituted or unsubstituted C1-C10 alkoxy, a substituted or unsubstituted C7-C30 aralkyl, a substituted or unsubstituted C6-C30 aryloxy, a substituted or unsubstituted C6-C30 aryl, a substituted or unsubstituted C3-C30 heteroaryl, a substituted or unsubstituted C3-C30 arylsilyl, a substituted or unsubstituted C0-C20 alkylamino, cyano, isocyano, and phosphino; adjacent substituents in R₁-R₄ are optionally connected to form a ring; and substituents in R₁-R₄ refer to being substituted with deuterium, F, Cl, Br, C1-C4 alkyl, C1-C4 alkoxy, C3-C6 cycloalkyl, C1-C4 alkyl-substituted amino, C6-C10 aryl, C1-C4 alkyl-substituted C6-C10 aryl, cyano, or isocyano.

5. The metal iridium complex according to claim 4, wherein the ligand La is selected from one of the following structural formula (23)-formula (24): 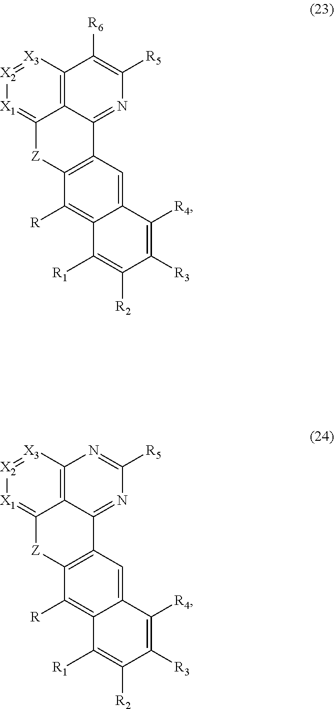
wherein X₁-X₃ are each independently N or CR₀, and two adjacent CR₀ groups among X₁-X₃ are connected to each other to form an aromatic ring with 6 to 30 carbon atoms or a heteroaromatic ring with 3 to 30 carbon atoms; and
wherein R₁-R₆ are each independently selected from the group consisting of hydrogen, deuterium, halogen, a substituted or unsubstituted alkyl with 1 to 8 main-chain carbon atoms, a substituted or unsubstituted cycloalkyl with 3 to 10 ring-forming carbon atoms, a substituted or unsubstituted heteroalkyl with 1 to 8 main-chain carbon atoms, a substituted or unsubstituted heterocycloalkyl with 3 to 10 ring-forming carbon atoms, a substituted or unsubstituted C3-C20 alkylsilyl, a substituted or unsubstituted C1-C8 alkoxy, a substituted or unsubstituted C7--C20 aralkyl, a substituted or unsubstituted C6-C20 aryloxy, a substituted or unsubstituted C6-C20 aryl, a substituted or unsubstituted C3-C20 heteroaryl, a substituted or unsubstituted C3-C30 arylsilyl, a substituted or unsubstituted C0-C10 alkylamino, cyano, and isocyano; adjacent substituents in R₁-R₄ and R₅-R₆ are optionally connected to form a ring, and substituents in R₁-R₆ refer to being substituted with deuterium, F, Cl, Br, C1-C4 alkyl, C1-C4 alkoxy, C3-C6 cycloalkyl, C1-C4 alkyl-substituted amino, C6-C10 aryl, C1-C4 alkyl-substituted C6-C10 aryl, cyano, or isocyano.

6. The metal iridium complex according to claim 1, wherein La is selected from one of the following structural formulas, or one of the following structural formulas in which the hydrogen atom(s) is/are partially or completely replaced by deuterium or fluorine:

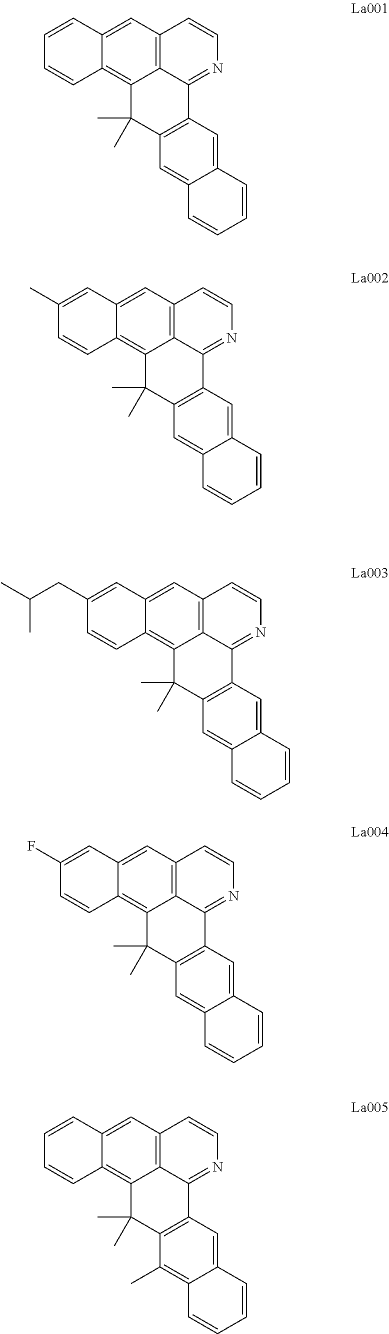 [SMILES: CC1(C)c2cc3ccccc3cc2-c2nccc3cc4ccccc4c1c23 ; Cc1ccc2c3c4c(nccc4cc2c1)-c1cc2ccccc2cc1C3(C)C ; CC(C)Cc1ccc2c3c4c(nccc4cc2c1)-c1cc2ccccc2cc1C3(C)C ; CC1(C)c2cc3ccccc3cc2-c2nccc3cc4cc(F)ccc4c1c23 ; Cc1c2c(cc3ccccc13)-c1nccc3cc4ccccc4c(c13)C2(C)C]

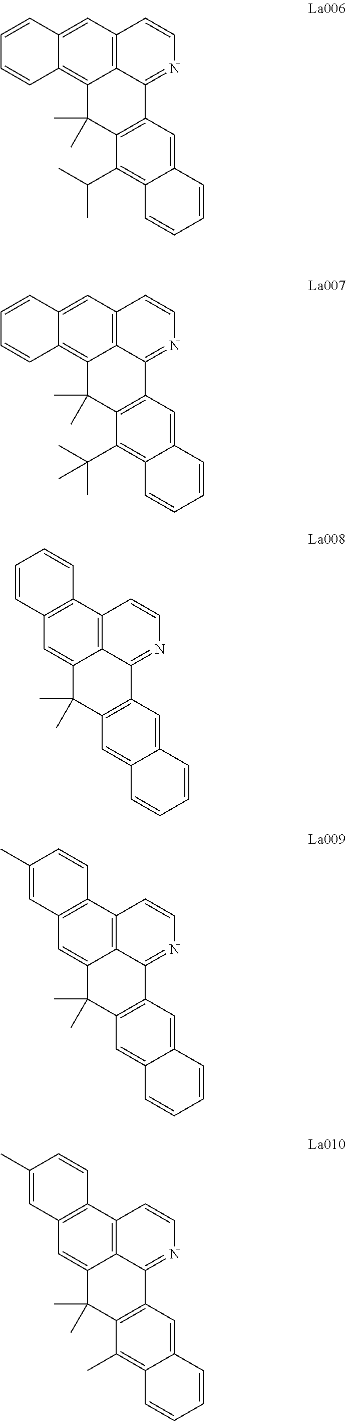 [SMILES: CC(C)c1c2c(cc3ccccc13)-c1nccc3cc4ccccc4c(c13)C2(C)C ; CC(C)(C)c1c2c(cc3ccccc13)-c1nccc3cc4ccccc4c(c13)C2(C)C ; CC1(C)c2cc3ccccc3cc2-c2nccc3c2c1cc1ccccc13 ; Cc1ccc2c(c1)cc1c3c(nccc32)-c2cc3ccccc3cc2C1(C)C ; Cc1ccc2c(c1)cc1c3c(nccc32)-c2cc3ccccc3c(C)c2C1(C)C]

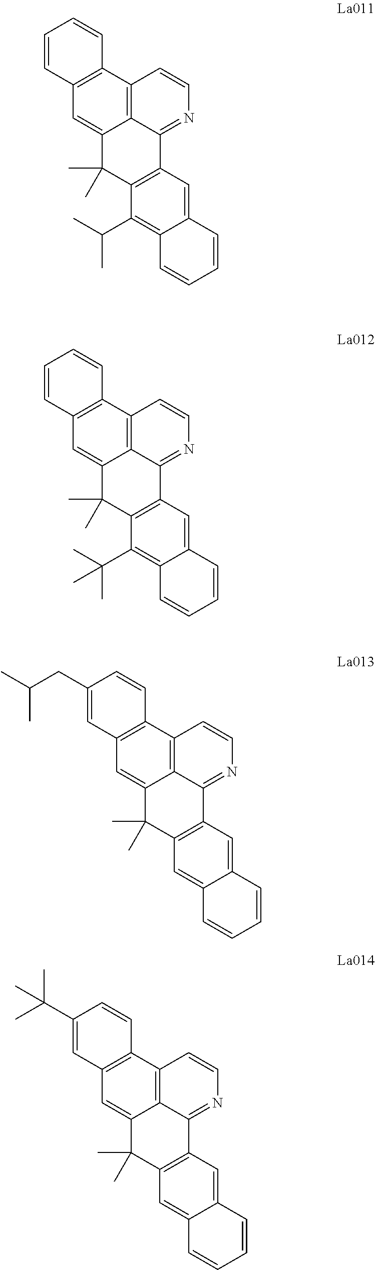 [SMILES: CC(C)c1c2c(cc3ccccc13)-c1nccc3c1c(cc1ccccc13)C2(C)C ; CC(C)(C)c1c2c(cc3ccccc13)-c1nccc3c1c(cc1ccccc13)C2(C)C ; CC(C)Cc1ccc2c(c1)cc1c3c(nccc32)-c2cc3ccccc3cc2C1(C)C ; CC(C)(C)c1ccc2c(c1)cc1c3c(nccc32)-c2cc3ccccc3cc2C1(C)C]

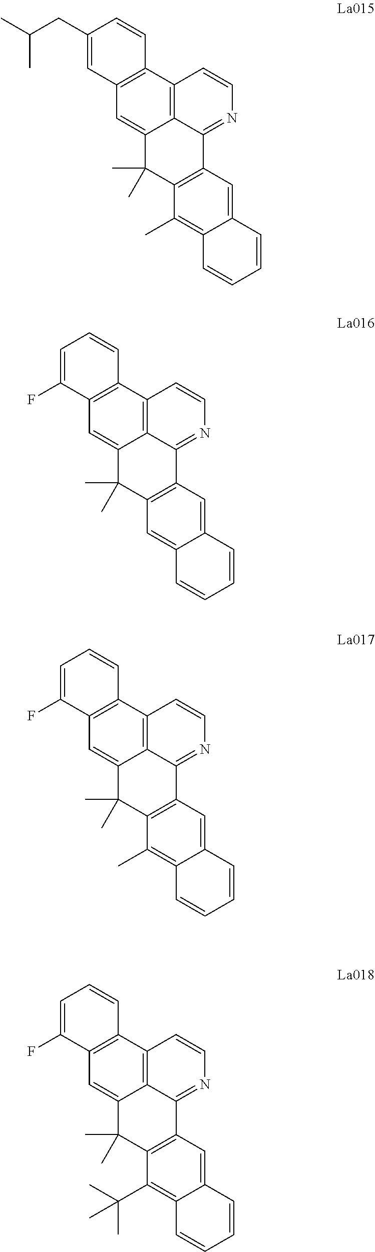 [SMILES: Cc1c2c(cc3ccccc13)-c1nccc3c1c(cc1cc(CC(C)C)ccc13)C2(C)C ; CC1(C)c2cc3ccccc3cc2-c2nccc3c2c1cc1c(F)cccc13 ; Cc1c2c(cc3ccccc13)-c1nccc3c1c(cc1c(F)cccc13)C2(C)C ; CC(C)(C)c1c2c(cc3ccccc13)-c1nccc3c1c(cc1c(F)cccc13)C2(C)C]

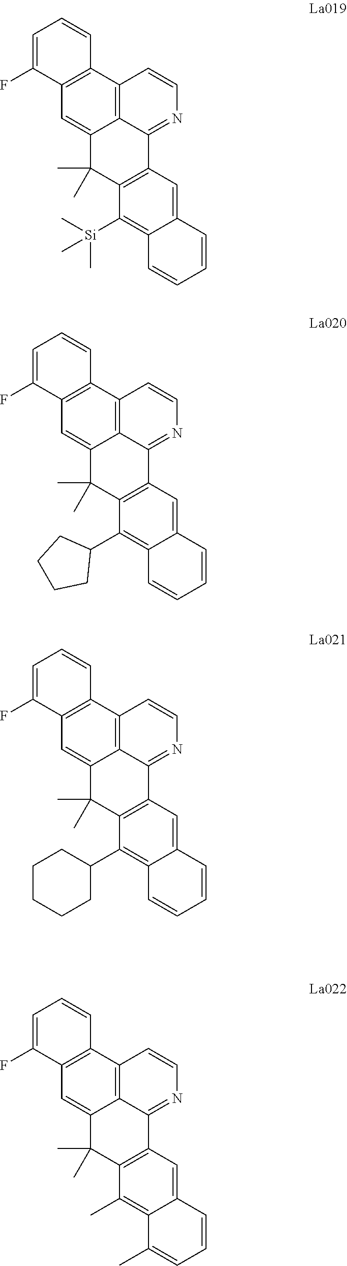 [SMILES: CC1(C)c2c(cc3ccccc3c2[Si](C)(C)C)-c2nccc3c2c1cc1c(F)cccc13 ; CC1(C)c2c(cc3ccccc3c2C2CCCC2)-c2nccc3c2c1cc1c(F)cccc13 ; CC1(C)c2c(cc3ccccc3c2C2CCCCC2)-c2nccc3c2c1cc1c(F)cccc13 ; Cc1cccc2cc3c(c(C)c12)C(C)(C)c1cc2c(F)cccc2c2ccnc-3c12]

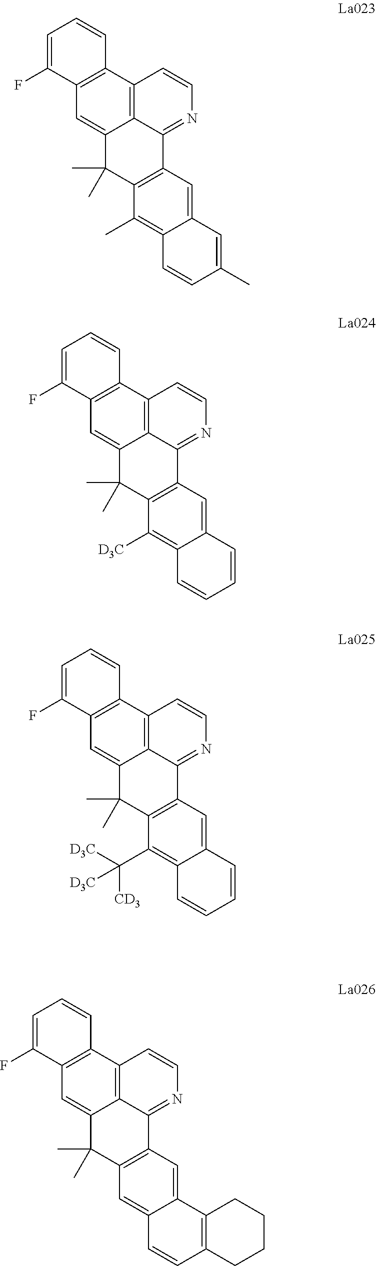 [SMILES: Cc1ccc2c(C)c3c(cc2c1)-c1nccc2c1c(cc1c(F)cccc12)C3(C)C ; [2H]C([2H])([2H])c1c2c(cc3ccccc13)-c1nccc3c1c(cc1c(F)cccc13)C2(C)C ; [2H]C([2H])([2H])C(c1c2c(cc3ccccc13)-c1nccc3c1c(cc1c(F)cccc13)C2(C)C)(C([2H])([2H])[2H])C([2H])([2H])[2H] ; CC1(C)c2cc3ccc4c(c3cc2-c2nccc3c2c1cc1c(F)cccc13)CCCC4]

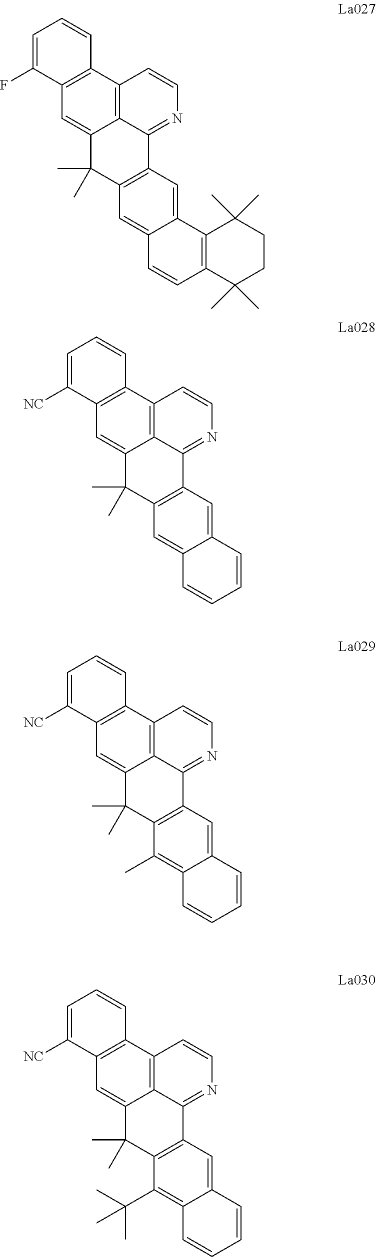 [SMILES: CC1(C)CCC(C)(C)c2c1ccc1cc3c(cc21)-c1nccc2c1c(cc1c(F)cccc12)C3(C)C ; CC1(C)c2cc3ccccc3cc2-c2nccc3c2c1cc1c(C#N)cccc13 ; Cc1c2c(cc3ccccc13)-c1nccc3c1c(cc1c(C#N)cccc13)C2(C)C ; CC(C)(C)c1c2c(cc3ccccc13)-c1nccc3c1c(cc1c(C#N)cccc13)C2(C)C]

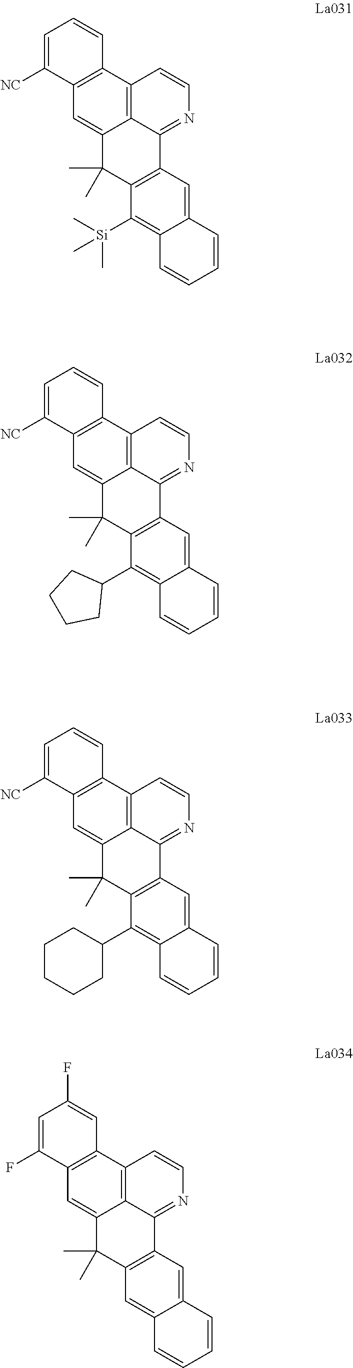 [SMILES: CC1(C)c2c(cc3ccccc3c2[Si](C)(C)C)-c2nccc3c2c1cc1c(C#N)cccc13 ; CC1(C)c2c(cc3ccccc3c2C2CCCC2)-c2nccc3c2c1cc1c(C#N)cccc13 ; CC1(C)c2c(cc3ccccc3c2C2CCCCC2)-c2nccc3c2c1cc1c(C#N)cccc13 ; CC1(C)c2cc3ccccc3cc2-c2nccc3c2c1cc1c(F)cc(F)cc13]

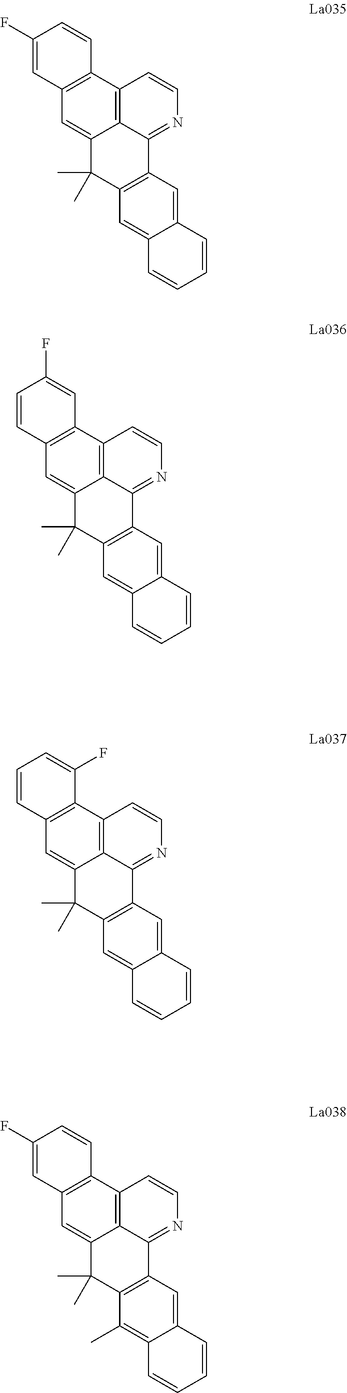 [SMILES: CC1(C)c2cc3ccccc3cc2-c2nccc3c2c1cc1cc(F)ccc13 ; CC1(C)c2cc3ccccc3cc2-c2nccc3c2c1cc1ccc(F)cc13 ; CC1(C)c2cc3ccccc3cc2-c2nccc3c2c1cc1cccc(F)c13 ; Cc1c2c(cc3ccccc13)-c1nccc3c1c(cc1cc(F)ccc13)C2(C)C]

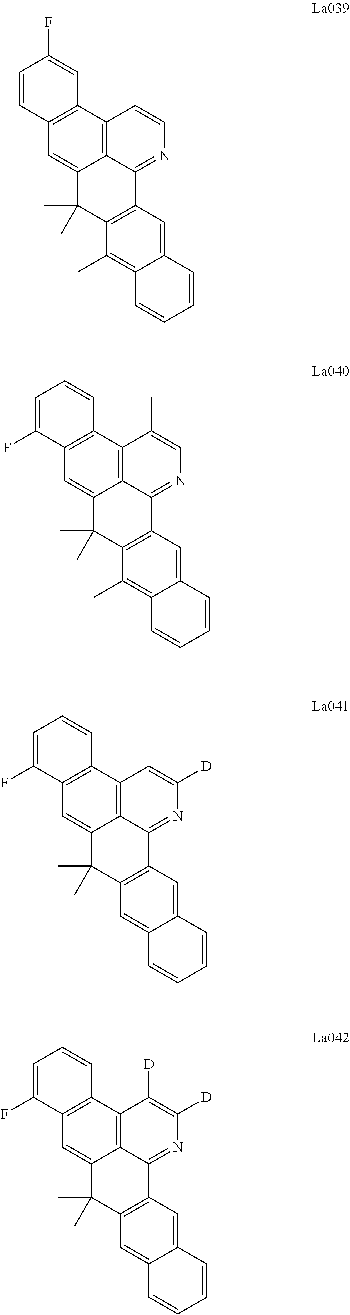 [SMILES: Cc1c2c(cc3ccccc13)-c1nccc3c1c(cc1ccc(F)cc13)C2(C)C ; Cc1c2c(cc3ccccc13)-c1ncc(C)c3c1c(cc1c(F)cccc13)C2(C)C ; [2H]c1cc2c3c(cc4c(F)cccc42)C(C)(C)c2cc4ccccc4cc2-c3n1 ; [2H]c1nc2c3c(cc4c(F)cccc4c3c1[2H])C(C)(C)c1cc3ccccc3cc1-2]

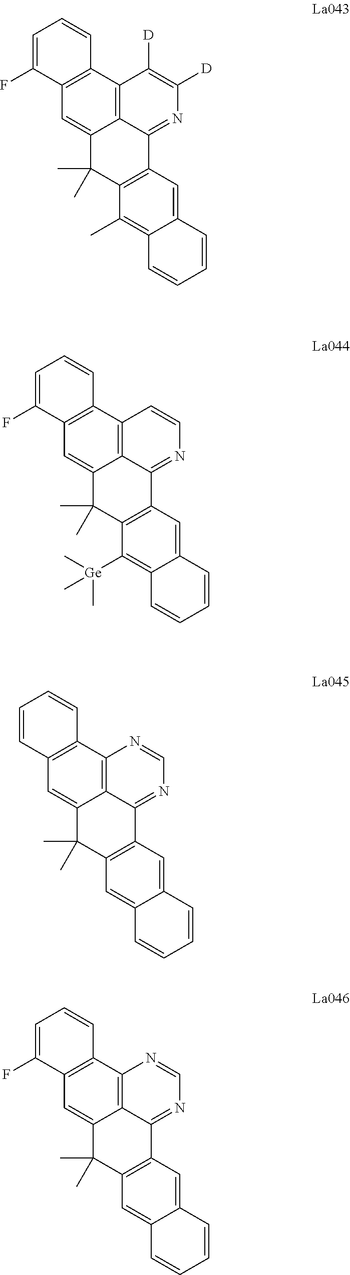

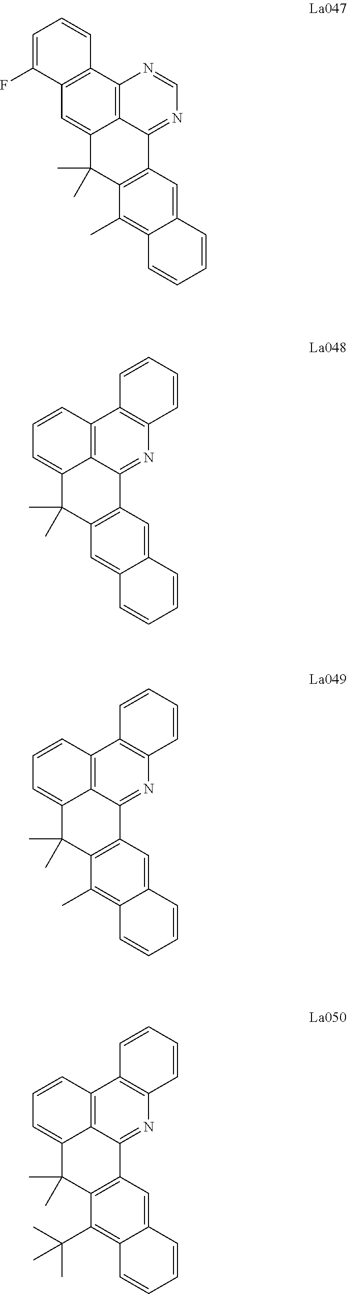 [SMILES: Cc1c2c(cc3ccccc13)-c1ncnc3c1c(cc1c(F)cccc13)C2(C)C ; CC1(C)c2cc3ccccc3cc2-c2nc3ccccc3c3cccc1c23 ; Cc1c2c(cc3ccccc13)-c1nc3ccccc3c3cccc(c13)C2(C)C ; CC(C)(C)c1c2c(cc3ccccc13)-c1nc3ccccc3c3cccc(c13)C2(C)C]

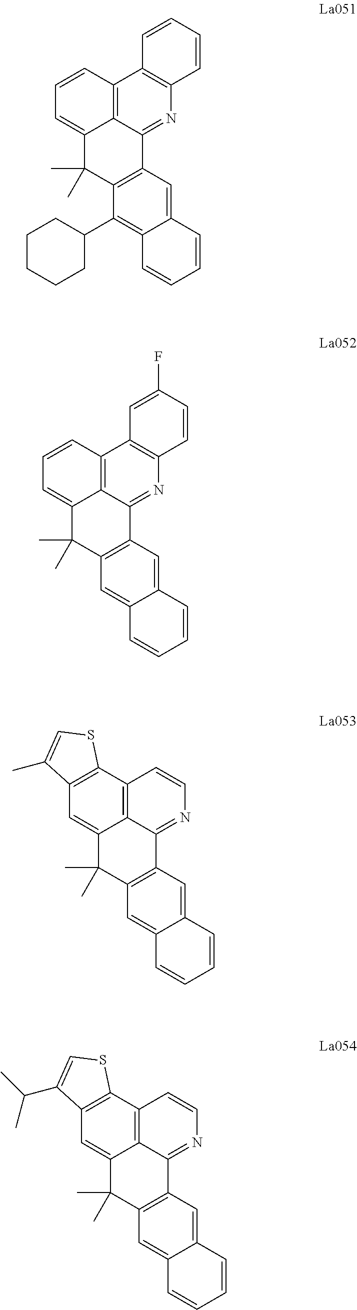 [SMILES: CC1(C)c2c(cc3ccccc3c2C2CCCCC2)-c2nc3ccccc3c3cccc1c23 ; CC1(C)c2cc3ccccc3cc2-c2nc3ccc(F)cc3c3cccc1c23 ; Cc1csc2c1cc1c3c(nccc32)-c2cc3ccccc3cc2C1(C)C ; CC(C)c1csc2c1cc1c3c(nccc32)-c2cc3ccccc3cc2C1(C)C]

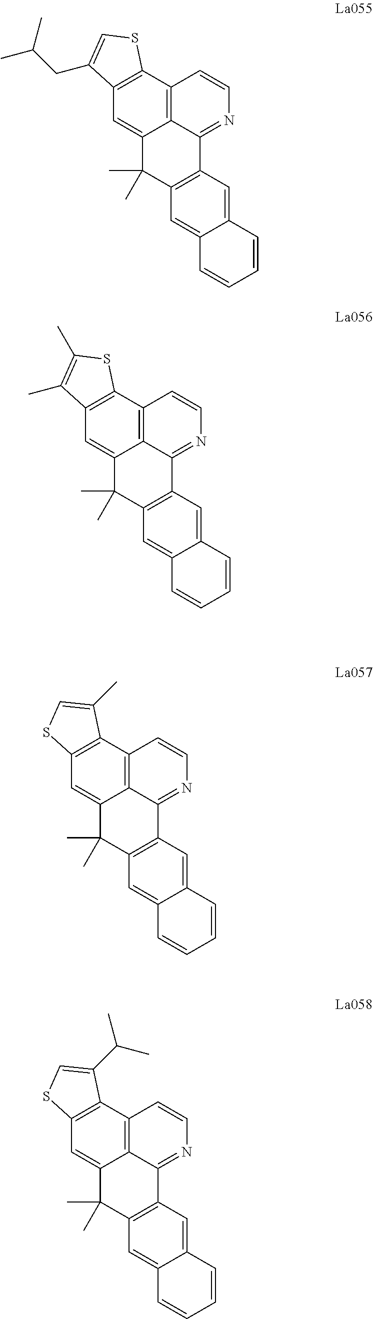 [SMILES: CC(C)Cc1csc2c1cc1c3c(nccc32)-c2cc3ccccc3cc2C1(C)C ; Cc1sc2c(cc3c4c(nccc42)-c2cc4ccccc4cc2C3(C)C)c1C ; Cc1csc2cc3c4c(nccc4c12)-c1cc2ccccc2cc1C3(C)C ; CC(C)c1csc2cc3c4c(nccc4c12)-c1cc2ccccc2cc1C3(C)C]

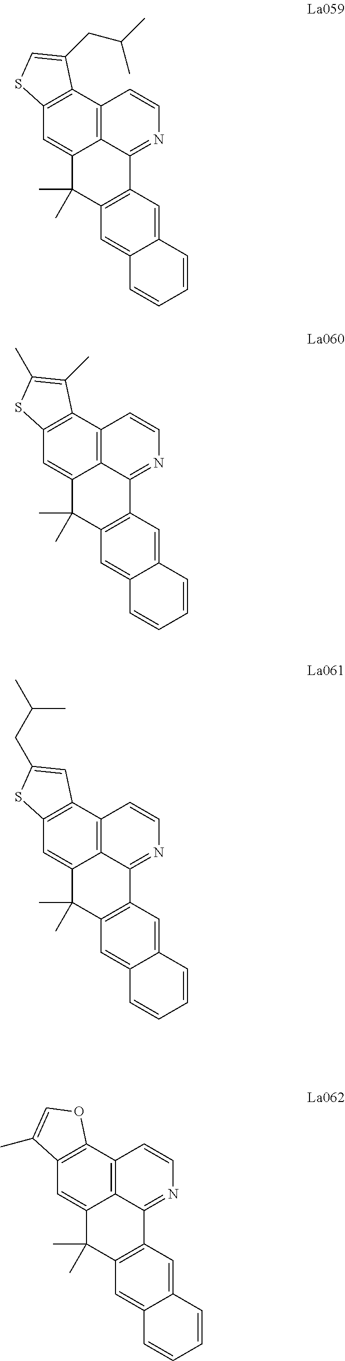 [SMILES: CC(C)Cc1csc2cc3c4c(nccc4c12)-c1cc2ccccc2cc1C3(C)C ; Cc1sc2cc3c4c(nccc4c2c1C)-c1cc2ccccc2cc1C3(C)C ; CC(C)Cc1cc2c(cc3c4c(nccc42)-c2cc4ccccc4cc2C3(C)C)s1 ; Cc1coc2c1cc1c3c(nccc32)-c2cc3ccccc3cc2C1(C)C]

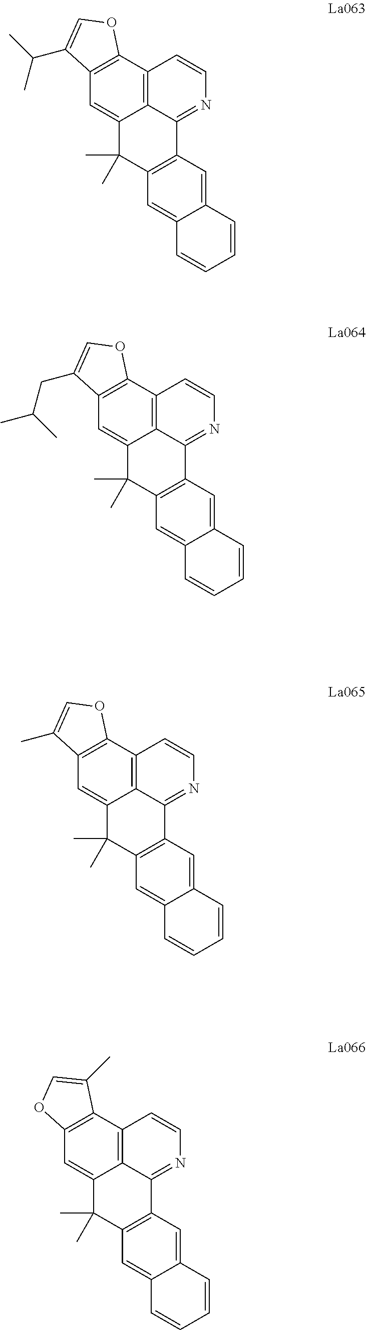 [SMILES: CC(C)c1coc2c1cc1c3c(nccc32)-c2cc3ccccc3cc2C1(C)C ; CC(C)Cc1coc2c1cc1c3c(nccc32)-c2cc3ccccc3cc2C1(C)C ; Cc1coc2c1cc1c3c(nccc32)-c2cc3ccccc3cc2C1(C)C ; Cc1coc2cc3c4c(nccc4c12)-c1cc2ccccc2cc1C3(C)C]

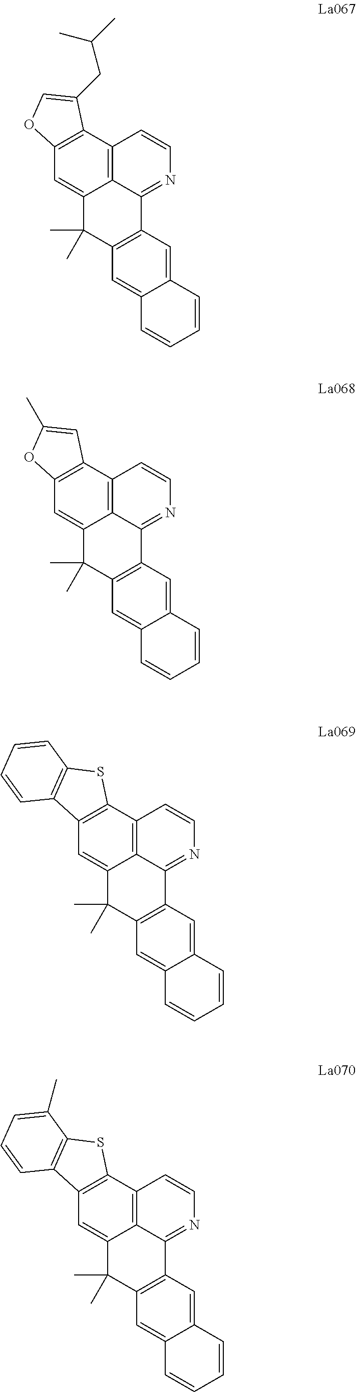 [SMILES: CC(C)Cc1coc2cc3c4c(nccc4c12)-c1cc2ccccc2cc1C3(C)C ; Cc1cc2c(cc3c4c(nccc42)-c2cc4ccccc4cc2C3(C)C)o1 ; CC1(C)c2cc3ccccc3cc2-c2nccc3c2c1cc1c2ccccc2sc31 ; Cc1cccc2c1sc1c3ccnc4c3c(cc21)C(C)(C)c1cc2ccccc2cc1-4]

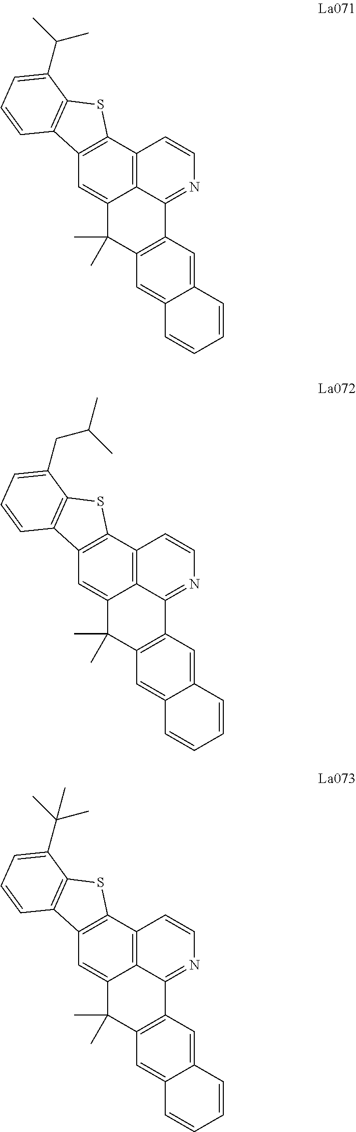 [SMILES: CC(C)c1cccc2c1sc1c3ccnc4c3c(cc21)C(C)(C)c1cc2ccccc2cc1-4 ; CC(C)Cc1cccc2c1sc1c3ccnc4c3c(cc21)C(C)(C)c1cc2ccccc2cc1-4 ; CC(C)(C)c1cccc2c1sc1c3ccnc4c3c(cc21)C(C)(C)c1cc2ccccc2cc1-4]

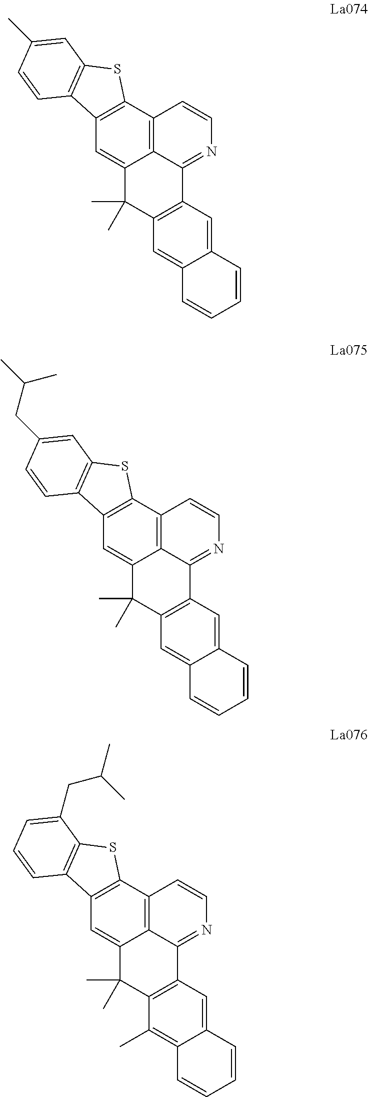 [SMILES: Cc1ccc2c(c1)sc1c3ccnc4c3c(cc21)C(C)(C)c1cc2ccccc2cc1-4 ; CC(C)Cc1ccc2c(c1)sc1c3ccnc4c3c(cc21)C(C)(C)c1cc2ccccc2cc1-4 ; Cc1c2c(cc3ccccc13)-c1nccc3c1c(cc1c4cccc(CC(C)C)c4sc31)C2(C)C]

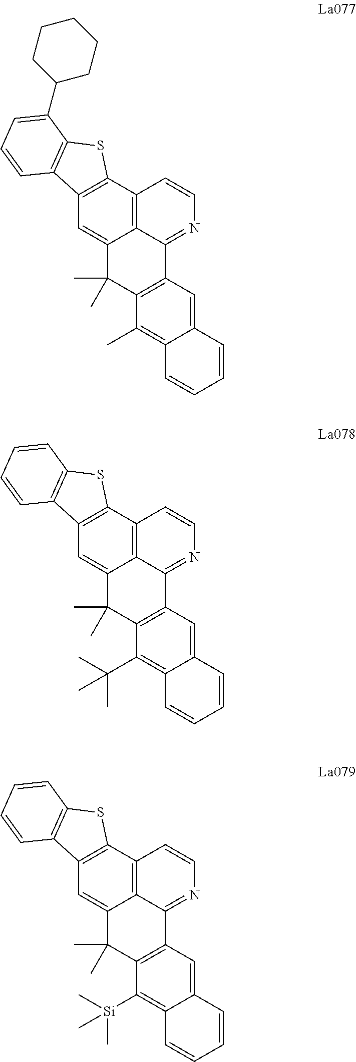 [SMILES: Cc1c2c(cc3ccccc13)-c1nccc3c1c(cc1c4cccc(C5CCCCC5)c4sc31)C2(C)C ; CC(C)(C)c1c2c(cc3ccccc13)-c1nccc3c1c(cc1c4ccccc4sc31)C2(C)C ; CC1(C)c2c(cc3ccccc3c2[Si](C)(C)C)-c2nccc3c2c1cc1c2ccccc2sc31]

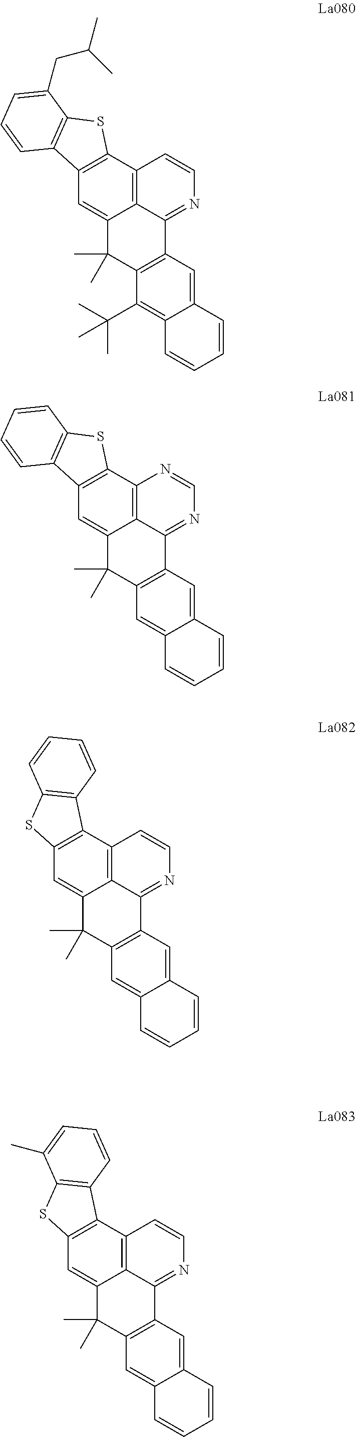 [SMILES: CC(C)Cc1cccc2c1sc1c3ccnc4c3c(cc21)C(C)(C)c1c-4cc2ccccc2c1C(C)(C)C ; CC1(C)c2cc3ccccc3cc2-c2ncnc3c2c1cc1c2ccccc2sc13 ; CC1(C)c2cc3ccccc3cc2-c2nccc3c2c1cc1sc2ccccc2c13 ; Cc1cccc2c1sc1cc3c4c(nccc4c12)-c1cc2ccccc2cc1C3(C)C]

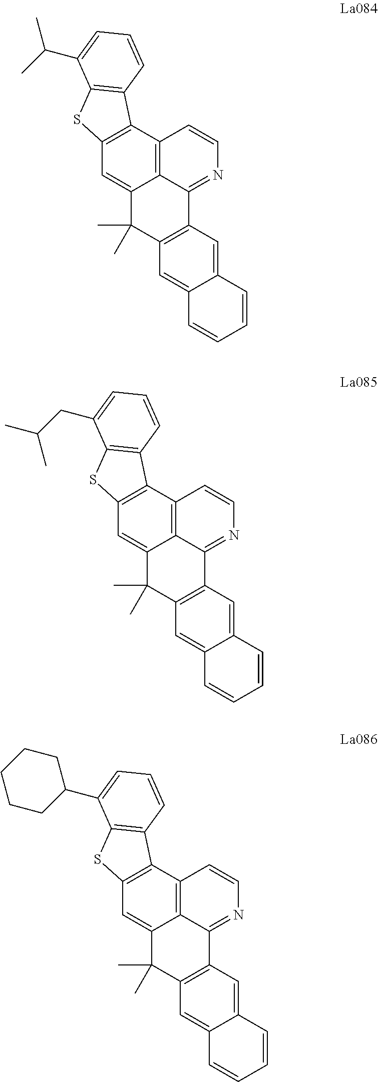 [SMILES: CC(C)c1cccc2c1sc1cc3c4c(nccc4c12)-c1cc2ccccc2cc1C3(C)C ; CC(C)Cc1cccc2c1sc1cc3c4c(nccc4c12)-c1cc2ccccc2cc1C3(C)C ; CC1(C)c2cc3ccccc3cc2-c2nccc3c2c1cc1sc2c(C4CCCCC4)cccc2c13]

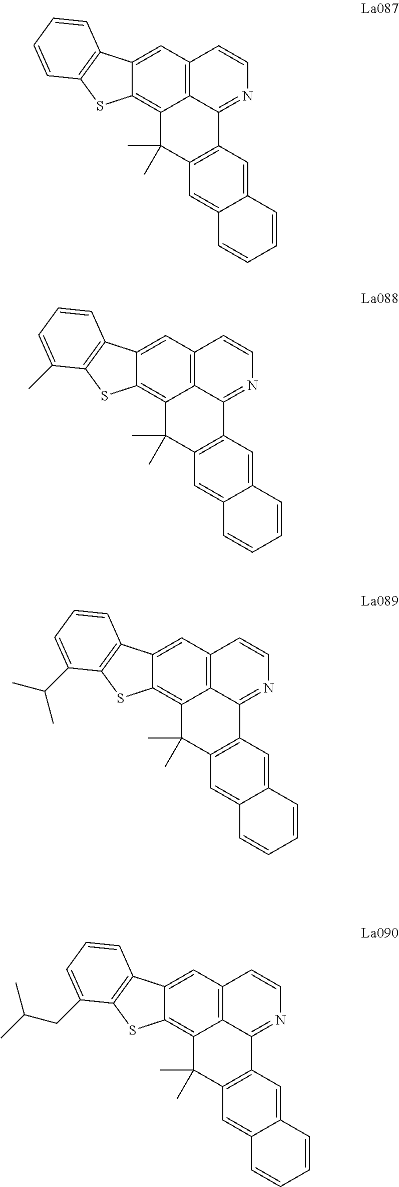 [SMILES: CC1(C)c2cc3ccccc3cc2-c2nccc3cc4c(sc5ccccc54)c1c23 ; Cc1cccc2c1sc1c3c4c(nccc4cc12)-c1cc2ccccc2cc1C3(C)C ; CC(C)c1cccc2c1sc1c3c4c(nccc4cc12)-c1cc2ccccc2cc1C3(C)C ; CC(C)Cc1cccc2c1sc1c3c4c(nccc4cc12)-c1cc2ccccc2cc1C3(C)C]

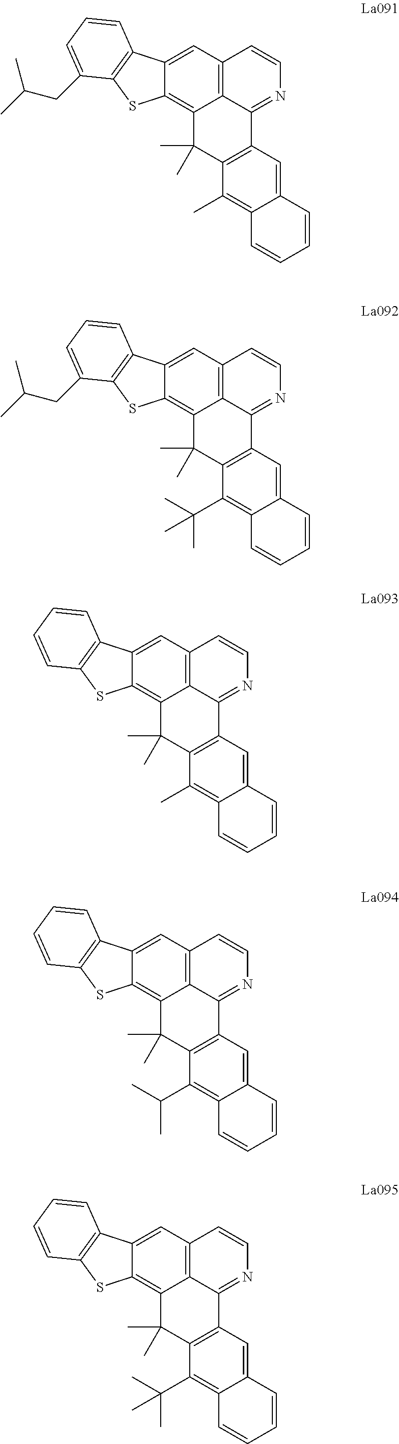 [SMILES: Cc1c2c(cc3ccccc13)-c1nccc3cc4c(sc5c(CC(C)C)cccc54)c(c13)C2(C)C ; CC(C)Cc1cccc2c1sc1c3c4c(nccc4cc12)-c1cc2ccccc2c(C(C)(C)C)c1C3(C)C ; Cc1c2c(cc3ccccc13)-c1nccc3cc4c(sc5ccccc54)c(c13)C2(C)C ; CC(C)c1c2c(cc3ccccc13)-c1nccc3cc4c(sc5ccccc54)c(c13)C2(C)C ; CC(C)(C)c1c2c(cc3ccccc13)-c1nccc3cc4c(sc5ccccc54)c(c13)C2(C)C]

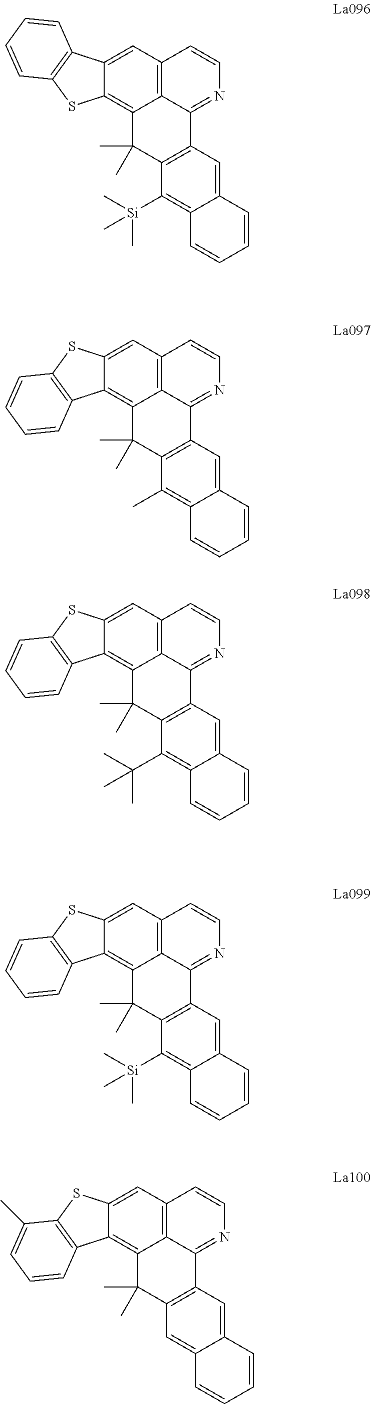 [SMILES: CC1(C)c2c(cc3ccccc3c2[Si](C)(C)C)-c2nccc3cc4c(sc5ccccc54)c1c23 ; Cc1c2c(cc3ccccc13)-c1nccc3cc4sc5ccccc5c4c(c13)C2(C)C ; CC(C)(C)c1c2c(cc3ccccc13)-c1nccc3cc4sc5ccccc5c4c(c13)C2(C)C ; CC1(C)c2c(cc3ccccc3c2[Si](C)(C)C)-c2nccc3cc4sc5ccccc5c4c1c23 ; Cc1cccc2c1sc1cc3ccnc4c3c(c12)C(C)(C)c1cc2ccccc2cc1-4]

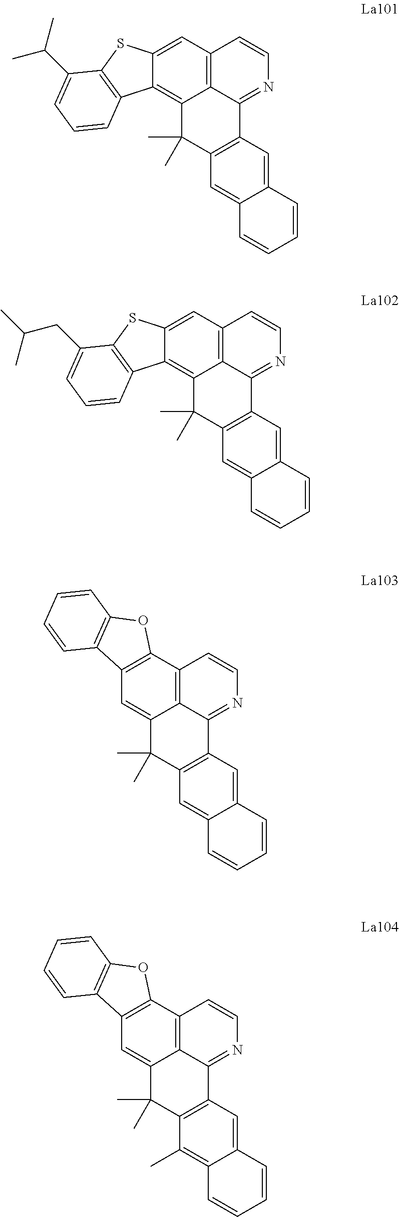 [SMILES: CC(C)c1cccc2c1sc1cc3ccnc4c3c(c12)C(C)(C)c1cc2ccccc2cc1-4 ; CC(C)Cc1cccc2c1sc1cc3ccnc4c3c(c12)C(C)(C)c1cc2ccccc2cc1-4 ; CC1(C)c2cc3ccccc3cc2-c2nccc3c2c1cc1c2ccccc2oc31 ; Cc1c2c(cc3ccccc13)-c1nccc3c1c(cc1c4ccccc4oc31)C2(C)C]

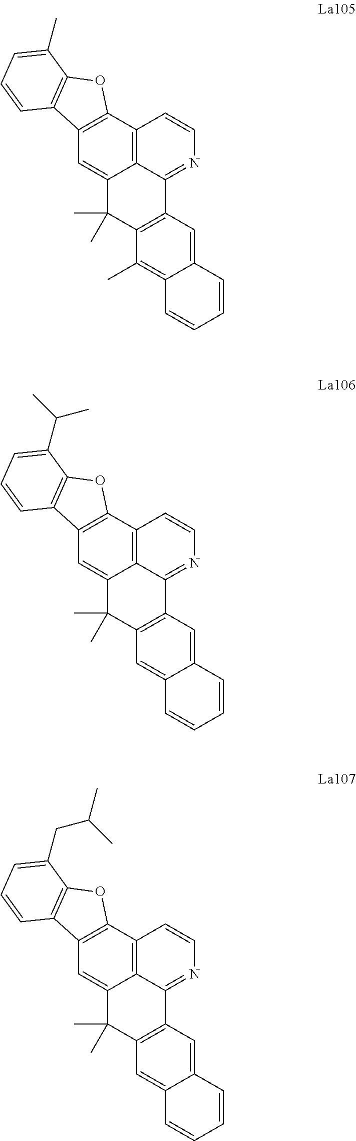 [SMILES: Cc1c2c(cc3ccccc13)-c1nccc3c1c(cc1c4cccc(C)c4oc31)C2(C)C ; CC(C)c1cccc2c1oc1c3ccnc4c3c(cc21)C(C)(C)c1cc2ccccc2cc1-4 ; CC(C)Cc1cccc2c1oc1c3ccnc4c3c(cc21)C(C)(C)c1cc2ccccc2cc1-4]

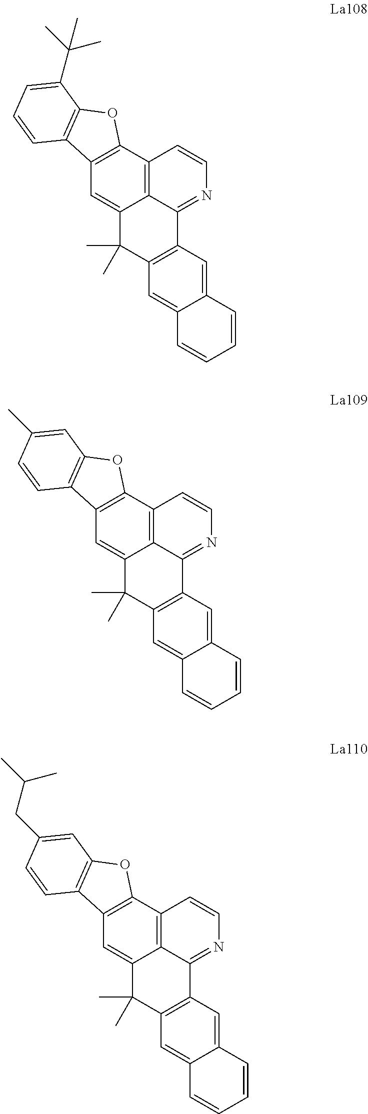 [SMILES: CC(C)(C)c1cccc2c1oc1c3ccnc4c3c(cc21)C(C)(C)c1cc2ccccc2cc1-4 ; Cc1ccc2c(c1)oc1c3ccnc4c3c(cc21)C(C)(C)c1cc2ccccc2cc1-4 ; CC(C)Cc1ccc2c(c1)oc1c3ccnc4c3c(cc21)C(C)(C)c1cc2ccccc2cc1-4]

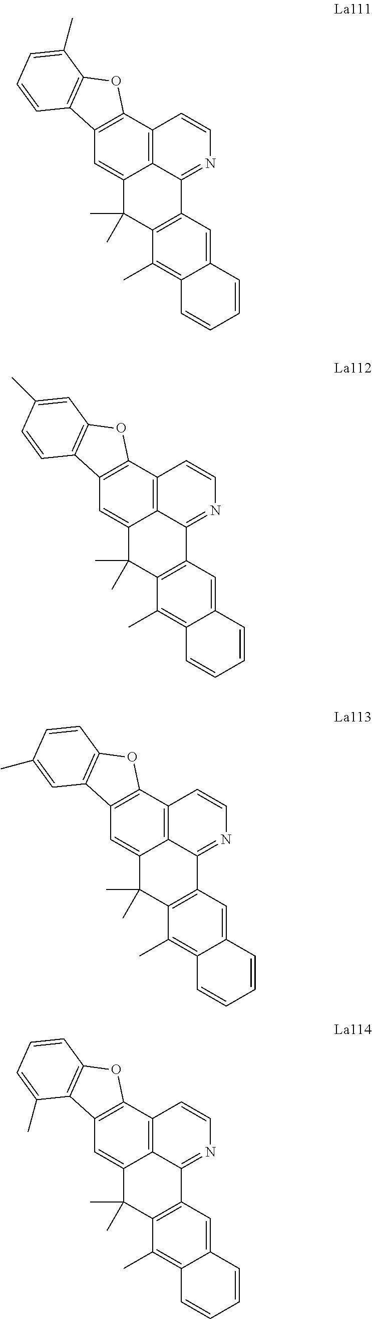 [SMILES: Cc1c2c(cc3ccccc13)-c1nccc3c1c(cc1c4cccc(C)c4oc31)C2(C)C ; Cc1ccc2c(c1)oc1c3ccnc4c3c(cc21)C(C)(C)c1c-4cc2ccccc2c1C ; Cc1ccc2oc3c4ccnc5c4c(cc3c2c1)C(C)(C)c1c-5cc2ccccc2c1C ; Cc1c2c(cc3ccccc13)-c1nccc3c1c(cc1c3oc3cccc(C)c31)C2(C)C]

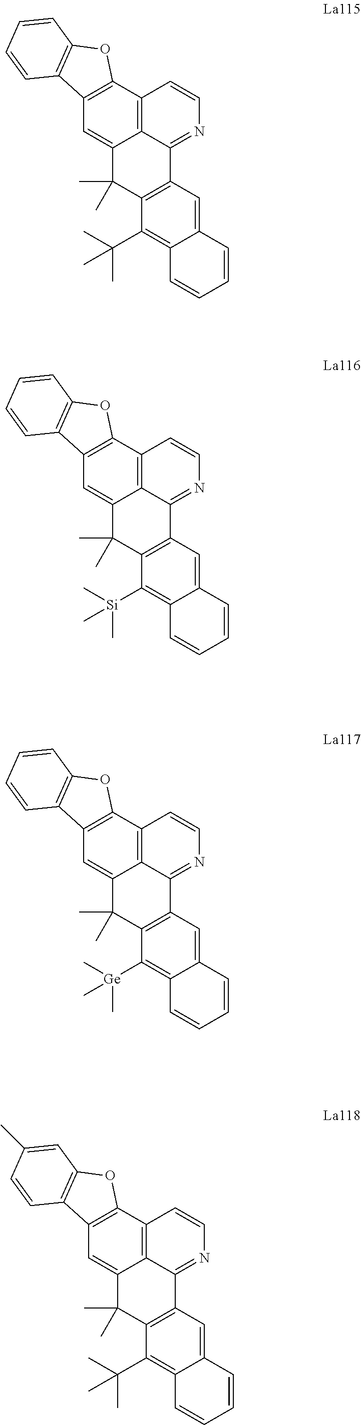

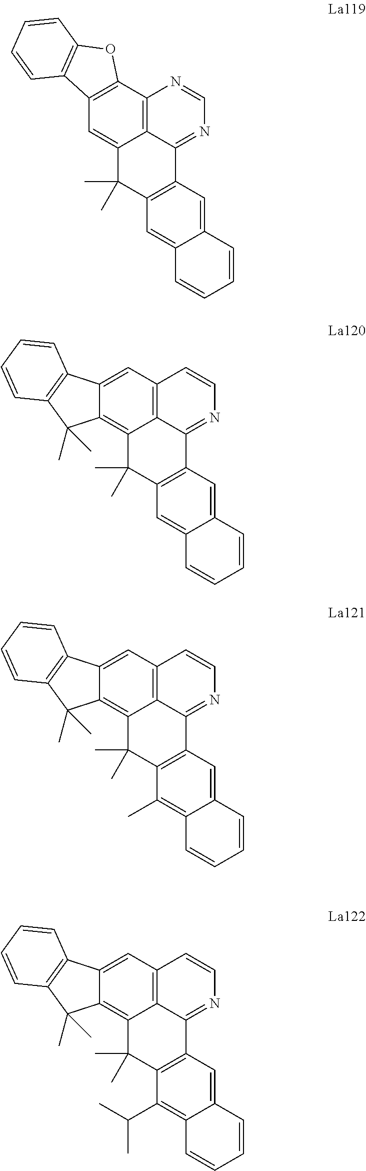 [SMILES: CC1(C)c2cc3ccccc3cc2-c2ncnc3c2c1cc1c2ccccc2oc13 ; CC1(C)c2ccccc2-c2cc3ccnc4c3c(c21)C(C)(C)c1cc2ccccc2cc1-4 ; Cc1c2c(cc3ccccc13)-c1nccc3cc4c(c(c13)C2(C)C)C(C)(C)c1ccccc1-4 ; CC(C)c1c2c(cc3ccccc13)-c1nccc3cc4c(c(c13)C2(C)C)C(C)(C)c1ccccc1-4]

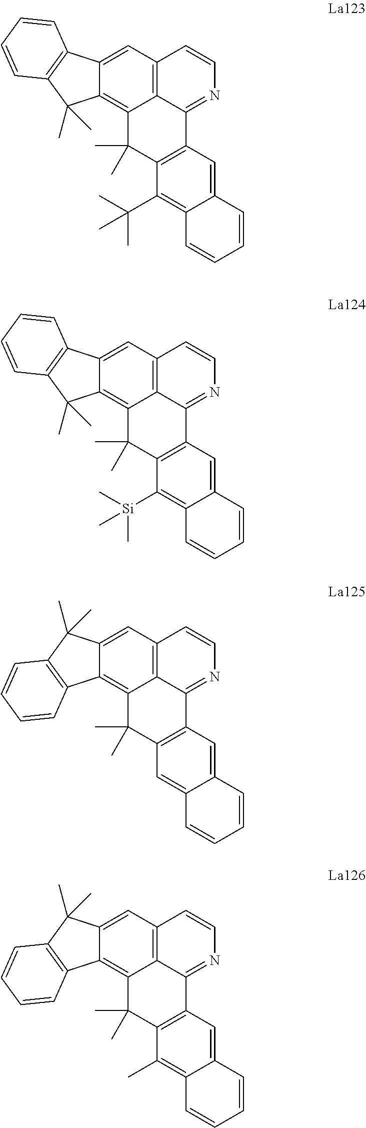 [SMILES: CC(C)(C)c1c2c(cc3ccccc13)-c1nccc3cc4c(c(c13)C2(C)C)C(C)(C)c1ccccc1-4 ; CC1(C)c2ccccc2-c2cc3ccnc4c3c(c21)C(C)(C)c1c-4cc2ccccc2c1[Si](C)(C)C ; CC1(C)c2ccccc2-c2c1cc1ccnc3c1c2C(C)(C)c1cc2ccccc2cc1-3 ; Cc1c2c(cc3ccccc13)-c1nccc3cc4c(c(c13)C2(C)C)-c1ccccc1C4(C)C]

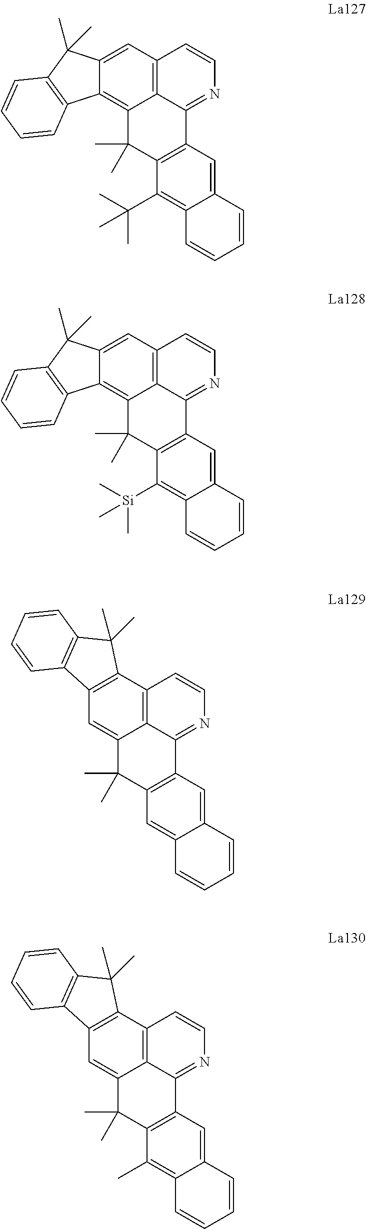 [SMILES: CC(C)(C)c1c2c(cc3ccccc13)-c1nccc3cc4c(c(c13)C2(C)C)-c1ccccc1C4(C)C ; CC1(C)c2ccccc2-c2c1cc1ccnc3c1c2C(C)(C)c1c-3cc2ccccc2c1[Si](C)(C)C ; CC1(C)c2ccccc2-c2cc3c4c(nccc4c21)-c1cc2ccccc2cc1C3(C)C ; Cc1c2c(cc3ccccc13)-c1nccc3c4c(cc(c13)C2(C)C)-c1ccccc1C4(C)C]

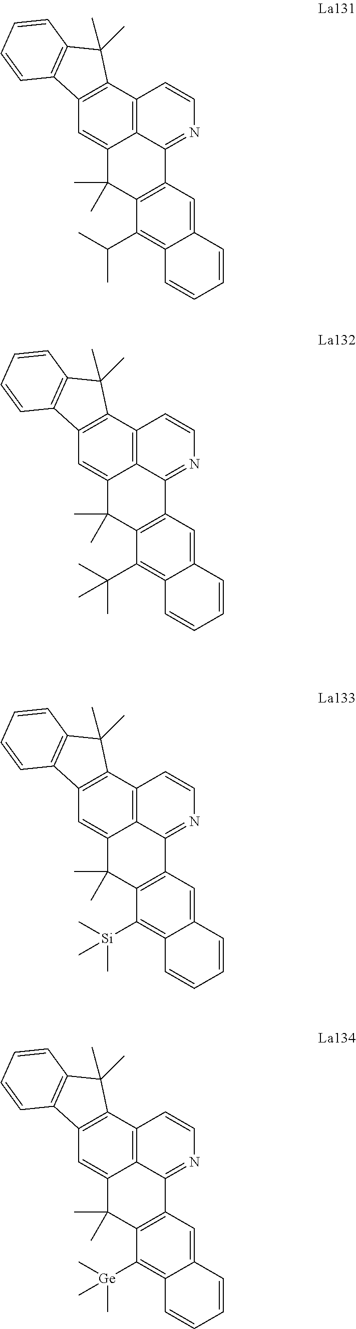

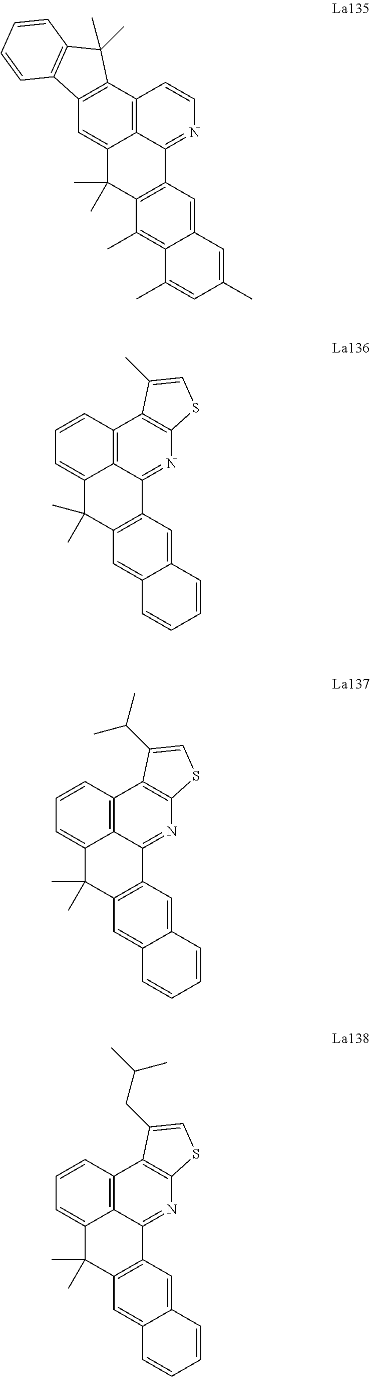

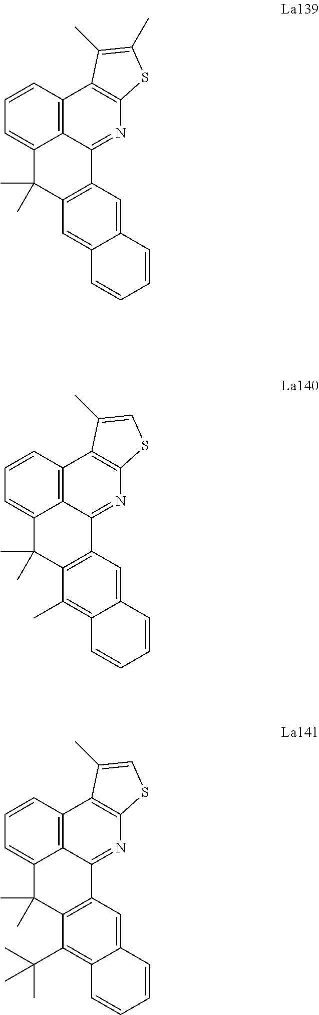 [SMILES: Cc1sc2nc3c4c(cccc4c2c1C)C(C)(C)c1cc2ccccc2cc1-3 ; Cc1c2c(cc3ccccc13)-c1nc3scc(C)c3c3cccc(c13)C2(C)C ; Cc1csc2nc3c4c(cccc4c12)C(C)(C)c1c-3cc2ccccc2c1C(C)(C)C]

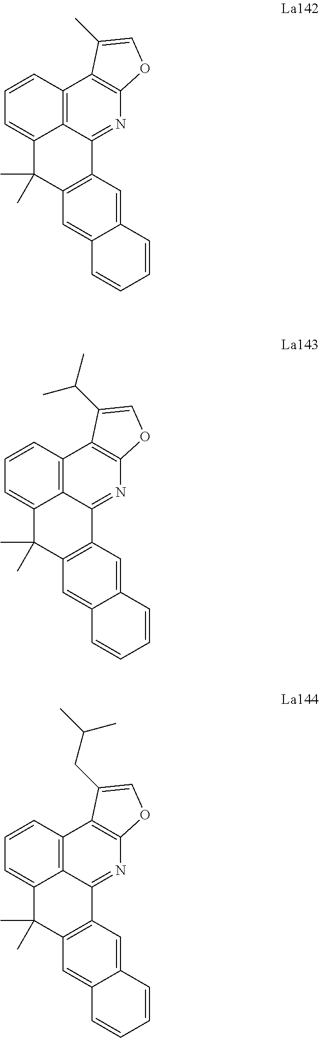 [SMILES: Cc1coc2nc3c4c(cccc4c12)C(C)(C)c1cc2ccccc2cc1-3 ; CC(C)c1coc2nc3c4c(cccc4c12)C(C)(C)c1cc2ccccc2cc1-3 ; CC(C)Cc1coc2nc3c4c(cccc4c12)C(C)(C)c1cc2ccccc2cc1-3]

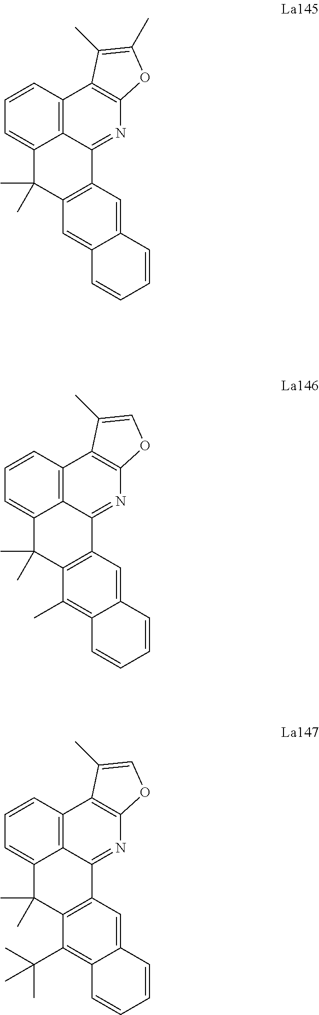 [SMILES: Cc1oc2nc3c4c(cccc4c2c1C)C(C)(C)c1cc2ccccc2cc1-3 ; Cc1c2c(cc3ccccc13)-c1nc3occ(C)c3c3cccc(c13)C2(C)C ; Cc1coc2nc3c4c(cccc4c12)C(C)(C)c1c-3cc2ccccc2c1C(C)(C)C]

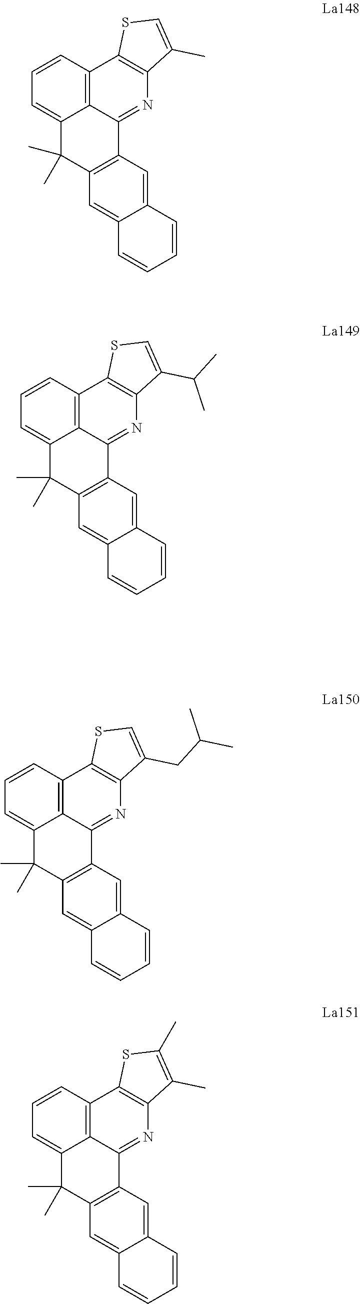

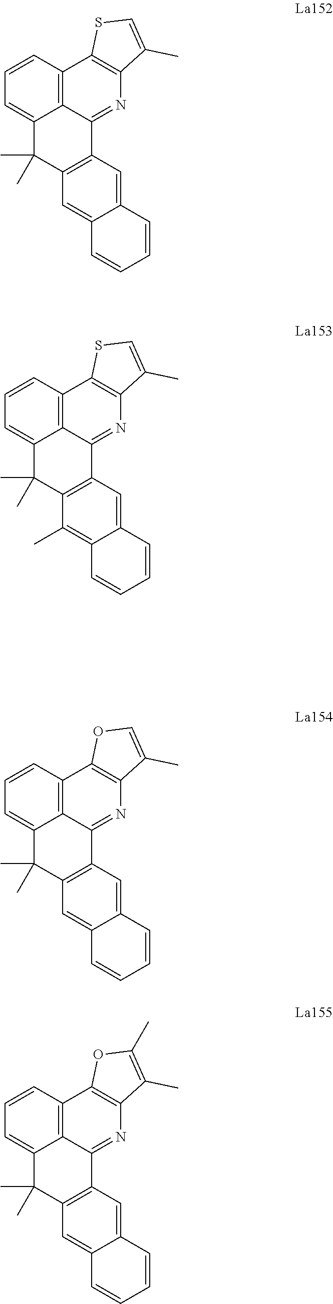

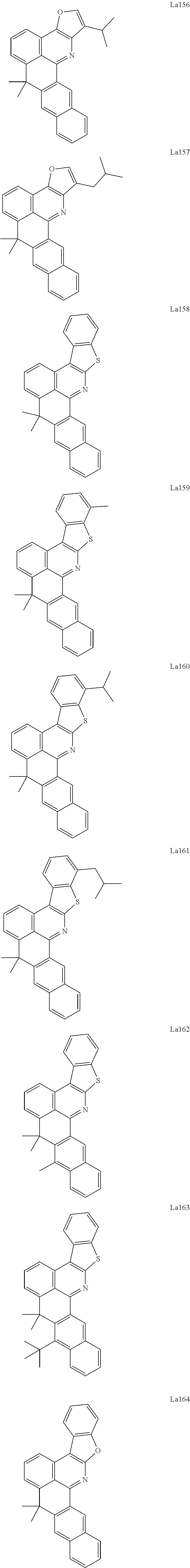

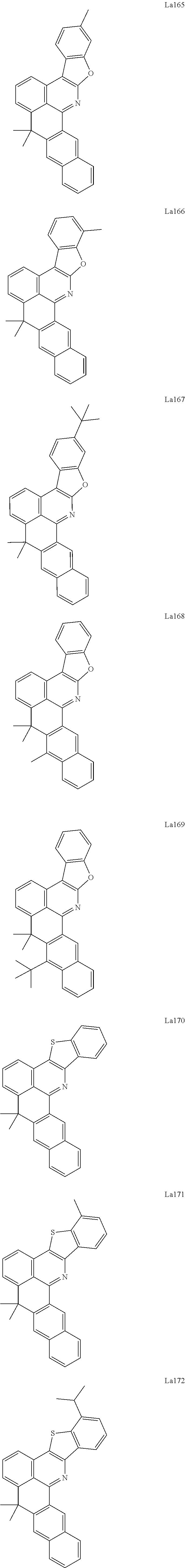

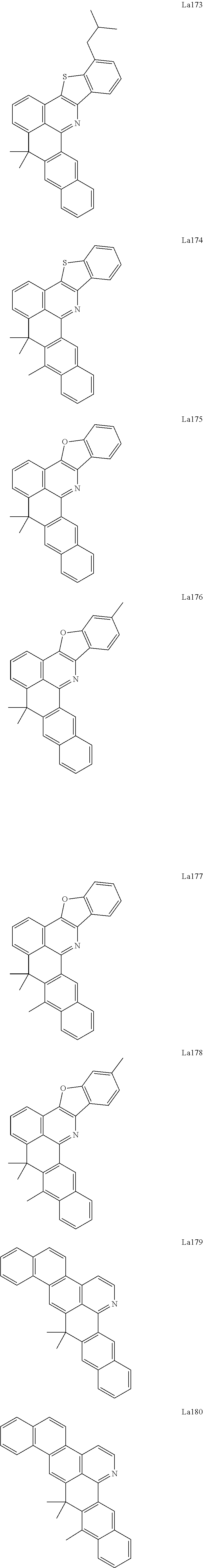

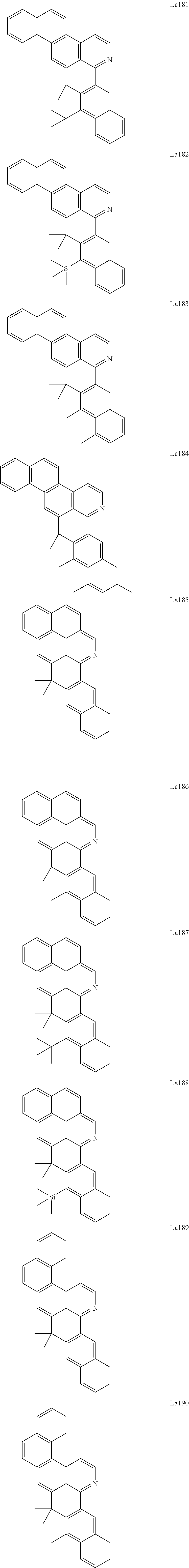

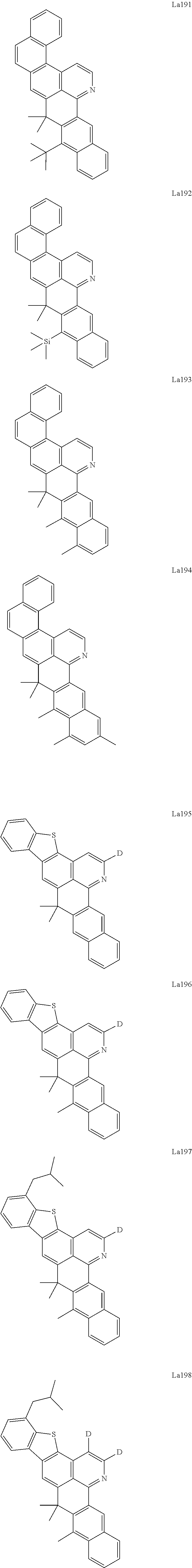

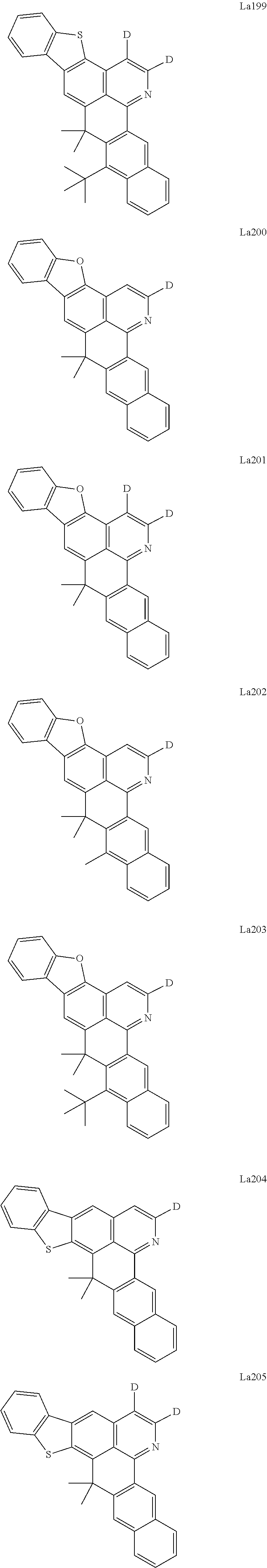

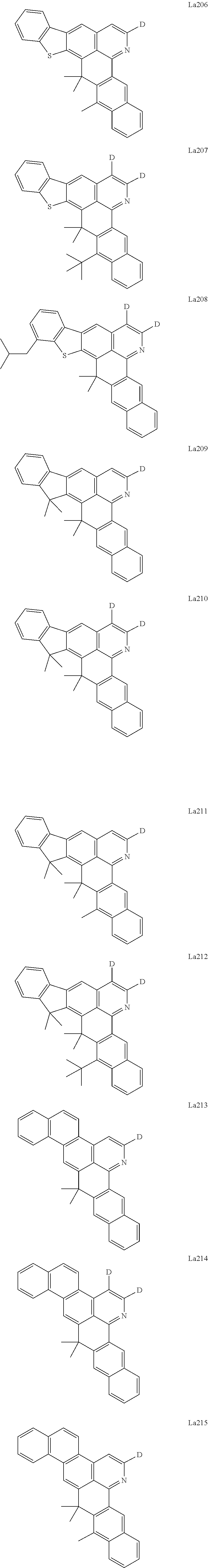

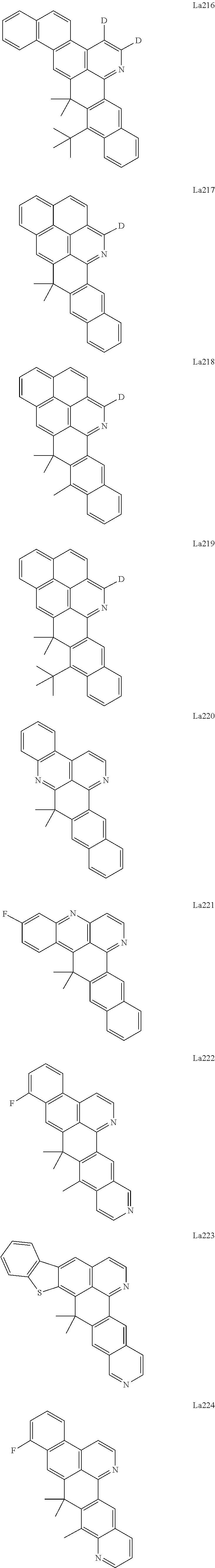

7. The metal iridium complex according to claim 1, wherein Lc and La have a same structure, and are formed a structure of (La)₂Ir(Lb).

8. The metal iridium complex according to claim 7, wherein Lb has a structure of formula (21): 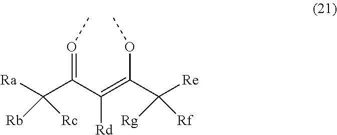
wherein a dotted line indicates a position connected to the metal iridium; and
wherein Rₐ-R_{g} are each independently selected from the group consisting of hydrogen, deuterium, halogen, a substituted or unsubstituted alkyl with 1 to 10 main-chain carbon atoms, a substituted or unsubstituted cycloalkyl with 3 to 20 ring-forming carbon atoms, a substituted or unsubstituted heteroalkyl with 1 to 10 main-chain carbon atoms, and a substituted or unsubstituted heterocycloalkyl with 3 to 20 ring-forming carbon atoms; alternatively; two of Rₐ, R_{b}, and R_{c} are connected to form an aliphatic ring structure, and two of Rₑ, R_{f}, and R_{g} are connected to form an aliphatic ring structure; and wherein substituents in Rₐ-R_{g} each refers to being substituted with deuterium, F, Cl, Br, C1-C4 alkyl, C1-C4 alkoxy, C3-C6 cycloalkyl, C1-C4 alkyl-substituted amino, cyano, isocyano, or phosphino.

9. The metal iridium complex according to claim 8, wherein Rₐ, R_{b}, and R_{c} are the same as Rₑ, R_{f}, and R_{g}, respectively.

10. The metal iridium complex according to claim 9, wherein Lb is selected from one of the following structural formulas, or one of the following structural formulas in which the hydrogen atom(s) is/are partially or completely replaced by deuterium or fluorine:

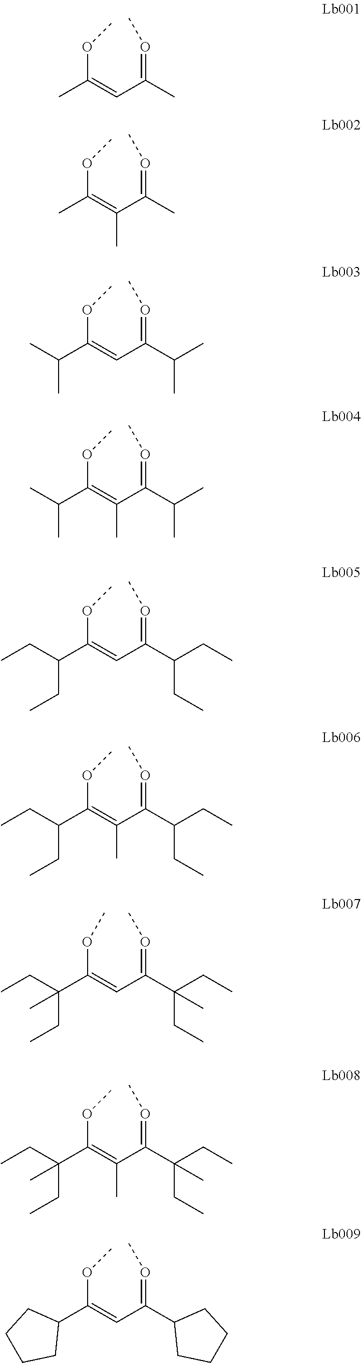

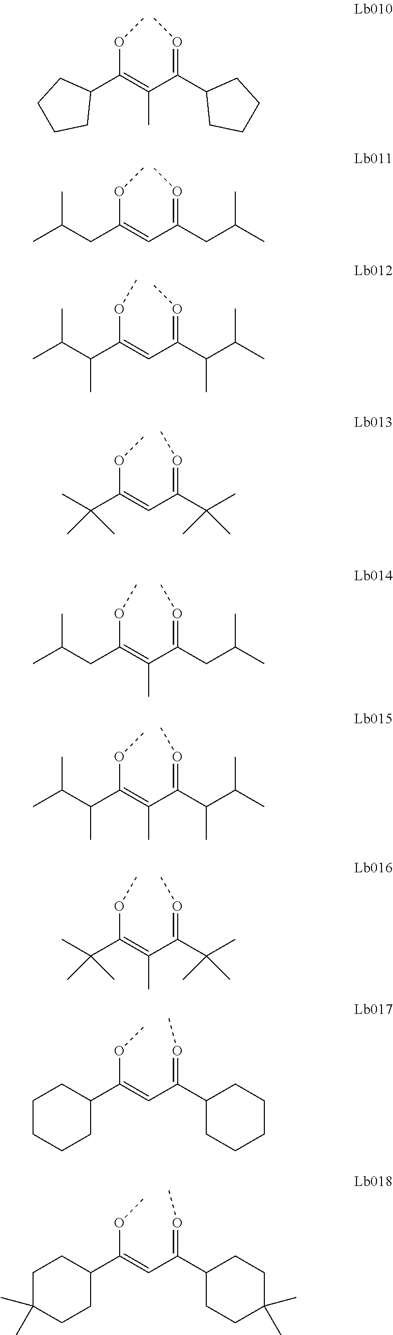

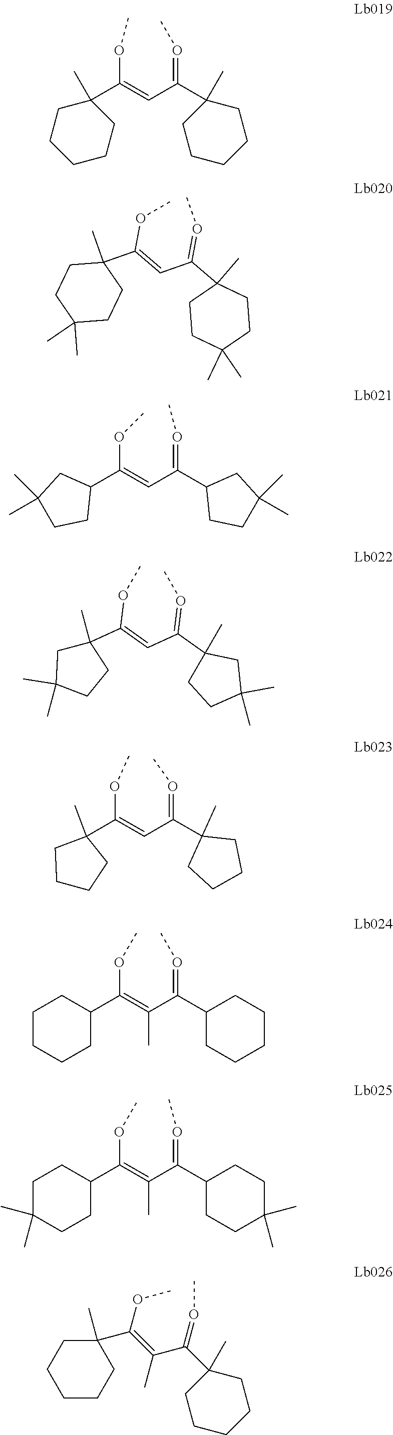

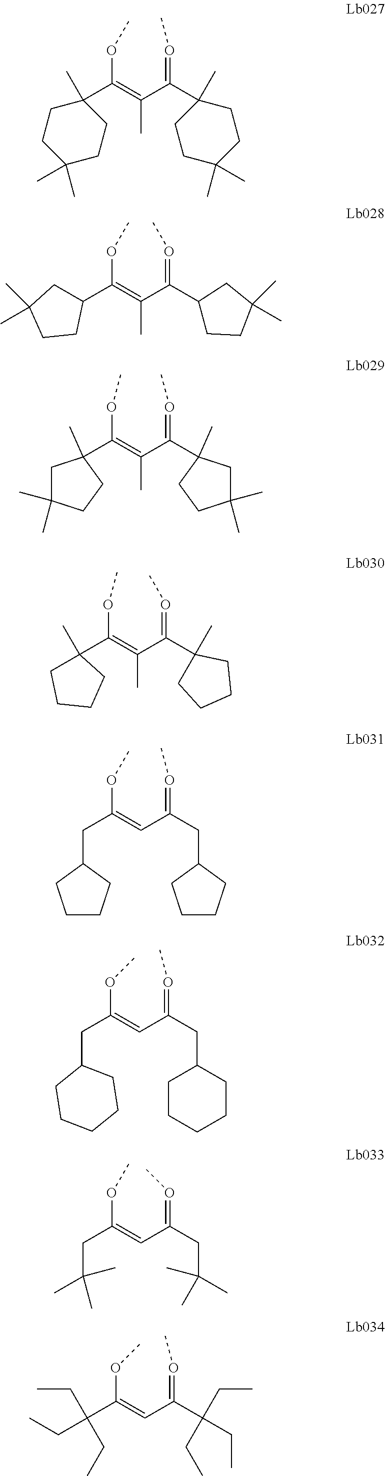

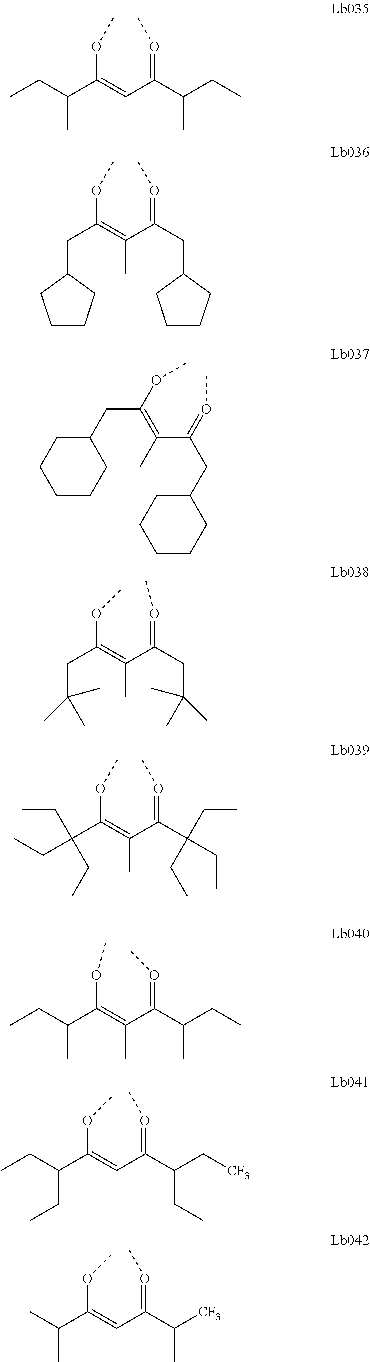

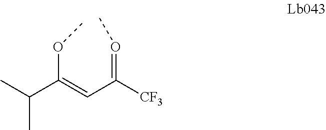

11. An electroluminescent device, comprising a cathode, an anode, and an organic layer arranged between the cathode and the anode, wherein the organic layer comprises the metal iridium complex according to claim 1.

12. The electroluminescent device according to claim 11, wherein the organic layer comprises a light-emitting layer, and the metal iridium complex serves as a light-emitting doping material of the light-emitting layer.
